(19) United States
(12) Patent Application Publication
(10) Pub. No.: US 2021/0284766 A1
(43) Pub. Date: Sep. 16, 2021

(54) RETARDATION FILM, ELLIPTICALLY POLARIZING PLATE, AND DISPLAY DEVICE INCLUDING THE SAME

(71) Applicant: DIC Corporation, Tokyo (JP)

(72) Inventors: Kouichi Endo, Kitaadachi-gun (JP); Kazuaki Hatsusaka, Kitaadachi-gun (JP); Mika Takasaki, Kitaadachi-gun (JP)

(73) Assignees: DIC Corporation, Tokyo (JP); DIC Corporation, Tokyo (JP)

(21) Appl. No.: 16/317,909

(22) PCT Filed: Jul. 6, 2017
(86) PCT No.: PCT/JP2017/024776

§ 371 Date: Jan. 15, 2019

(30) Foreign Application Priority Data
Jul. 15, 2016 (JP) 2016-140423

(51) Int. Cl. C08F 22/24; G02B 5/30; H01L 51/52; C08F 22/26; C08J 5/18

(52) U.S. Cl. CPC C08F 22/24; G02B 5/3016; G02B 5/3083; C08J 2335/02; C08F 22/26; C08J 5/18; H01L 51/5293

(57) ABSTRACT

The present application provides a retardation film that is a single film having a good antireflection function, and that maintains the function even after being exposed at high temperatures, and other objects are to provide an elliptically polarizing plate and a display device that include such retardation films. The retardation film includes a retardation layer. The optical film satisfies (Formula 1-1), Re(450)/Re(550)<1 (Formula 1-1) (wherein the retardation layer is formed of a material that is a polymerizable composition containing at least one polymerizable liquid-crystal compound selected from the group consisting of General formulas (1) to (7), and the retardation layer has a hybrid structure.

### TECHNICAL FIELD

Existing ¼-wave plates each constituted by a single retardation plate are configured to give ¼-wavelength retardation only for specified wavelengths. For this reason, when ¼-wave plates are used as antireflection filters for suppressing surface reflection of displays and the like, sufficient antireflection properties are not provided for wavelengths that are not close to the specified wavelengths at which ¼-wavelength retardation is given. Thus, displays and the like appear to be tinted with blue, violet, red, or another color, and this poor viewability has been a problem.

In order to address this problem, a retardation plate has been proposed in which a plurality of retardation plates are laminated together such that their optical axes intersect each other (Patent Literatures 1 to 3). For example, according to Patent Literature 2, the following has been reported: when a retardation ratio Re(450)/Re(550) of retardation Re(450) at a wavelength of 450 nm to retardation Re(550) at a wavelength of 550 nm is used to define wavelength characteristics of a retardation plate, a retardation plate provides good antireflection properties in which two retardation plates constituted by a retardation plate having a retardation ratio of 1.16 and the other retardation plate having a retardation ratio of 1.025 are laminated together. In addition, according to Patent Literature 3, it has been reported that a retardation plate provides good antireflection properties in which two retardation plates each having a retardation ratio of 1.005 are laminated together.

However, the retardation plates of Patent Literatures 1 to 3 each have an insufficient width of the wavelength range in which ¼-wavelength retardation is given. When such a retardation plate is laminated with a polarizing plate to produce a circularly polarizing plate, this polarizing plate also has an insufficient width of the wavelength range in which good antireflection properties are provided. Thus, displays and the like including such a retardation plate or a circularly polarizing plate have not been sufficiently improved for viewability. Specifically, reflected light inevitably occurring is slightly recognized in oblique observation of displays and the like, and the slightly recognized reflected light does not appear achromatic, but appears to be tinted with blue, violet, red, or the like, which has been problematic. In this tinting, reflection of surroundings of the viewer such as a fluorescent lamp or the sun, the reflection being tinted with blue, violet, red, or the like, appears on displays and the like. This is an extremely serious problem from the viewpoint of viewability of displays and the like.

In addition, each of Patent Literatures 1 to 3 involves lamination with an oriented film having a thickness of several tens of micrometers. As a result of this lamination, the retardation plate has a thickness of 150 to 200 μm. Thus, the retardation plate has a problem of having an excessively large thickness for displays and the like, which are always in a trend toward a reduction in thickness.

In addition, Patent Literatures 1 to 3 each use an oriented film whose slow axis is fixed in the drawing direction. Thus, the step of laminating together the retardation plate and a polarizing plate such that the slow axis of the retardation plate and the transmission axis of the polarizing plate intersect each other needs to be performed by a poorly productive film-fed process, which has been problematic.

On the other hand, Patent Literature 4 describes a retardation plate that is useful as a wide-wavelength-range retardation plate and that uses a compound having reverse wavelength dispersion characteristics. However, this does not perfectly compensate for oblique incident light, and viewing-angle characteristics are poor, which has been problematic.

Incidentally, displays used for smartphones and the like are often required to have high reliability. Thus, there has been a demand for optical characteristics that substantially do not change after exposure at high temperatures.

### CITATION LIST

### Patent Literature

### PTL 1: Japanese Unexamined Patent Application Publication No. 10-68816

### PTL 2: Japanese Unexamined Patent Application Publication No. 10-90521

### PTL 3: Japanese Unexamined Patent Application Publication No. 11-52131

### PTL 4: Japanese Unexamined Patent Application Publication No. 2002-267838

### SUMMARY OF INVENTION

### Technical Problem

An object of the present invention is to provide a retardation film that is a single film having a good antireflection function, and that maintains the function even after being exposed at high temperatures. Other objects of the present invention are to provide an elliptically polarizing plate and a display device that include such retardation films.

### Solution to Problem

In order to achieve the above-described objects, thorough studies have been performed and, as a result, the present invention has been conceived.

Specifically, the present invention provides a retardation film including a retardation layer, wherein the optical film satisfies (Formula 1-1), Re(450)/Re(550)<1 (Formula 1-1) (where Re(450) represents in-plane retardation at a wavelength of 450 nm, and Re(550) represents in-plane retardation at a wavelength of 550 nm), the retardation layer is formed of a material that is a polymerizable composition containing at least one polymerizable liquid-crystal compound selected from the group consisting of General formulas (1) to (7), and the retardation layer has a hybrid structure.

The present invention also provides an elliptically polarizing plate, a display device, and an organic light-emitting display device that include the retardation film.

### Advantageous Effects of Invention

A retardation film according to the present invention has optical characteristics suitable for providing an antireflection function, so that it suppresses surface reflection on various display devices. In particular, when the retardation film is used for organic EL displays, high viewability is provided. In addition, the retardation film maintains its characteristics and function even after exposure at high temperatures, and hence is optimal for display devices for outdoor use, for example.

### DESCRIPTION OF EMBODIMENTS

Hereinafter, best modes of a retardation film according to the present invention will be described.

A retardation film according to the present invention is a retardation film that exhibits reverse wavelength dispersion characteristics and satisfies (Formula 1-1). Re(450 nm)/Re (550 nm)<1.0 (Formula 1-1) (where Re (450 nm) represents in-plane retardation at a wavelength of 450 nm of a retardation film according to the present invention, and Re (550 nm) represents in-plane retardation at a wavelength of 550 nm).

The retardation film more preferably satisfies (Formula 1-2) below, still more preferably satisfies (Formula 1-3) below.

0.7<Re(450 nm)/Re(550 nm)<0.9 (Formula 1-2)

0.8<Re(450 nm)/Re(550 nm)<0.87 (Formula 1-3)

### BRIEF DESCRIPTION OF DRAWINGS

FIG. 1 is a conceptual view illustrating a hybrid structure according to the present invention in terms of the alignment state and tilt angles.

FIG. 2 is a conceptual view illustrating another hybrid structure according to the present invention in terms of the alignment state and tilt angles; this hybrid structure is an inverted structure relative to FIG. 1 in terms of the substrate interface and the air interface.

FIG. 3 is a conceptual view, in a case where liquid-crystal molecules in a polymerizable liquid-crystal composition have a twist angle, the conceptual view illustrating the twist angle, and an alignment state having a twisted structure in the substrate plane.

### LIQUID-CRYSTAL COMPOUND

A polymerizable composition used for this retardation film contains a polymerizable liquid-crystal compound, and the polymerizable liquid-crystal compound is selected from the group consisting of General formulas (1) to (7). Incidentally, in the present invention, the term “liquid-crystal compound” means a compound having a mesogenic skeleton, and the compound alone may not necessarily exhibit liquid crystallinity. Another term “polymerizable” means that a polymerization treatment of irradiation with light such as ultraviolet light or heating turns the compound into a polymer (film). The compounds represented by General formulas (1) to (7) exhibit, when being aligned, reverse wavelength dispersion characteristics.

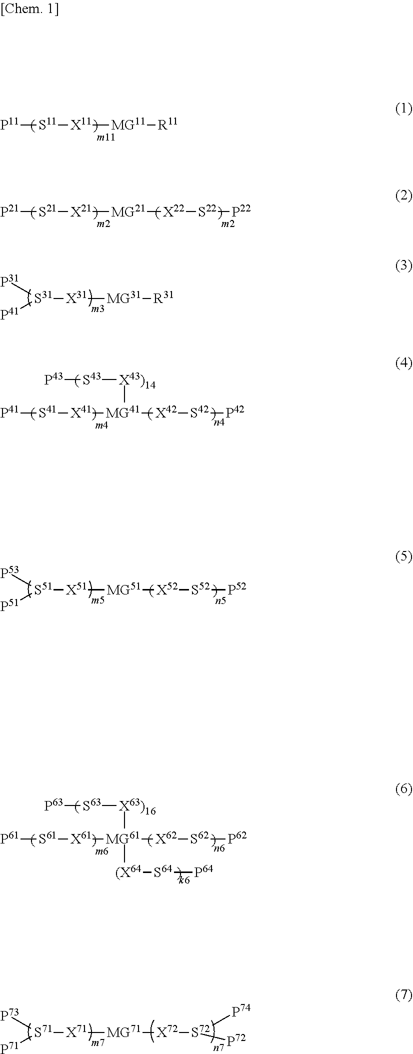

(where P¹ to P⁷⁴ represent a polymerizable group,

S¹¹ to S⁷² represent a spacer group or a single bond; when a plurality of S¹¹'s to S⁷²'s are present, they may be the same or different,

X¹¹ to X⁷² represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C═C—, or a single bond; when a plurality of X¹¹'s to X⁷²'s are present, they may be the same or different (provided that the P—(S—X)— bonds do not include —O—O—),

MG¹¹ to MG⁷ each independently represent Formula (a),

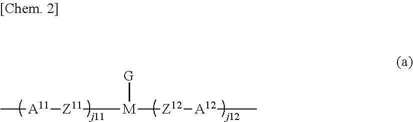

(where

A¹¹ and A¹² each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group; these groups may be unsubstituted or may be substituted by at least one L¹; when a plurality of A¹¹'s and/or A¹²'s are present, they may be the same or different,

Z¹ and Z¹ each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C═C—, or a single bond; when a plurality of Z¹¹'s and/or Z¹'s are present, they may be the same or different,

M represents a group selected from Formula (M-1) to Formula (M-11) below,

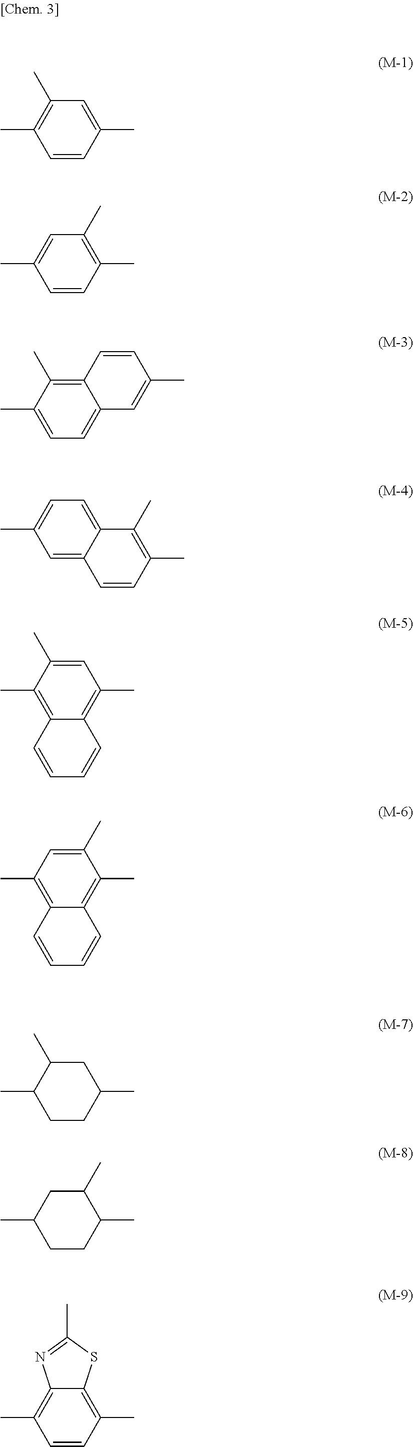

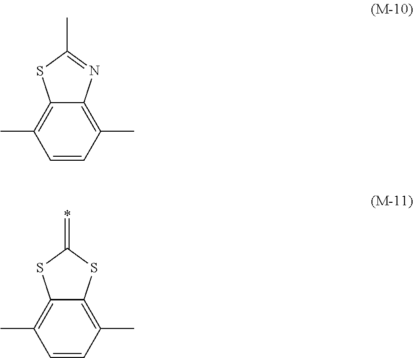

these groups may be unsubstituted or may be substituted by at least one L

G represents Formula (G-1) to Formula (G-6) below,

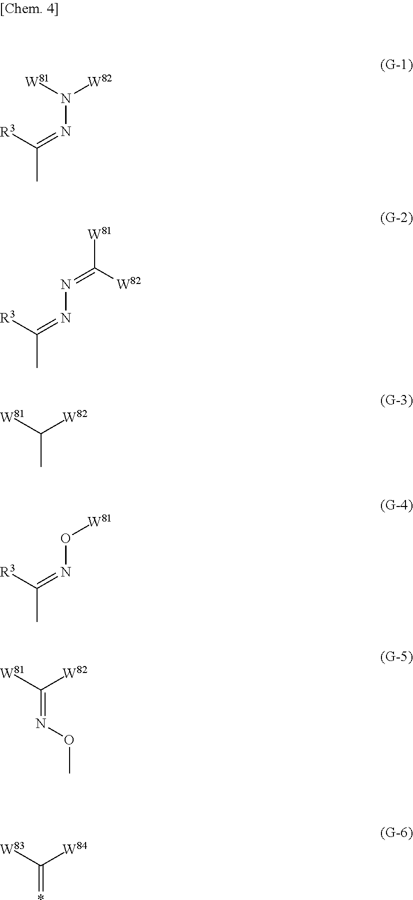

(where R³ represents a hydrogen atom or an alkyl group having 1 to 20 carbon atoms; the alkyl group may be linear or branched; any hydrogen atom in the alkyl group may be substituted by a fluorine atom; in the alkyl group, one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, or —C═C—,

W⁸¹ represents a group having 5 to 30 carbon atoms and having at least one aromatic group, and the group may be unsubstituted or may be substituted by at least one L

W⁸² represents a hydrogen atom or an alkyl group having 1 to 20 carbon atoms; the alkyl group may be linear or branched; any hydrogen atom in the alkyl group may be substituted by a fluorine atom and/or —OH; in the alkyl group, one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C═C—; W⁸² may be defined as with W⁸¹; W⁸¹ and W⁸² may be linked together to form a single ring structure; W⁸² may represent a group represented by P⁸—(S⁸—X⁸)ⱼ— where P⁸ represents a polymerizable group, S⁸ represents a spacer group or a single bond, when a plurality of S⁸'s are present, they may be the same or different, X⁸ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C═C—, or a single bond, when a plurality of X⁸'s are present, they may be the same or different (provided that P⁸—(S⁸—X⁸)ⱼ— does not include any —O—O— bond) where j represents an integer of 0 to 10,

W⁸³ and W⁸⁴ each independently represent a halogen atom, a cyano group, a hydroxy group, a nitro group, a carboxyl group, a carbamoyloxy group, an amino group, a sulfamoyl group, a group having 5 to 30 carbon atoms and having at least one aromatic group, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms; in the alkyl group, cycloalkyl group, alkenyl group, cycloalkenyl group, alkoxy group, acyloxy group, and alkylcarbonyloxy group, one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, or —C═C—; provided that, when M is selected from Formula (M-1) to Formula (M-10) above, G is selected from Formula (G-1) to Formula (G-5); when M is represented by Formula (M-11), G is represented by Formula (G-6),

L¹ represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms; the alkyl group may be linear or branched; any hydrogen atom may be substituted by a fluorine atom; in the alkyl group, one —CH₂— or non-adjacent two or more —CH₂— may each be independently substituted by a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, and —C═C—; when a plurality of L¹'s are present in a compound, they may be the same or different,

j11 represents an integer of 1 to 5, j12 represents an integer of 1 to 5, provided that j11+j12 is an integer of 2 to 5), R¹¹ and R³¹ represent a hydrogen atom, a fluorine atom, a chlorine atom, a bromine atom, an iodine atom, a pentafluorosulfuranyl group, a cyano group, a nitro group, an isocyano group, a thioisocyano group, or an alkyl group having 1 to 20 carbon atoms; the alkyl group may be linear or branched; any hydrogen atom in the alkyl group may be substituted by a fluorine atom; in the alkyl group, one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, or —C═C—; m11 represents an integer of 0 to 8; and m2 to m7, n2 to n7, l4 to l6, and k6 each independently represent an integer of 0 to 5).

In General formula (1) to General formula (7), the polymerizable groups P¹¹ to P⁷⁴ preferably represent groups selected from Formula (P-1) to Formula (P-20) below.

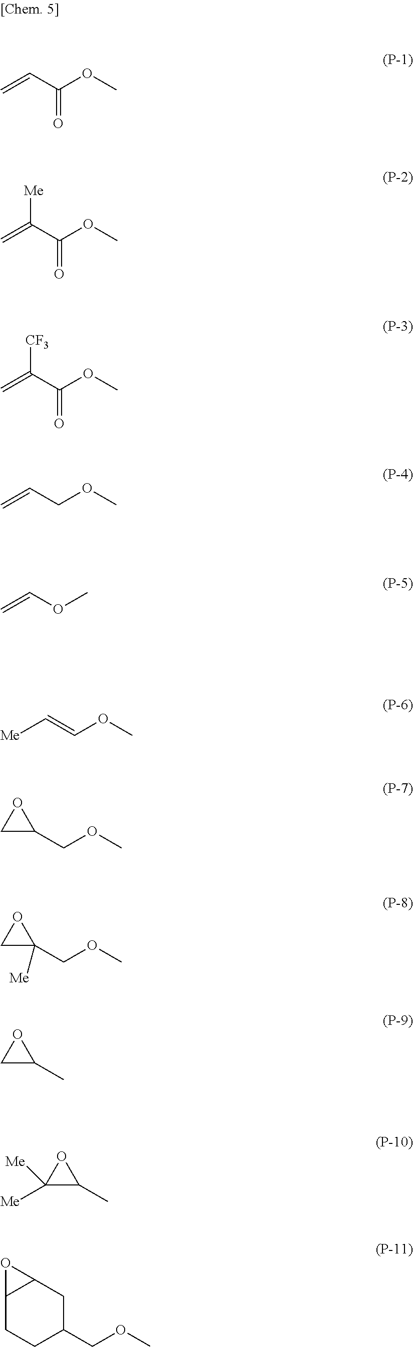

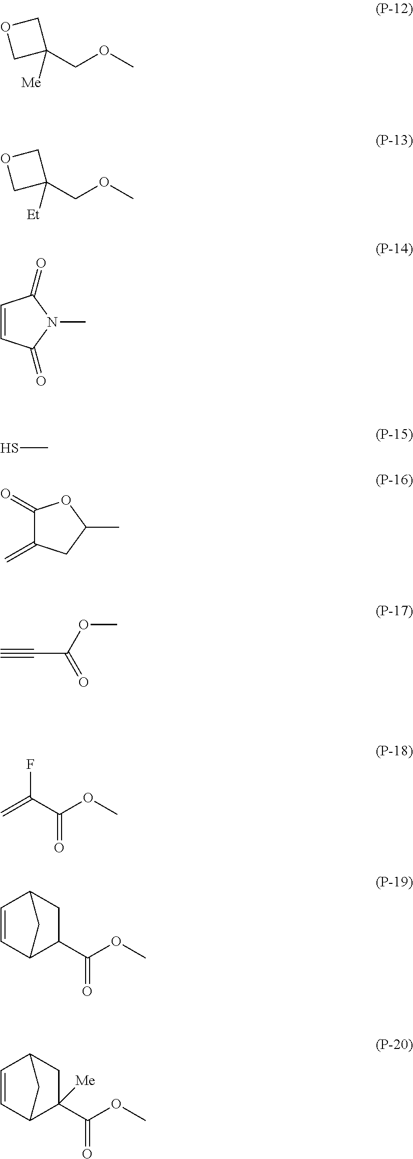

These polymerizable groups are polymerized by radical polymerization, radical addition polymerization, cationic polymerization, or anionic polymerization. In particular, when a polymerization method by ultraviolet polymerization is performed, preferred are Formula (P-1), Formula (P-2), Formula (P-3), Formula (P-4), Formula (P-5), Formula (P-7), Formula (P-11), Formula (P-13), Formula (P-15), and Formula (P-18); more preferred are Formula (P-1), Formula (P-2), Formula (P-7), Formula (P-11), and Formula (P-13); still more preferred are Formula (P-1), Formula (P-2), and Formula (P-3); and particularly preferred are Formula (P-1) and Formula (P-2).

In General formula (1) to General formula (7), S¹¹ to S⁷² represent a spacer group or a single bond; when a plurality of S¹¹'s to S⁷²'s are present, they may be the same or different. The spacer group is preferably an alkylene group having 1 to 20 carbon atoms in which one —CH₂— or non-adjacent two or more —CH₂— may each be independently substituted by —O—, —COO—, —OCO—, —OCO—O—, —CO—NH—, —NH—CO—, —CH═CH—, —C═C—, or Formula (S-1) below.

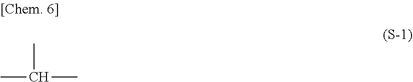

When a plurality of S's are present, they may be the same or different from the viewpoint of high availability of raw material and ease of synthesis; more preferably, each independently represent a single bond or an alkylene group having 1 to 10 carbon atoms in which one —CH₂— or non-adjacent two or more —CH₂— may each be independently substituted by —O—, —COO—, or —OCO—; still more preferably, each independently represent an alkylene group having 1 to 10 carbon atoms or a single bond; particularly preferably, when a plurality of S's are present, they may be the same or different and may each independently represent an alkylene group having 1 to 8 carbon atoms.

In General formula (1) to General formula (7), X¹ to X² represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C═C—, or a single bond; when a plurality of X¹¹'s to X⁷²'s are present, they may be the same or different (provided that the P—(S—X)-bonds do not include —O—O—). From the viewpoint of high availability of raw material and ease of synthesis, when a plurality of X¹¹'s to X⁷²'s are present, they may be the same or different, and they preferably each independently represent —O—, —S—, —OCH₂—, —CH₂O—, —COO—, —OCO—, —CO—S—, —S—CO—, —O—CO—O—, —CO—NH—, —NH—CO—, —COO—CH₂CH₂—, —OCO—CH₂CH₂—, —CH₂CH₂—COO—, —CH₂CH₂—OCO—, or a single bond; more preferably each independently represent —O—, —OCH₂—, —CH₂O—, —COO—, —OCO—, —COO—CH₂CH₂—, —OCO—CH₂CH₂—, —CH₂CH₂—COO—, —CH₂CH₂—OCO—, or a single bond; in particular, preferably, when a plurality of X¹¹'s to X⁷²'s are present, they may be the same or different, and each independently represent —O—, —COO—, —OCO—, or a single bond.

In General formula (1) to General formula (7), A¹¹ and A¹ each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group; these groups may be unsubstituted or may be substituted by at least one L; when a plurality of A¹¹'s and/or A¹'s are present, they may be the same or different. From the viewpoint of high availability of raw material and ease of synthesis, A¹¹ and A¹² preferably each independently represent a 1,4-phenylene group, a 1,4-cyclohexylene group, or naphthalene-2,6-diyl that may be unsubstituted or may be substituted by at least one L¹; more preferably, each independently represent a group selected from the following Formula (A-1) to Formula (A-11),

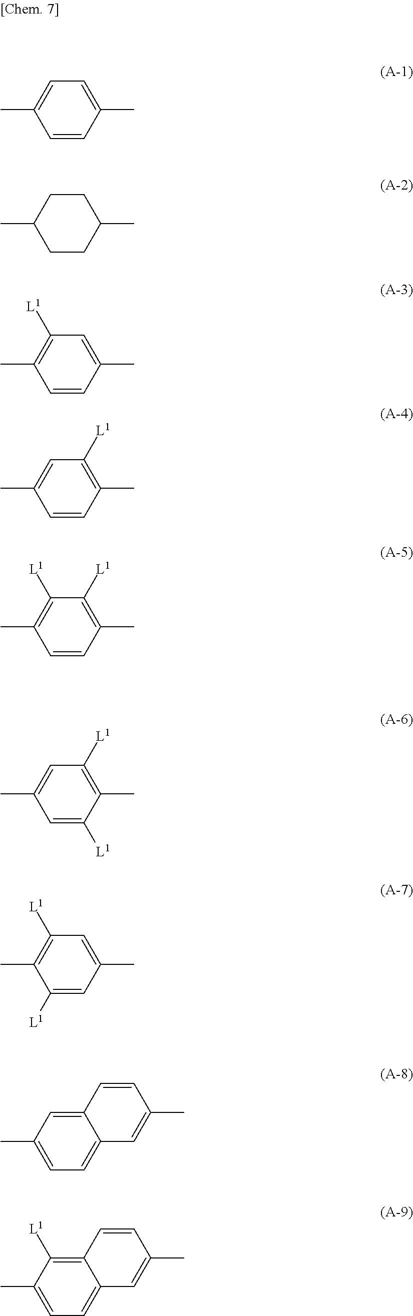

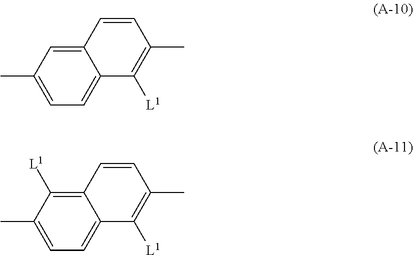

still more preferably, each independently represent a group selected from Formula (A-1) to Formula (A-8); particularly preferably each independently represent a group selected from Formula (A-1) to Formula (A-4).

In General formula (1) to General formula (7), Z¹¹ and Z¹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —OCO—NH—, —NH—COO—, —NH—CO—NH—, —NH—O—, —O—NH—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C═C—, or a single bond; when a plurality of Z¹¹'s and/or Z¹'s are present, they may be the same or different. From the viewpoint of liquid crystallinity of the compound, high availability of raw material, and ease of synthesis, Z¹¹ and Z¹² preferably each independently represent a single bond, —OCH₂—, —CH₂O—, —COO—, —OCO—, —CF₂O—, —OCF₂—, —CH₂CH₂—, —CF₂CF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —CH═CH—, —CF═CF—, —C═C—, or a single bond; more preferably each independently represent —OCH₂—, —CH₂O—, —CH₂CH₂—, —COO—, —OCO—, —COO—CH₂CH₂—, —OCO—CH₂CH₂—, —CH₂CH₂—COO—, —CH₂CH₂—OCO—, —CH═CH—, —C═C—, or a single bond; still more preferably each independently represent —CH₂CH₂—, —COO—, —OCO—, —COO—CH₂CH₂—, —OCO—CH₂CH₂—, —CH₂CH₂—COO—, —CH₂CH₂—OCO—, or a single bond; particularly preferably each independently represent —CH₂CH₂—, —COO—, —OCO—, or a single bond.

In General formula (1) to General formula (7), M's represent a group selected from the following Formula (M-1) to Formula (M-11).

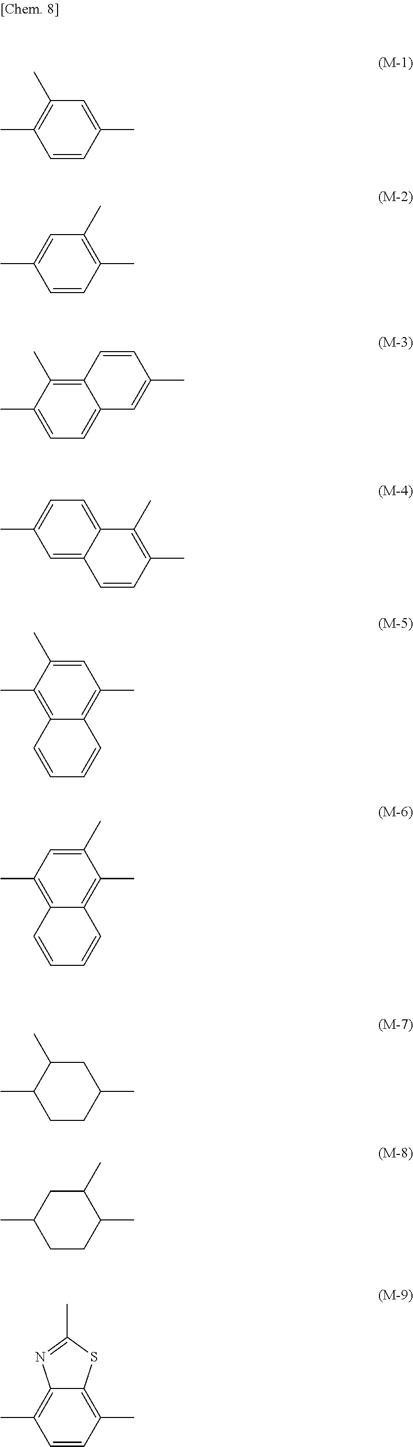

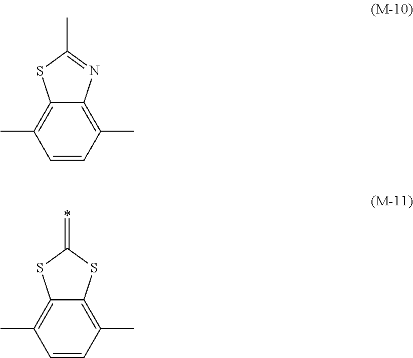

These groups may be unsubstituted or may be substituted by at least one L¹. From the viewpoint of high availability of raw materials and ease of synthesis, M's preferably each independently represent a group selected from Formula (M-1) and Formula (M-2) that may be unsubstituted or may be substituted by at least one L¹, or Formula (M-3) to Formula (M-6) that are unsubstituted; more preferably represent a group selected from Formula (M-1) and Formula (M-2) that may be unsubstituted or may be substituted by at least one L particularly preferably represent a group selected from Formula (M-1) and Formula (M-2) that are unsubstituted.

In General formula (1) to General formula (7), R¹¹ and R³¹ represent a hydrogen atom, a fluorine atom, a chlorine atom, a bromine atom, an iodine atom, a pentafluorosulfuranyl group, a cyano group, a nitro group, an isocyano group, a thioisocyano group, or a linear or branched alkyl group having 1 to 20 carbon atoms in which one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, or —C═C—; in the alkyl group, any hydrogen atom may be substituted by a fluorine atom. From the viewpoint of liquid crystallinity and ease of synthesis, R¹ preferably represents a hydrogen atom, a fluorine atom, a chlorine atom, a cyano group, or a linear or branched alkyl group having 1 to 12 carbon atoms in which one —CH₂— or non-adjacent two or more —CH₂— may each be independently substituted by —O—, —COO—, —OCO—, or —O—CO—O—; more preferably represents a hydrogen atom, a fluorine atom, a chlorine atom, a cyano group, or a linear alkyl group or linear alkoxy group having 1 to 12 carbon atoms; particularly preferably represents a linear alkyl group or linear alkoxy group having 1 to 12 carbon atoms.

In General formula (1) to General formula (7), G represents a group selected from Formula (G-1) to Formula (G-6).

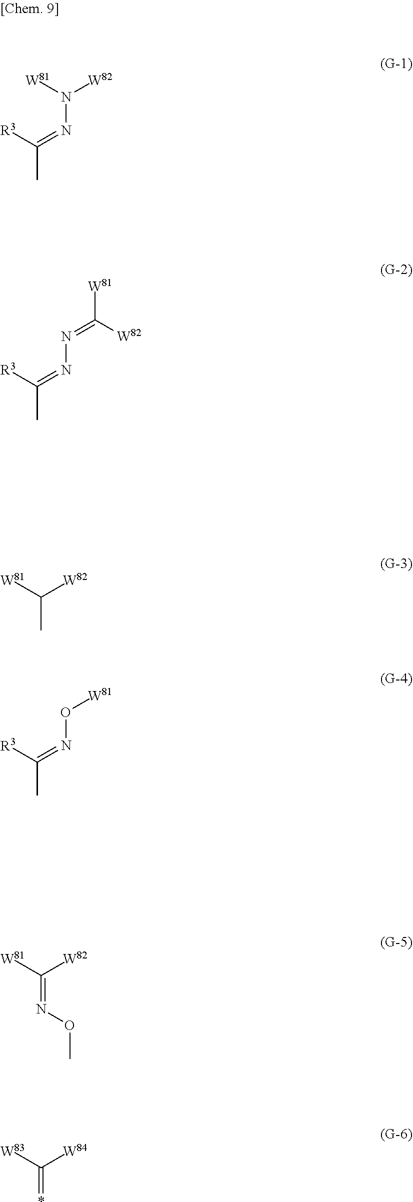

In these formulas, R³ represents a hydrogen atom or an alkyl group having 1 to 20 carbon atoms; the alkyl group may be linear or branched; any hydrogen atom in the alkyl group may be substituted by a fluorine atom; in the alkyl group, one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, or —C═C—,

W⁸¹ represents a group having 5 to 30 carbon atoms and having at least one aromatic group, and the group may be unsubstituted or may be substituted by at least one L¹, and

W⁸² represents a hydrogen atom or an alkyl group having 1 to 20 carbon atoms; the alkyl group may be linear or branched; any hydrogen atom in the alkyl group may be substituted by a fluorine atom; in the alkyl group, one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C═C—; W⁸² may be defined as with W⁸¹; or W⁸¹ and W⁸² may be linked together to form a ring structure.

The aromatic group included in W⁸¹ may be an aromatic hydrocarbon group or an aromatic hetero group, or may include both of these groups. Such an aromatic group may be bonded with a single bond or a linking group (—OCO—, —COO—, —CO—, or —O—), or may form a condensed ring. W⁸¹ may include, in addition to the aromatic group, an acyclic structure and/or a cyclic structure other than aromatic groups. From the viewpoint of high availability of raw material and ease of synthesis, the aromatic group included in W⁸¹ may be unsubstituted or represented by the following Formula (W-1) to Formula (W-19) that may be substituted by at least one L¹.

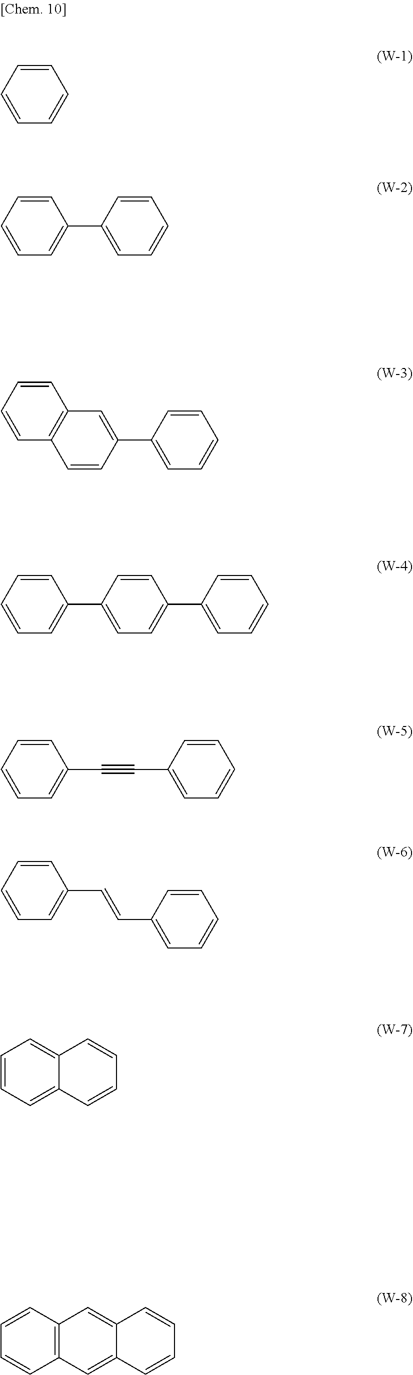

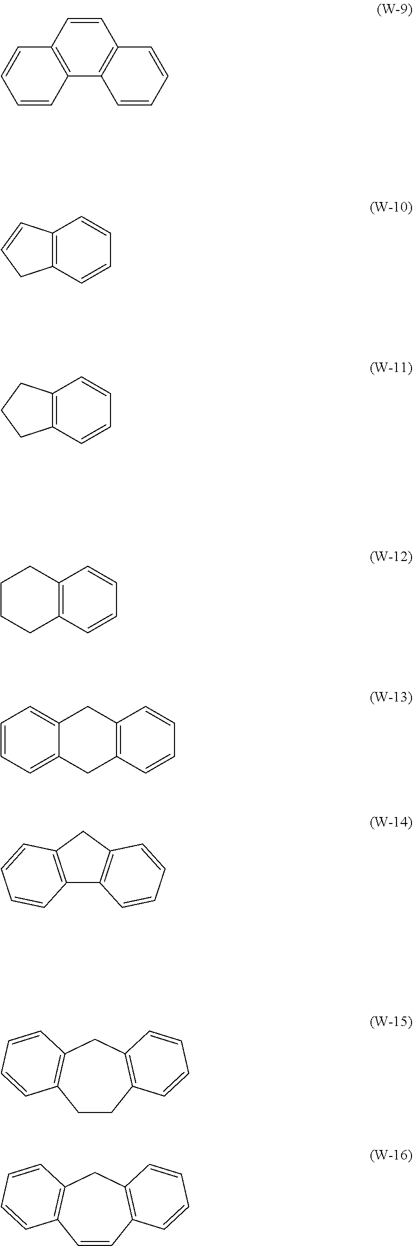

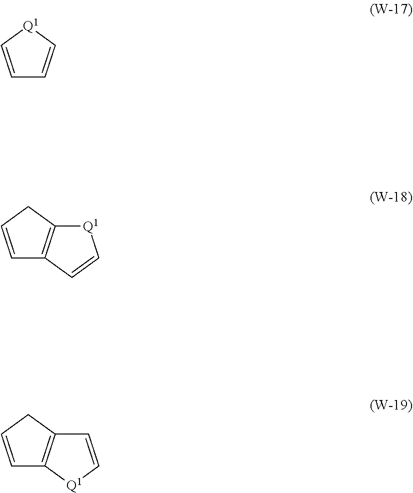

(where these groups may have bonds at any points; two or more aromatic groups selected from these groups may be bonded together with a single bond to form a group; Q represents —O—, —S—, —NR⁴— (where R⁴ represents a hydrogen atom or an alkyl group having 1 to 8 carbon atoms), or —CO—. In these aromatic groups, —CH═ may each be independently substituted by —N═; —CH₂— may each be independently substituted by —O—, —S—, —NR⁴— (where R⁴ represents a hydrogen atom or an alkyl group having 1 to 8 carbon atoms), or —CO—, provided that the groups do not include any —O—O-bonds. The group represented by Formula (W-1) is preferably a group selected from the following Formula (W-1-1) to Formula (W-1-8) that may be unsubstituted or may be substituted by at least one L¹,

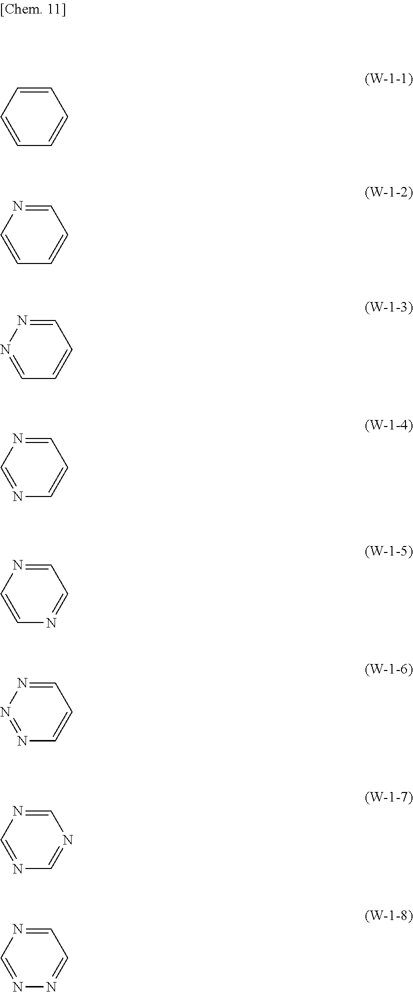

(where these groups may have bonds at any points) The group represented by Formula (W-7) is preferably a group selected from the following Formula (W-7-1) to Formula (W-7-7) that may be unsubstituted or may be substituted by at least one L¹,

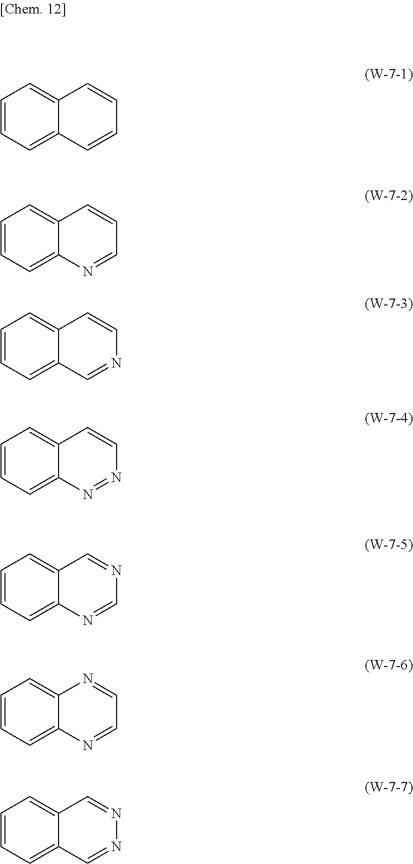

(where these groups may have bonds at any points). The group represented by Formula (W-10) is preferably a group selected from the following Formula (W-10-1) to Formula (W-10-8) that may be unsubstituted or may be substituted by at least one L¹,

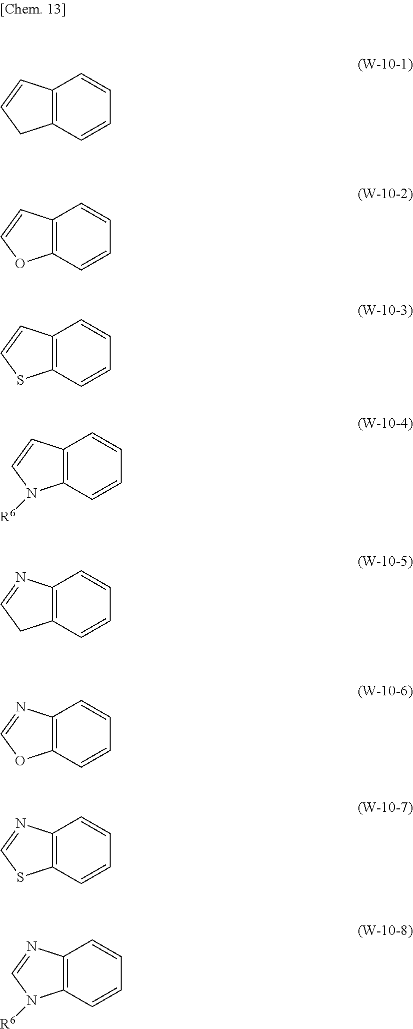

(where these groups may have bonds at any points, and R⁶ represents a hydrogen atom or an alkyl group having 1 to 8 carbon atoms). The group represented by Formula (W-11) is preferably a group selected from the following Formula (W-11-1) to Formula (W-11-13) that may be unsubstituted or that may be substituted by at least one L¹,

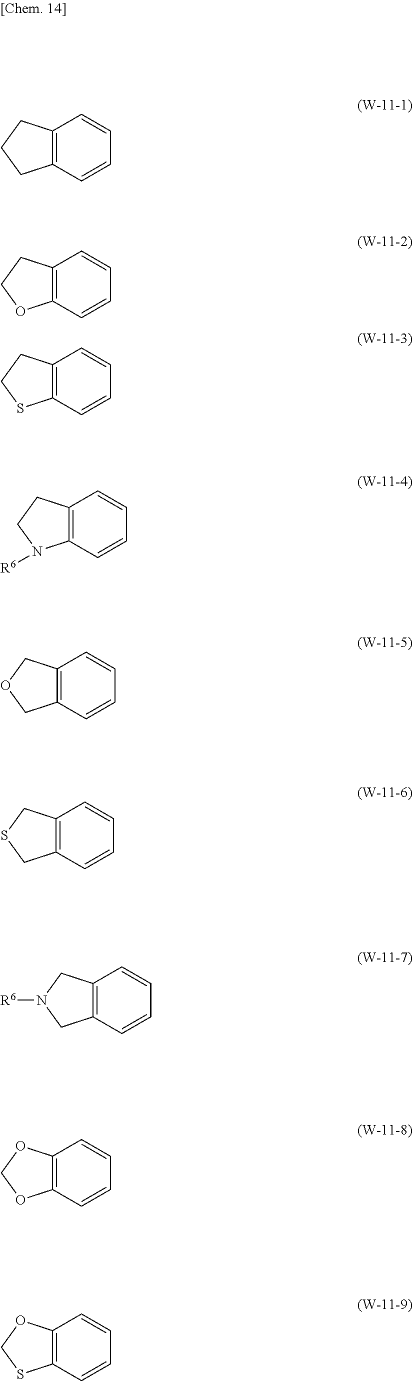

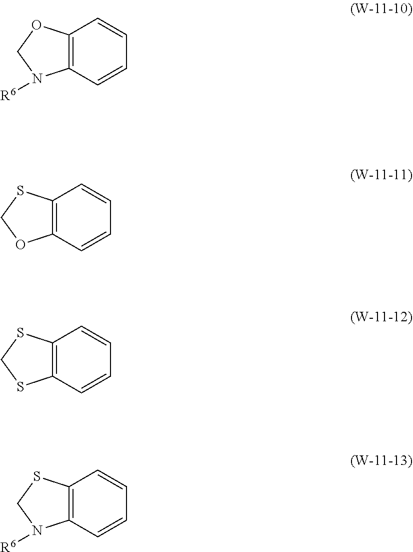

(where these groups may have bonds at any points, and R⁶ represents a hydrogen atom or an alkyl group having 1 to 8 carbon atoms). The group represented by Formula (W-12) is preferably a group selected from the following Formula (W-12-1) to Formula (W-12-19) that may be unsubstituted or may be substituted by at least one L¹,

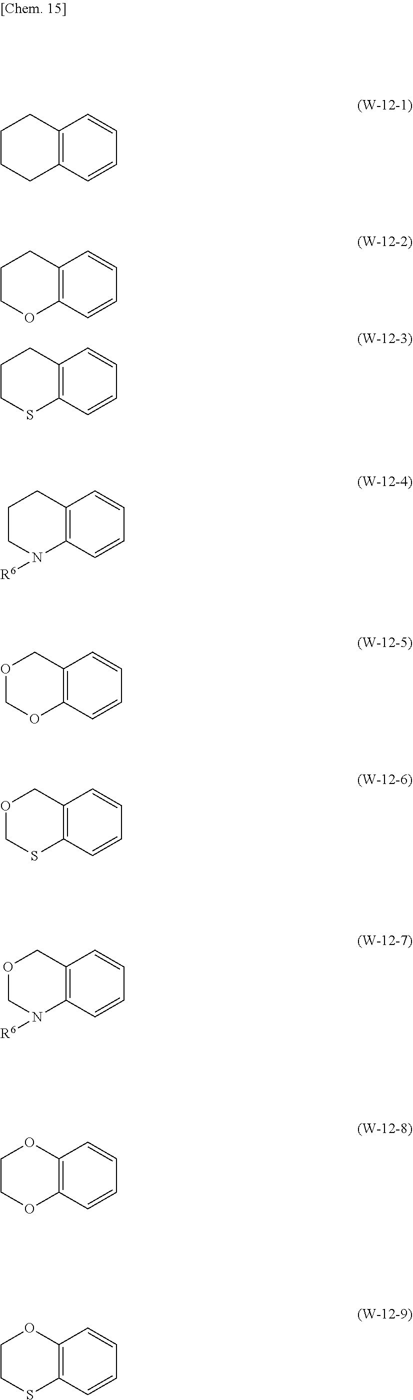

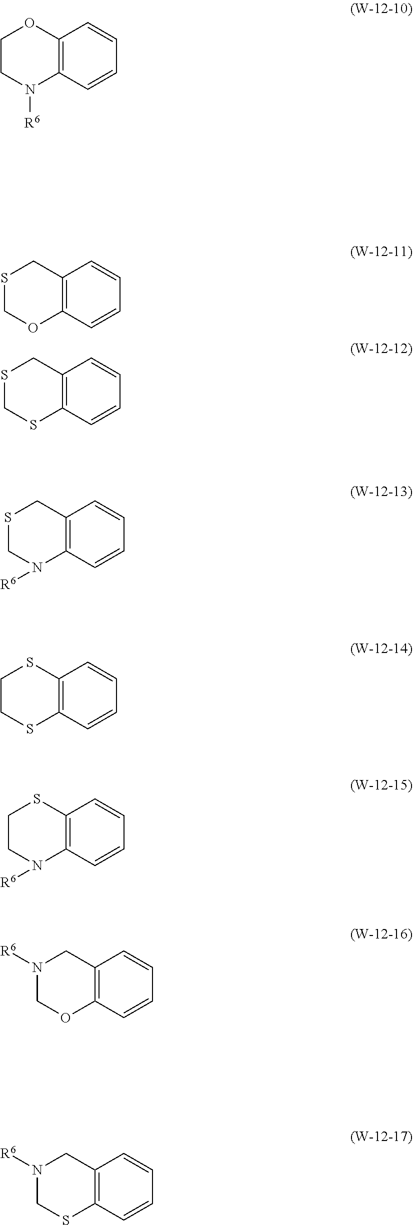

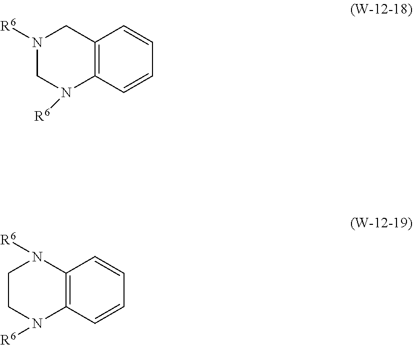

(where these groups may have bonds at any points; R⁶ represents a hydrogen atom or an alkyl group having 1 to 8 carbon atoms; when a plurality of R⁶'s are present, they may be the same or different). The group represented by Formula (W-13) is preferably a group selected from the following Formula (W-13-1) to Formula (W-13-10) that may be unsubstituted or may be substituted by at least one L¹,

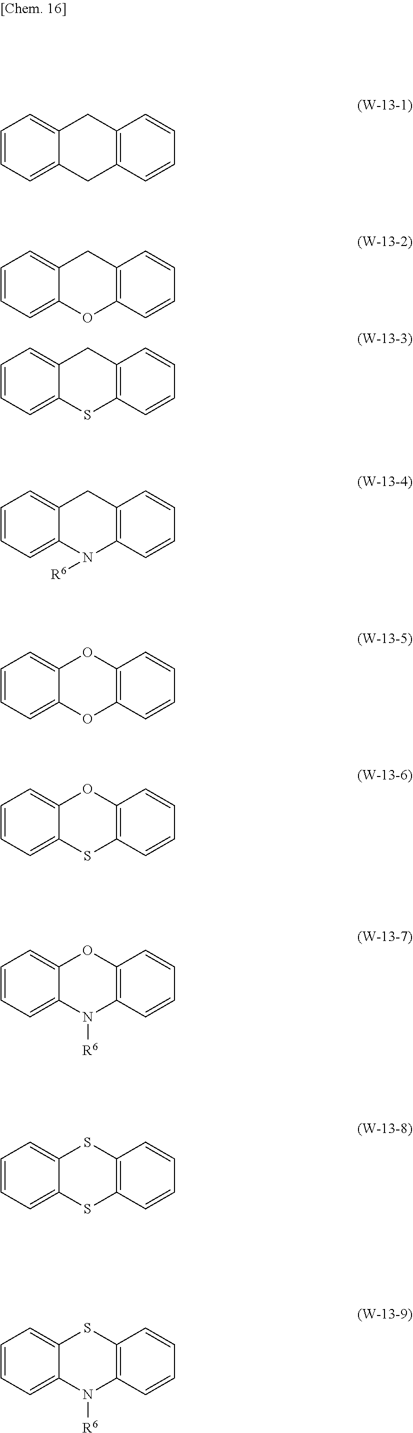

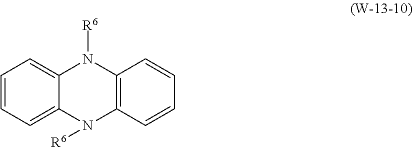

(where these groups may have bonds at any points; R⁶ represents a hydrogen atom or an alkyl group having 1 to 8 carbon atoms; when a plurality of R⁶'s are present, they may be the same or different). The group represented by Formula (W-14) is preferably a group selected from the following Formula (W-14-1) to Formula (W-14-4) that may be unsubstituted or may be substituted by at least one L¹,

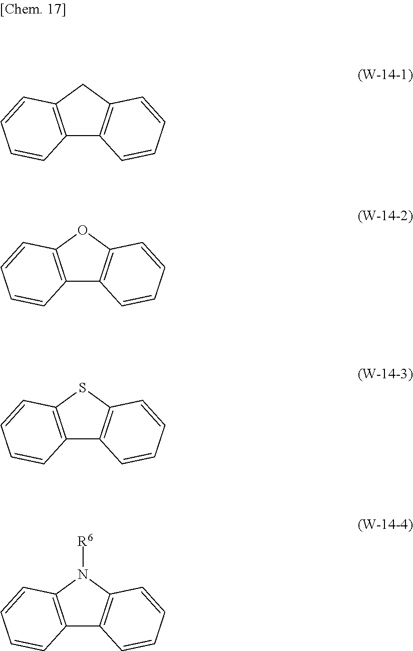

(where these groups may have bonds at any points, and R⁶ represents a hydrogen atom or an alkyl group having 1 to 8 carbon atoms). The group represented by Formula (W-15) is preferably a group selected from the following Formula (W-15-1) to Formula (W-15-18) that may be unsubstituted or may be substituted by at least one L¹,

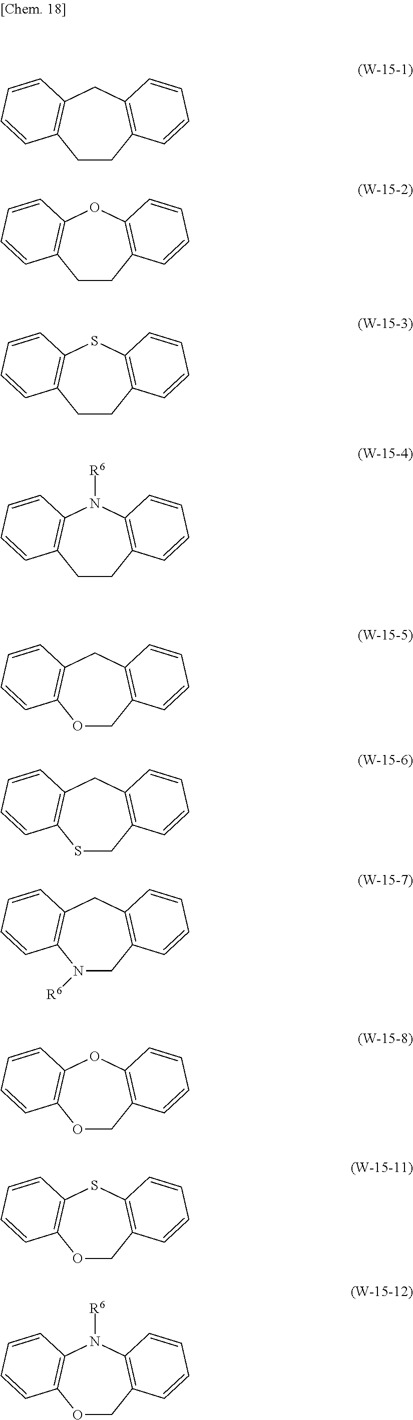

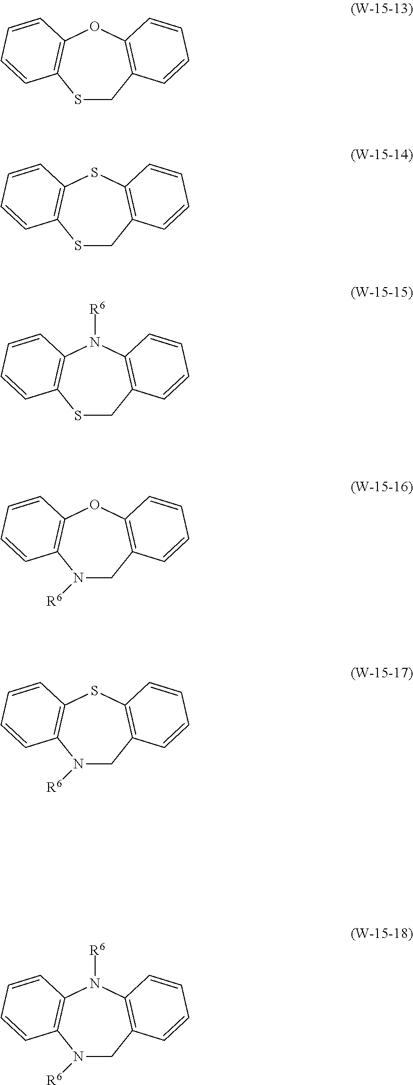

(where these groups may have bonds at any points, and R⁶ represents a hydrogen atom or an alkyl group having 1 to 8 carbon atoms). The group represented by Formula (W-16) is preferably a group selected from the following Formula (W-16-1) to Formula (W-16-4) that may be unsubstituted or may be substituted by at least one L¹,

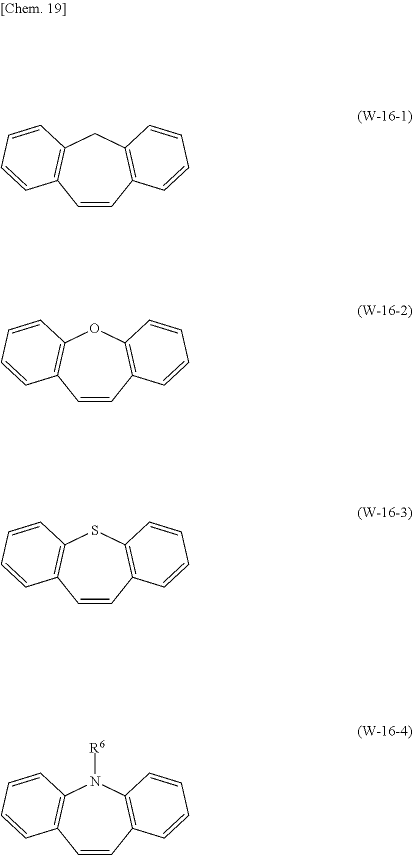

(where these groups may have bonds at any points, and R⁶ represents a hydrogen atom or an alkyl group having 1 to 8 carbon atoms). The group represented by Formula (W-17) is preferably a group selected from the following Formula (W-17-1) to Formula (W-17-6) that may be unsubstituted or may be substituted by at least one L¹,

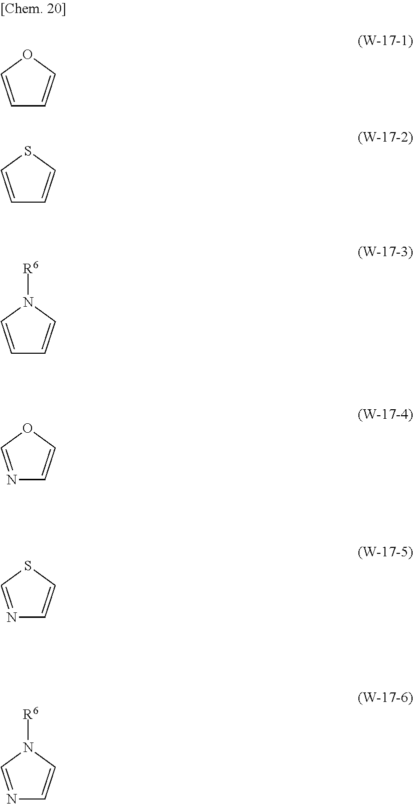

(where these groups may have bonds at any points, and R⁶ represents a hydrogen atom or an alkyl group having 1 to 8 carbon atoms). The group represented by Formula (W-18) is preferably a group selected from the following Formula (W-18-1) to Formula (W-18-6) that may be unsubstituted or may be substituted by at least one L¹,

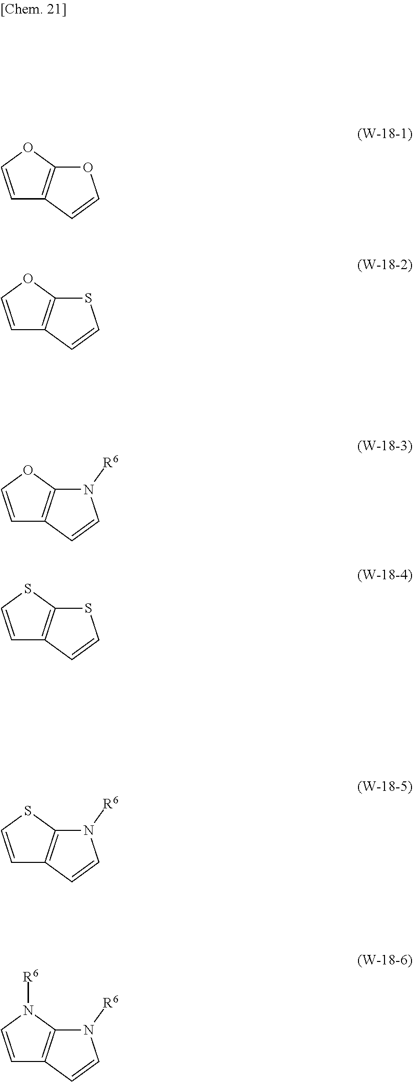

(where these groups may have bonds at any points; R⁶ represents a hydrogen atom or an alkyl group having 1 to 8 carbon atoms; when a plurality of R⁶'s are present, they may be the same or different). The group represented by Formula (W-19) is preferably a group selected from the following Formula (W-19-1) to Formula (W-19-9) that may be unsubstituted or may be substituted by at least one L¹,

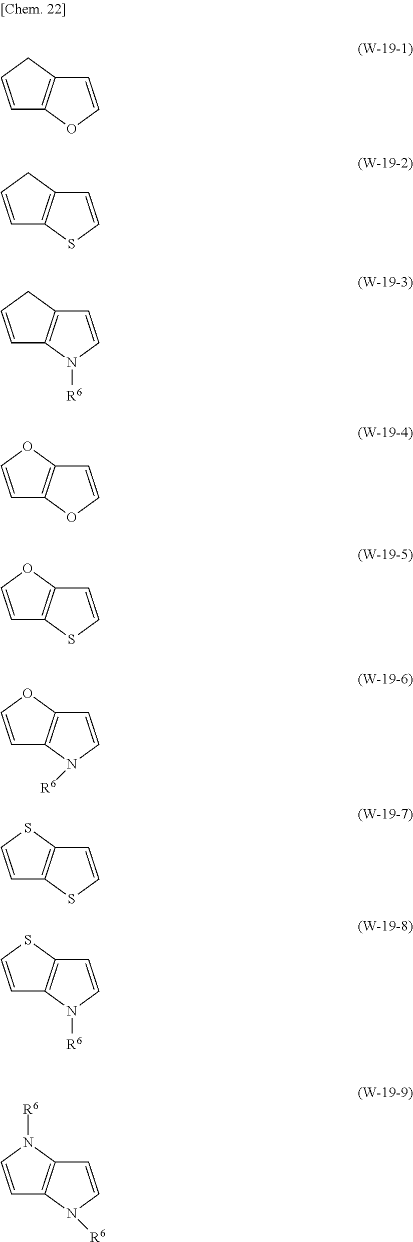

(where these groups may have bonds at any points; R⁶ represents a hydrogen atom or an alkyl group having 1 to 8 carbon atoms; when a plurality of R⁶'s are present, they may be the same or different). The aromatic group included in W⁸¹ is more preferably a group selected from Formula (W-1-1), Formula (W-7-1), Formula (W-7-2), Formula (W-7-7), Formula (W-8), Formula (W-10-6), Formula (W-10-7), Formula (W-10-8), Formula (W-11-8), Formula (W-11-9), Formula (W-11-10), Formula (W-11-11), Formula (W-11-12), and Formula (W-11-13) that may be unsubstituted or may be substituted by at least one L¹; particularly preferably a group selected from Formula (W-1-1), Formula (W-7-1), Formula (W-7-2), Formula (W-7-7), Formula (W-10-6), Formula (W-10-7), and Formula (W-10-8) that may be unsubstituted or may be substituted by at least one L¹. Furthermore, W⁸¹ particularly preferably represents a group selected from the following Formula (W-a-1) to Formula (W-a-6),

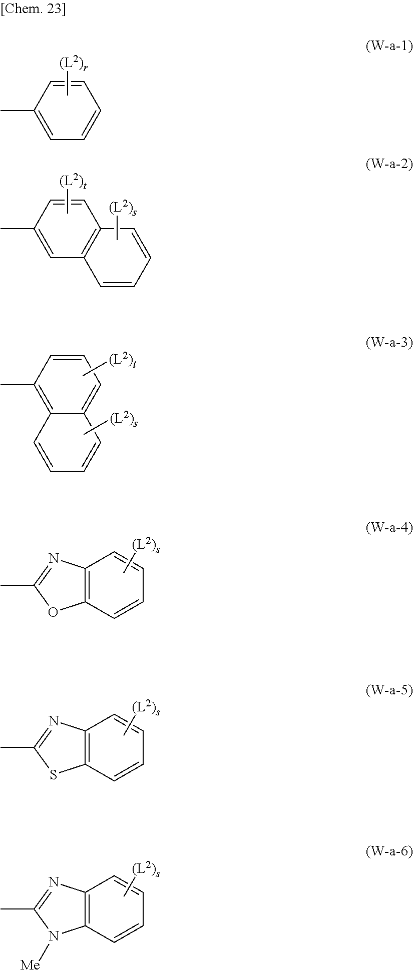

(where r represents an integer of 0 to 5; s represents an integer of 0 to 4; and t represents an integer of 0 to 3)

From the viewpoint of high availability of raw material and ease of synthesis, W⁸² more preferably represents a hydrogen atom; a linear or branched alkyl group having 1 to 20 carbon atoms in which any hydrogen atom in the group may be substituted by a fluorine atom and/or —OH, and one —CH₂- or non-adjacent two or more —CH₂— may each be independently substituted by —O—, —CO—, —COO—, —OCO—, —O—CO—O—, —CH═CH—COO—, —CH═CH—OCO—, —COO—CH═CH—, —OCO—CH═CH—, —CH═CH—, —CF═CF—, or —C═C—; or a group represented by P⁸—(S⁸—X⁸)—. W⁸² still more preferably represents a hydrogen atom; a linear or branched alkyl group having 1 to 20 carbon atoms in which any hydrogen atom in the group may be substituted by a fluorine atom, and one —CH₂— or non-adjacent two or more —CH₂— may each be independently substituted by —O—, —CO—, —COO—, or —OCO—; or a group represented by P⁸—(S⁸—X⁸)ⱼ—. W⁸² yet more preferably represents a hydrogen atom; a linear alkyl group having 1 to 12 carbon atoms in which one —CH₂- or non-adjacent two or more —CH₂— may each be independently substituted by —O—; or a group represented by P⁸—(S⁸—X⁸)—. W⁸² still yet more preferably represents a hydrogen atom; a linear alkyl group having 1 to 12 carbon atoms in which one —CH₂— or non-adjacent two or more —CH₂— are each independently substituted by —O—; or a group represented by P⁸—(S⁸—X⁸)ⱼ—.

When W⁸² represents a group having 2 to 30 carbon atoms and having at least one aromatic group, W⁸² preferably represents a group selected from Formula (W-1) to Formula (W-18) above. In this case, more preferred structures are the same as above.

When W⁸² represents a group represented by P⁸—(S⁸—X⁸)ⱼ—, the preferred structures of the groups represented by P⁸, S⁸, and X⁸ are the same as the above-described preferred structures of the groups represented by P¹ to P⁷⁴, S¹¹ to S⁷² and X¹¹ to X⁷². j preferably represents an integer of 0 to 3, more preferably 0 or 1.

The end group of W⁸² may be a OH group.

When W⁸¹ and W⁸² are linked together to form a ring structure, a cyclic group represented by —N⁸¹W⁸² is preferably a group selected from the following Formula (W-b-1) to Formula (W-b-42) that may be unsubstituted or may be substituted by at least one L¹,

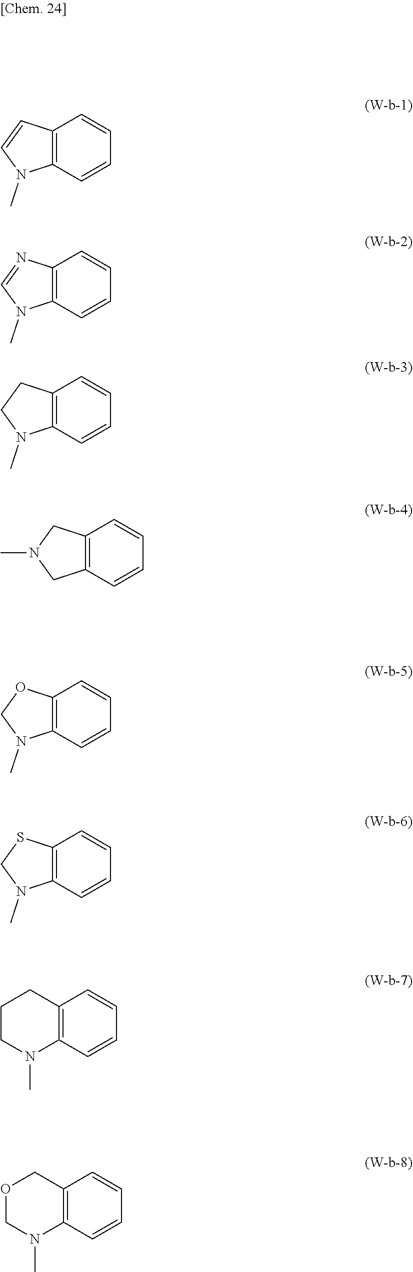

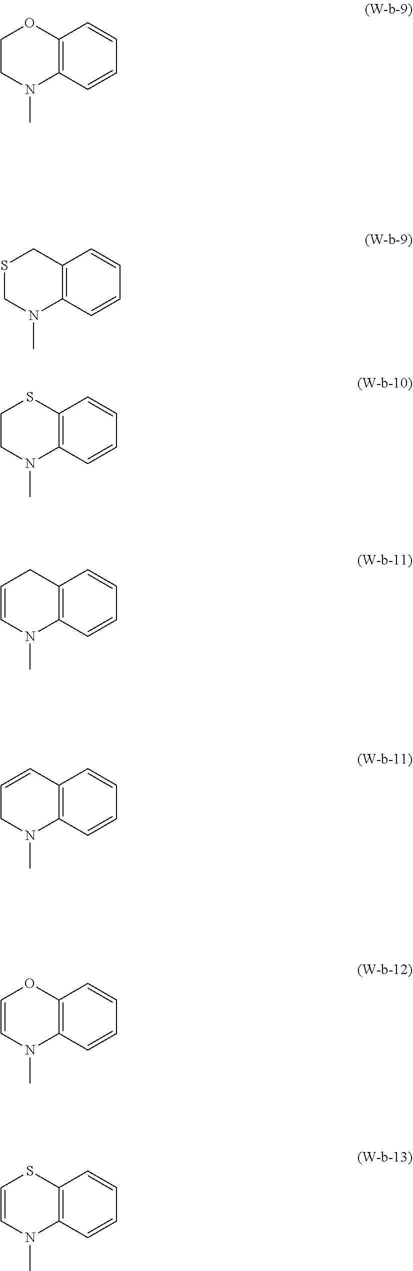

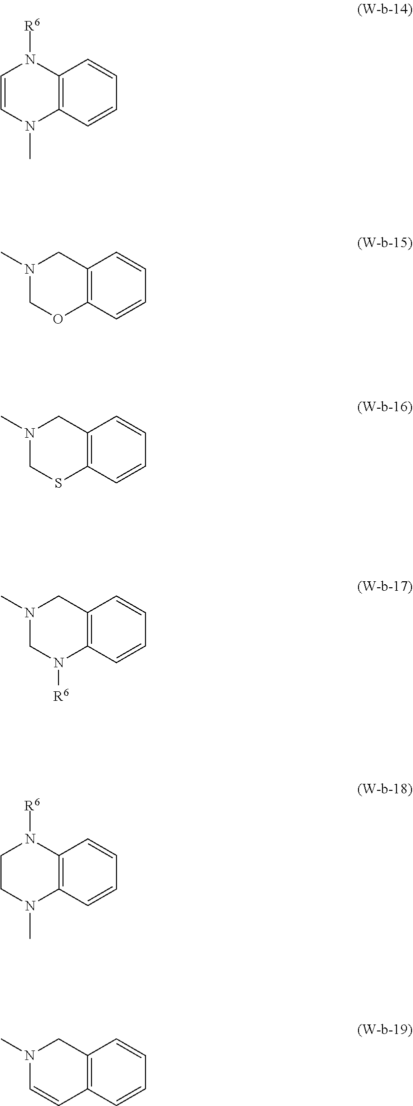

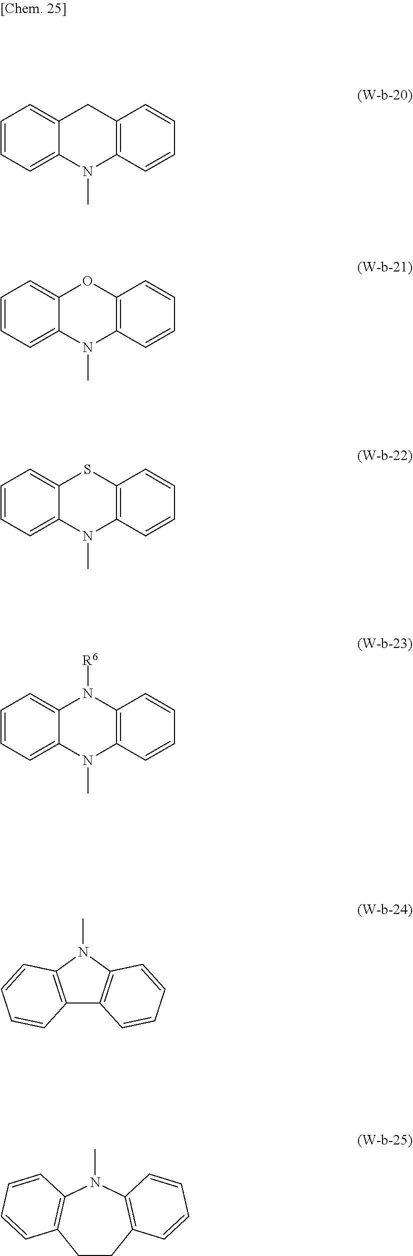

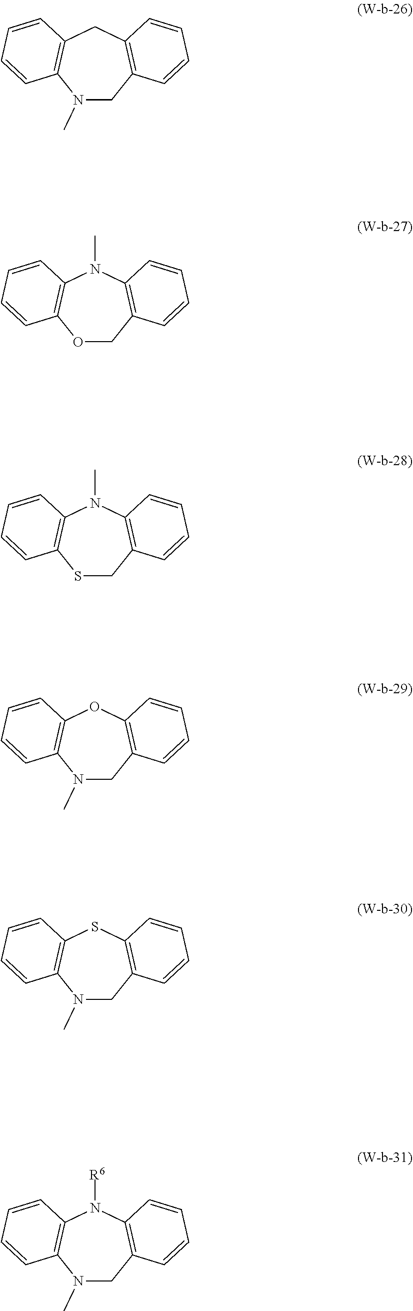

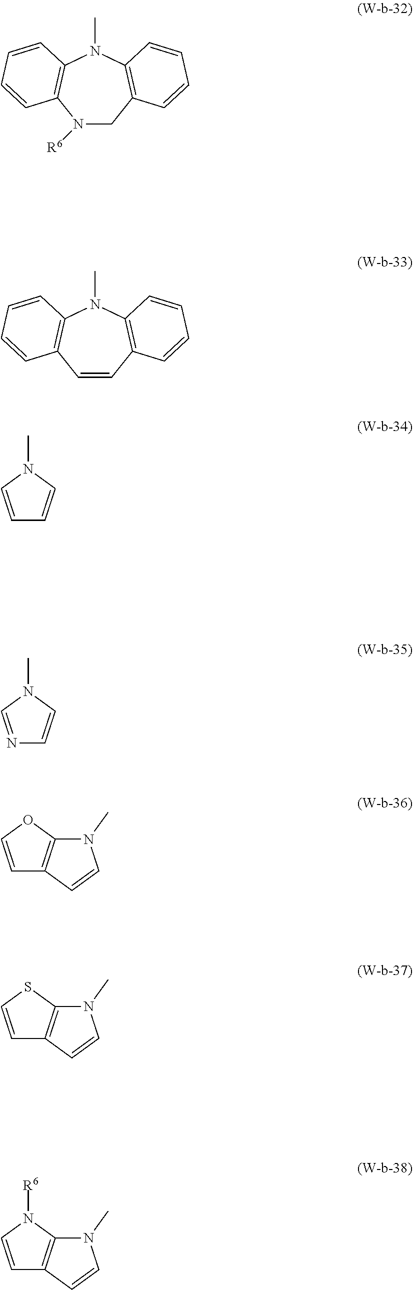

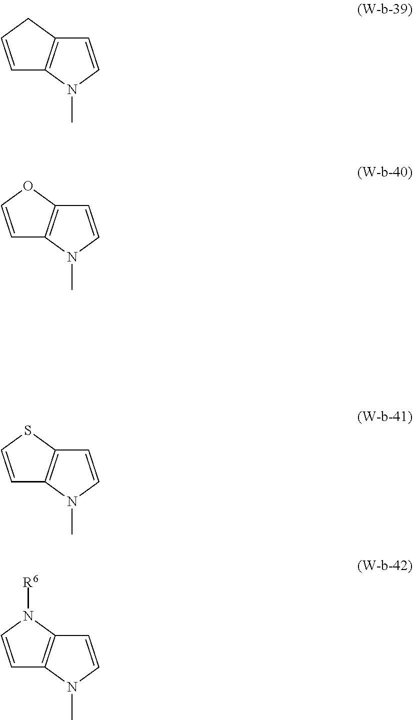

(where R⁶ represents a hydrogen atom or an alkyl group having 1 to 8 carbon atoms), particularly preferably, from the viewpoint of high availability of raw material and ease of synthesis, a group selected from Formula (W-b-20), Formula (W-b-21), Formula (W-b-22), Formula (W-b-23), Formula (W-b-24), Formula (W-b-25), and Formula (W-b-33) that may be unsubstituted or that may be substituted by at least one L¹.

Another cyclic group represented by ═CW⁸¹W⁸² is preferably a group selected from the following Formula (W-c-1) to Formula (W-c-81) that may be unsubstituted or may be substituted by at least one L¹,

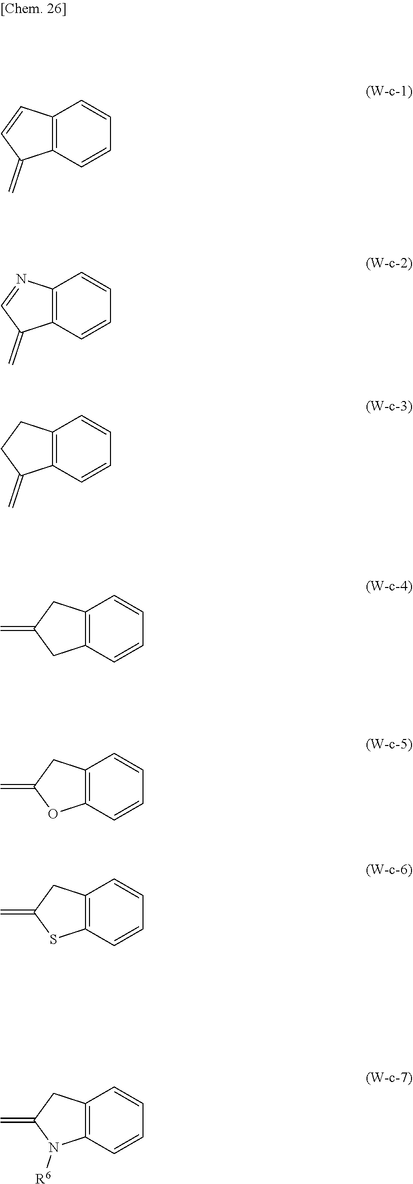

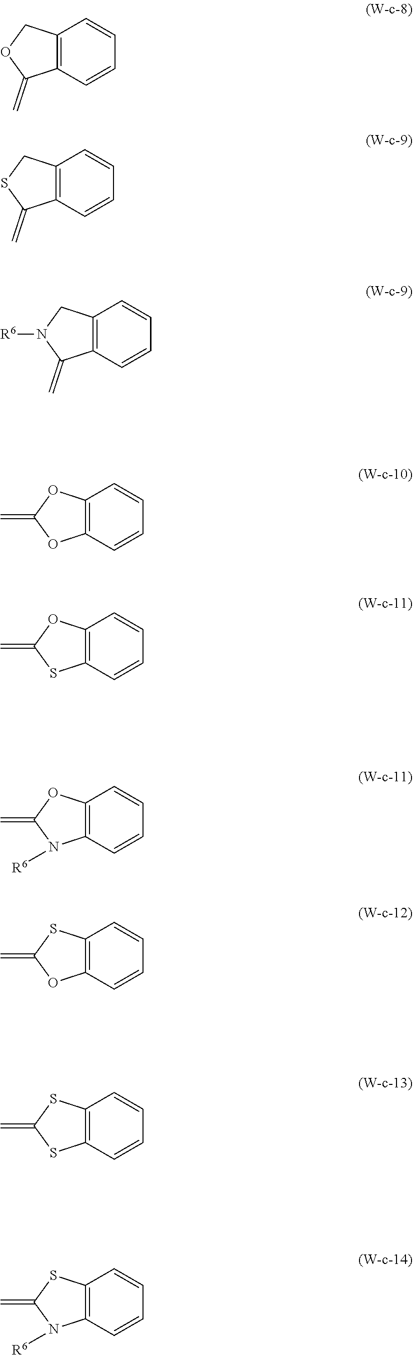

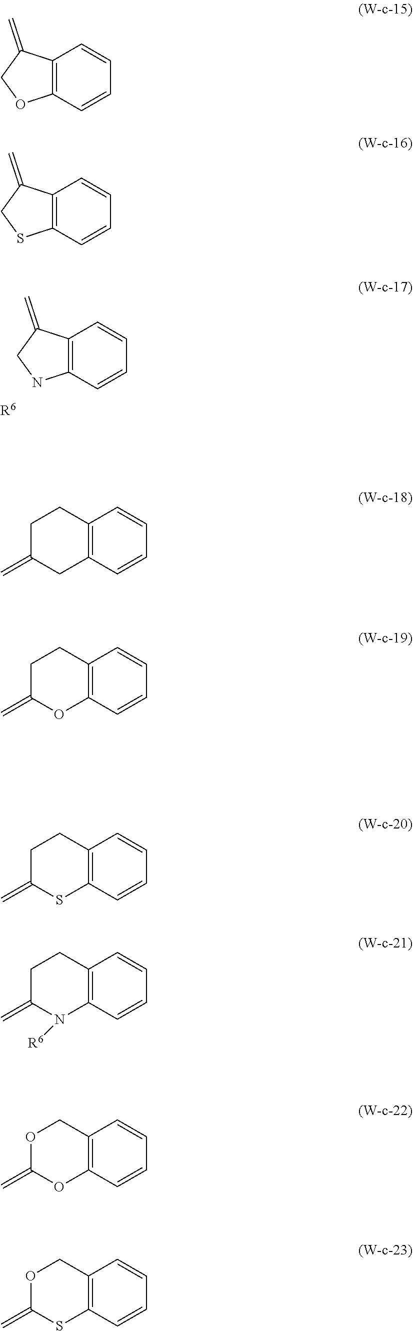

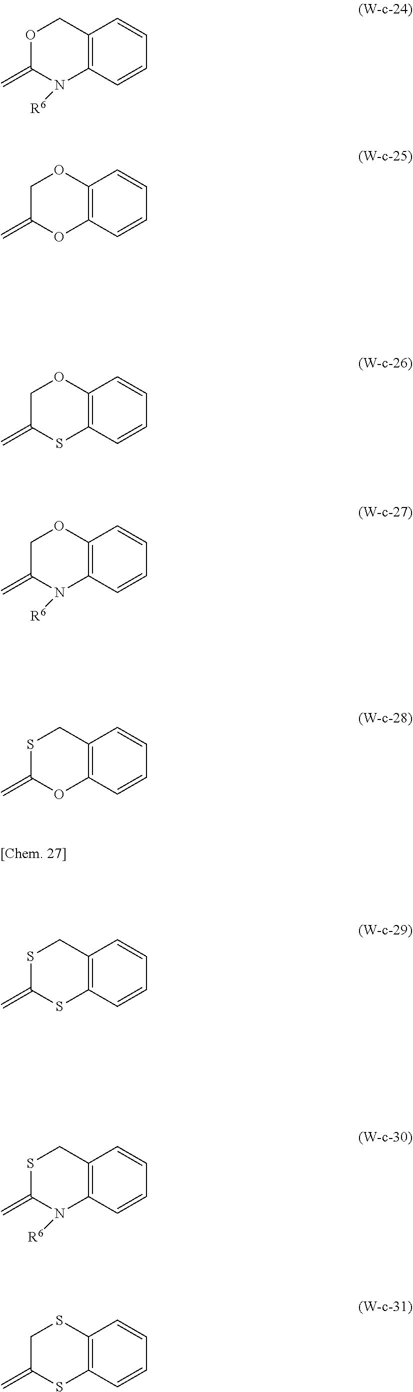

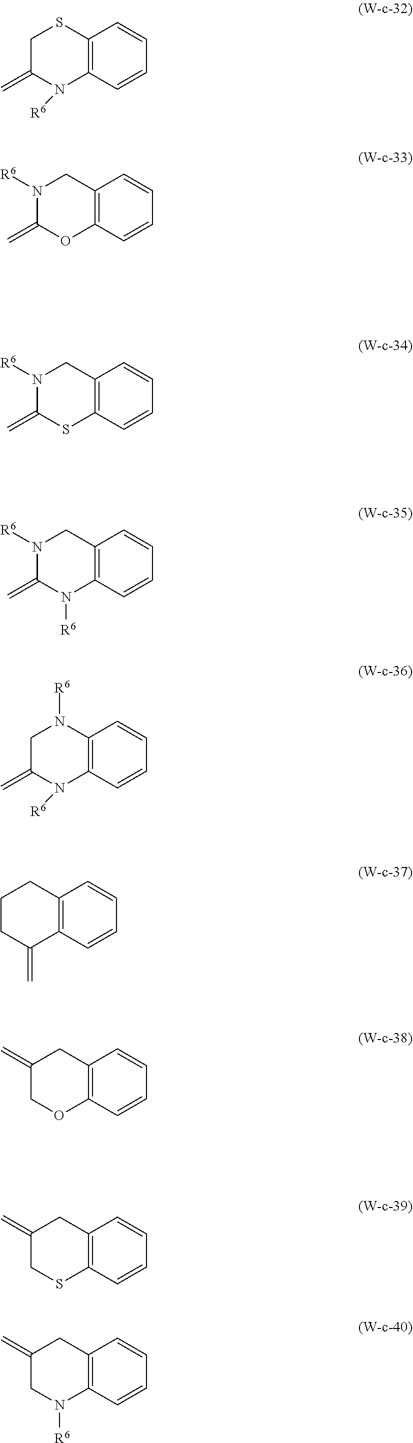

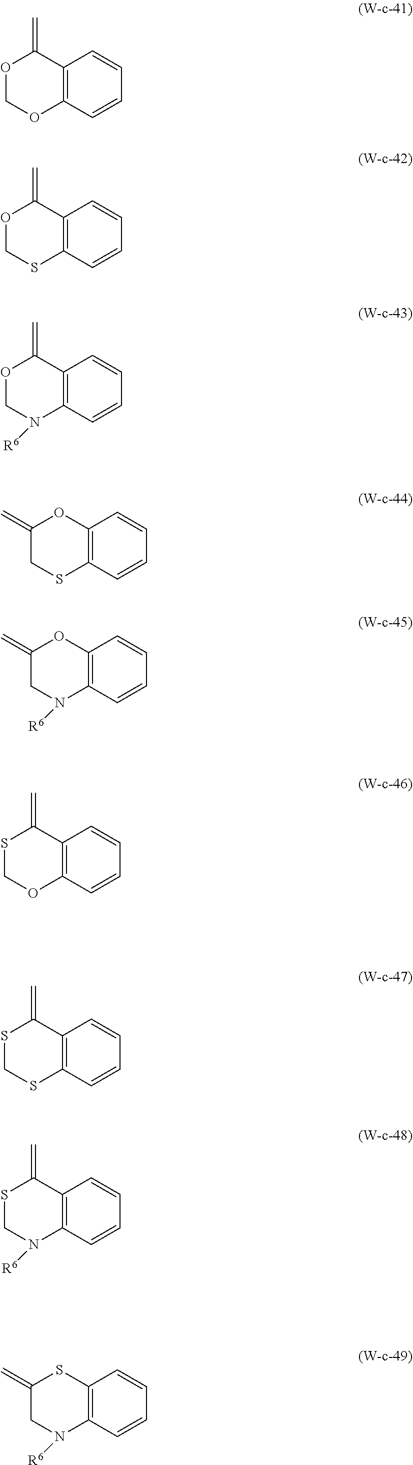

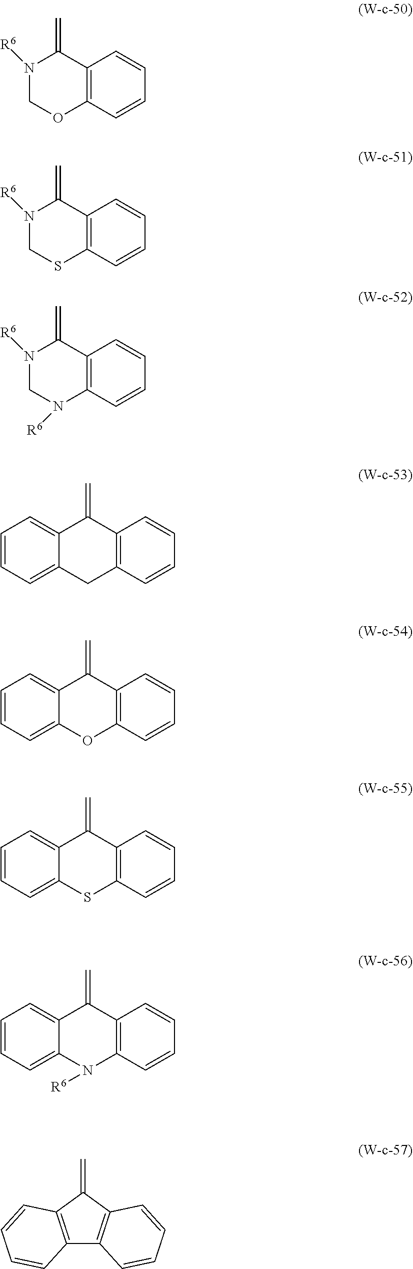

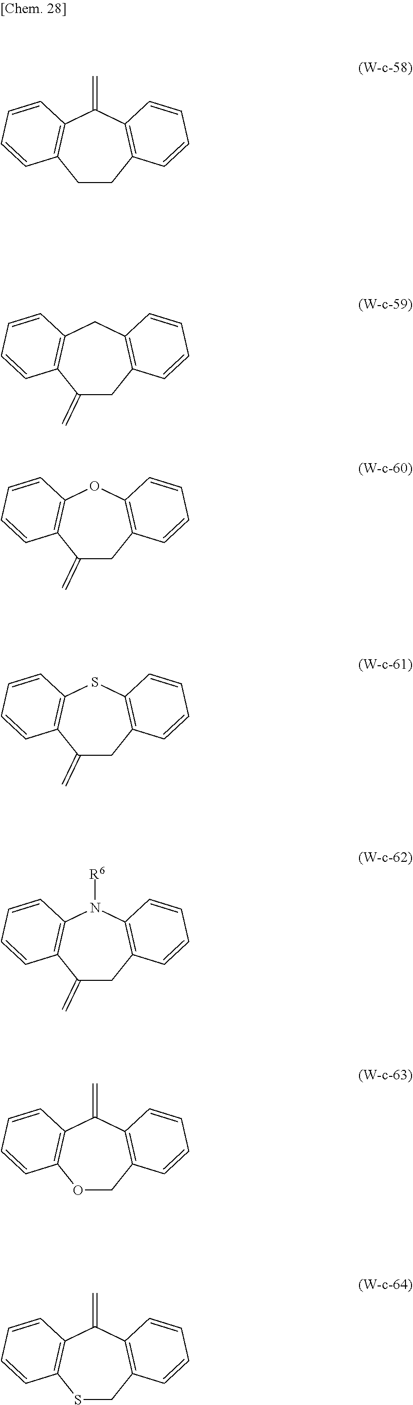

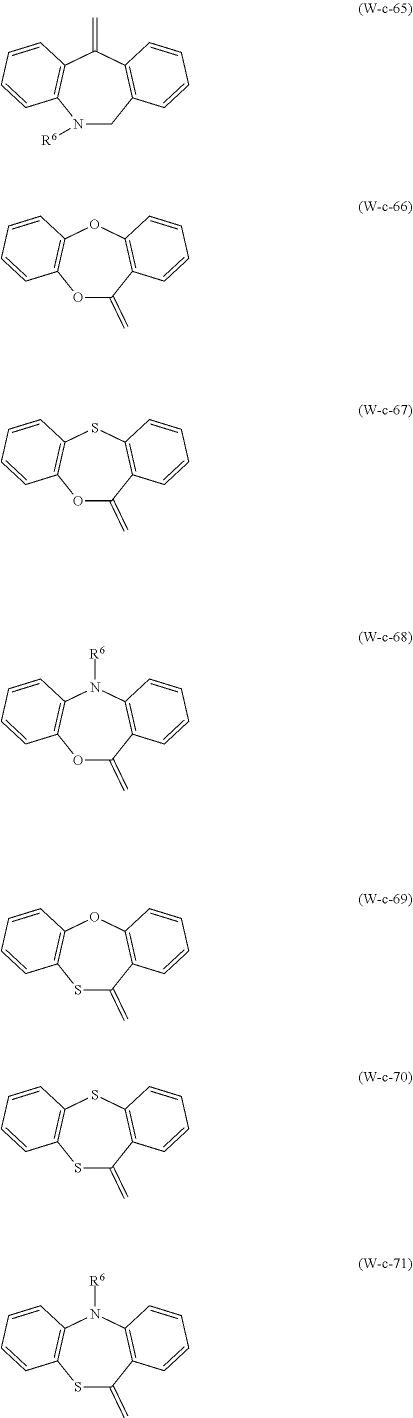

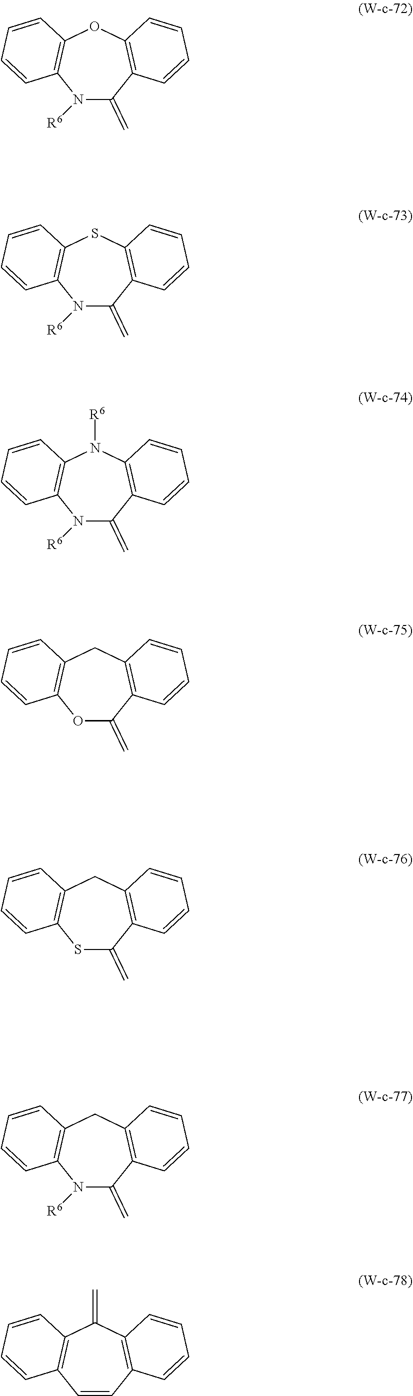

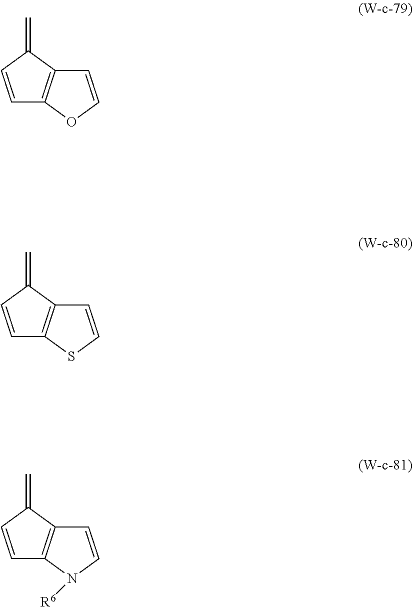

(where R⁶ represents a hydrogen atom or an alkyl group having 1 to 8 carbon atoms; when a plurality of R⁶'s are present, they may be the same or different); particularly preferably, from the viewpoint of high availability of raw material and ease of synthesis, a group selected from Formula (W-c-11), Formula (W-c-12), Formula (W-c-13), Formula (W-c-14), Formula (W-c-53), Formula (W-c-54), Formula (W-c-55), Formula (W-c-56), Formula (W-c-57), and Formula (W-c-78) that may be unsubstituted or that may be substituted by at least one L.

The total number of n electrons included in W⁸¹ and W⁸¹ is preferably 4 to 24 from the viewpoint of wavelength dispersion characteristics, storage stability, liquid crystallinity, and ease of synthesis. W⁸³ and W⁸⁴ each independently represent a halogen atom, a cyano group, a hydroxy group, a nitro group, a carboxyl group, a carbamoyloxy group, an amino group, a sulfamoyl group, a group having 5 to 30 carbon atoms and having at least one aromatic group, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms.

In the alkyl group, cycloalkyl group, alkenyl group, cycloalkenyl group, alkoxy group, acyloxy group, and alkylcarbonyloxy group, one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, or —C═C—. W³ more preferably represents a group selected from a cyano group, a nitro group, a carboxyl group, and an alkyl group, alkenyl group, acyloxy group, or alkylcarbonyloxy group having 1 to 20 carbon atoms in which one —CH₂— or non-adjacent two or more —CH₂— are each independently substituted by —O—, —S—, —CO—, —COO—, —OCO—, —CO—S—, —S—CO—, —O—CO—O—, —CO—NH—, —NH—CO—, or —C═C—; particularly preferably represents a group selected from a cyano group, a carboxyl group, and an alkyl group, alkenyl group, acyloxy group, or alkylcarbonyloxy group having 1 to 20 carbon atoms in which one —CH₂— or non-adjacent two or more —CH₂— are each independently substituted by —CO—, —COO—, —OCO—, —O—CO—O—, —CO—NH—, —NH—CO—, or —C═C—. W⁴ more preferably represents a group selected from a cyano group, a nitro group, a carboxyl group, and an alkyl group, alkenyl group, acyloxy group, or alkylcarbonyloxy group having 1 to 20 carbon atoms in which one —CH₂— or non-adjacent two or more —CH₂— are each independently substituted by —O—, —S—, —CO—, —COO—, —OCO—, —CO—S—, —S—CO—, —O—CO—O—, —CO—NH—, —NH—CO—, or —C═C—; particularly preferably represents a group selected from a cyano group, a carboxyl group, and an alkyl group, alkenyl group, acyloxy group, or alkylcarbonyloxy group having 1 to 20 carbon atoms in which one —CH₂— or non-adjacent two or more —CH₂— are each independently substituted by —CO—, —COO—, —OCO—, —O—CO—O—, —CO—NH—, —NH—CO—, or —C═C—.

L¹ represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or a linear or branched alkyl group having 1 to 20 carbon atoms in which one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C═C—; in this alkyl group, any hydrogen atom may be substituted by a fluorine atom. From the viewpoint of liquid crystallinity and ease of synthesis, L¹ preferably represents a fluorine atom, a chlorine atom, a pentafluorosulfuranyl group, a nitro group, a methylamino group, a dimethylamino group, a diethylamino group, a diisopropylamino group, or a linear or branched alkyl group having 1 to 20 carbon atoms in which any hydrogen atom may be substituted by a fluorine atom, and one —CH₂— or non-adjacent two or more —CH₂— may each be independently substituted by a group selected from —O—, —S—, —CO—, —COO—, —OCO—, —O—CO—O—, —CH═CH—, —CF═CF—, and —C═C—; more preferably represents a fluorine atom, a chlorine atom, or a linear or branched alkyl group having 1 to 12 carbon atoms in which any hydrogen atom may be substituted by a fluorine atom, and one —CH₂— or non-adjacent two or more —CH₂— may each be independently substituted by a group selected from —O—, —COO—, and —OCO—; still more preferably represents a fluorine atom, a chlorine atom, or a linear or branched alkyl group or alkoxy group having 1 to 12 carbon atoms in which any hydrogen atom may be substituted by a fluorine atom; particularly preferably represents a fluorine atom, a chlorine atom, or a linear alkyl group or linear alkoxy group having 1 to 8 carbon atoms.

In General formula (1) to General formula (7), substituents bonded to MG¹¹ to MG⁷¹ are bonded to A¹¹ and/or A¹² of General formula (a) above.

In General formula (1), m11 represents an integer of 0 to 8, from the viewpoint of liquid crystallinity, high availability of raw material, and ease of synthesis, preferably represents an integer of 0 to 4, more preferably represents an integer of 0 to 2, still more preferably represents 0 or 1, particularly preferably represents 1.

In General formula (2) to General formula (7), m2 to m7, n2 to n7, l4 to l6, and k6 each independently represent an integer of 0 to 5, from the viewpoint of liquid crystallinity, high availability of raw material, and ease of synthesis, preferably represents an integer of 0 to 4, more preferably represents an integer of 0 to 2, still more preferably represents 0 or 1, particularly preferably represents 1.

In General formula (a), j11 and j12 each independently represent an integer of 1 to 5, provided that j11+j12 is an integer of 2 to 5. From the viewpoint of liquid crystallinity, ease of synthesis, and storage stability, j11 and j12 preferably each independently represent an integer of 1 to 4, more preferably represents an integer of 1 to 3, particularly preferably represents 1 or 2. j11+j12 is preferably an integer of 2 to 4.

Specific preferred examples of the compound represented by General formula (1) include compounds represented by the following Formula (1-a-1) to Formula (1-a-93).

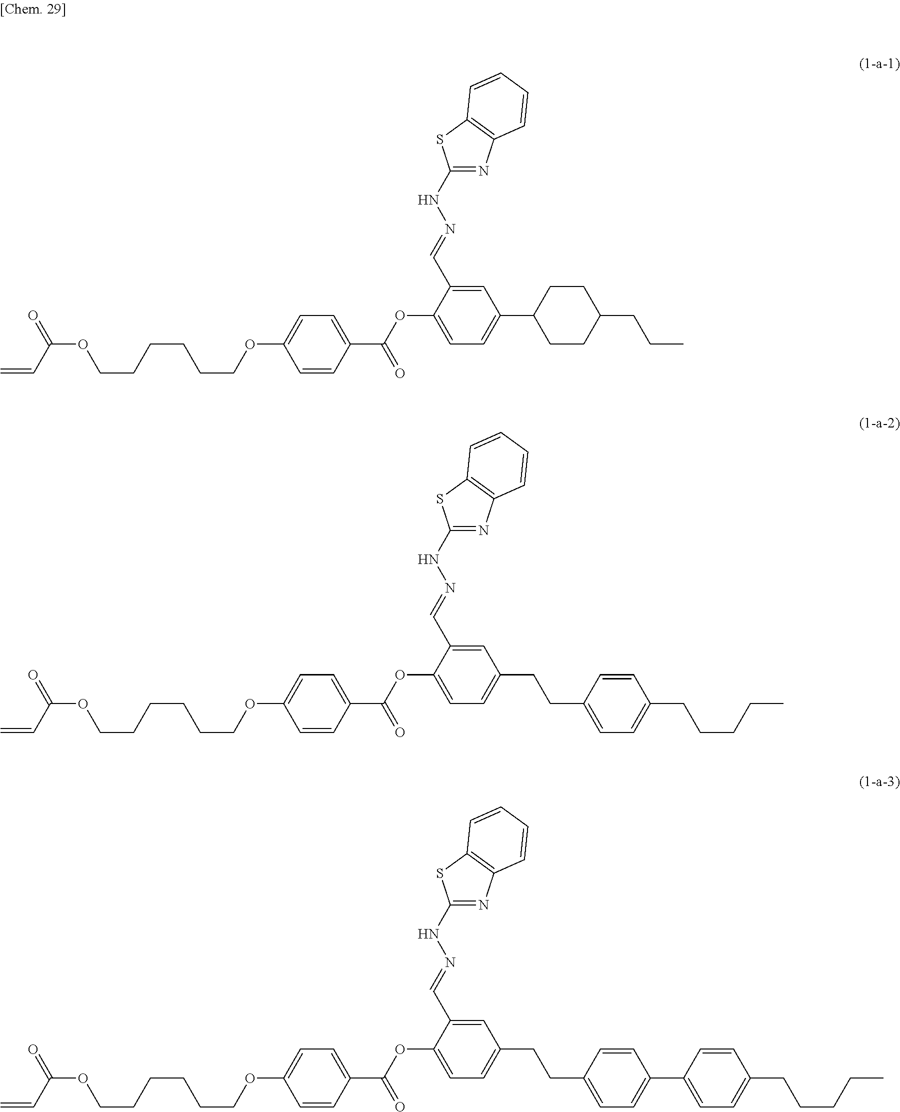

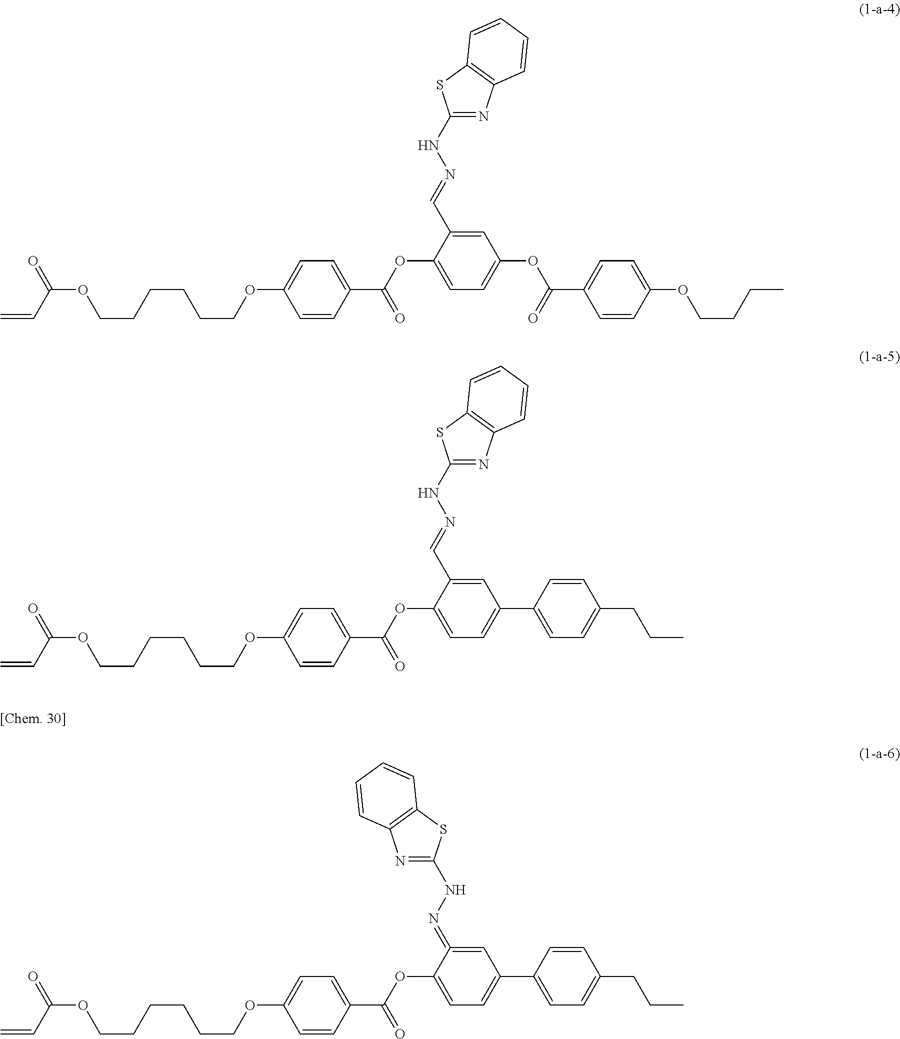

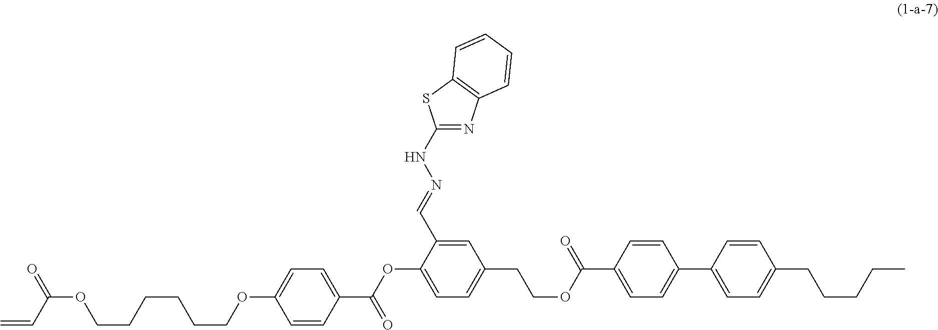

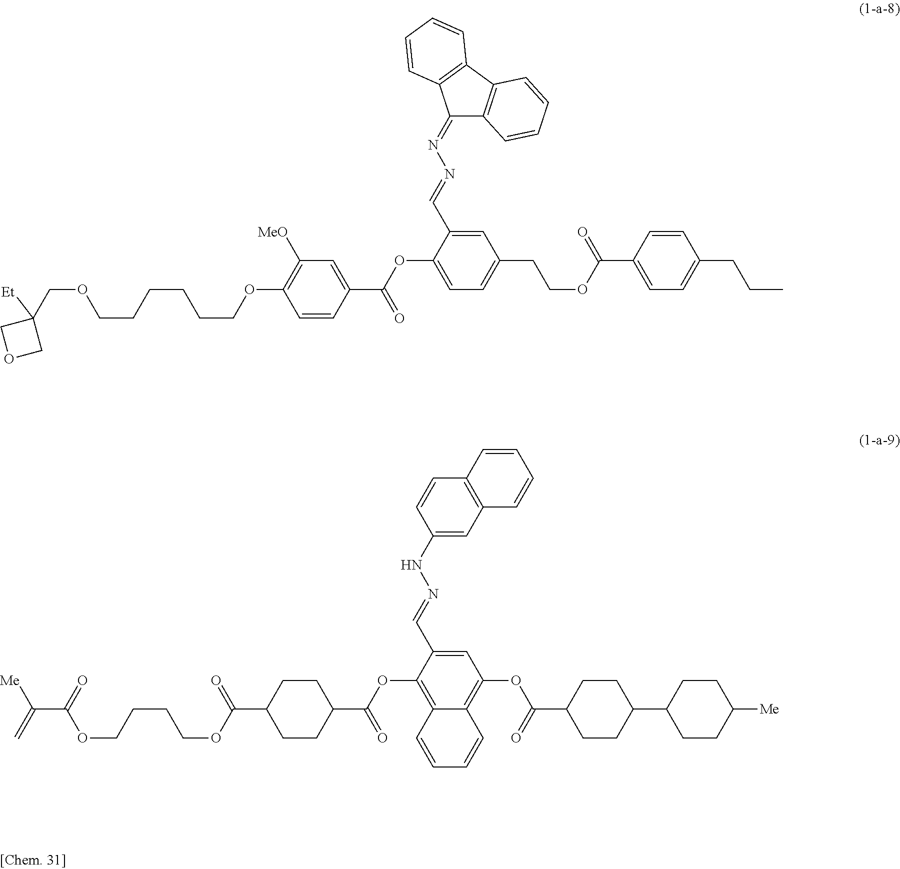

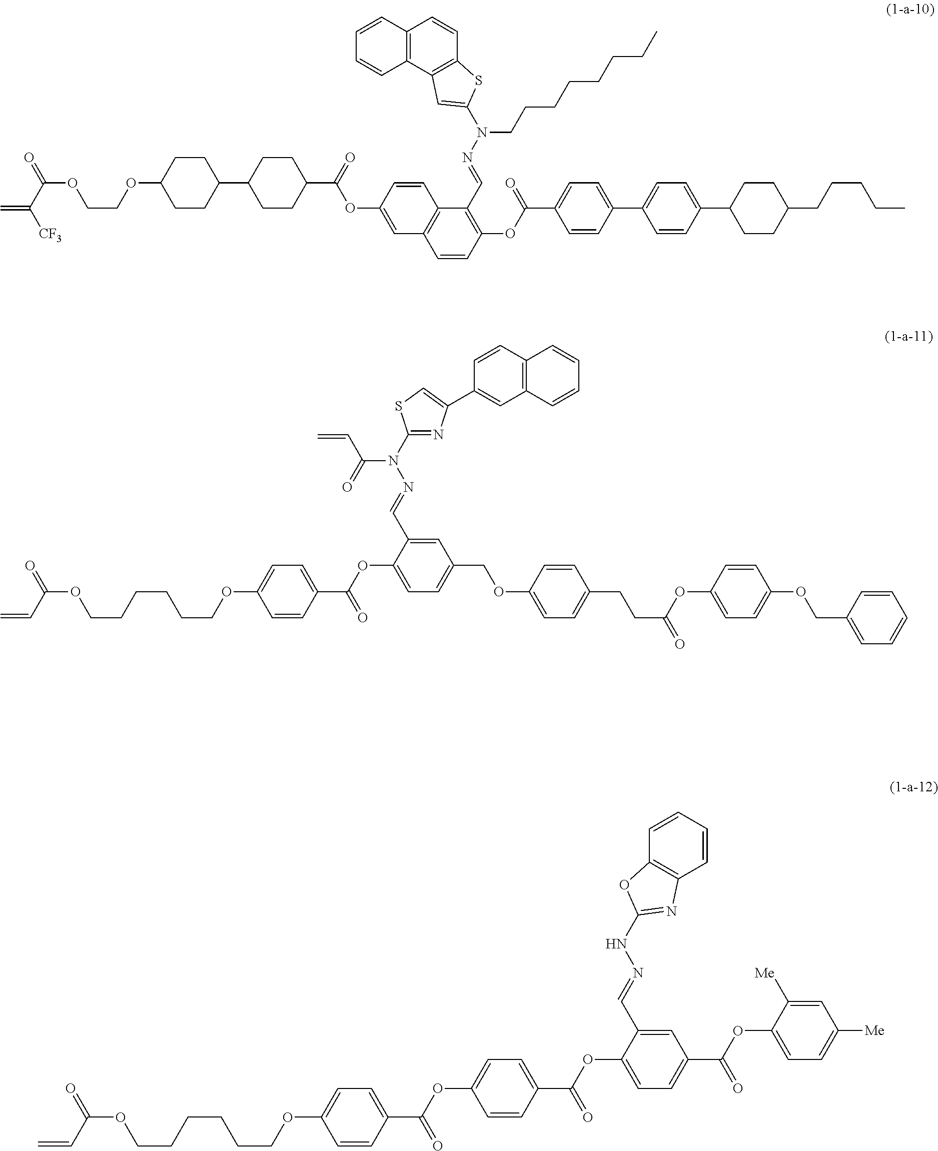

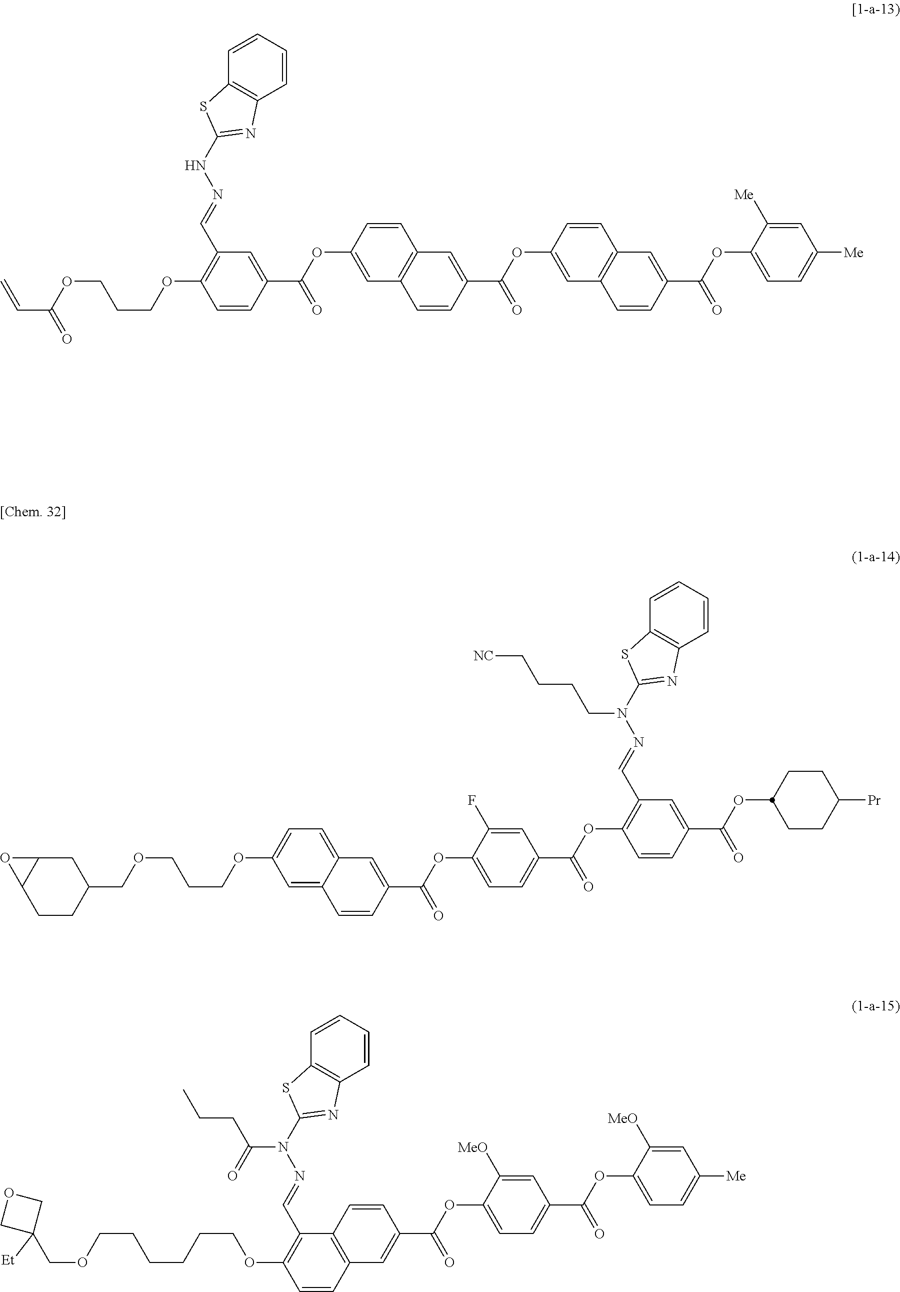

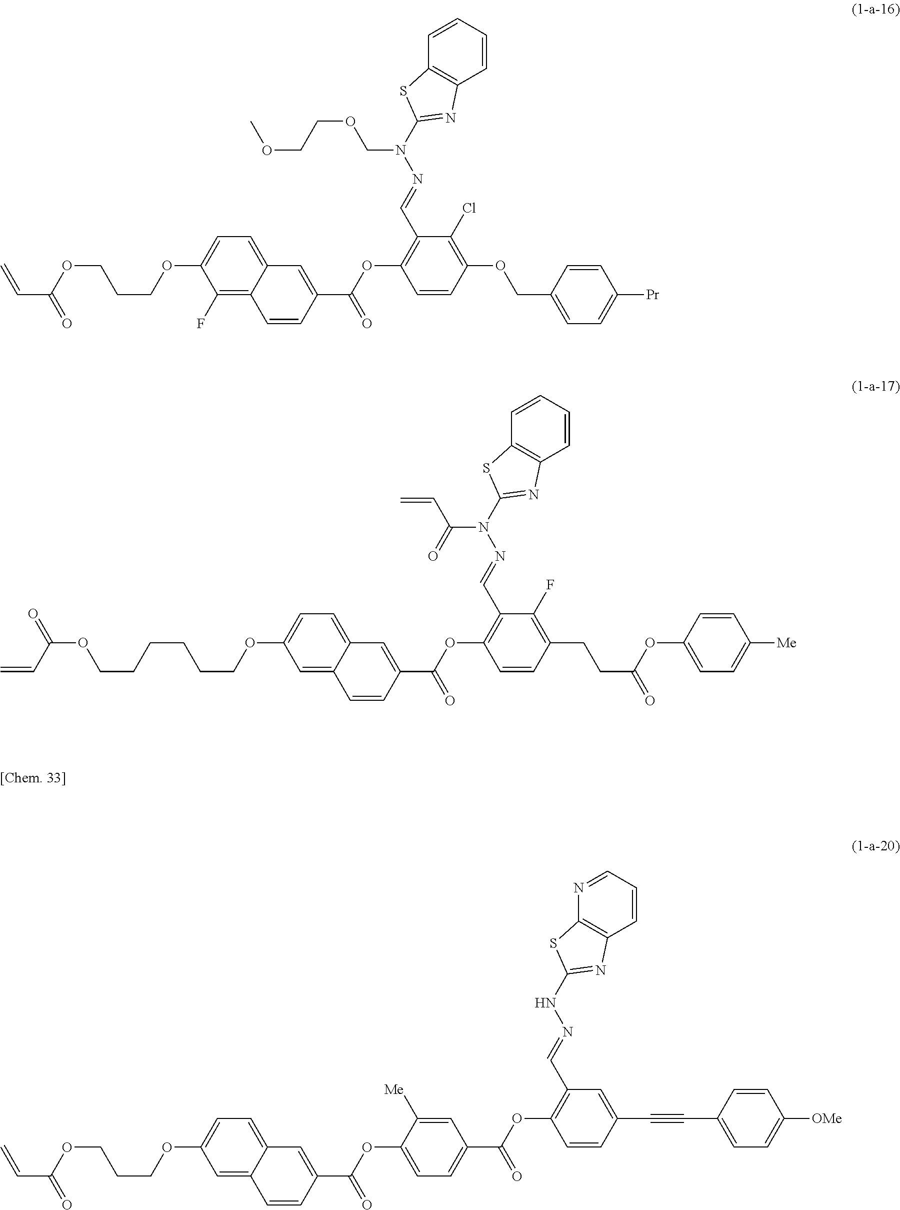

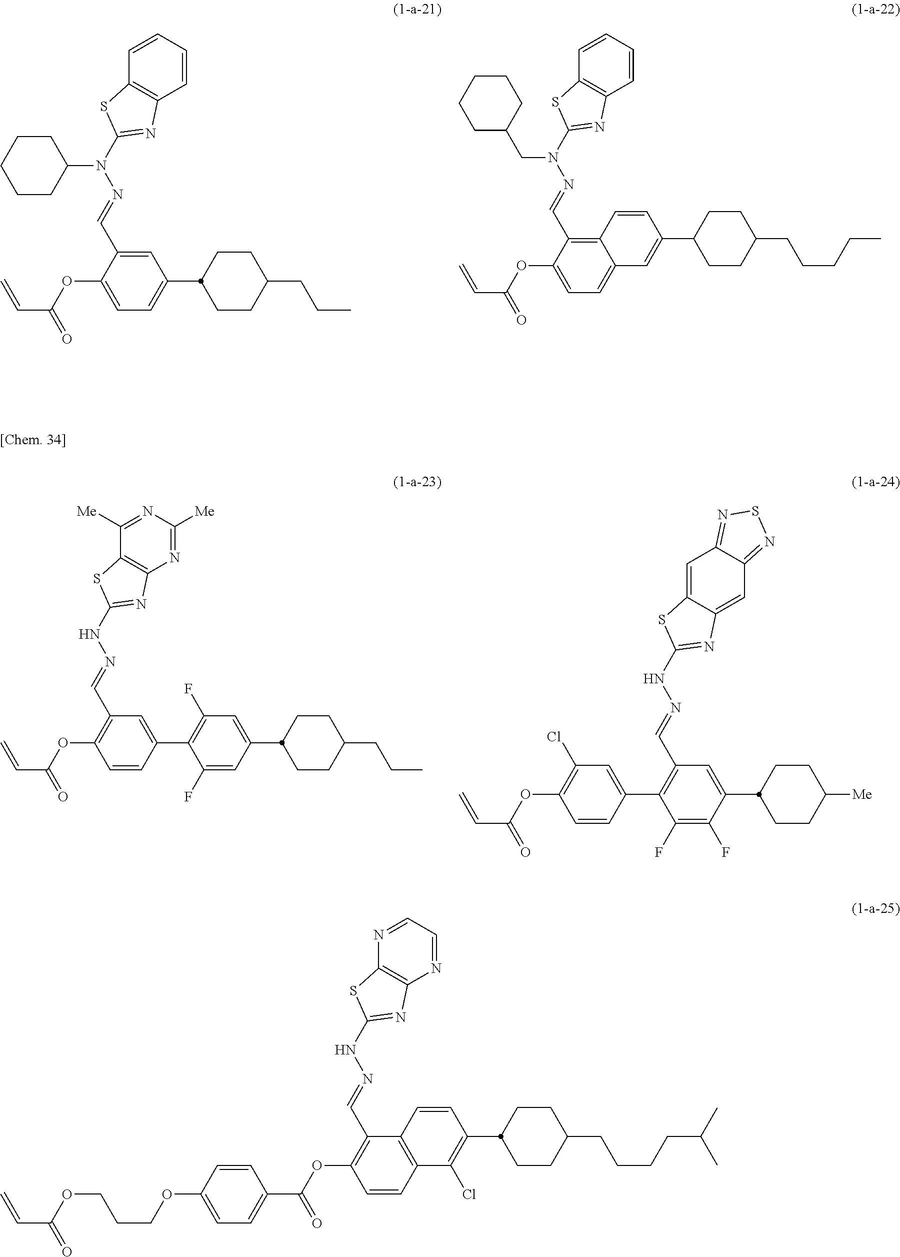

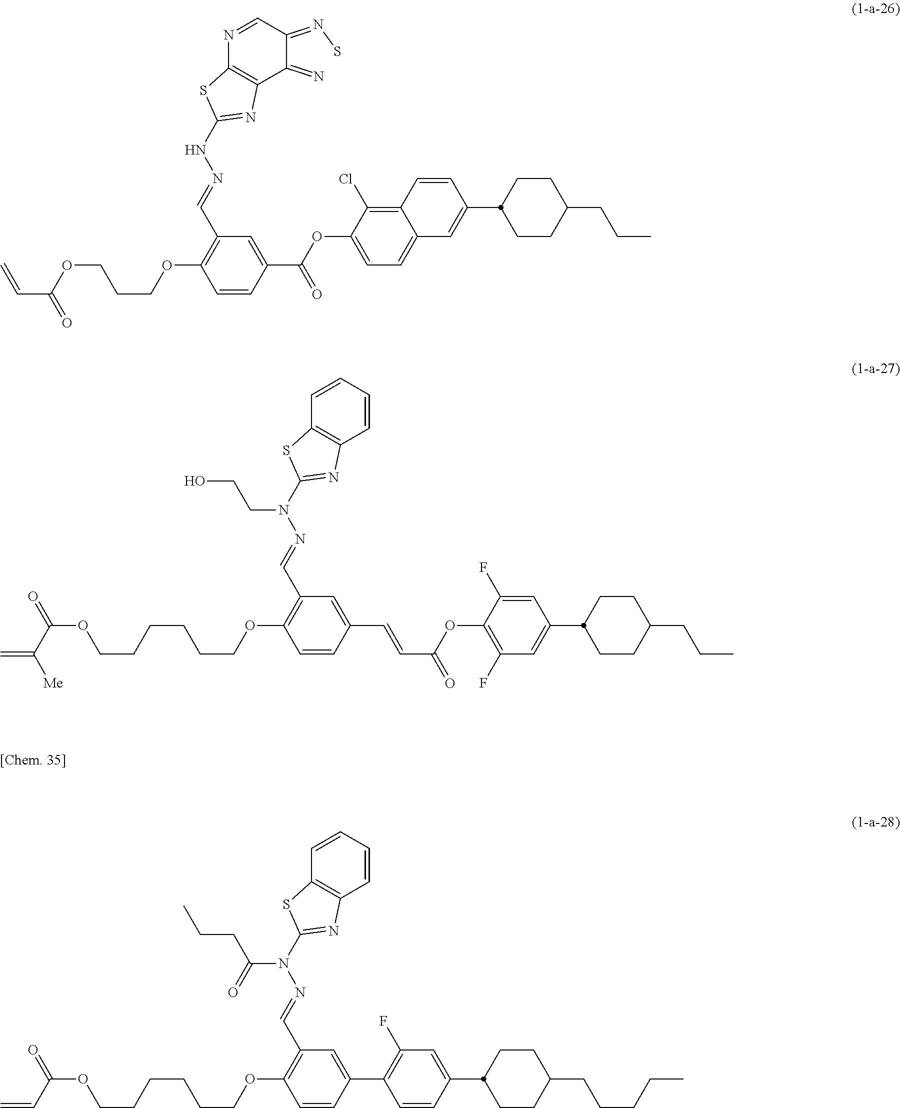

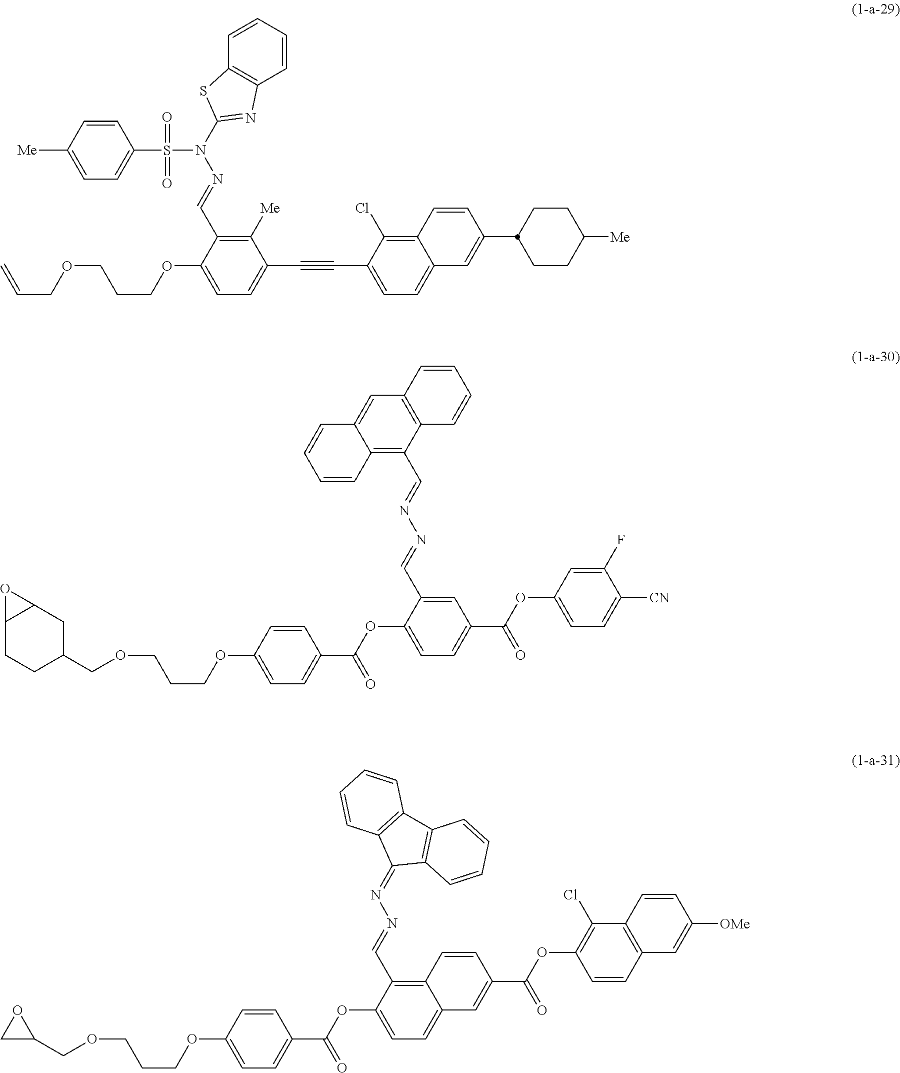

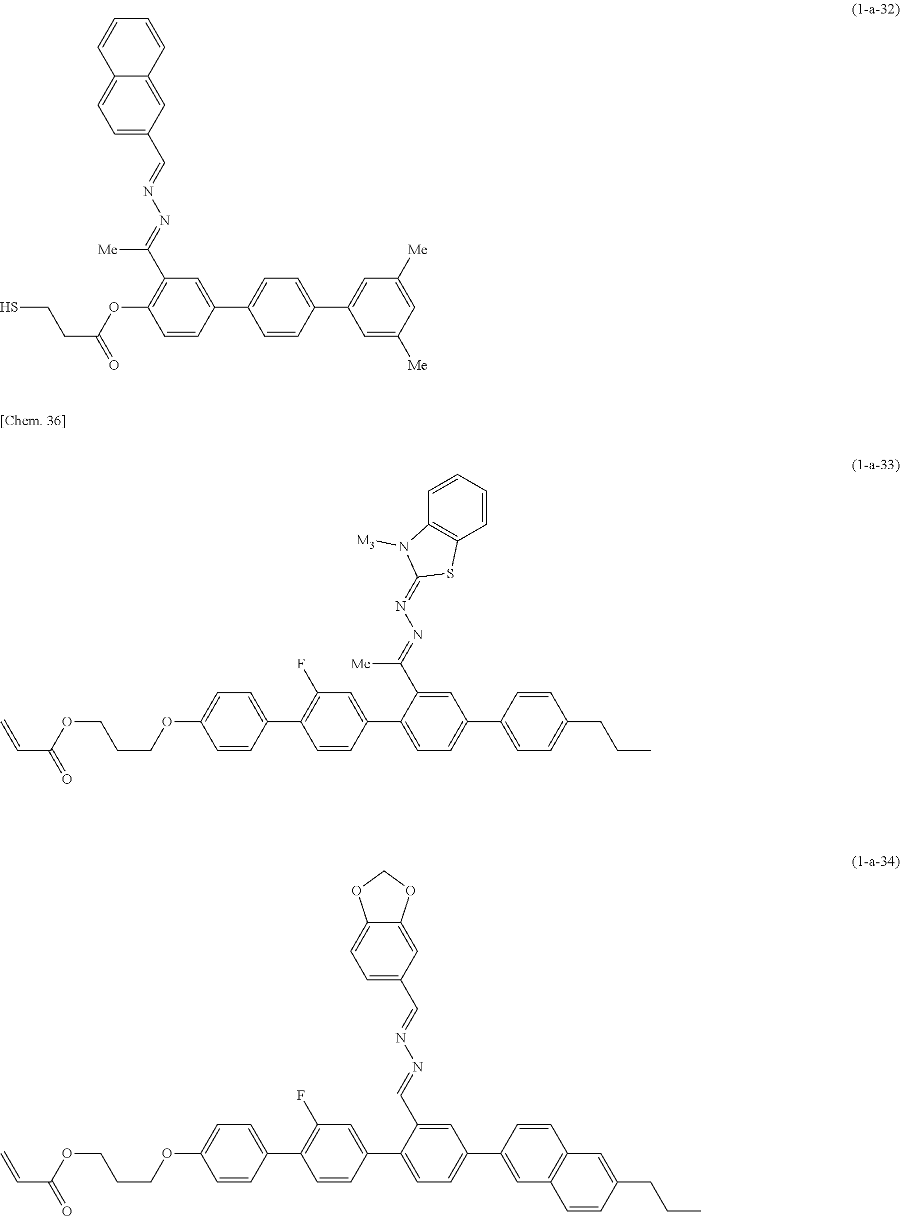

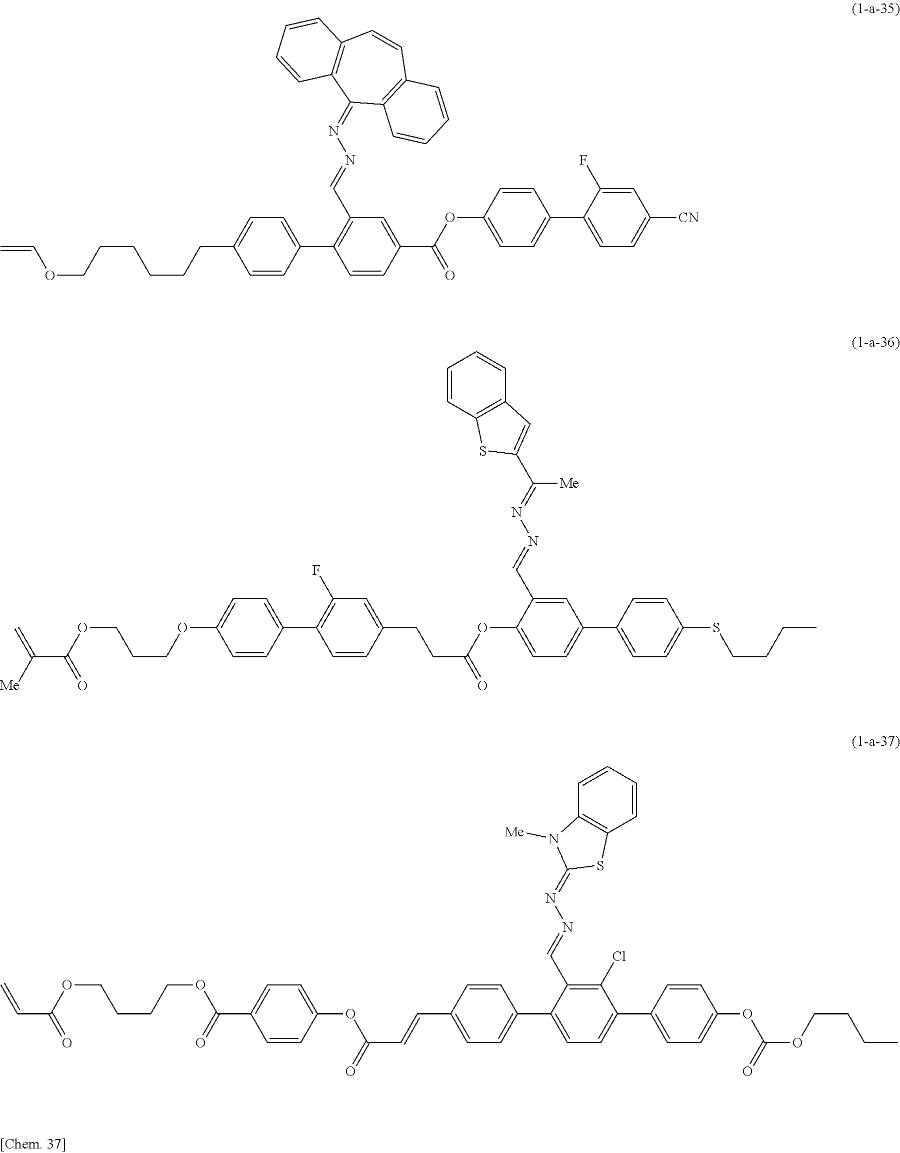

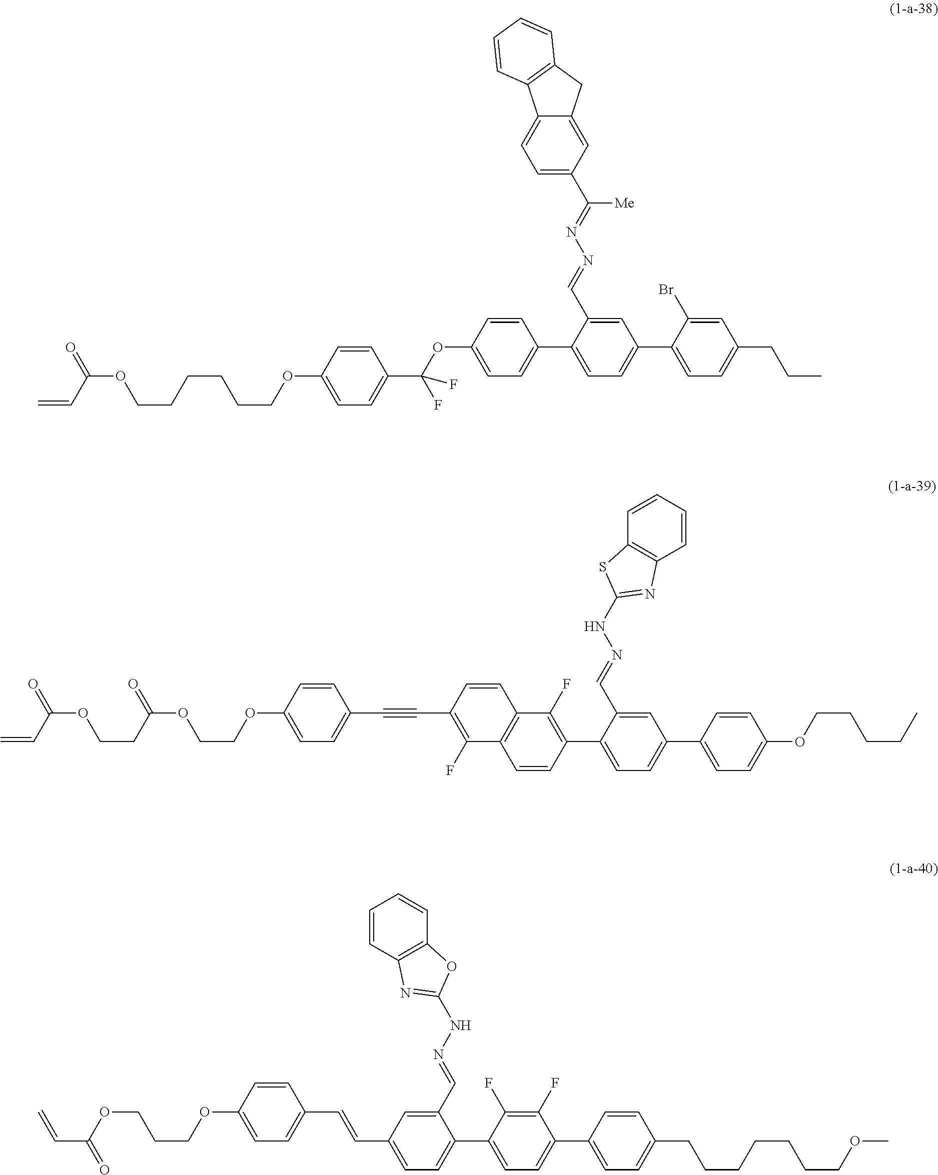

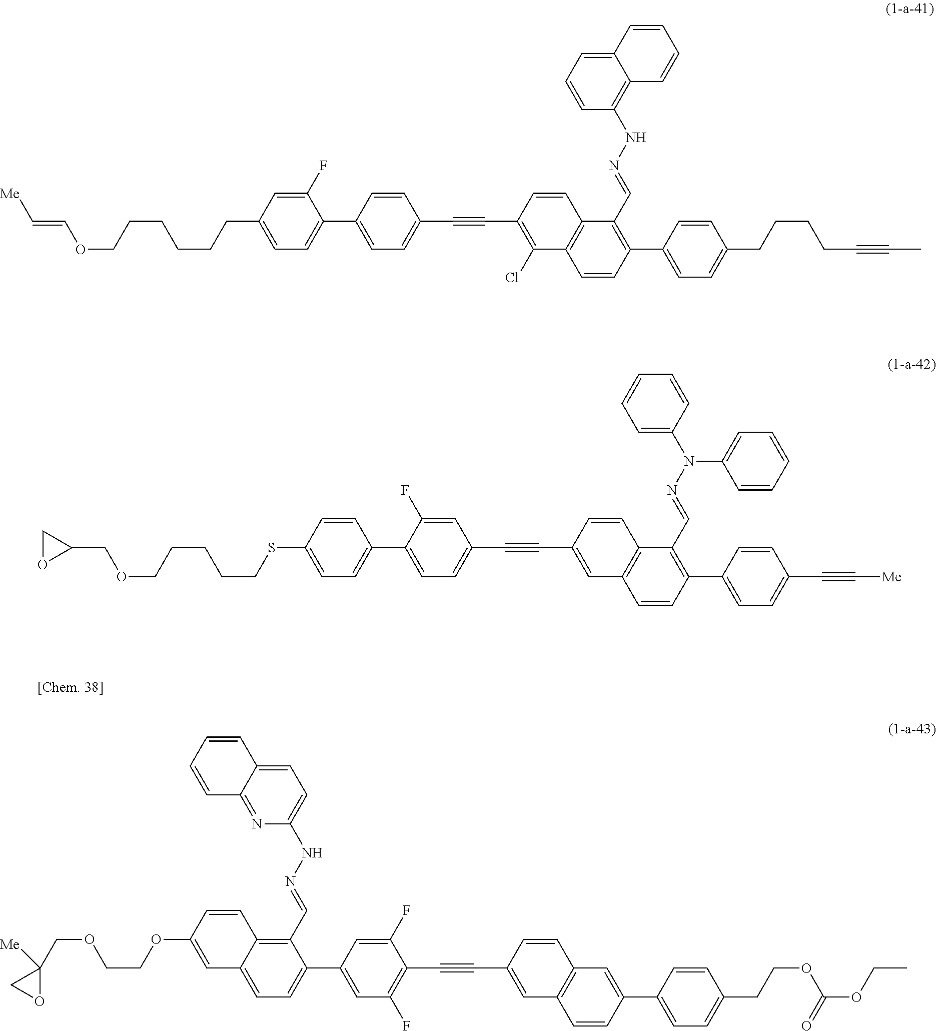

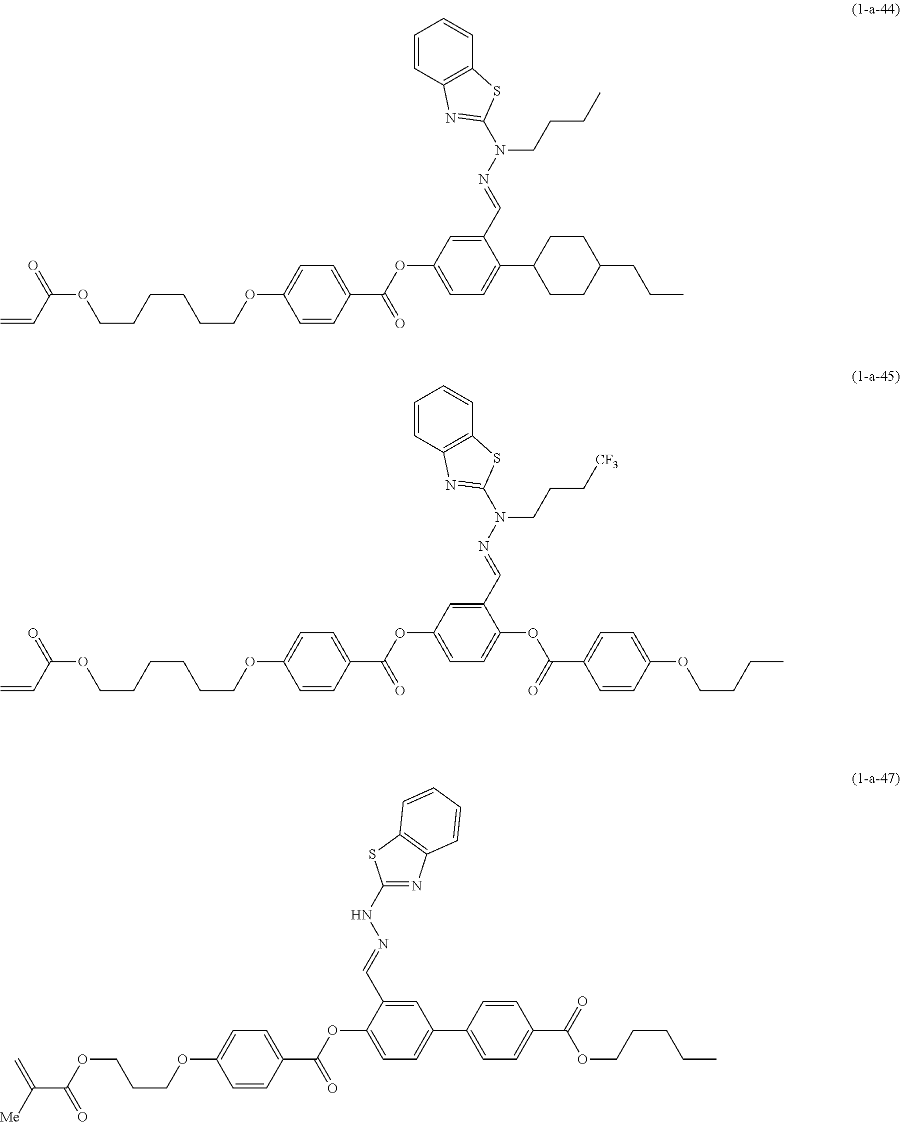

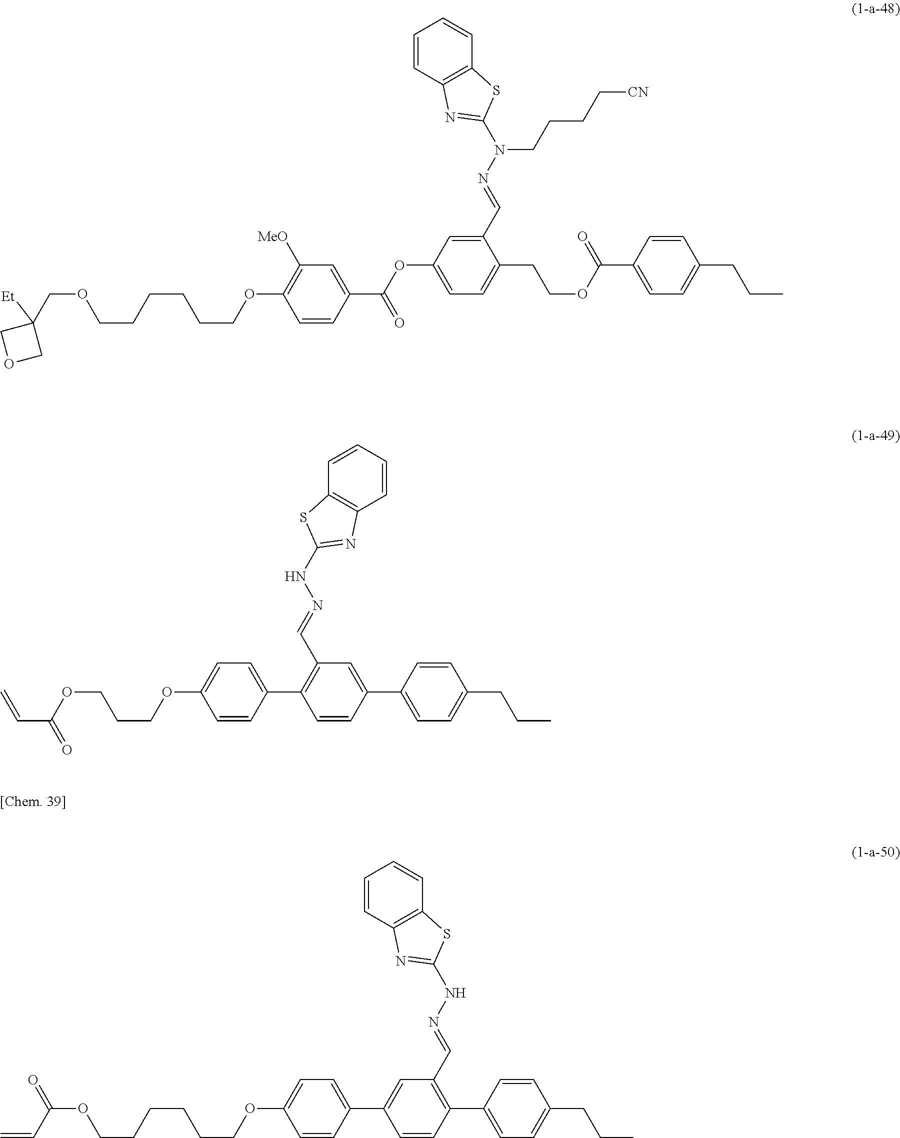

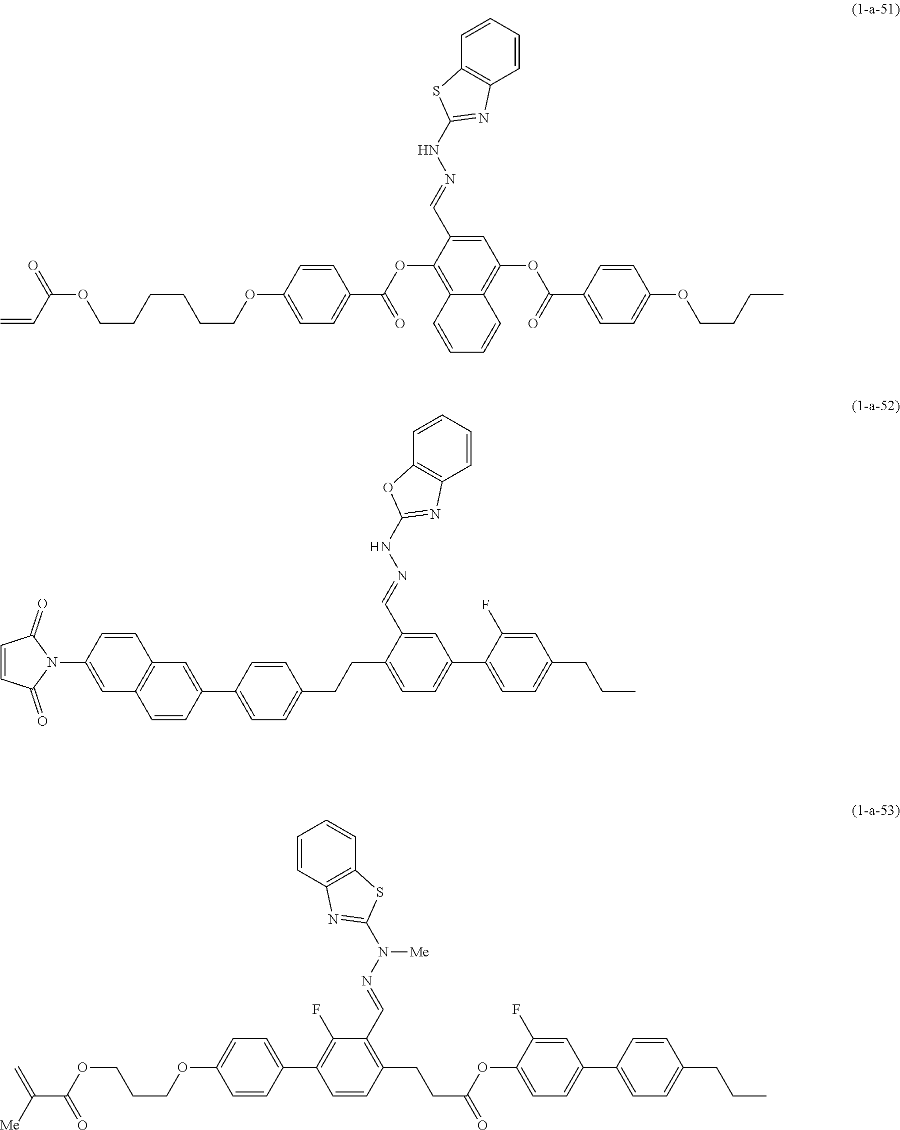

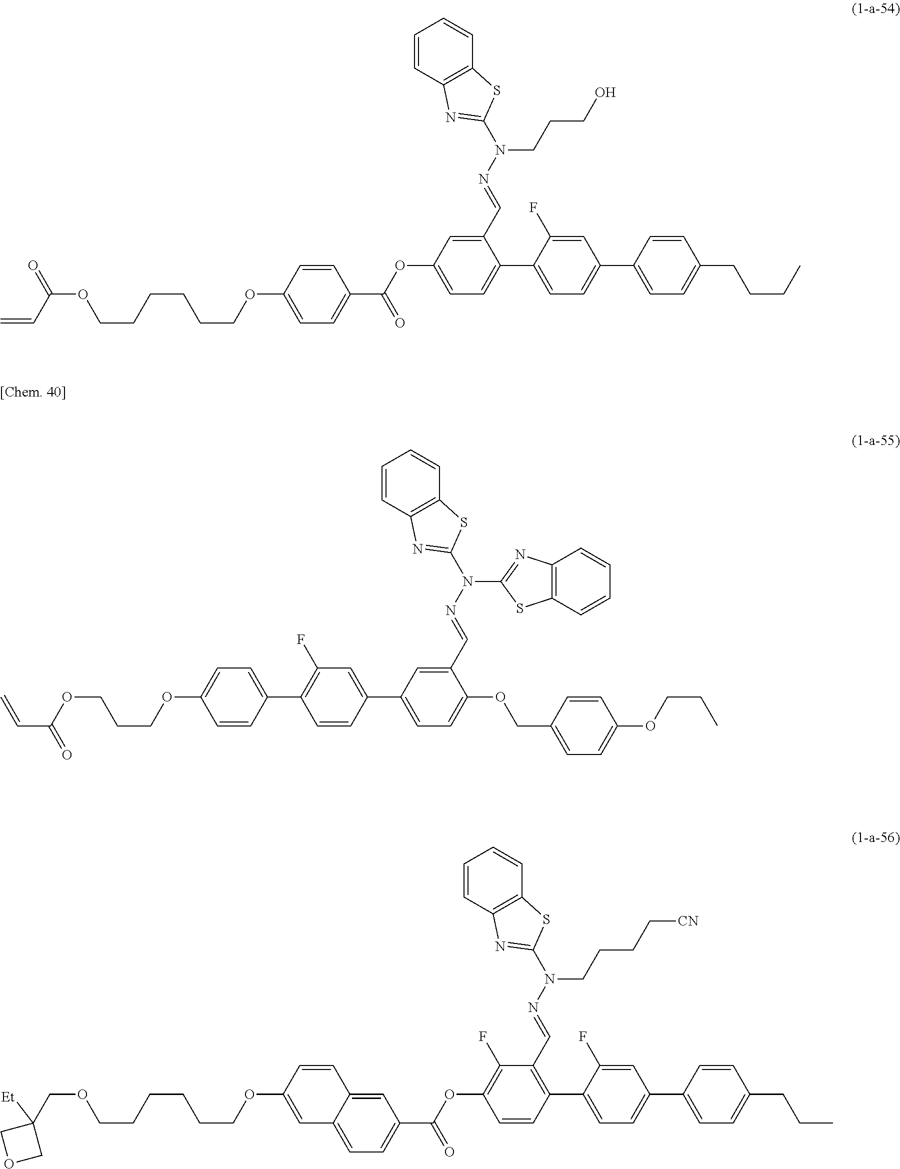

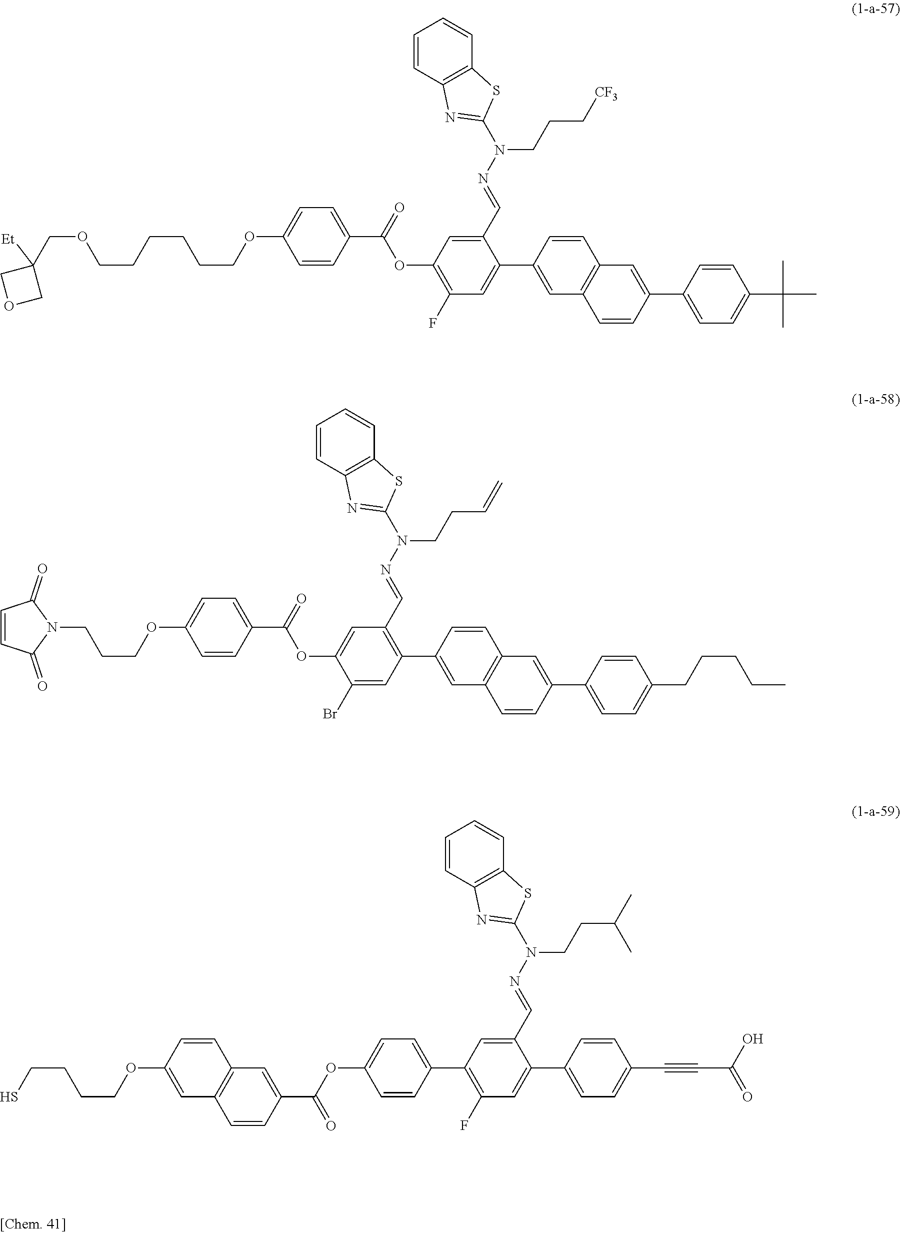

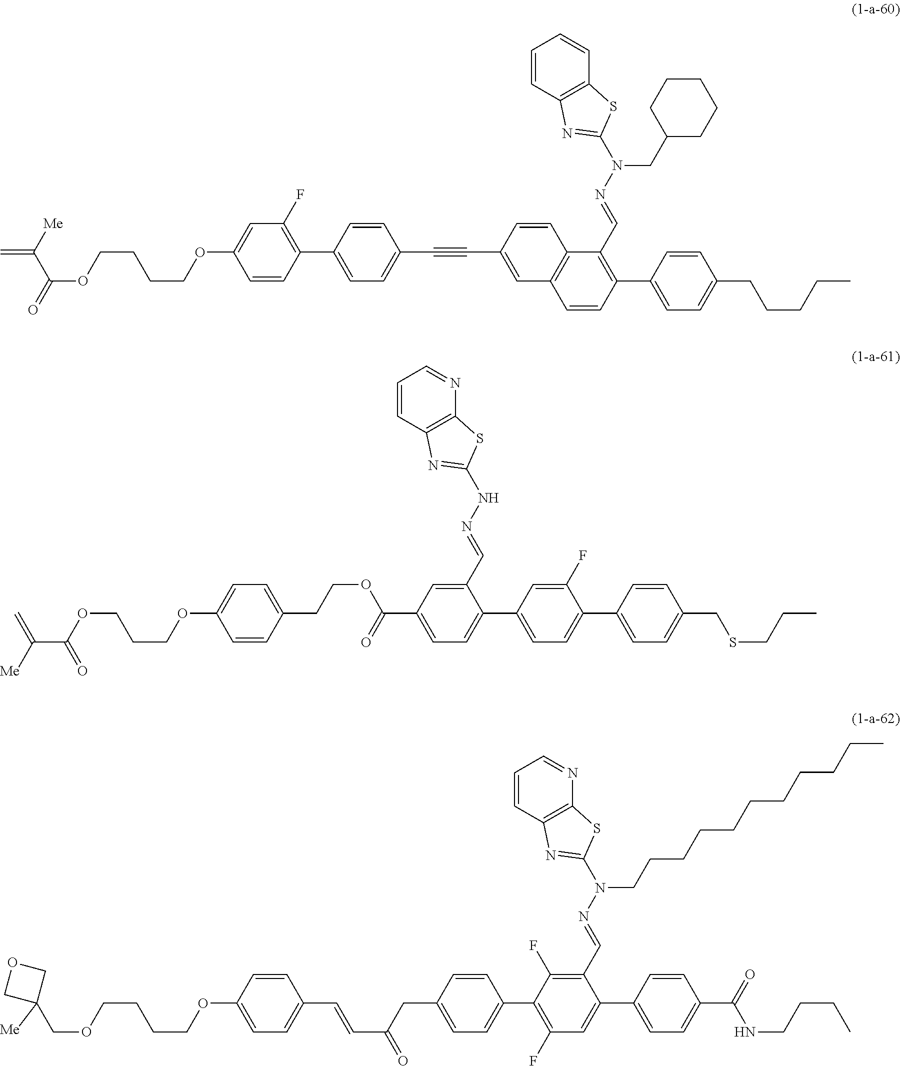

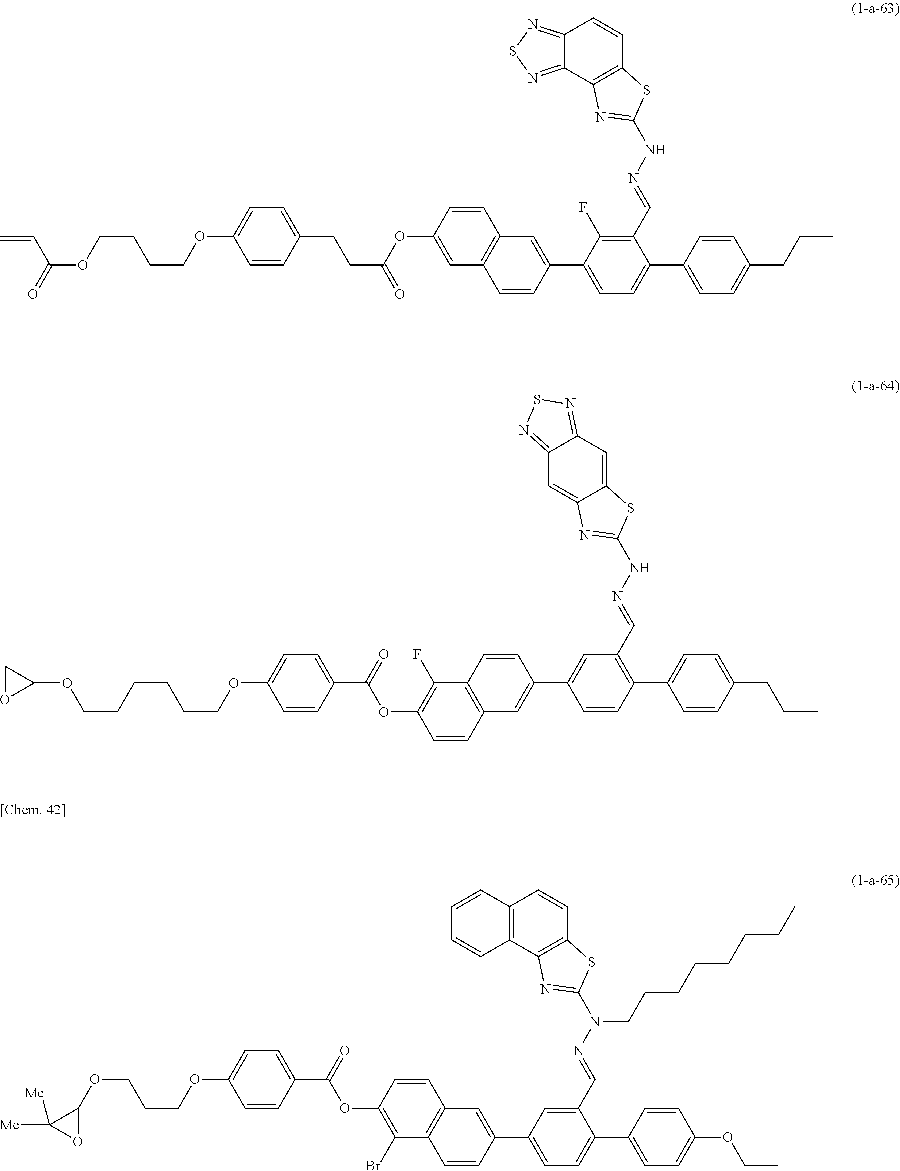

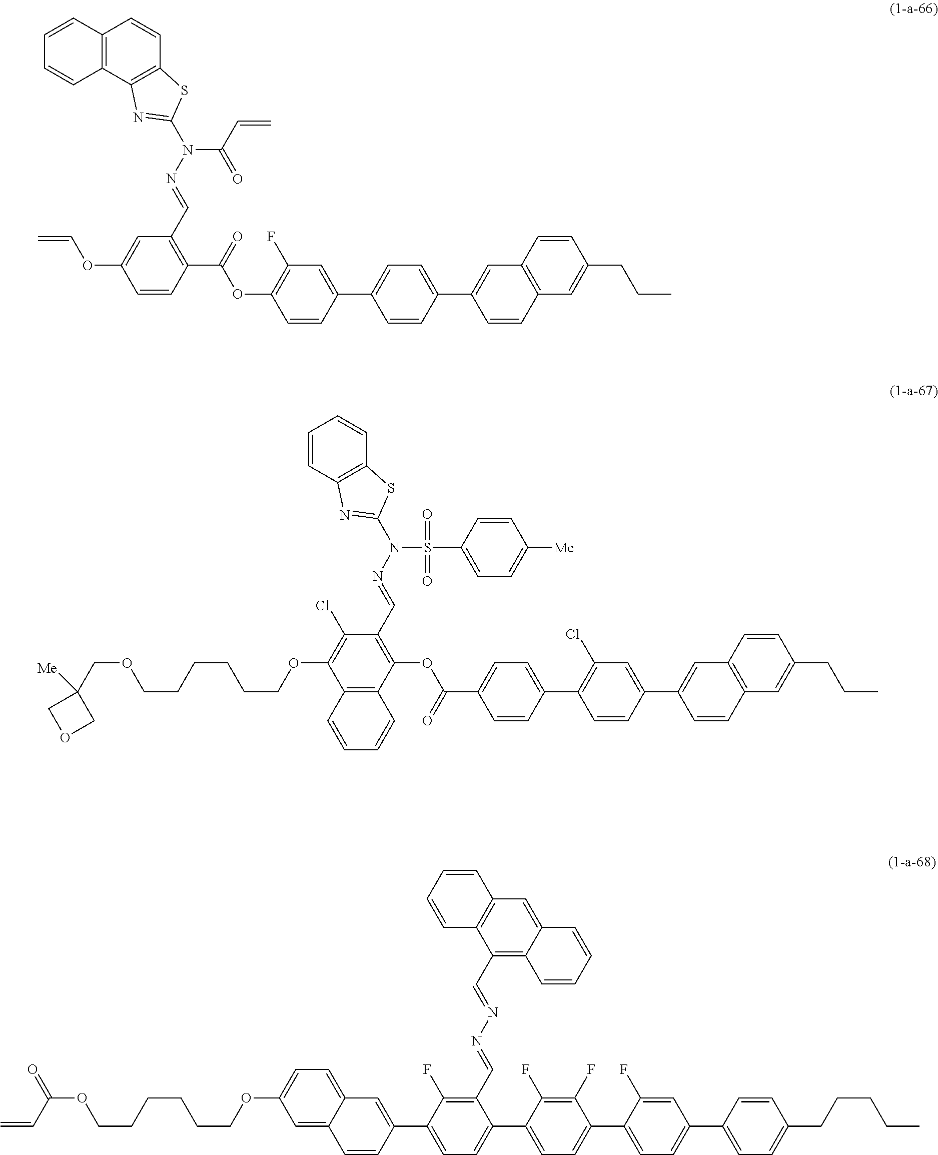

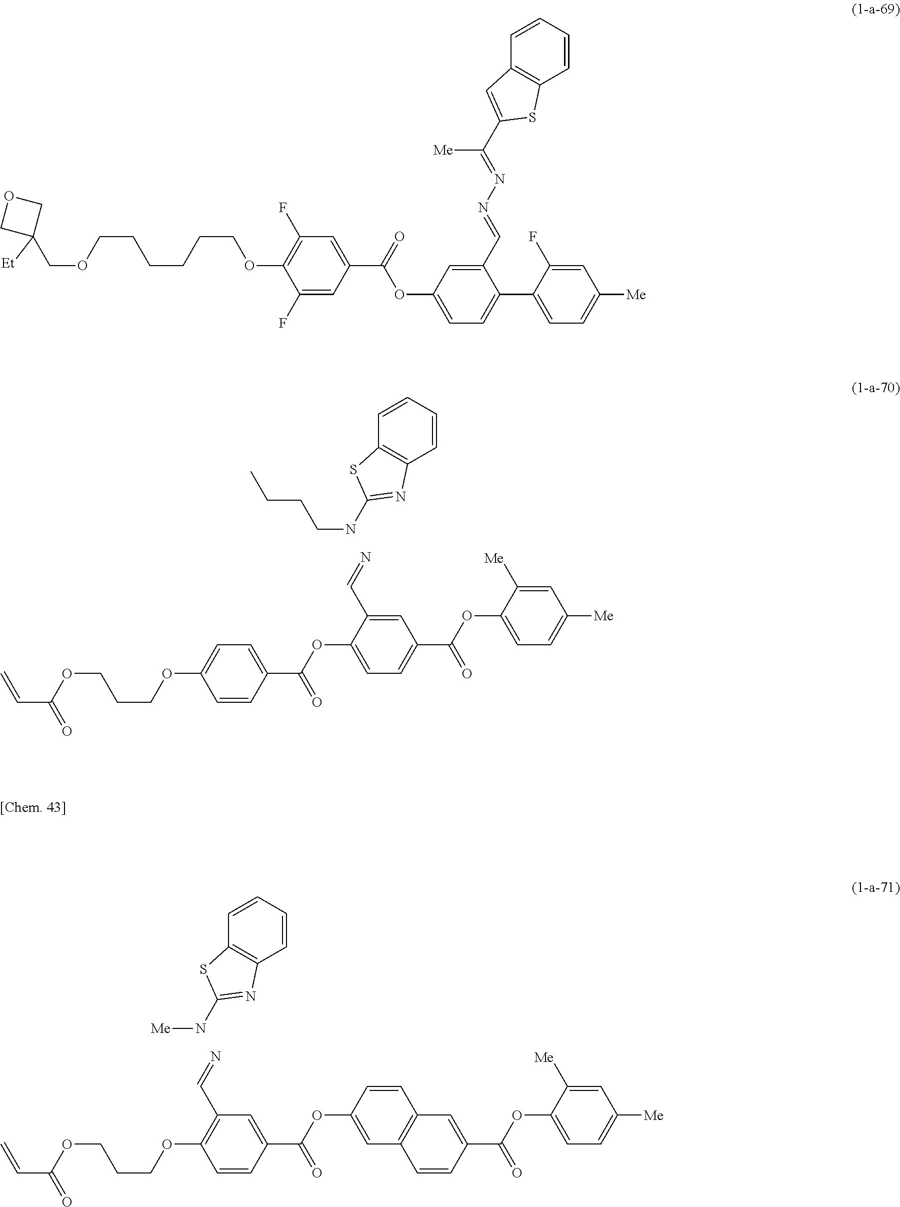

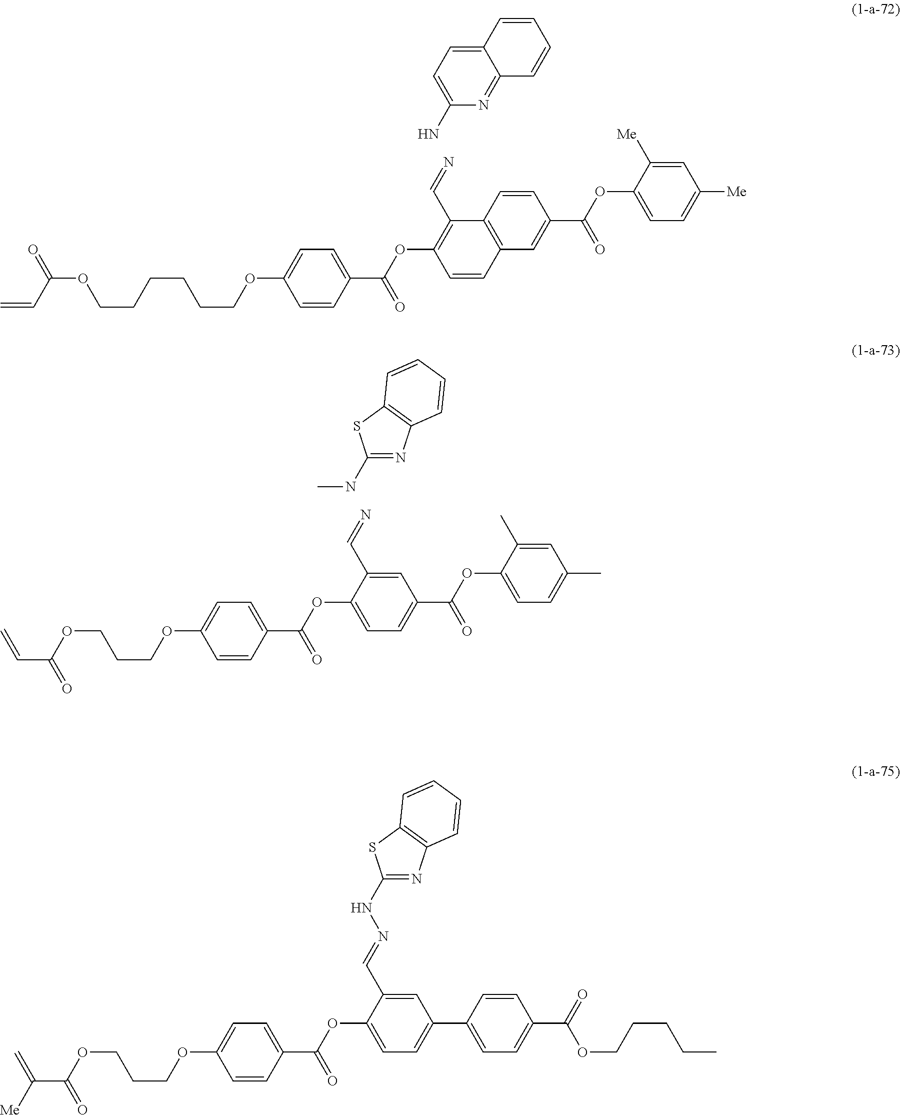

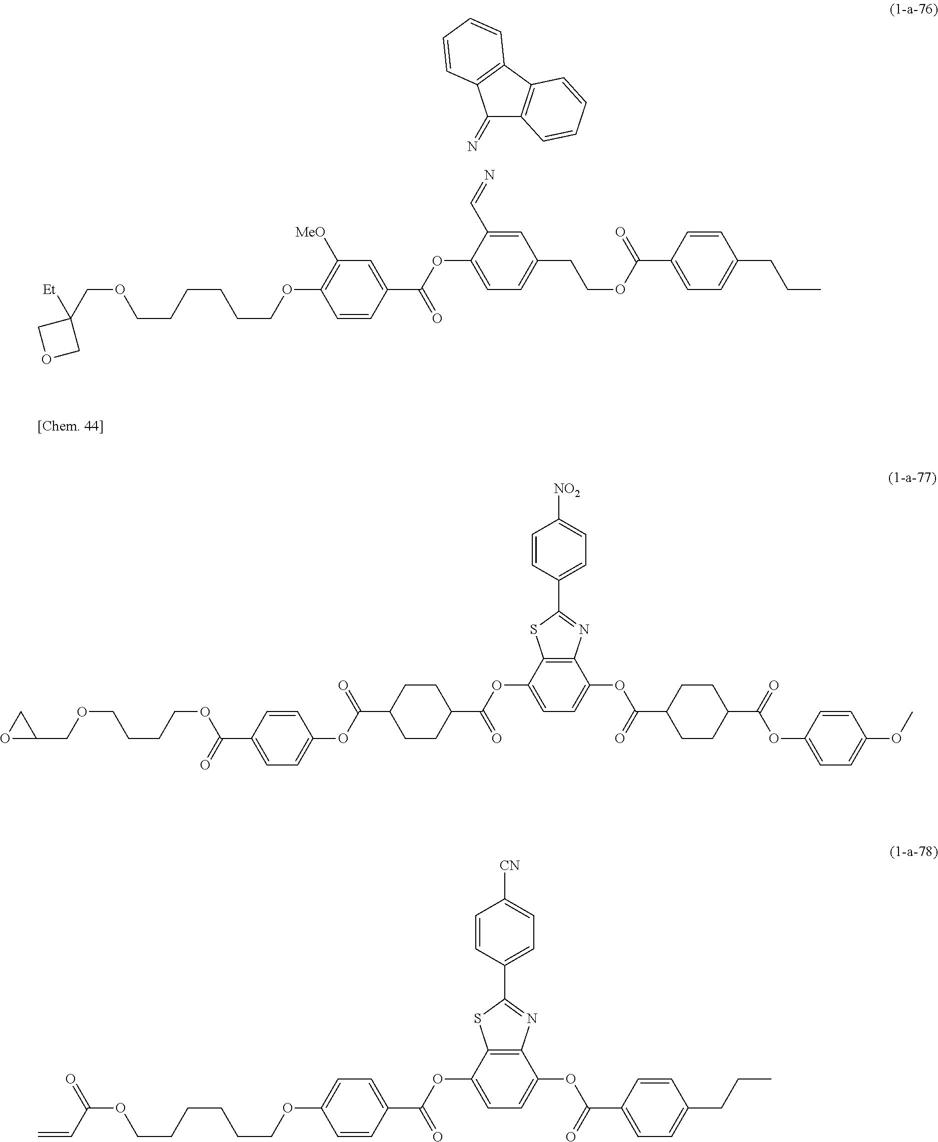

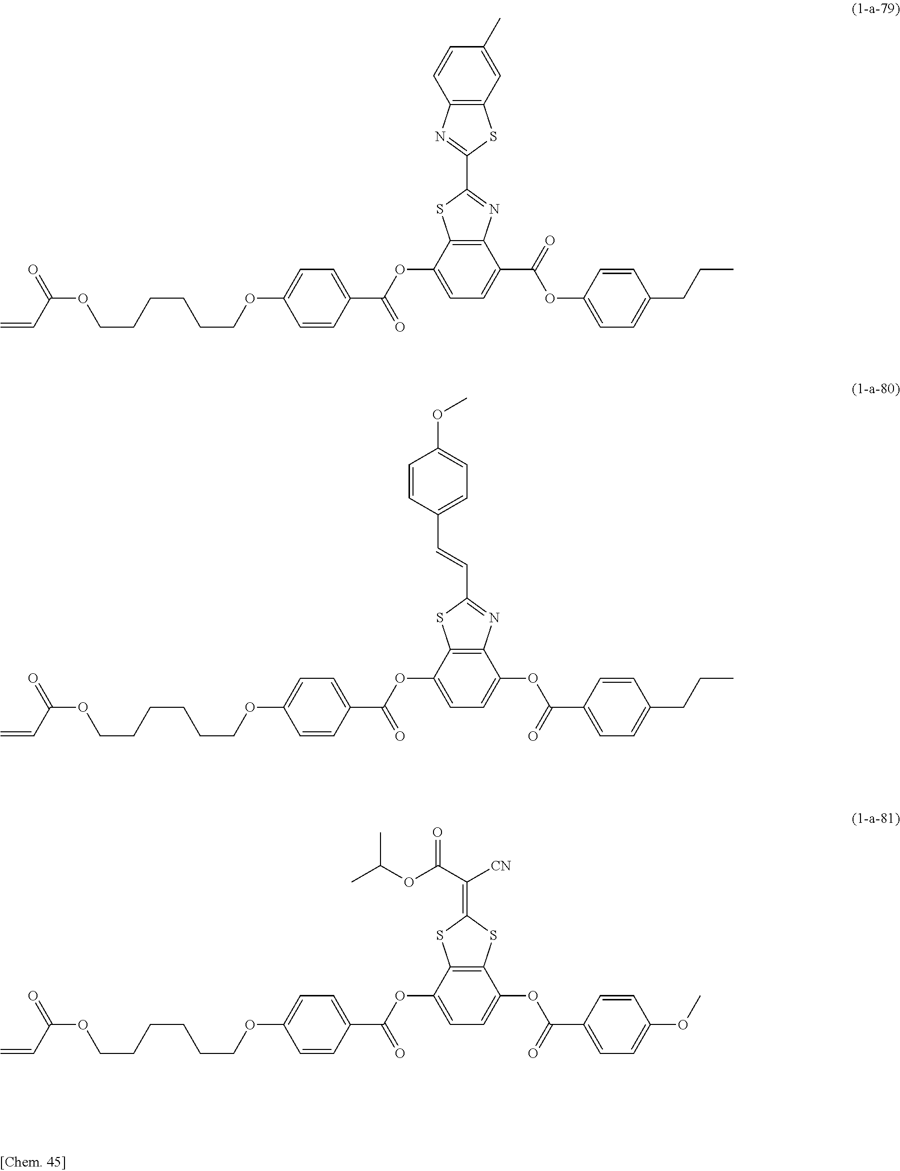

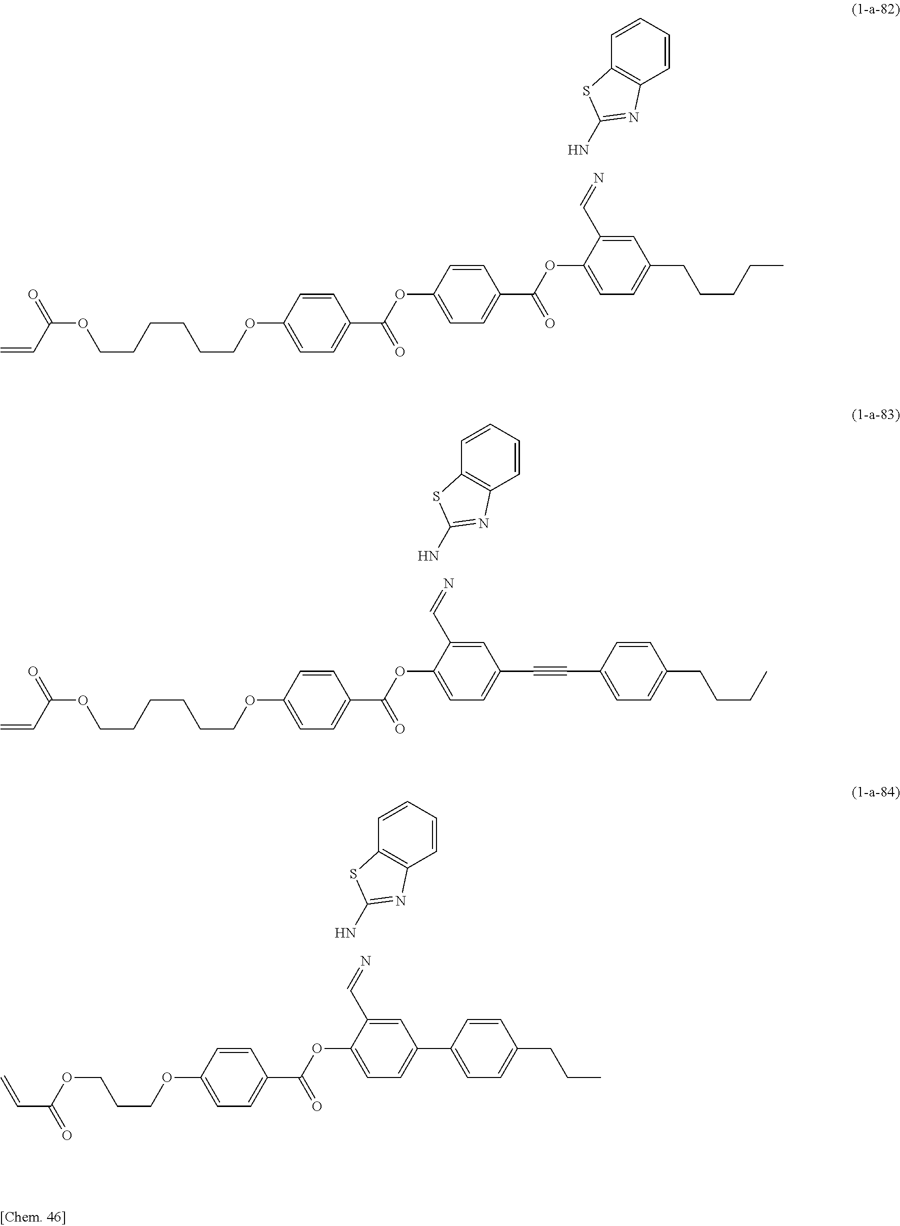

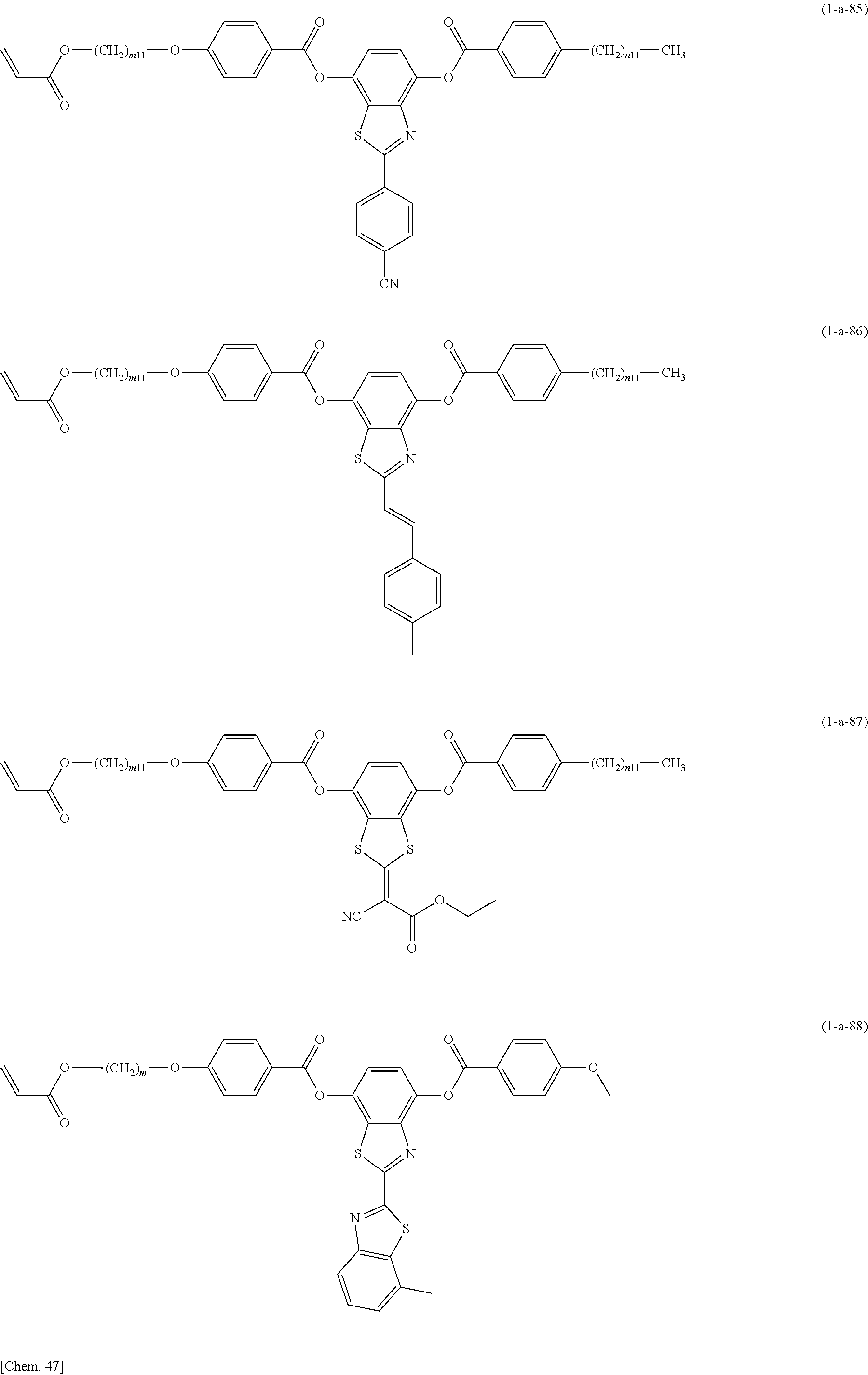

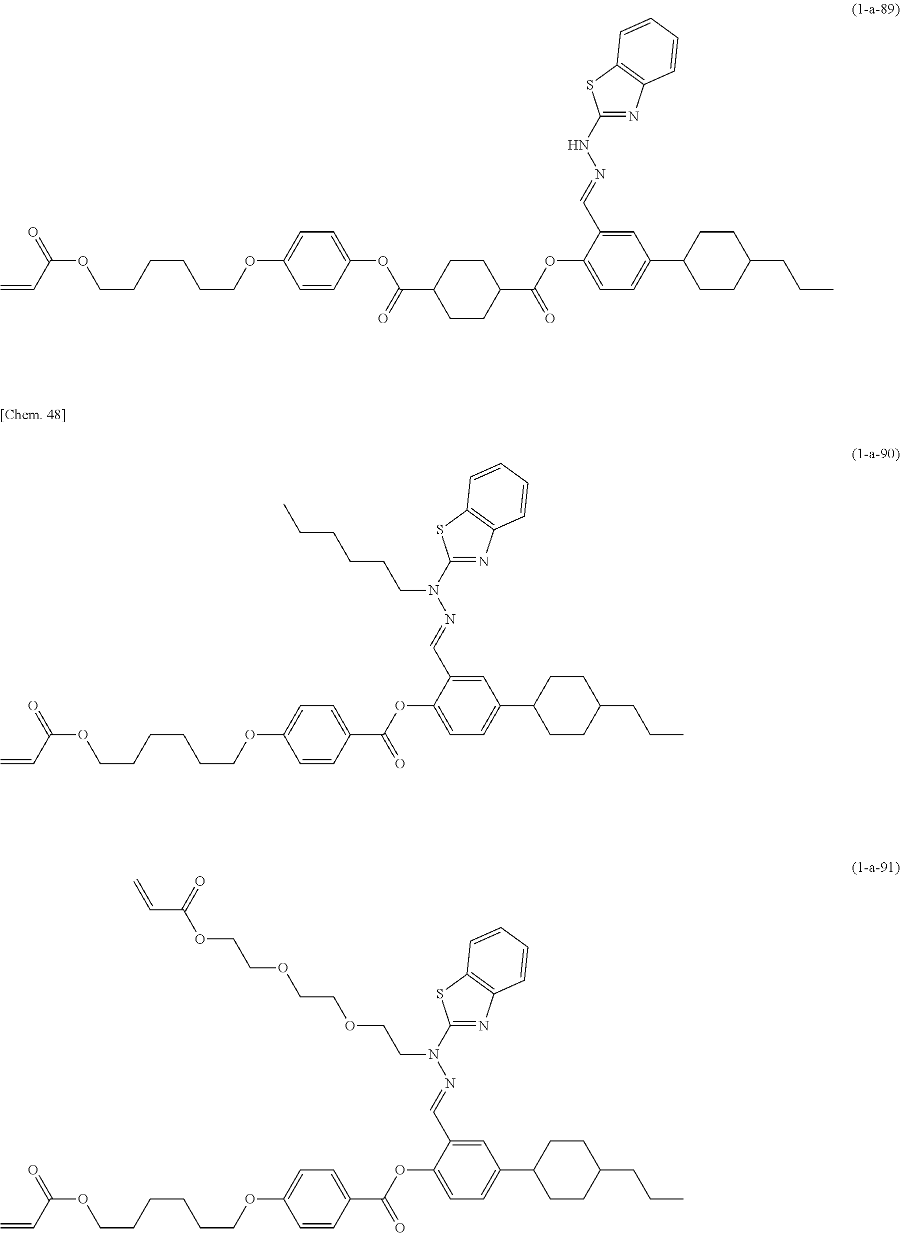

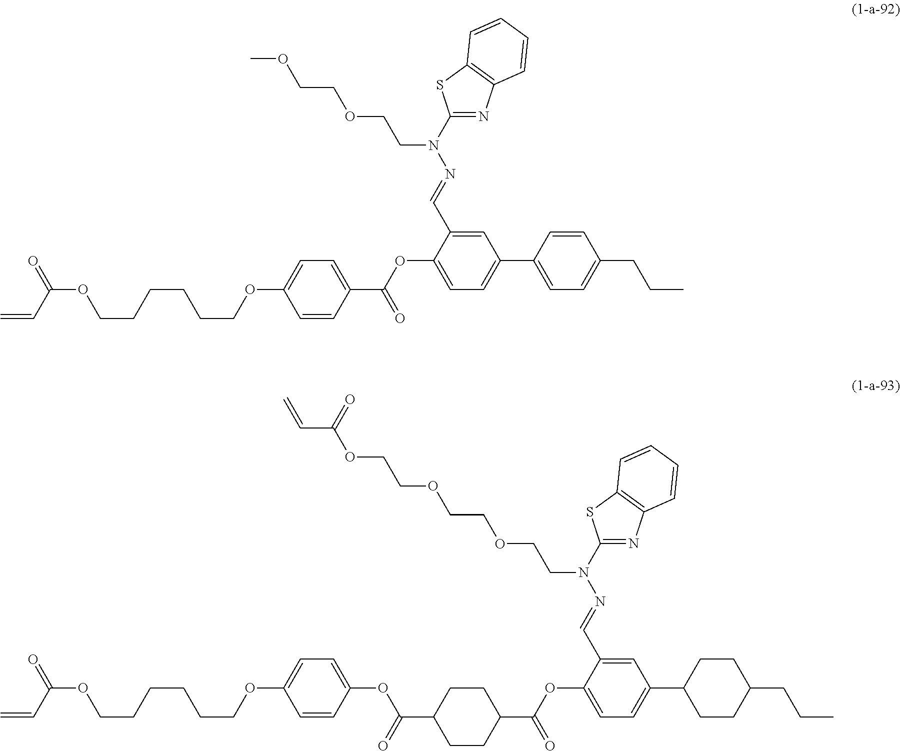

These liquid-crystal compounds may be used alone or in combination of two or more thereof.

Specific preferred examples of the compound represented by General formula (2) include compounds represented by the following Formula (2-a-1) to Formula (2-a-68).

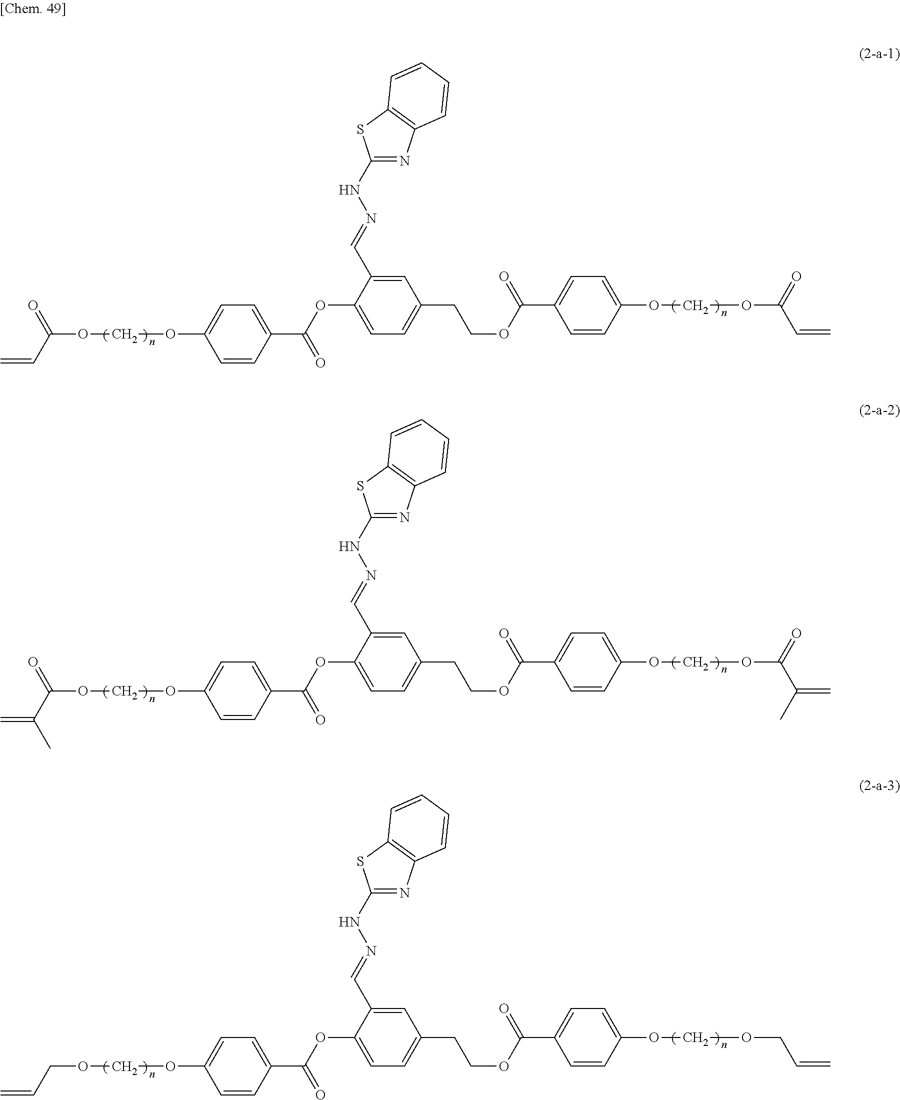

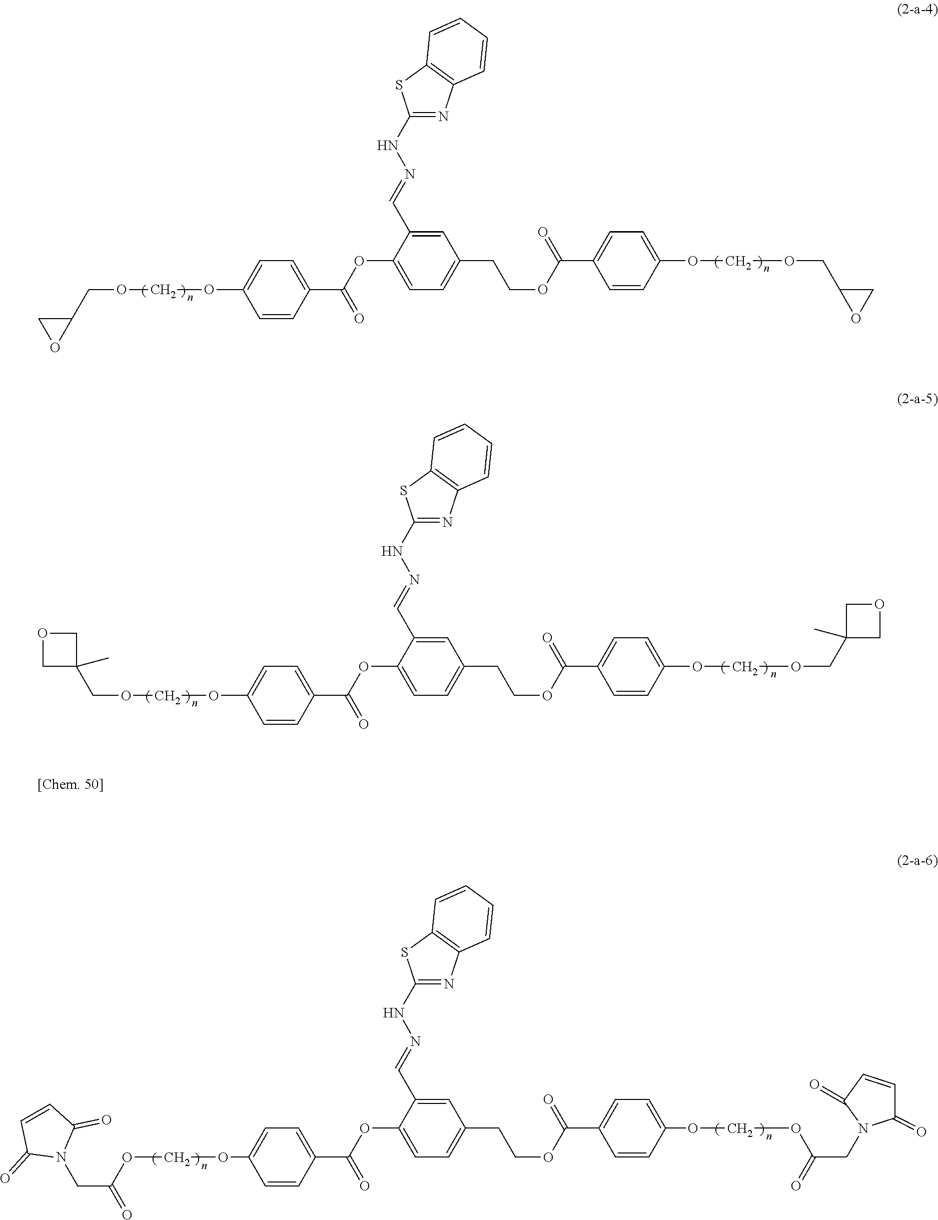

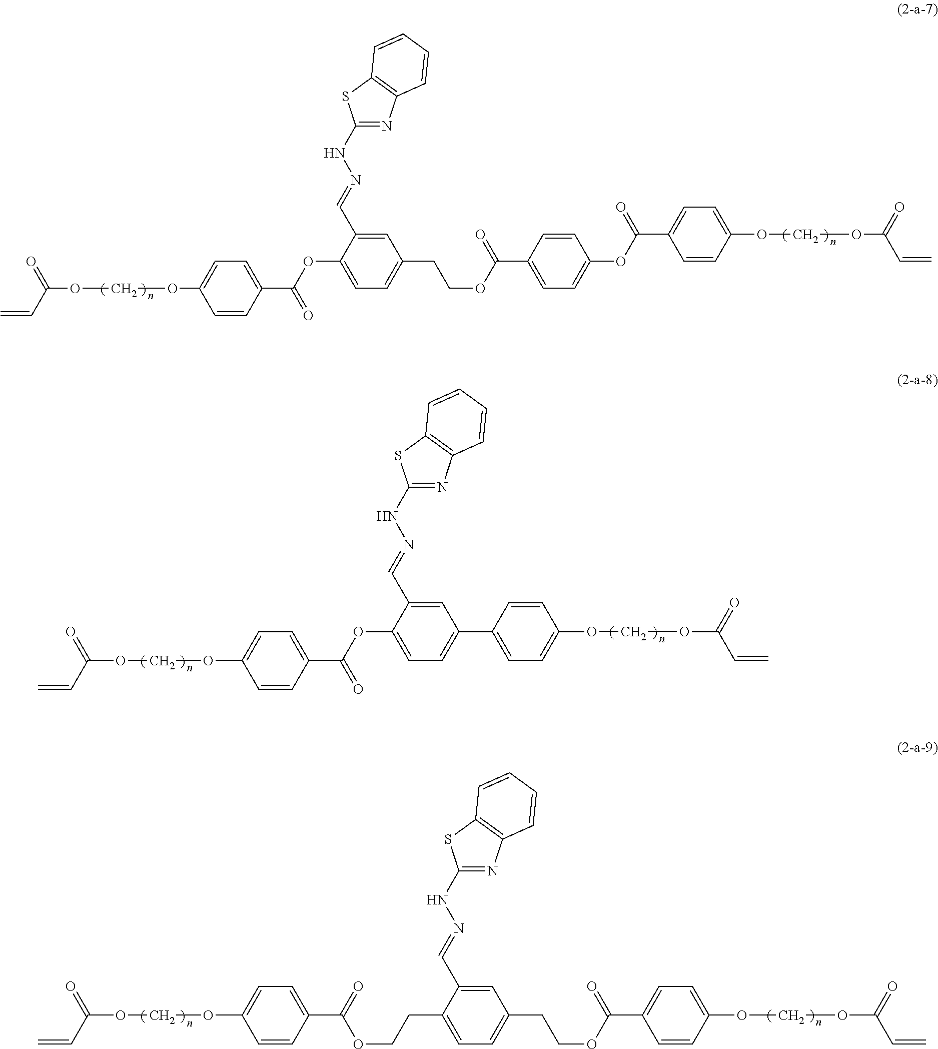

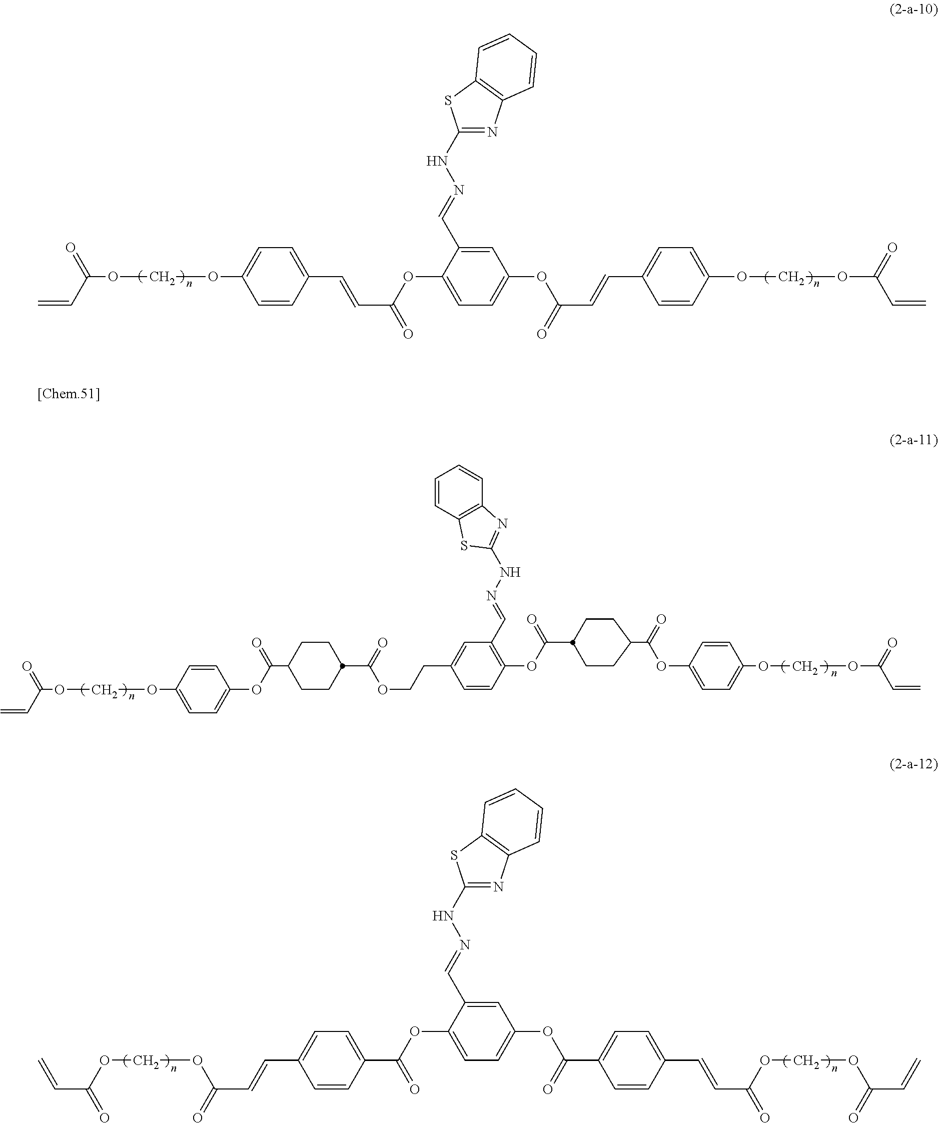

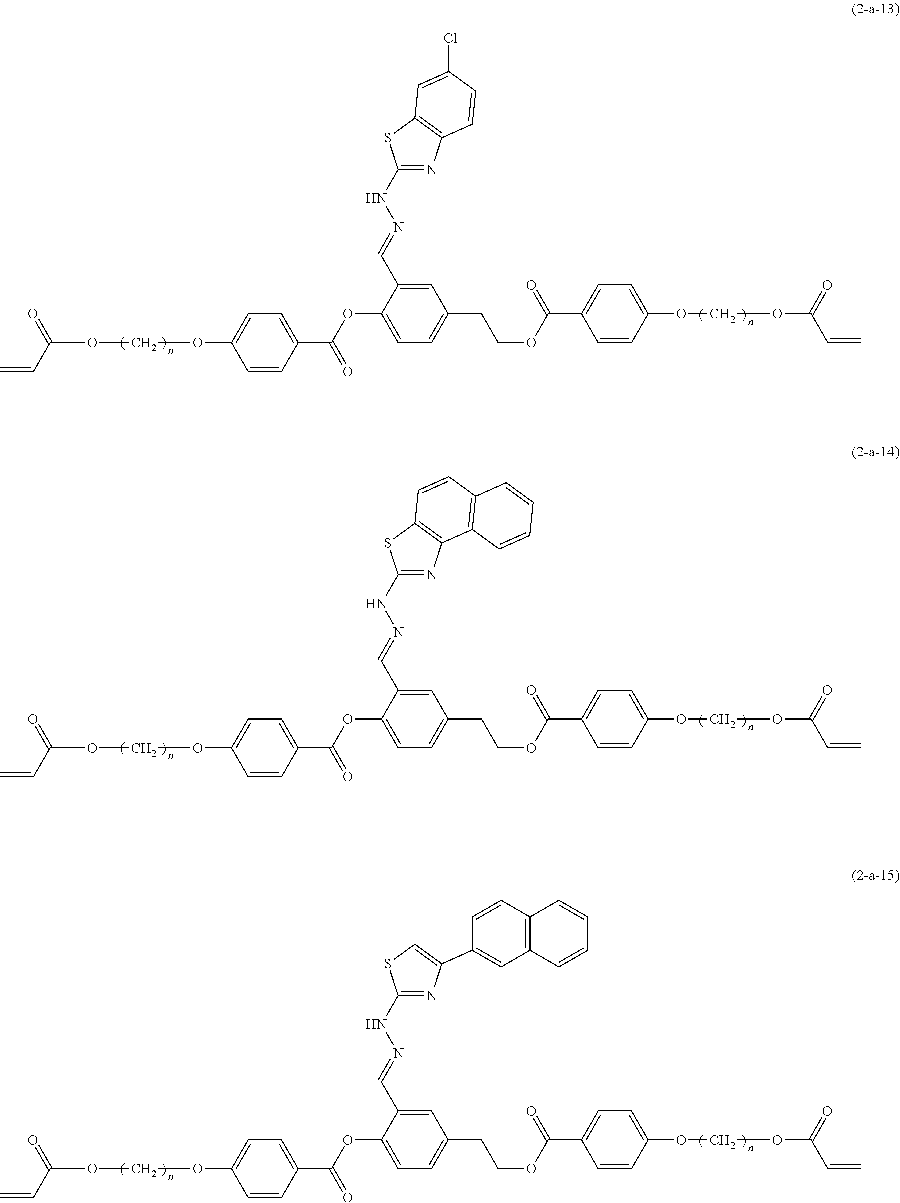

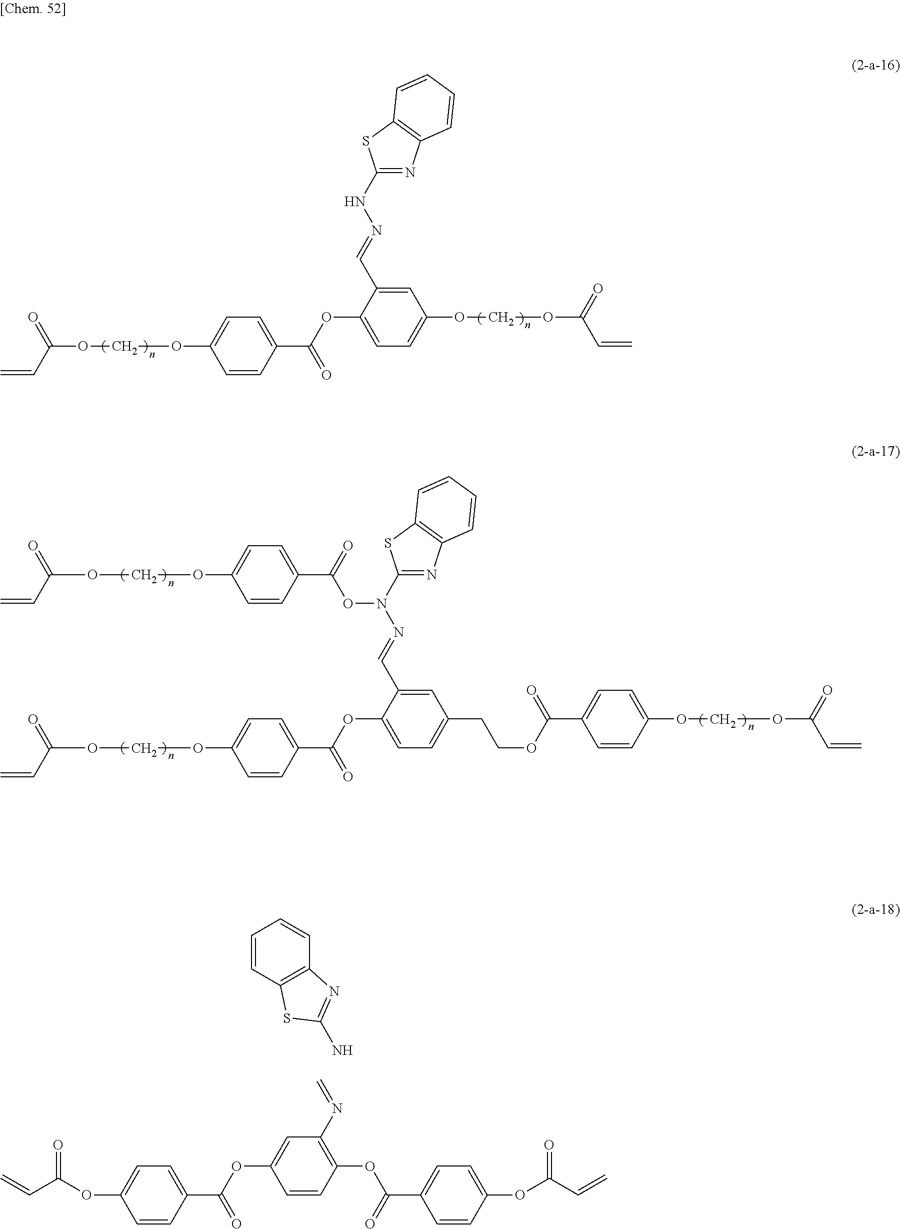

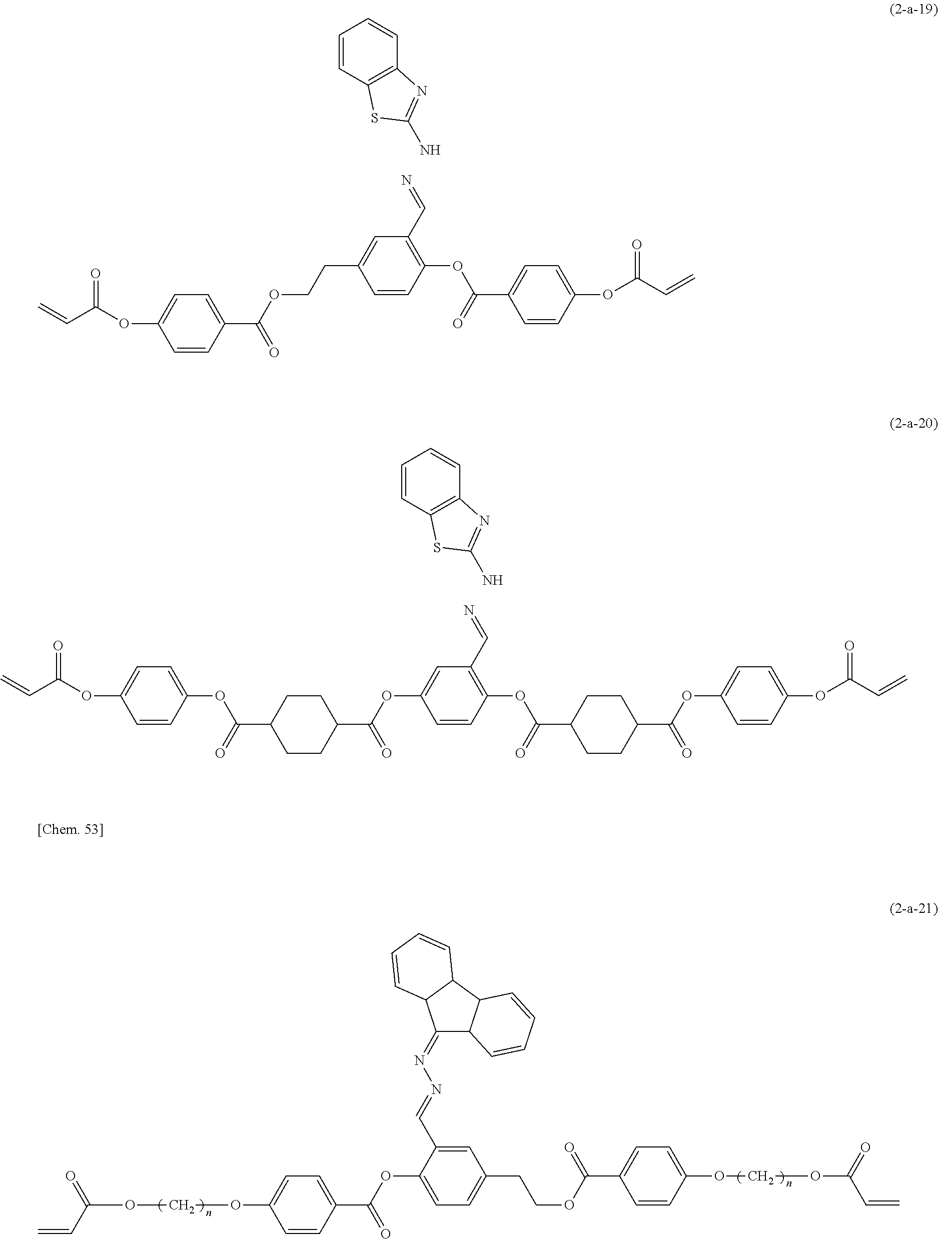

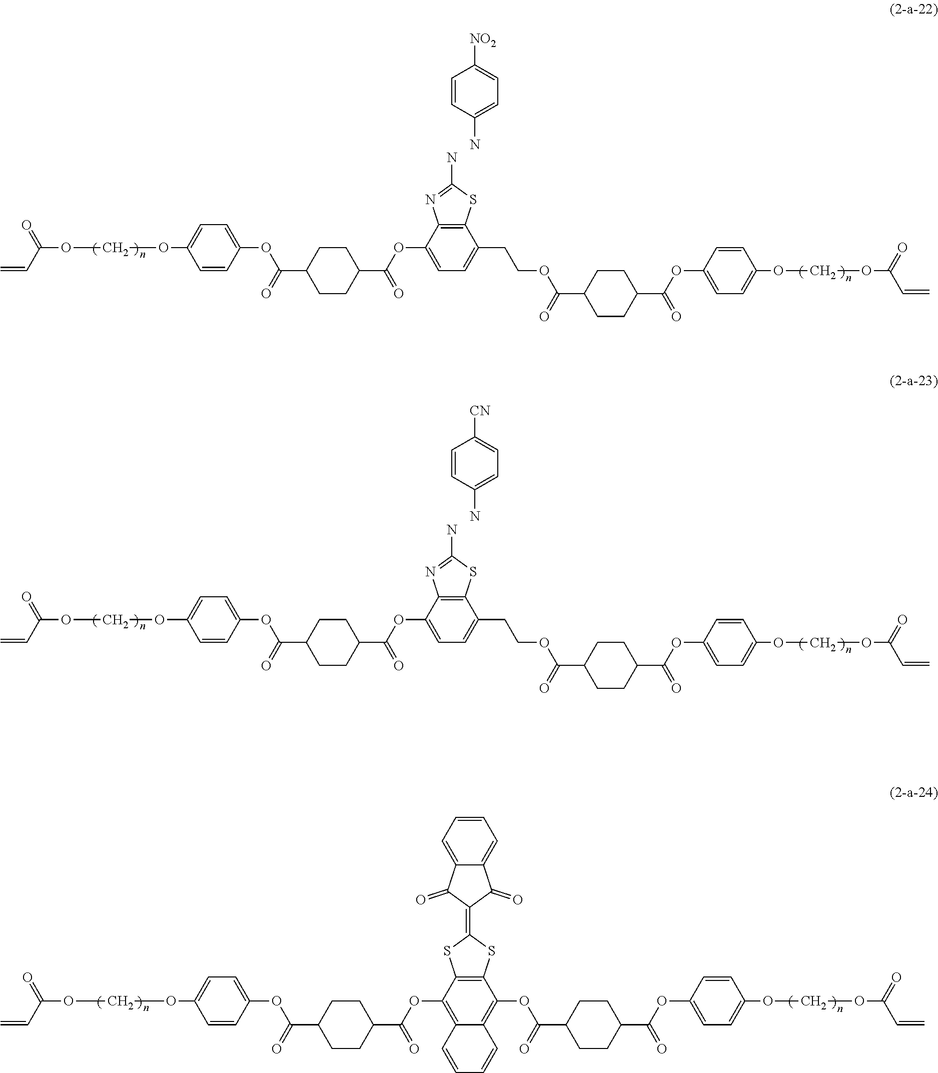

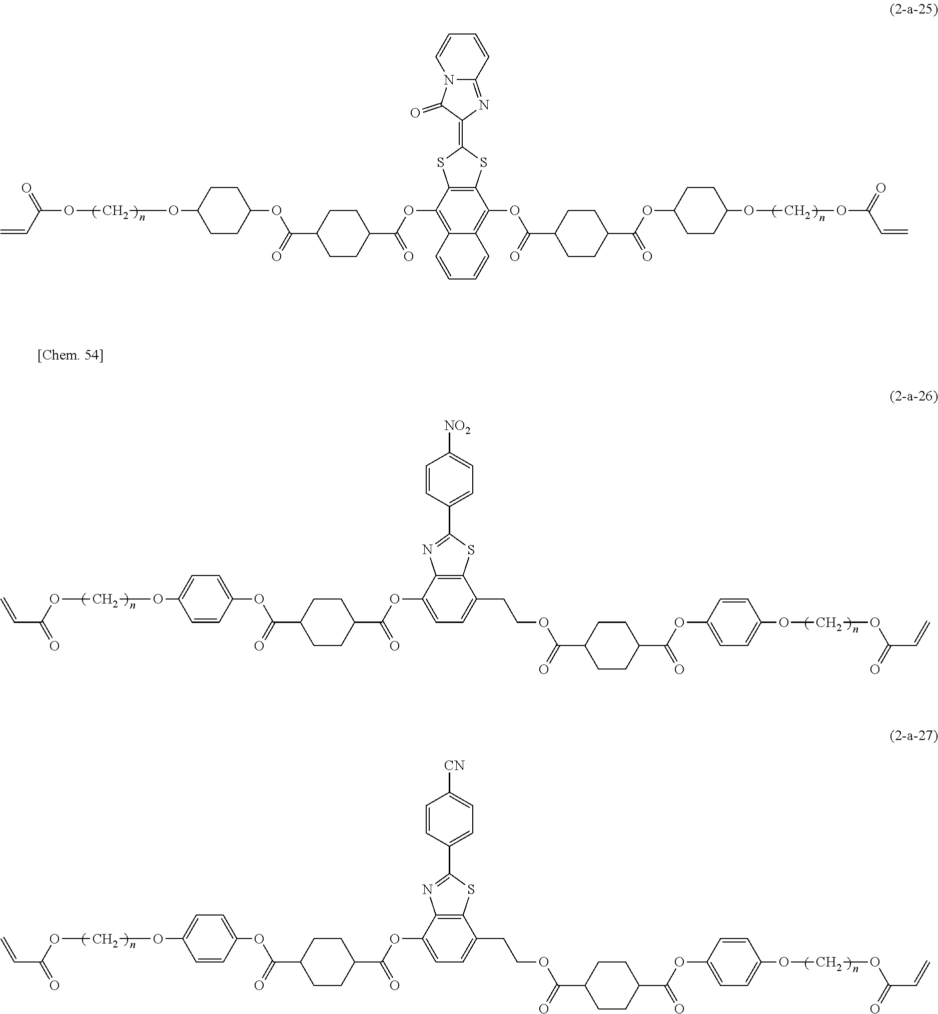

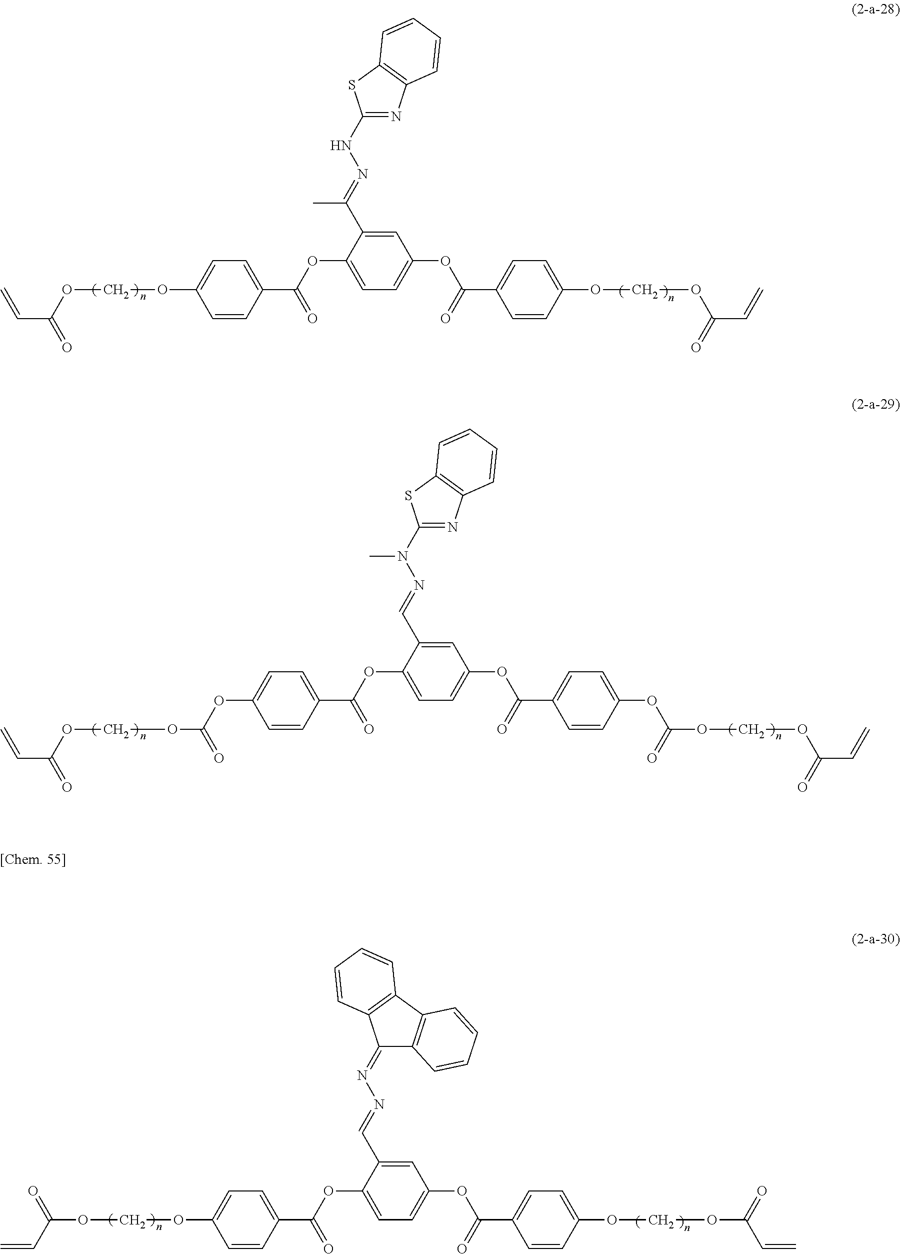

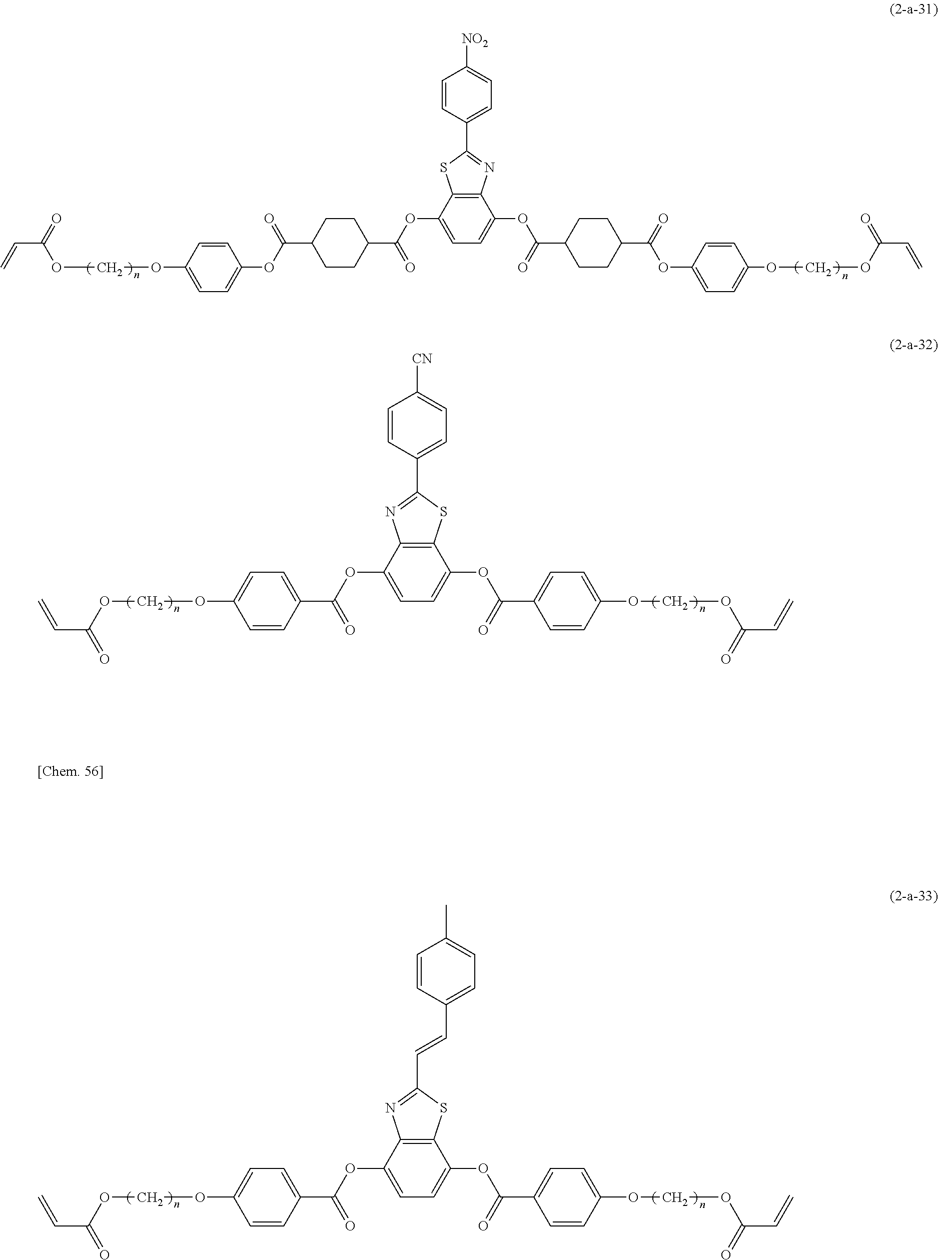

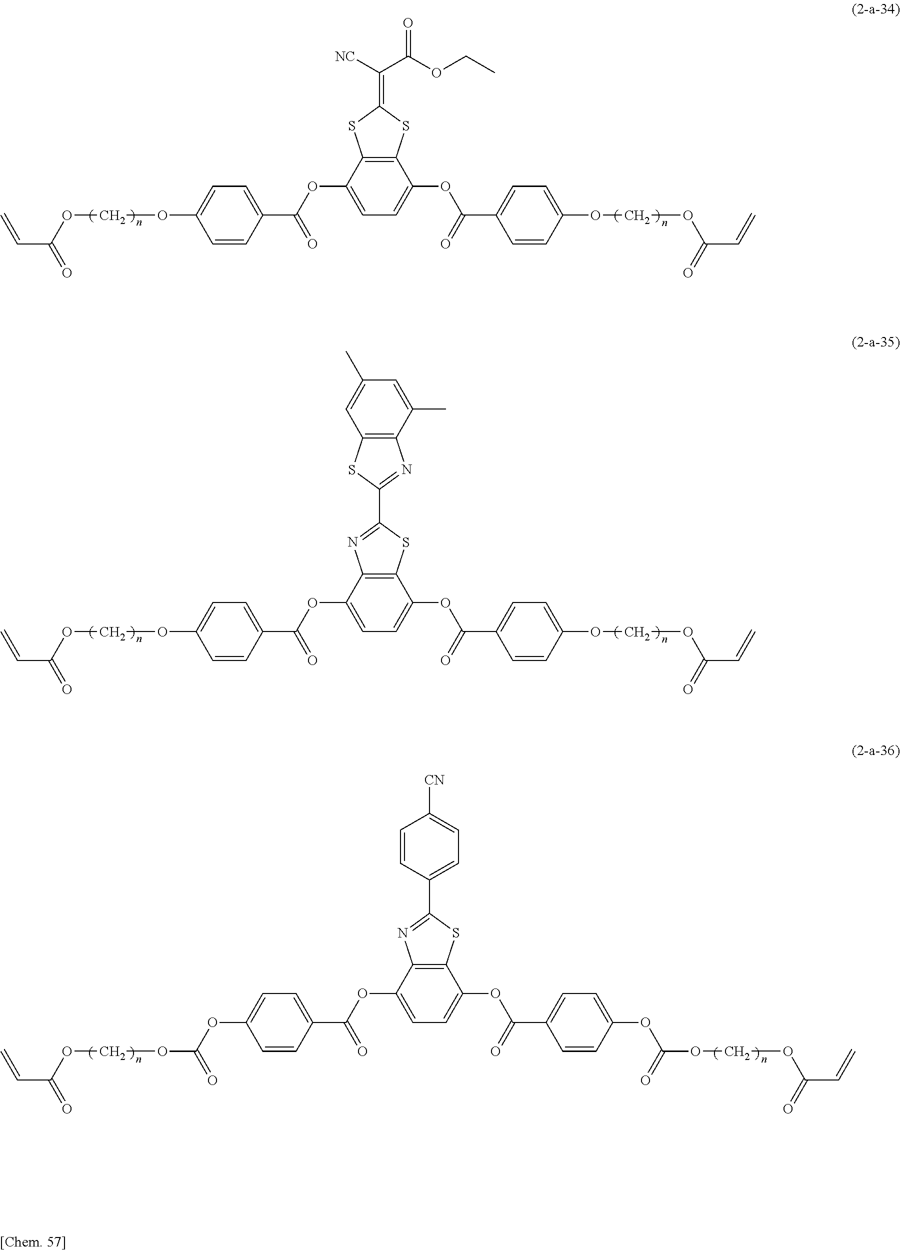

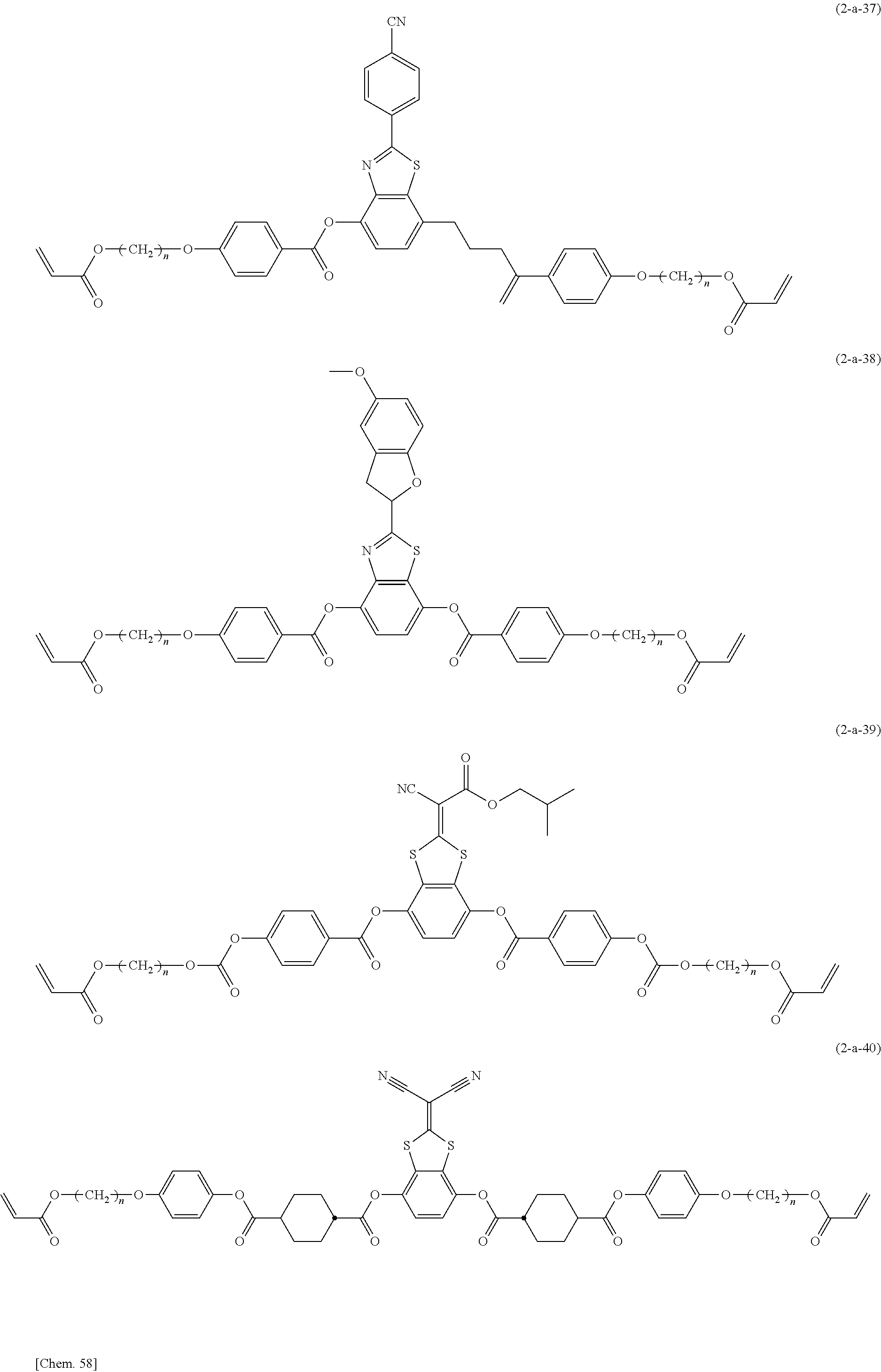

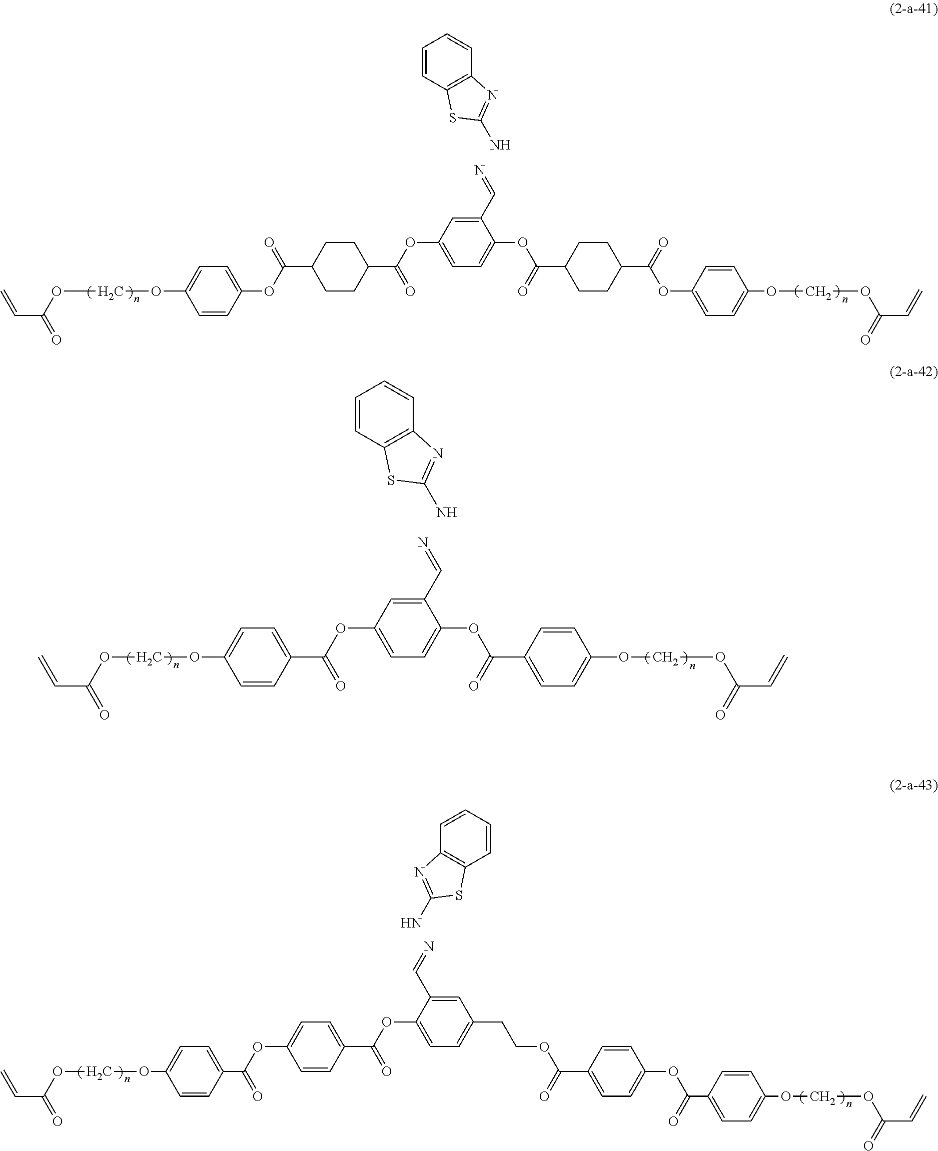

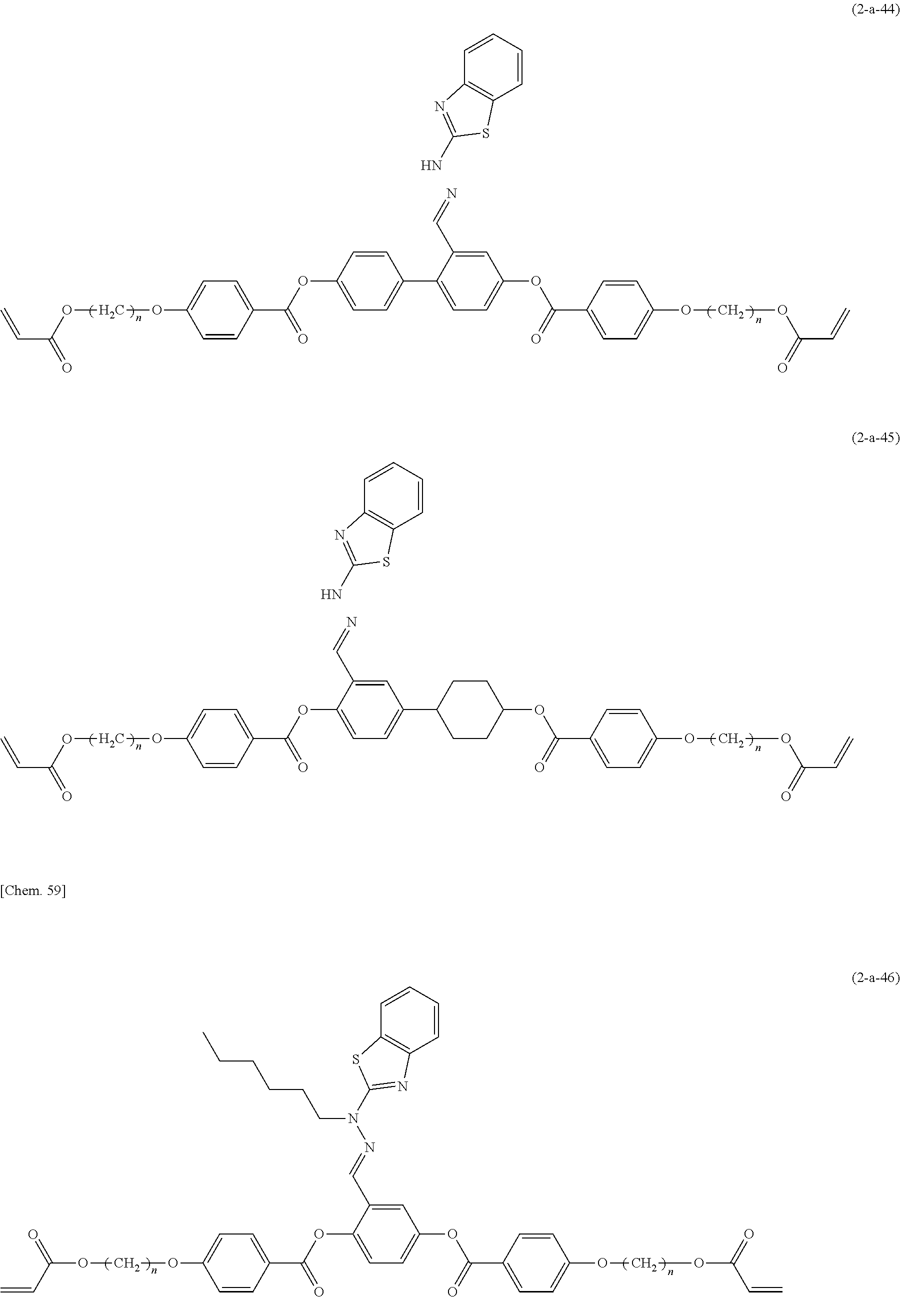

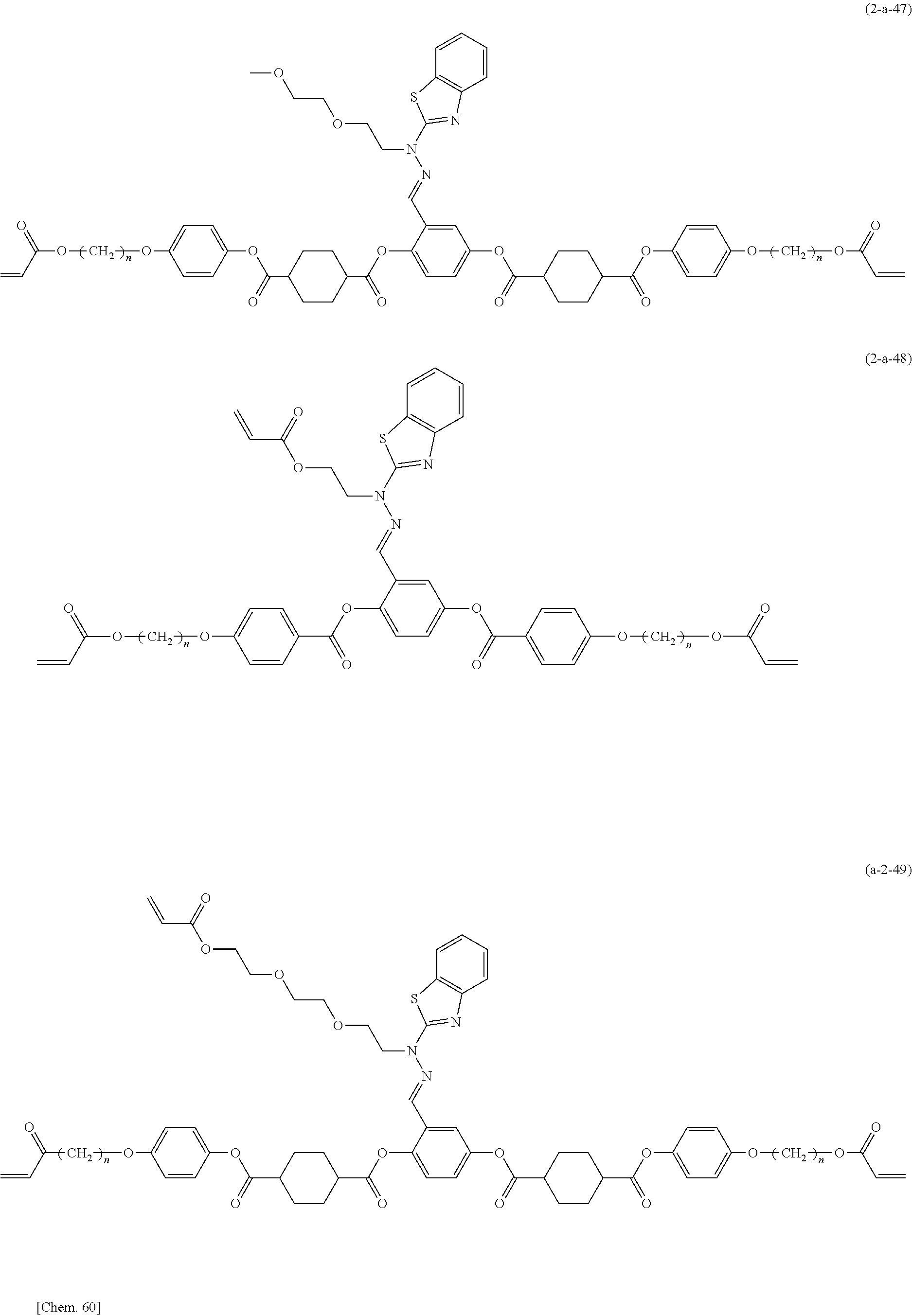

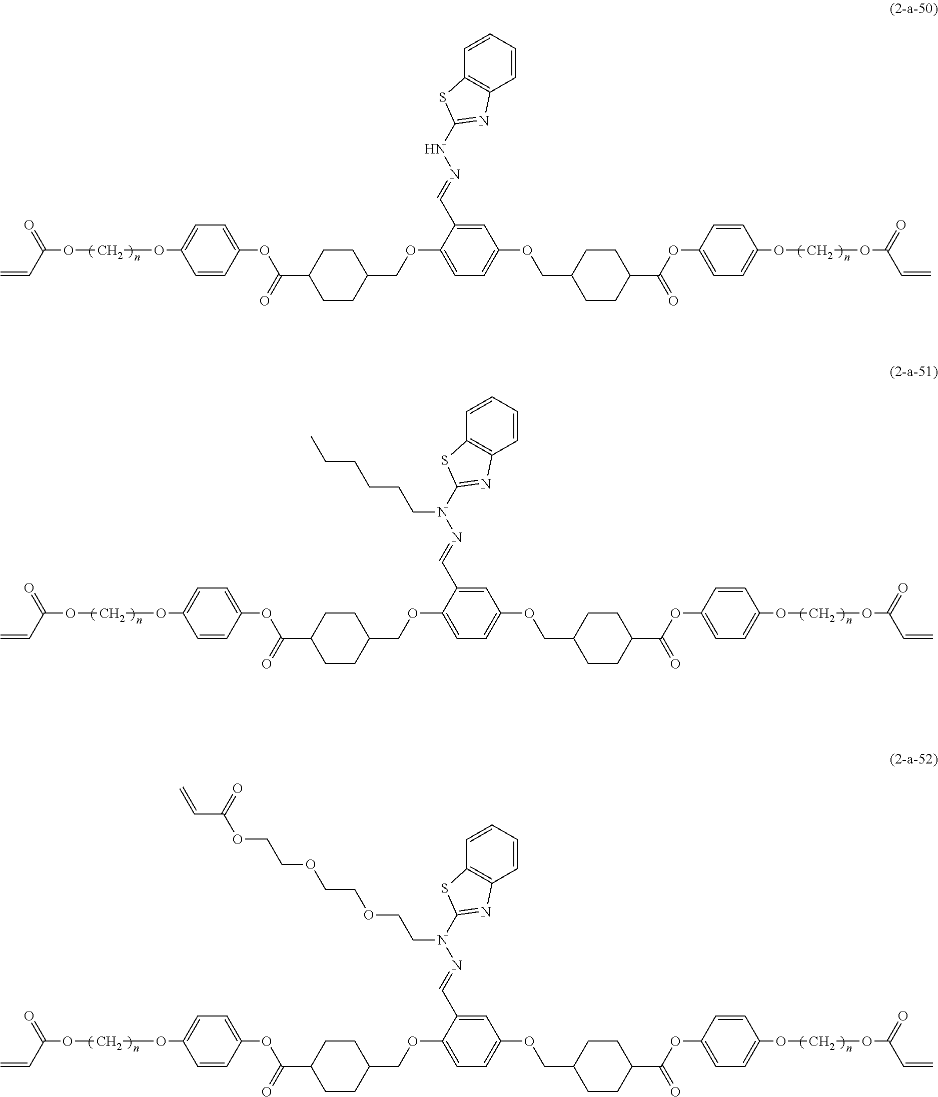

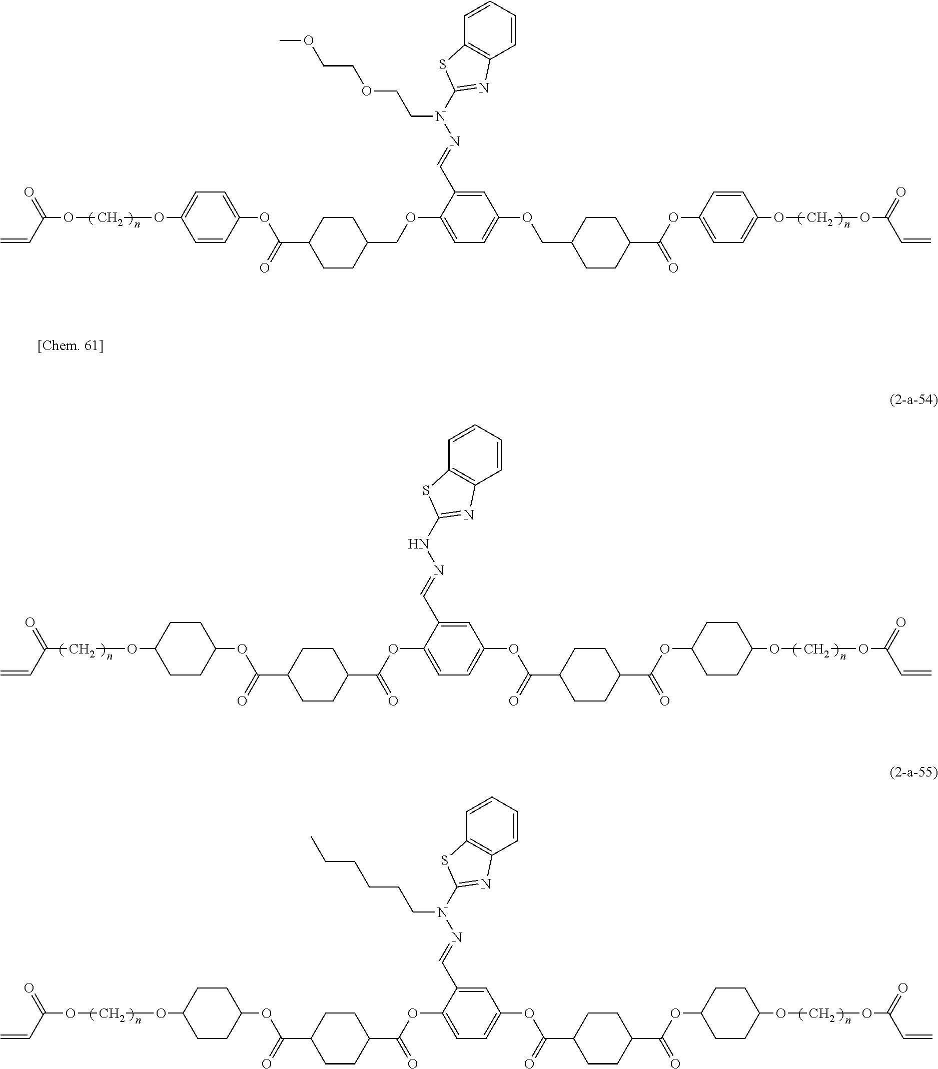

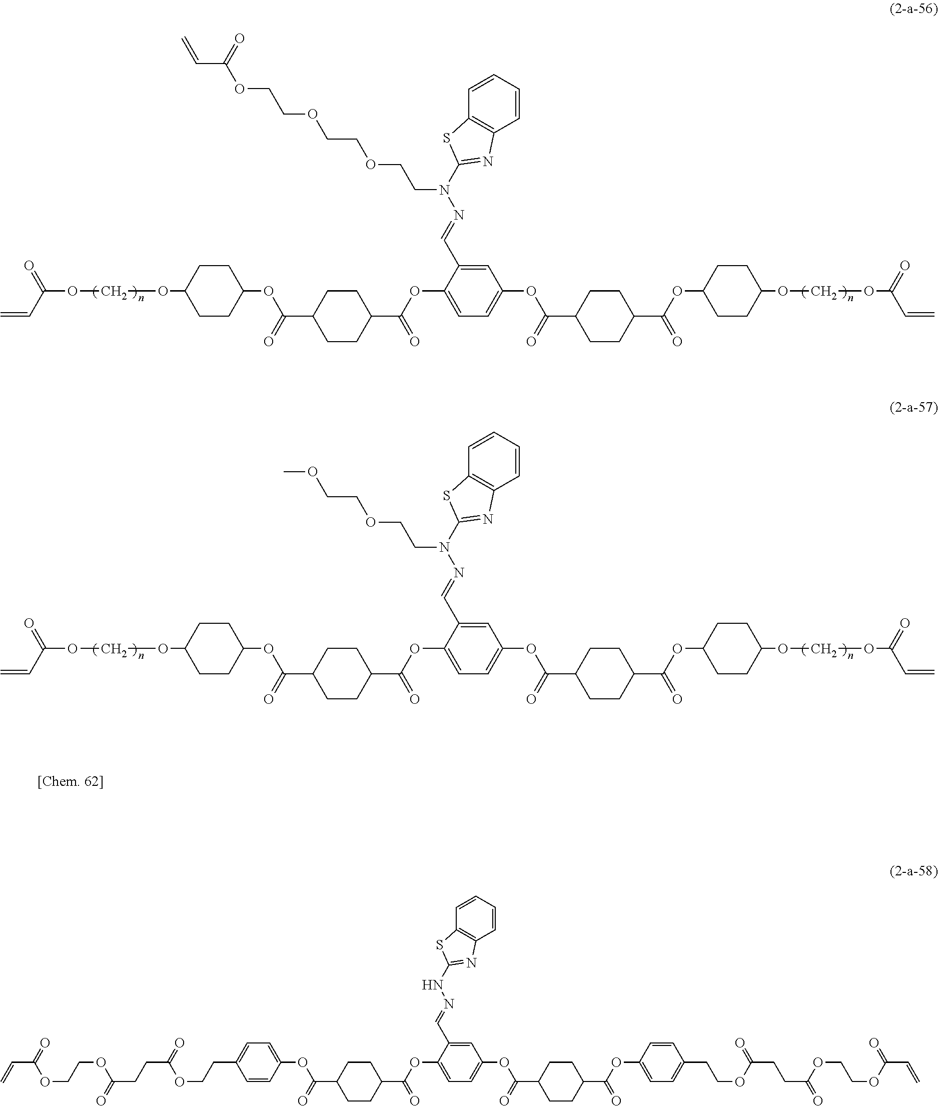

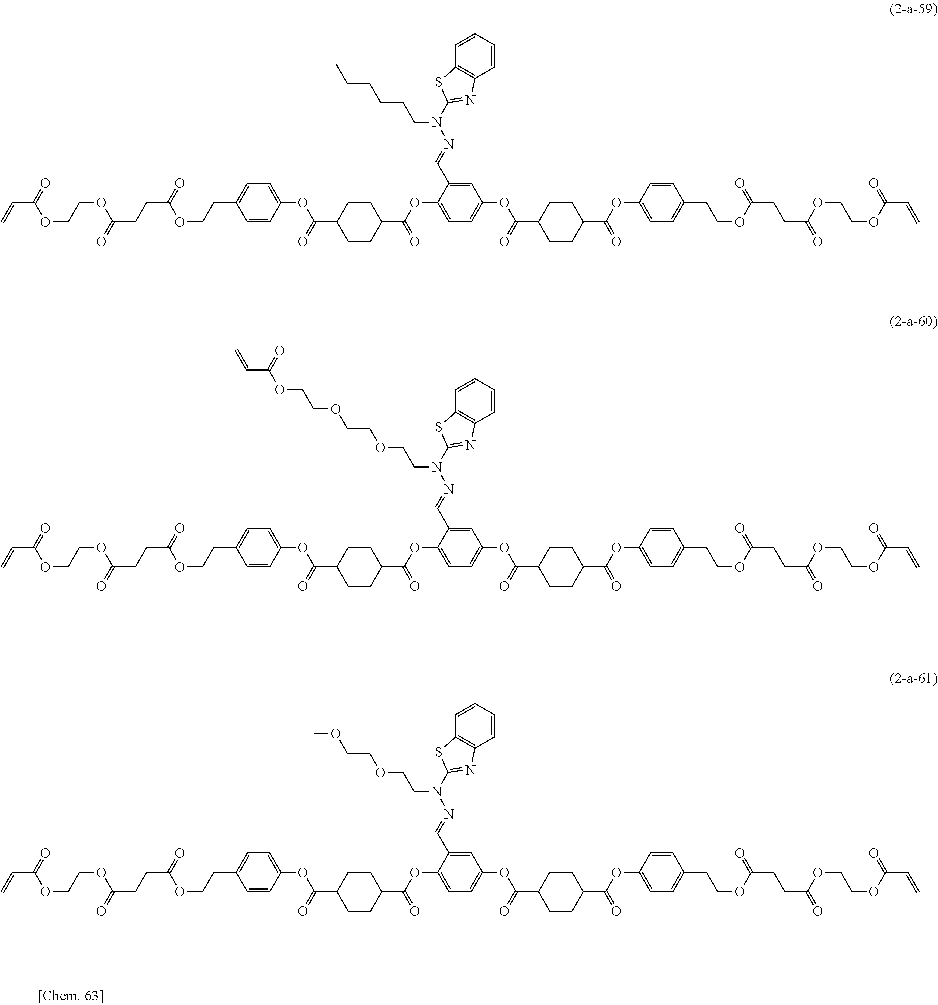

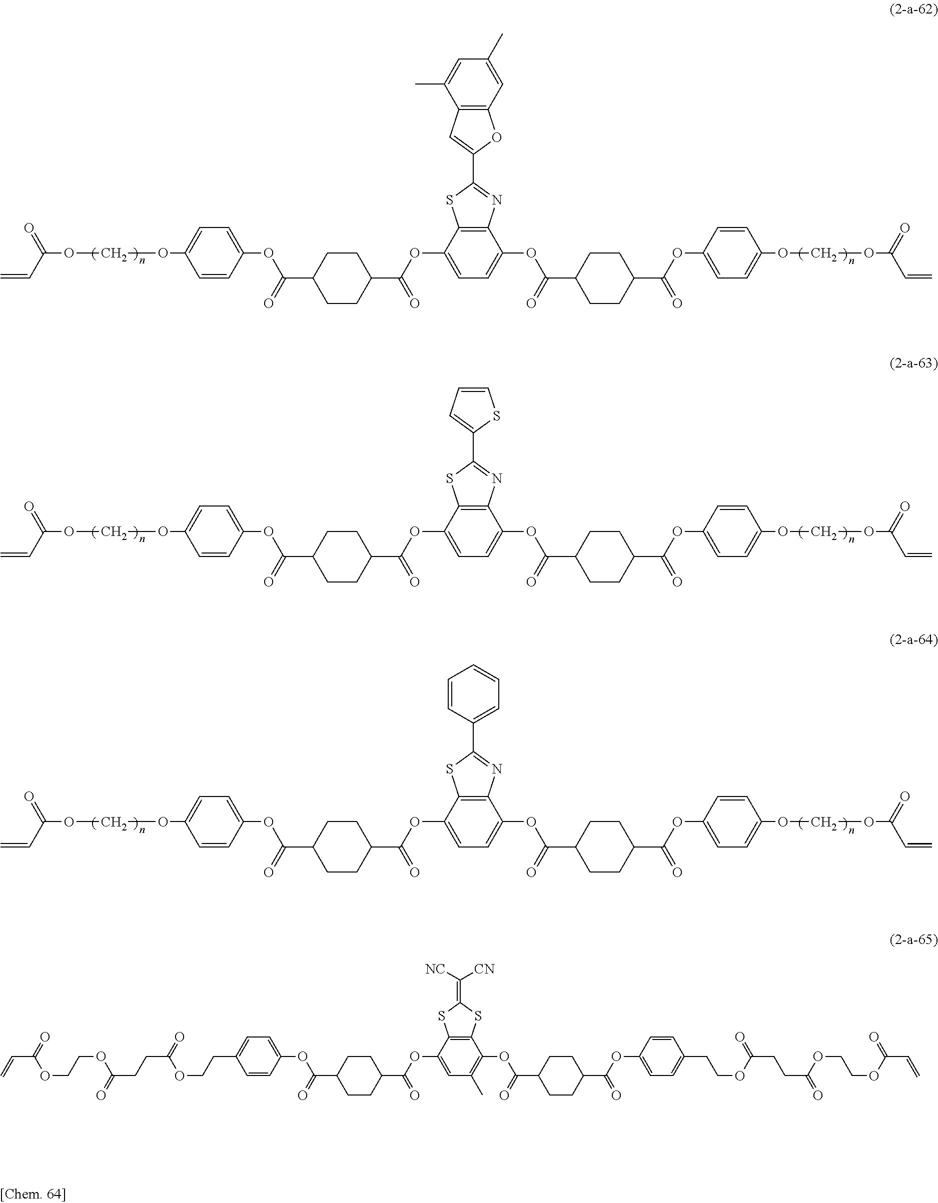

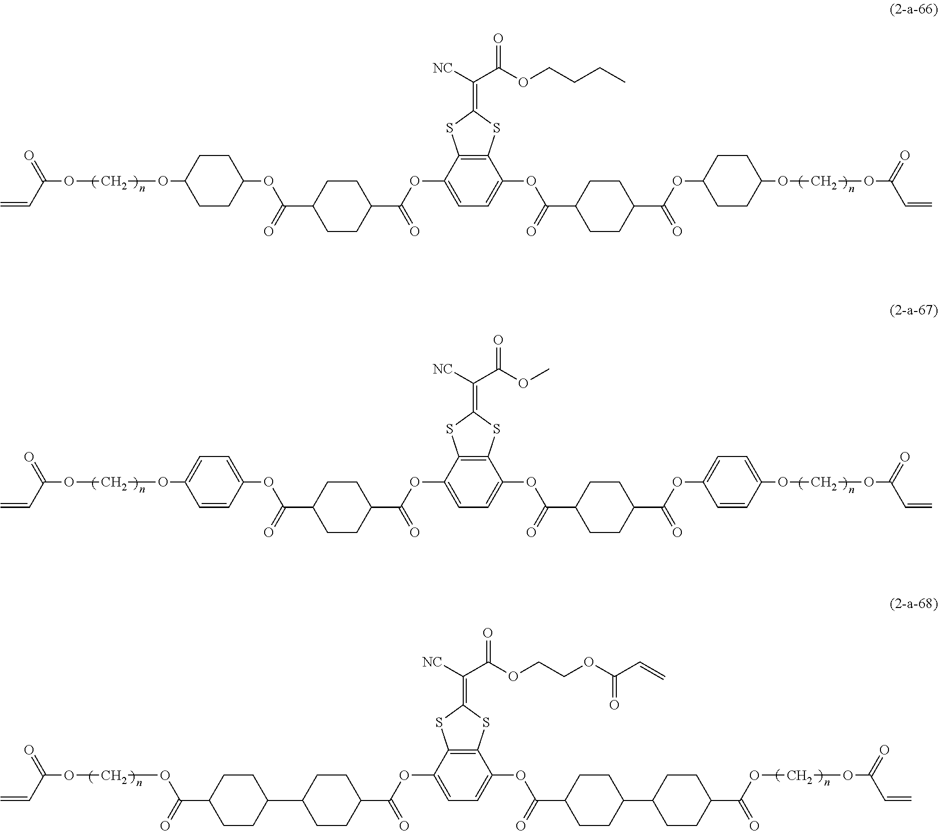

(where n represents an integer of 1 to 10). These liquid-crystal compounds may be used alone or in combination of two or more thereof.

Incidentally, in order to obtain a retardation film including a retardation layer according to the present invention, the material forming the retardation layer preferably contains the polymerizable liquid-crystal compound represented by General formula (2-a) above. In particular, the content of this compound relative to the total amount of polymerizable liquid-crystal compound contained in the material forming the retardation layer is preferably 5 to 100 mass %, more preferably 10 to 100 mass %, particularly preferably 15 to 100 mass %.

Specific preferred examples of the compound represented by General formula (3) include compounds represented by the following Formula (3-a-1) to Formula (3-a-17).

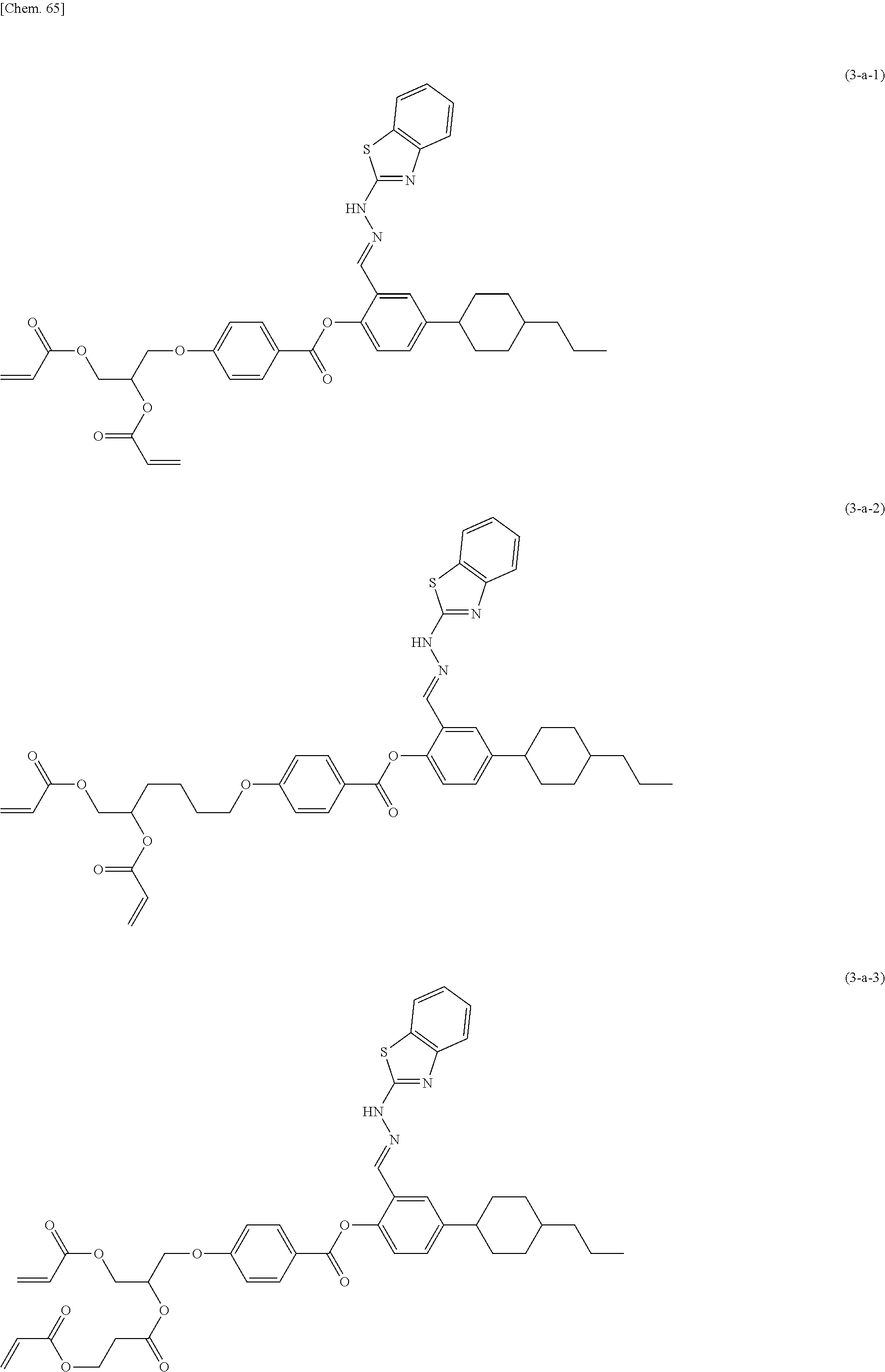

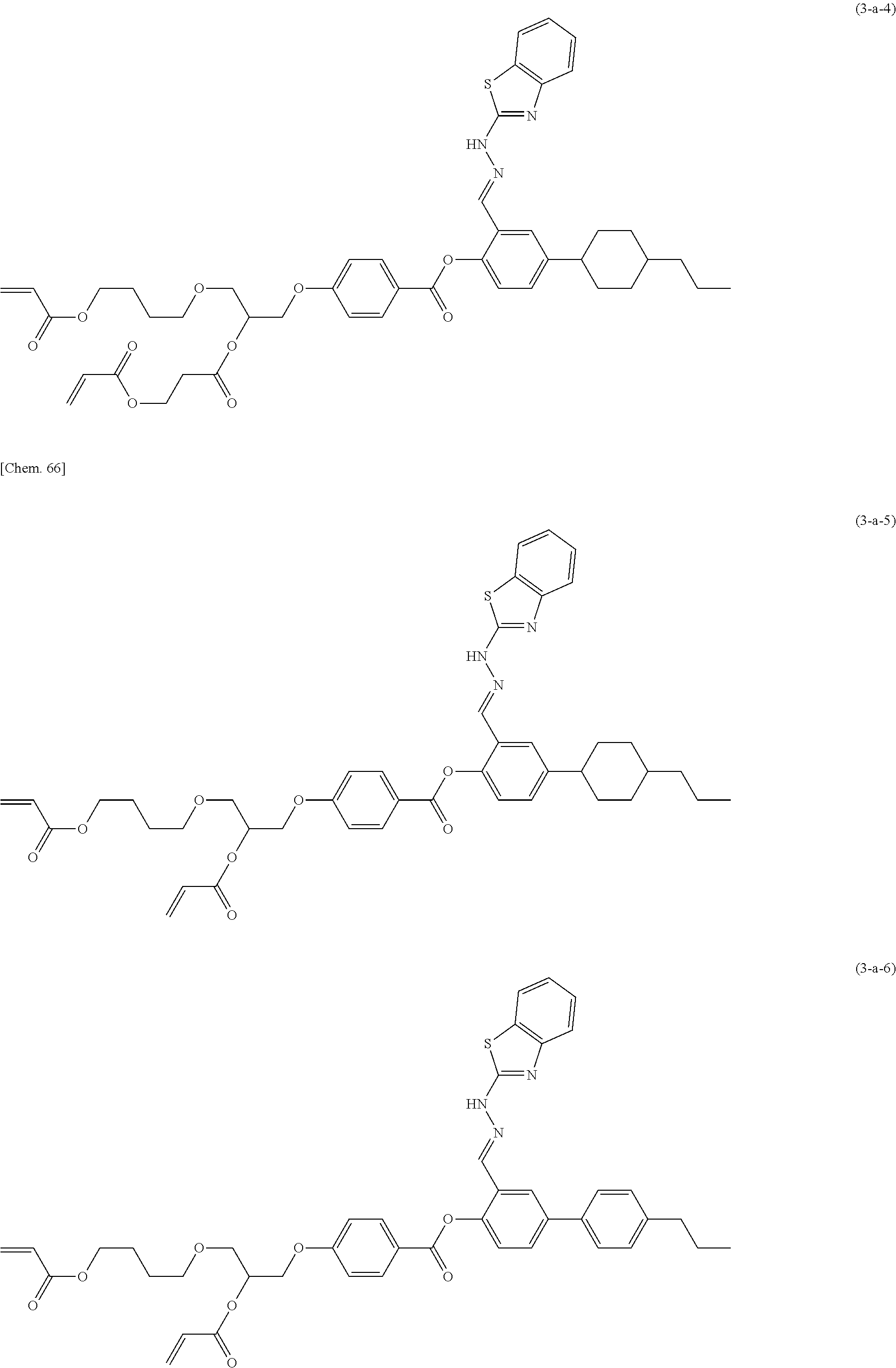

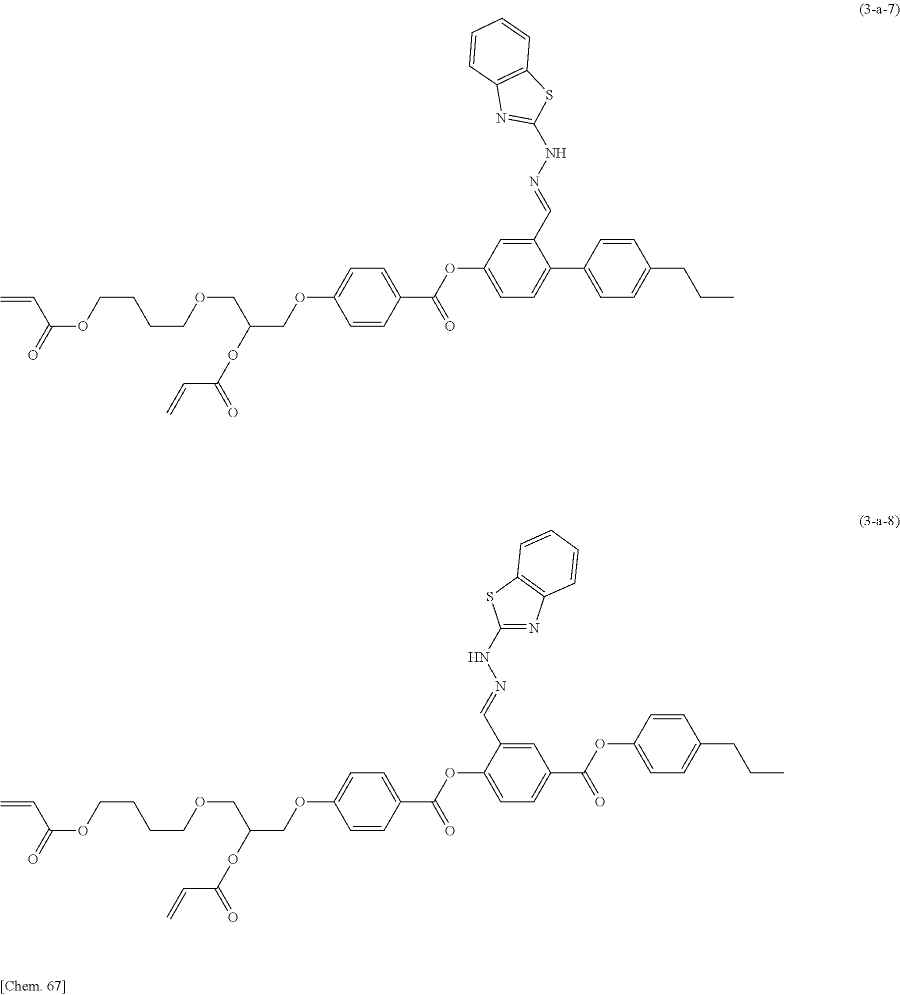

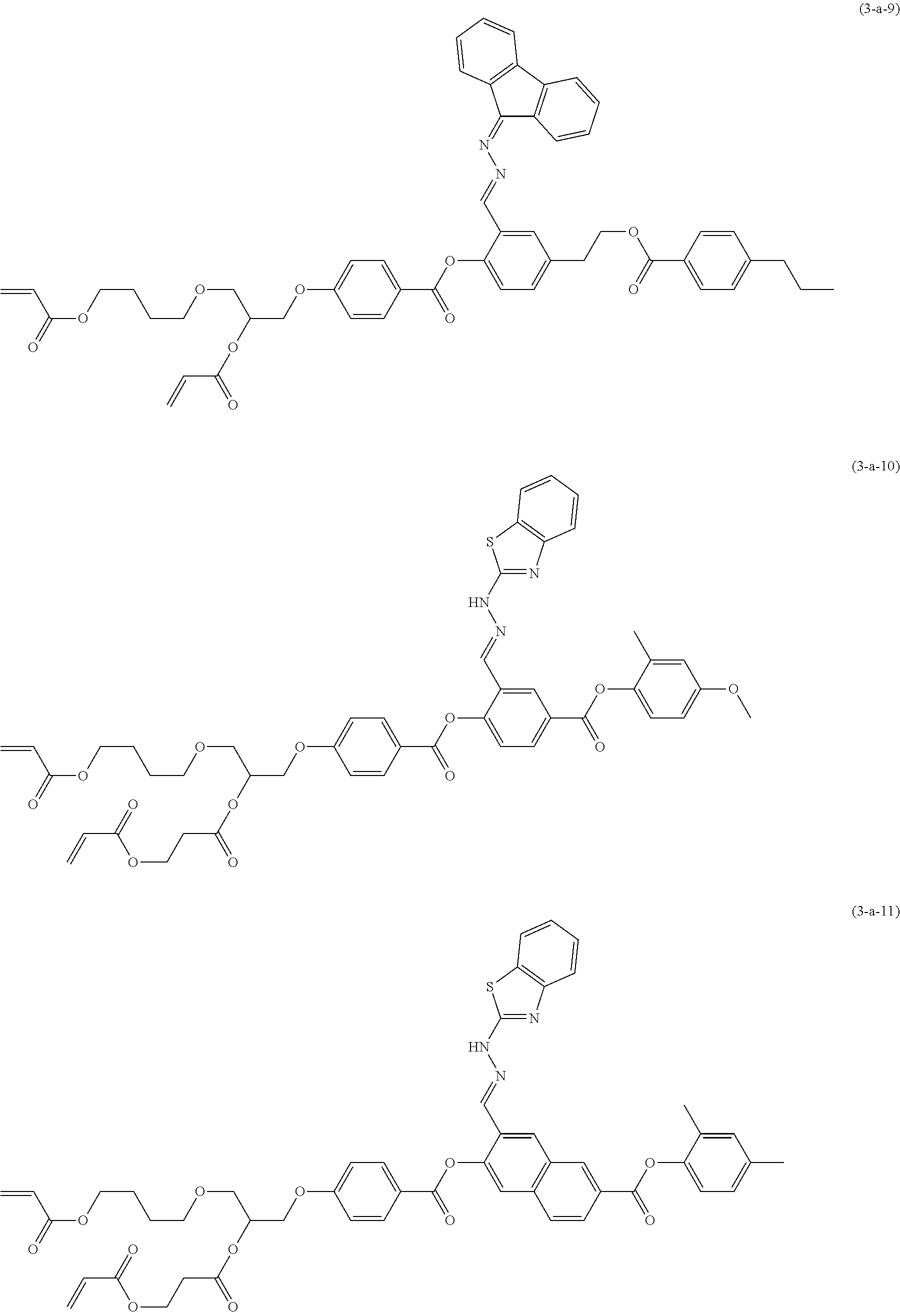

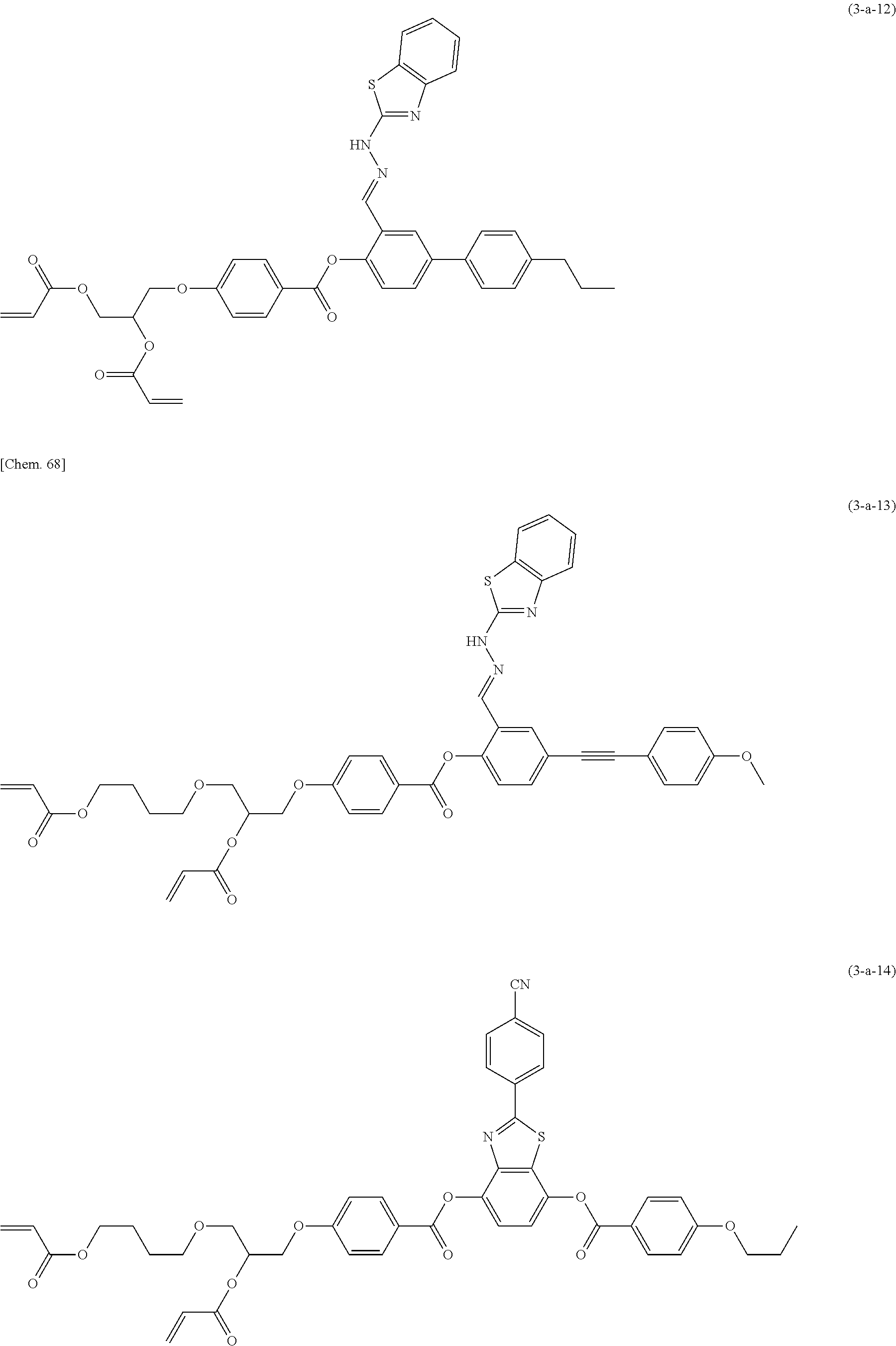

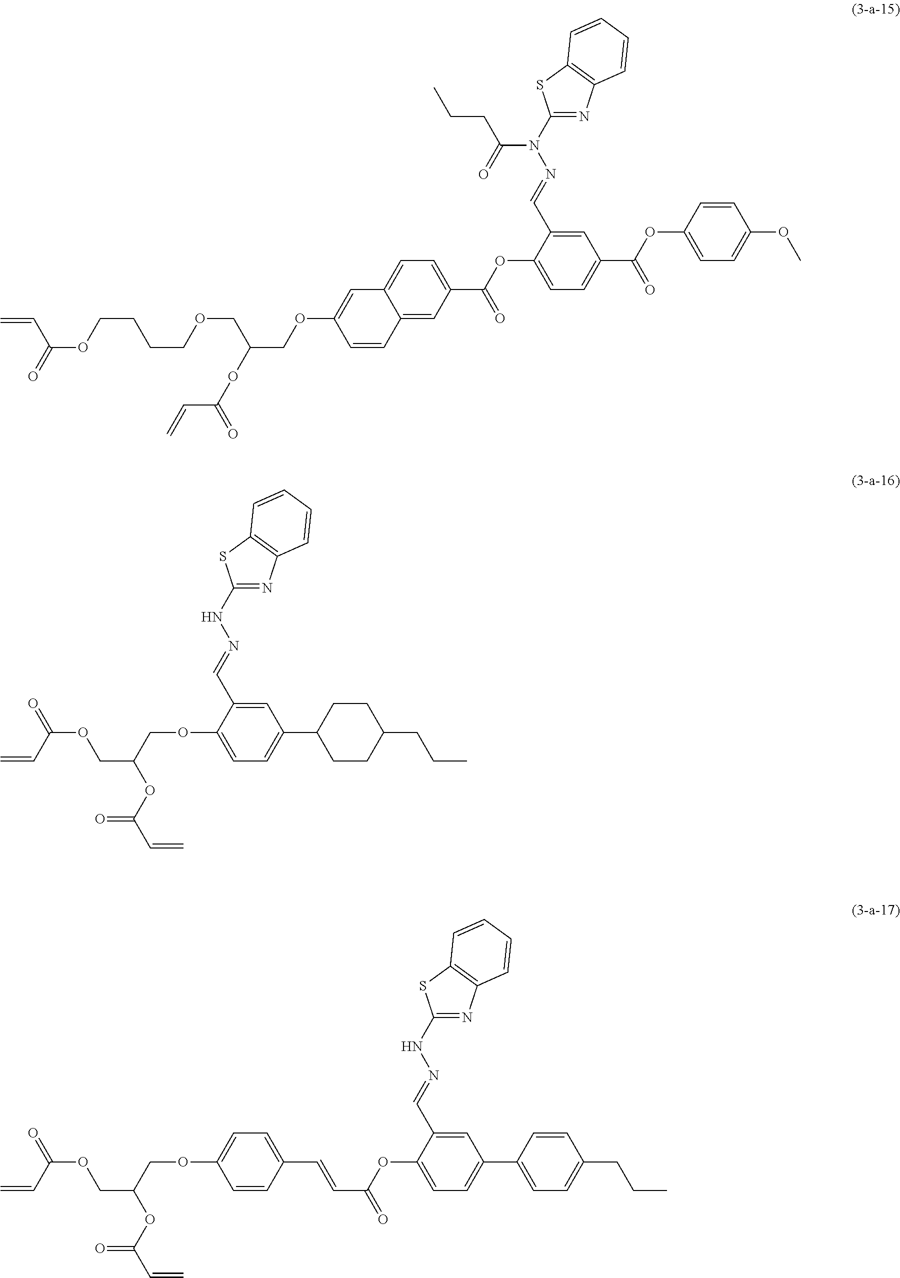

These liquid-crystal compounds may be used alone or in combination of two or more thereof.

Specific preferred examples of the compound represented by General formula (4) include compounds represented by the following Formula (4-a-1) to Formula (4-a-26).

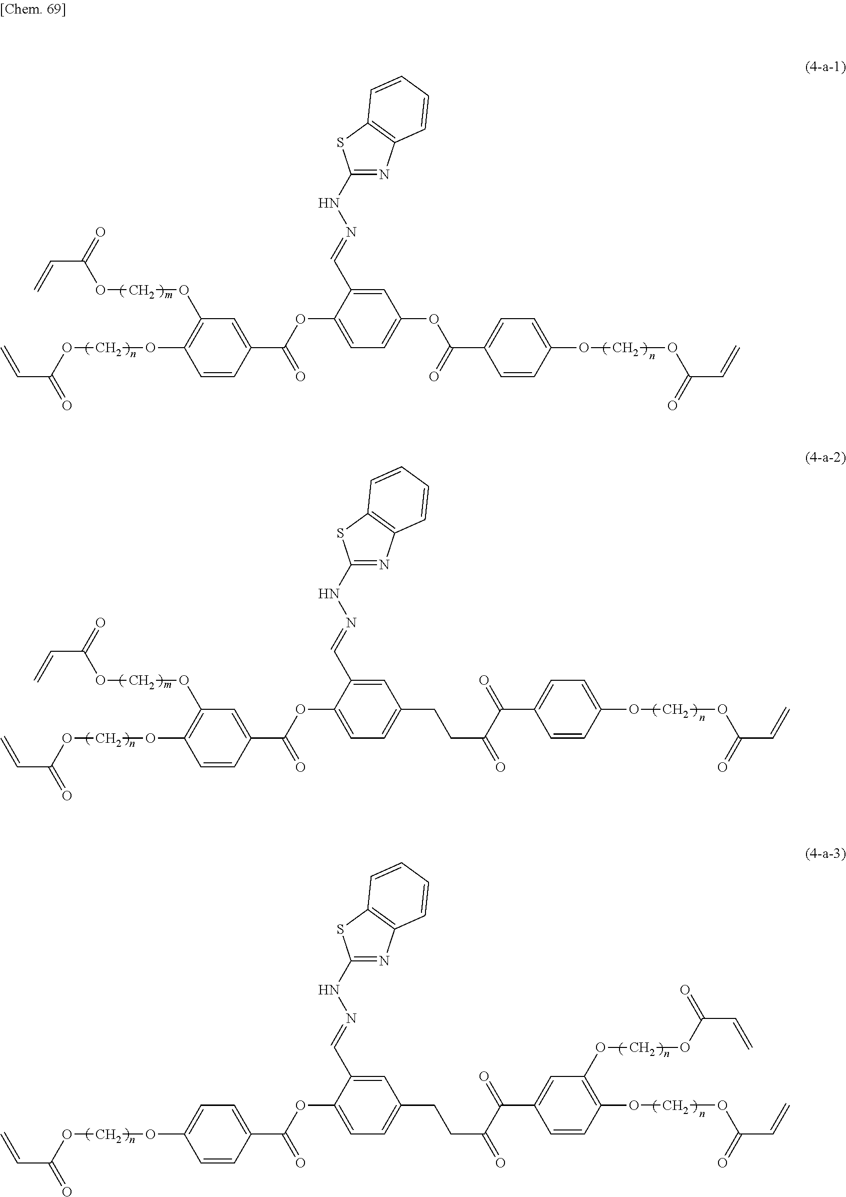

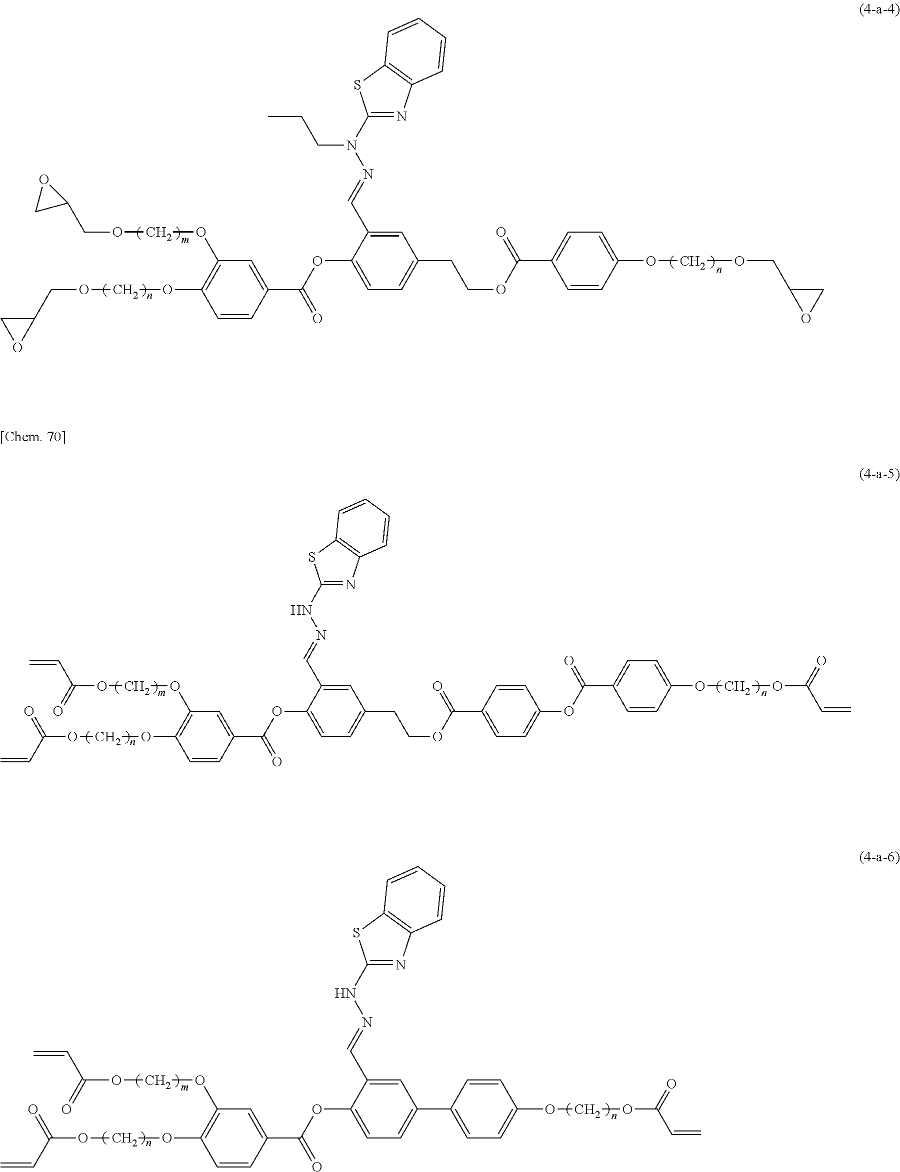

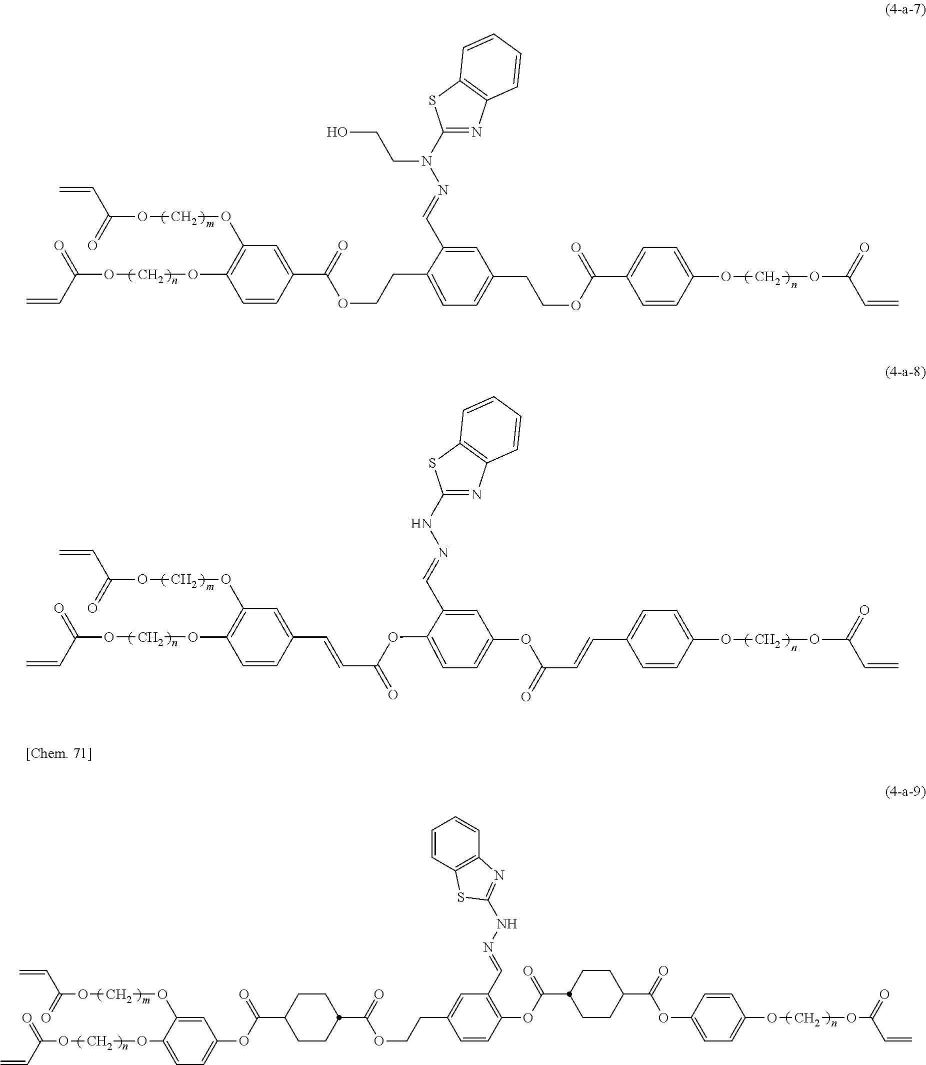

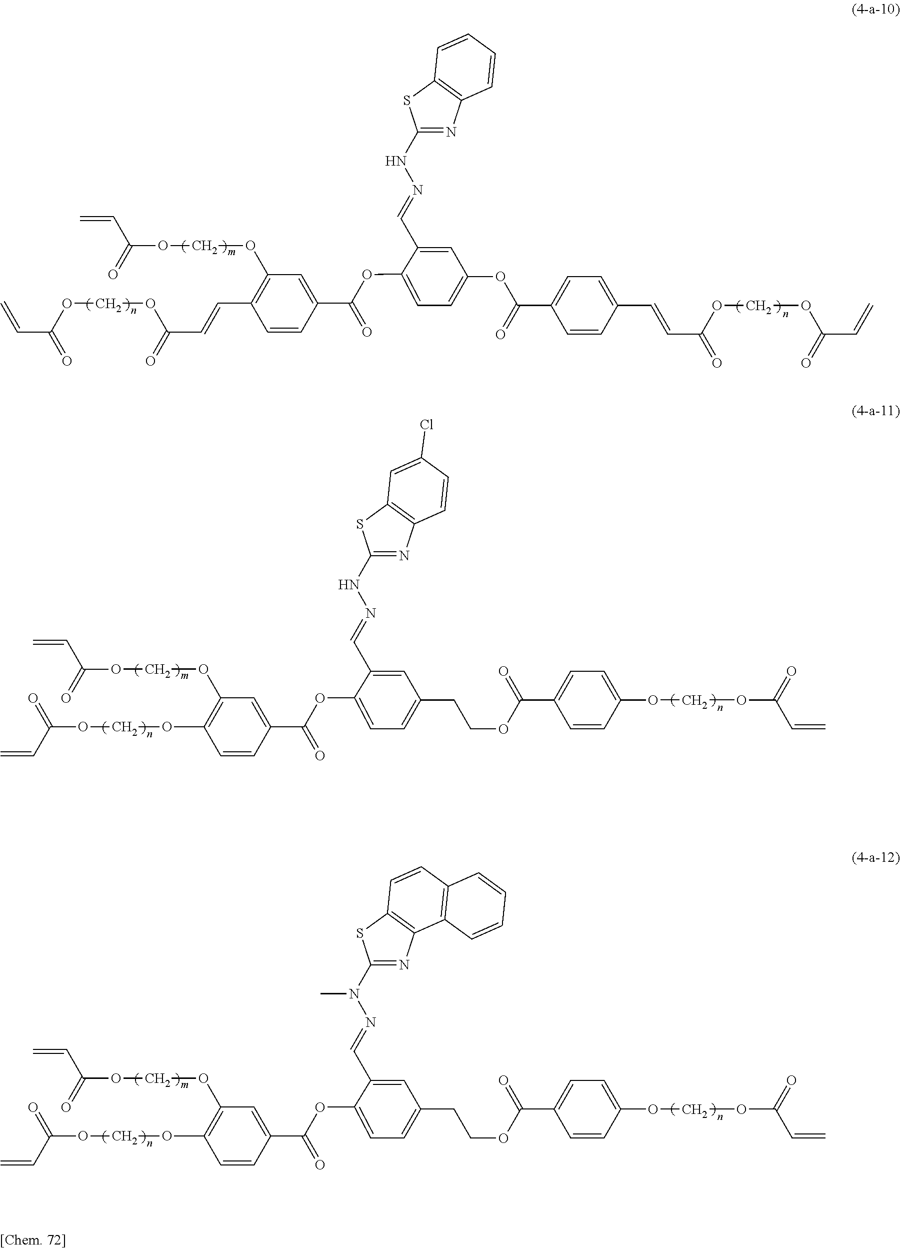

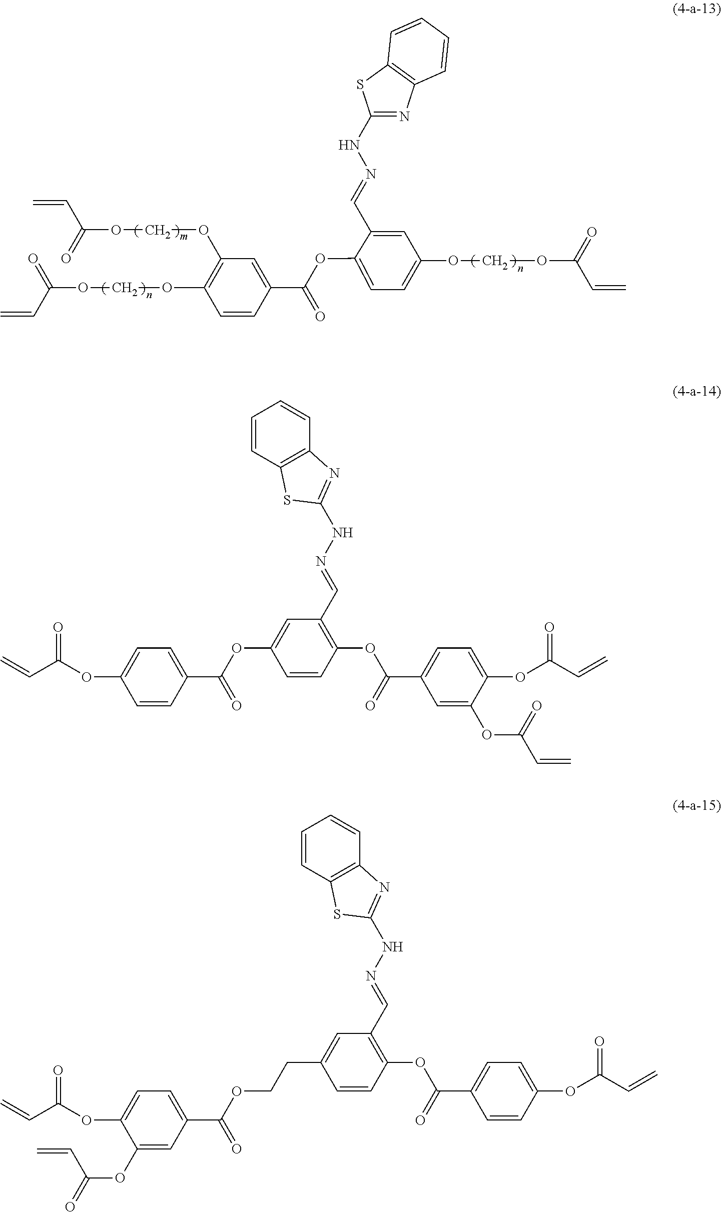

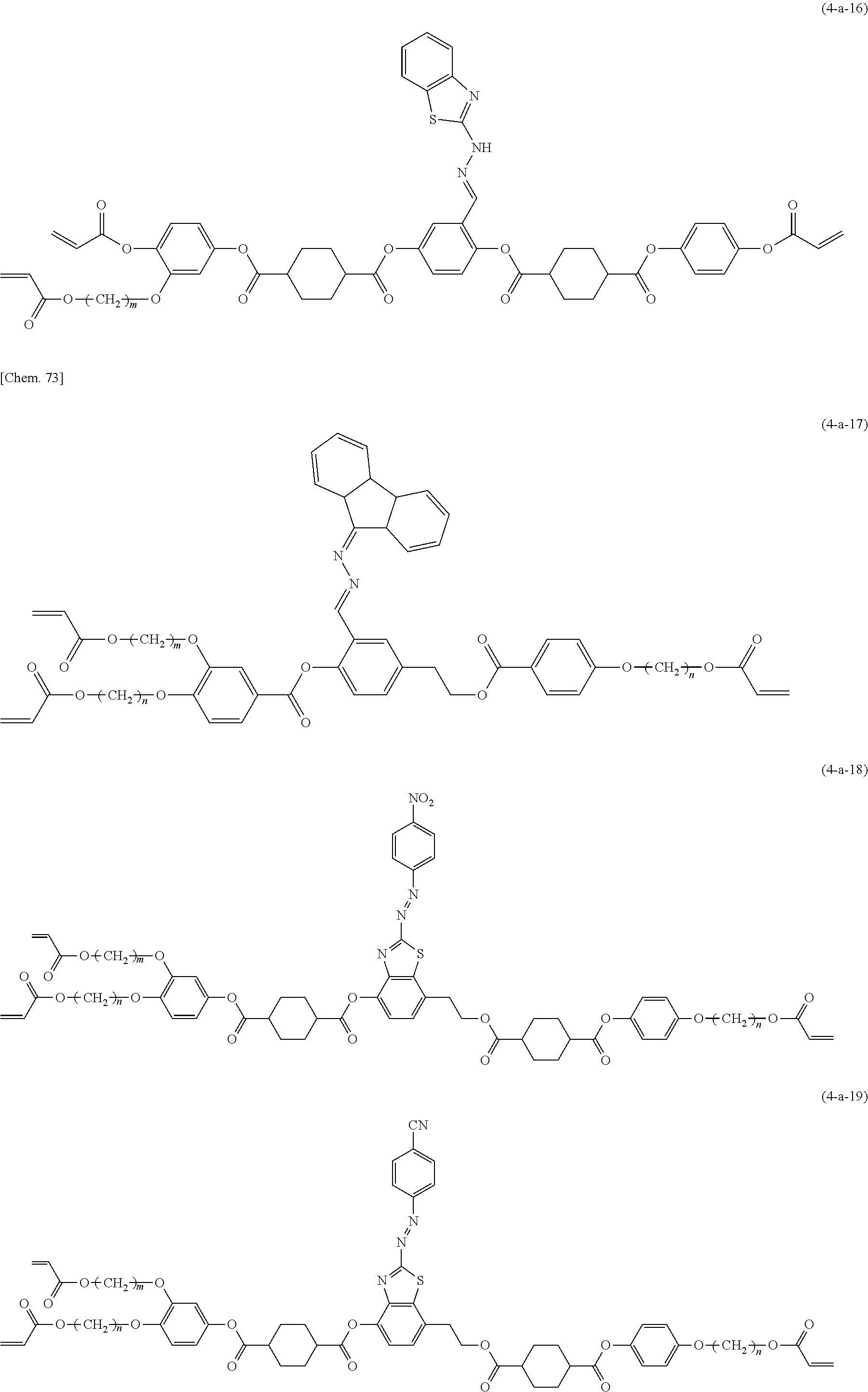

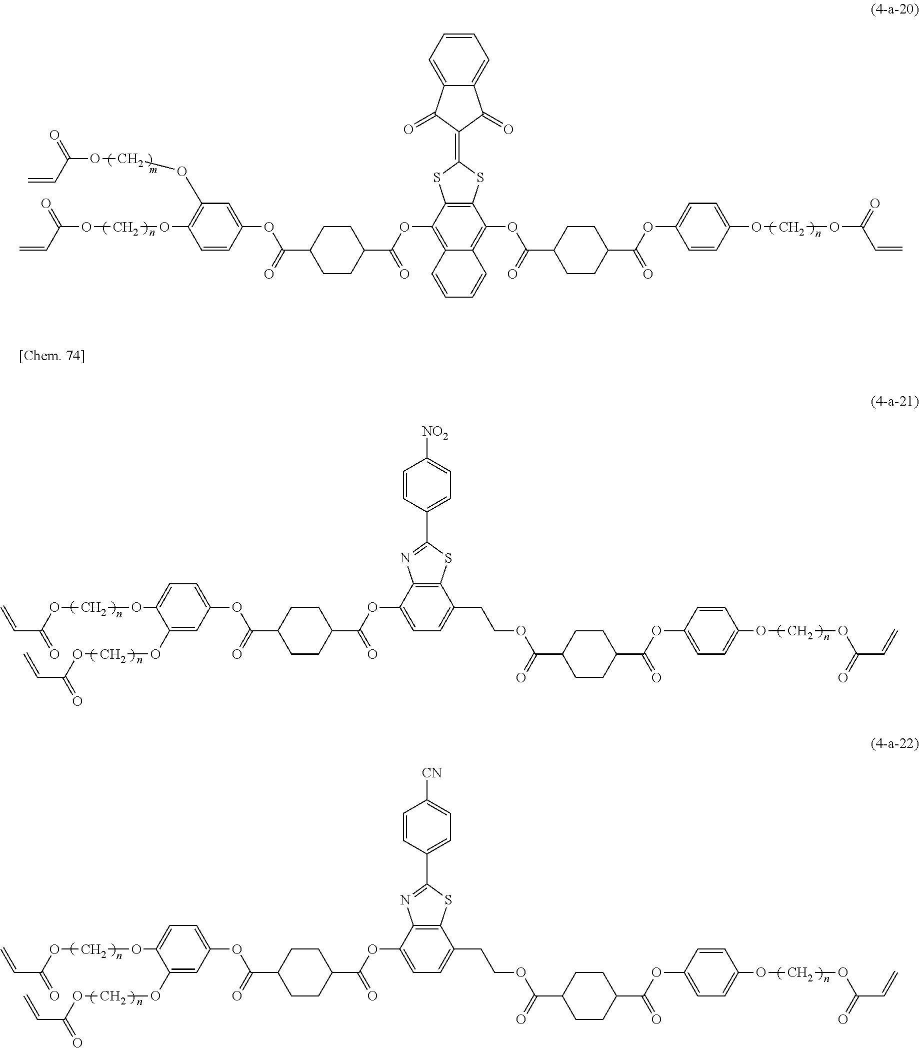

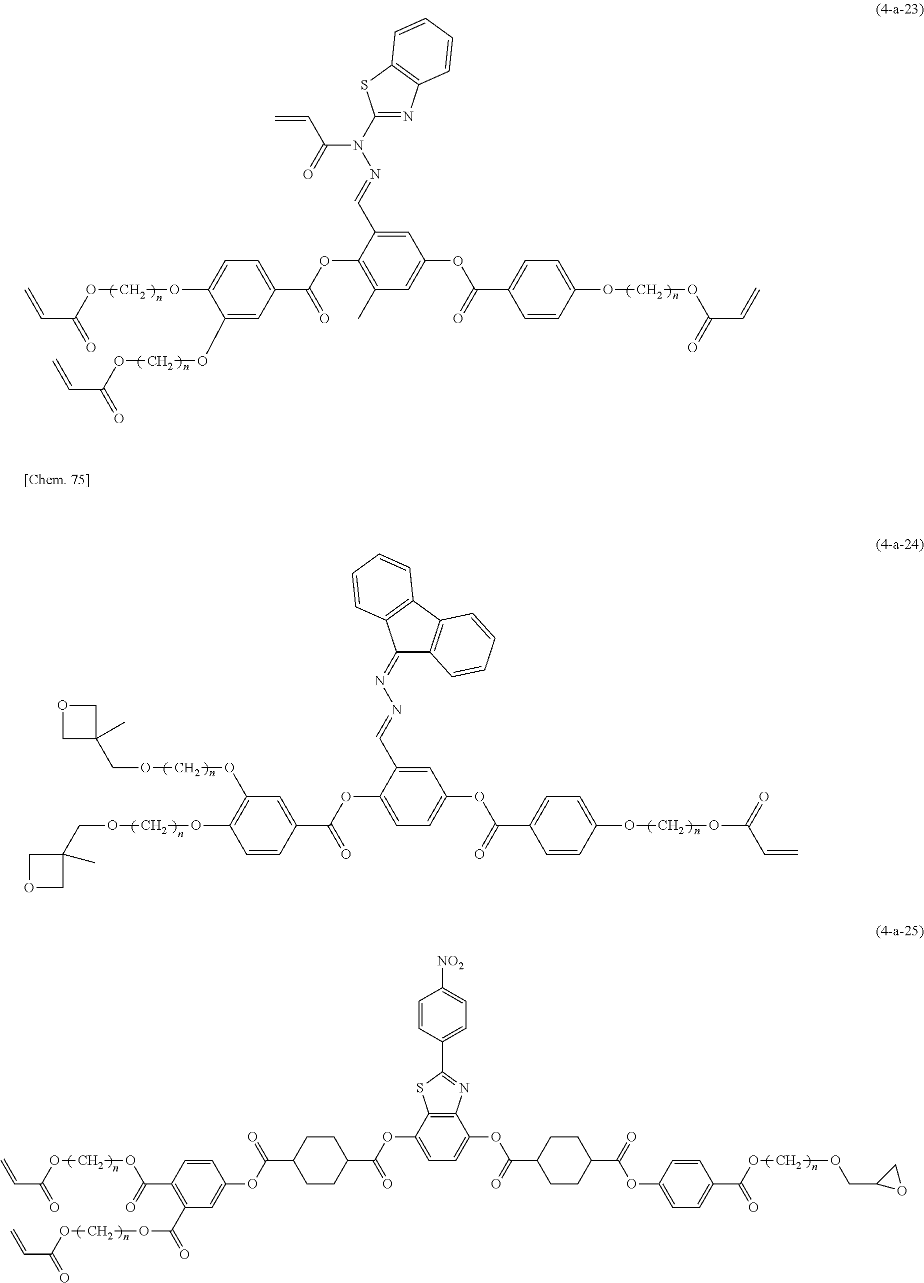

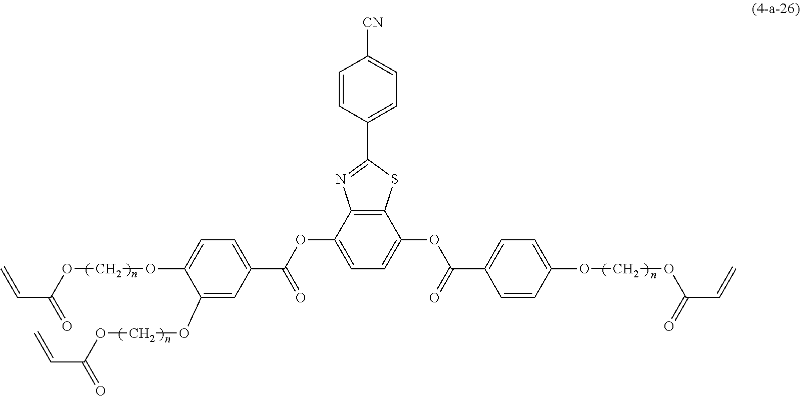

(where m and n each independently represent an integer of 1 to 10). These liquid-crystal compounds may be used alone or in combination of two or more thereof.

Specific preferred examples of the compound represented by General formula (5) include compounds represented by the following Formula (5-a-1) to Formula (5-a-29).

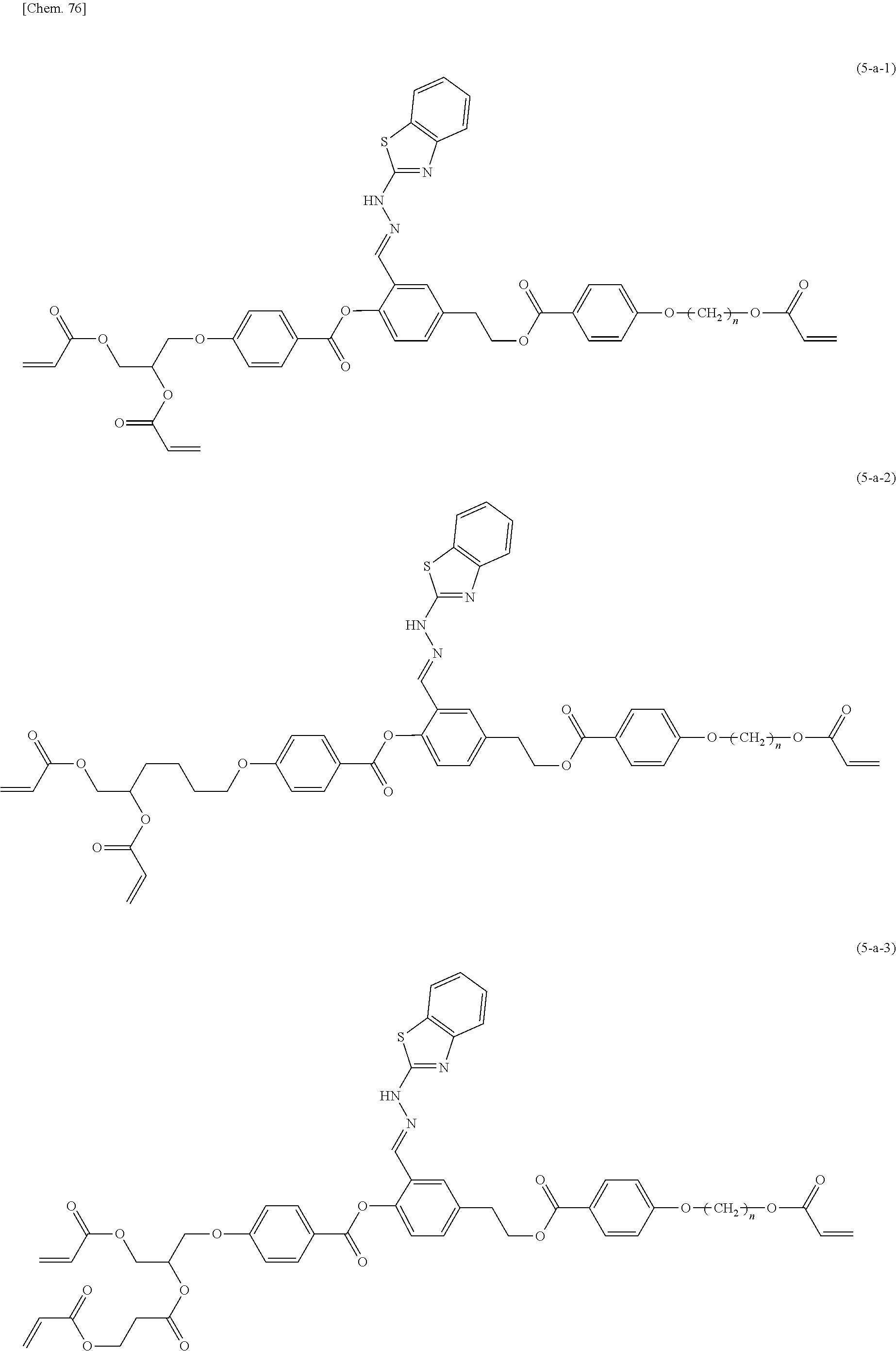

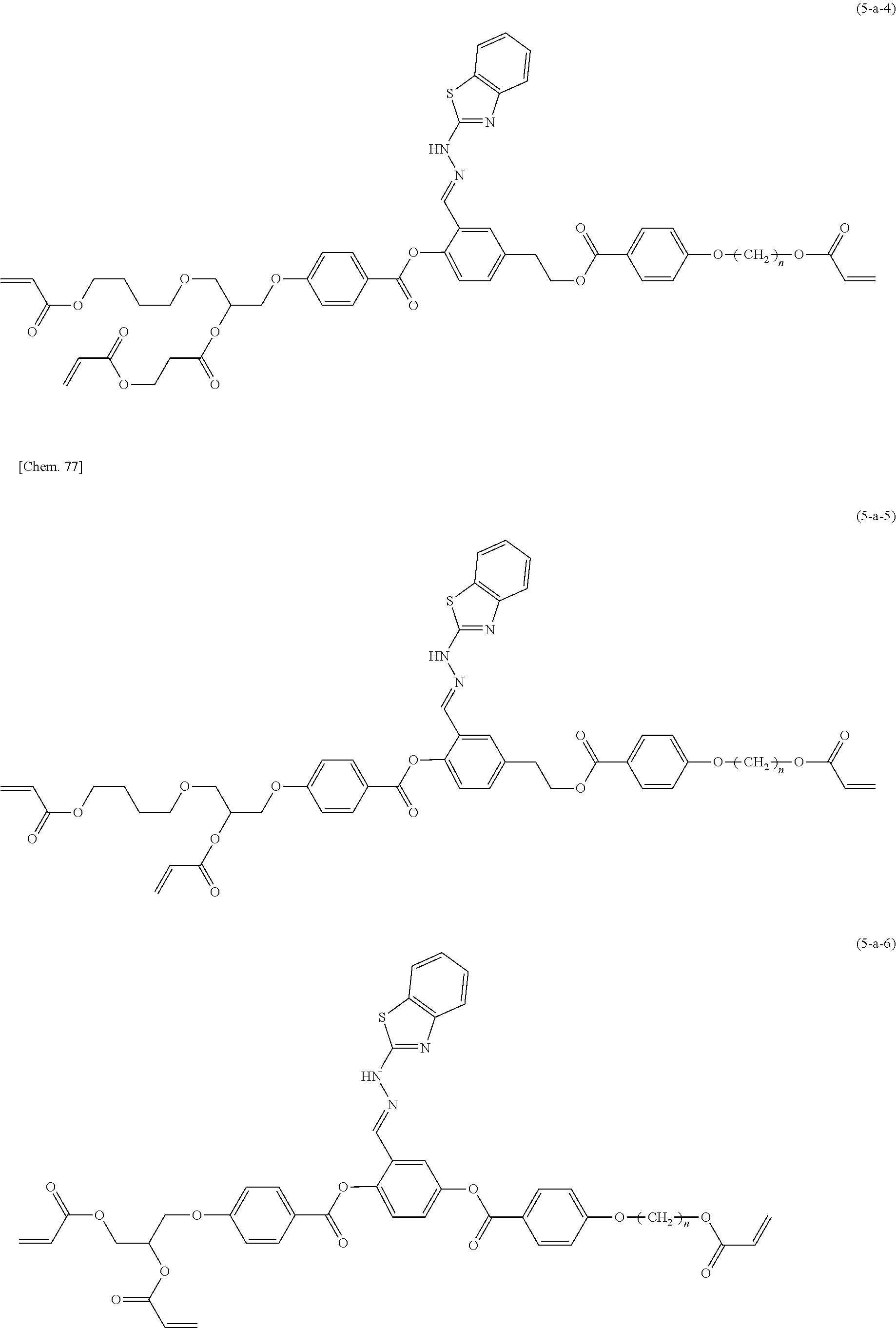

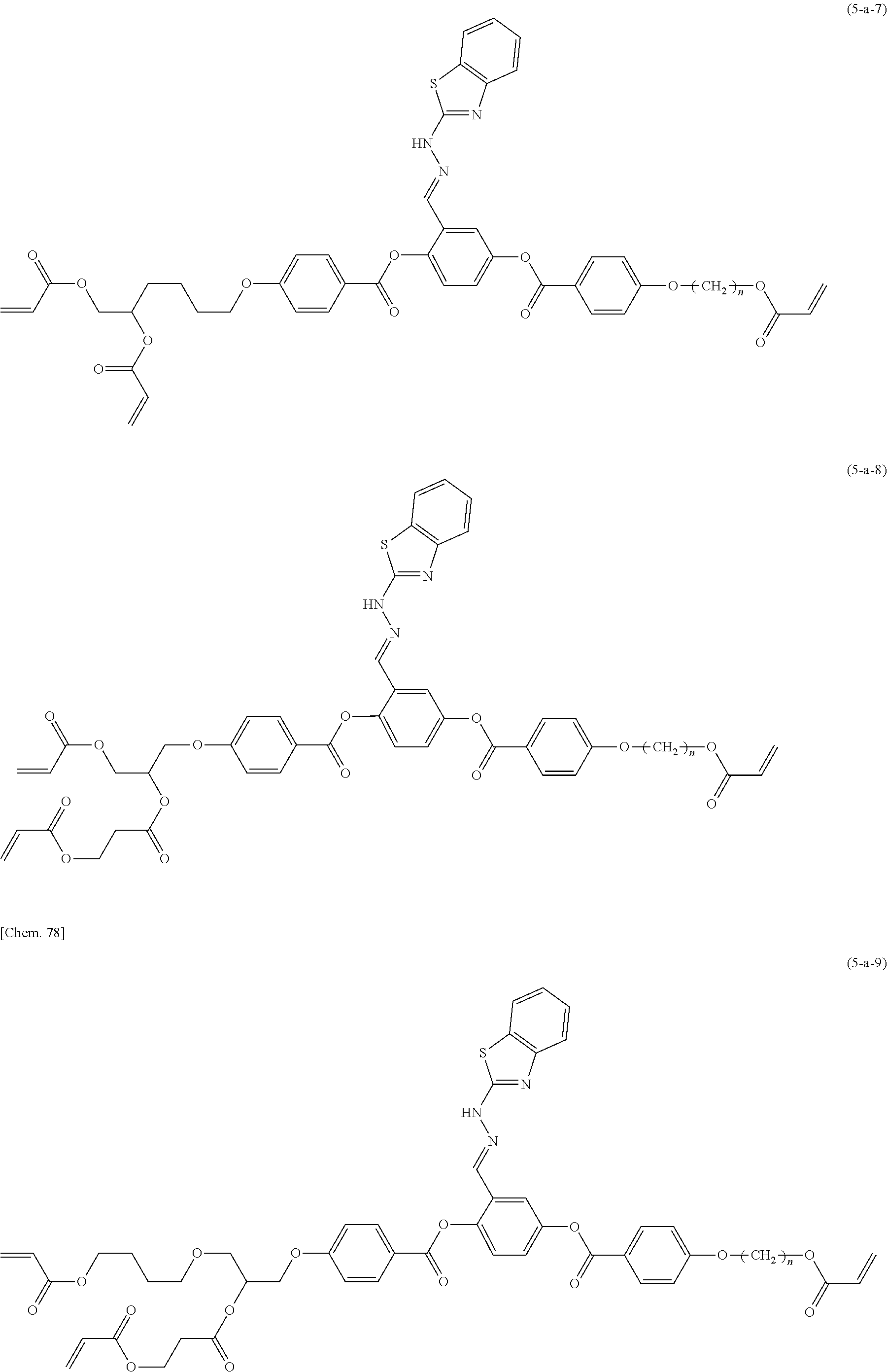

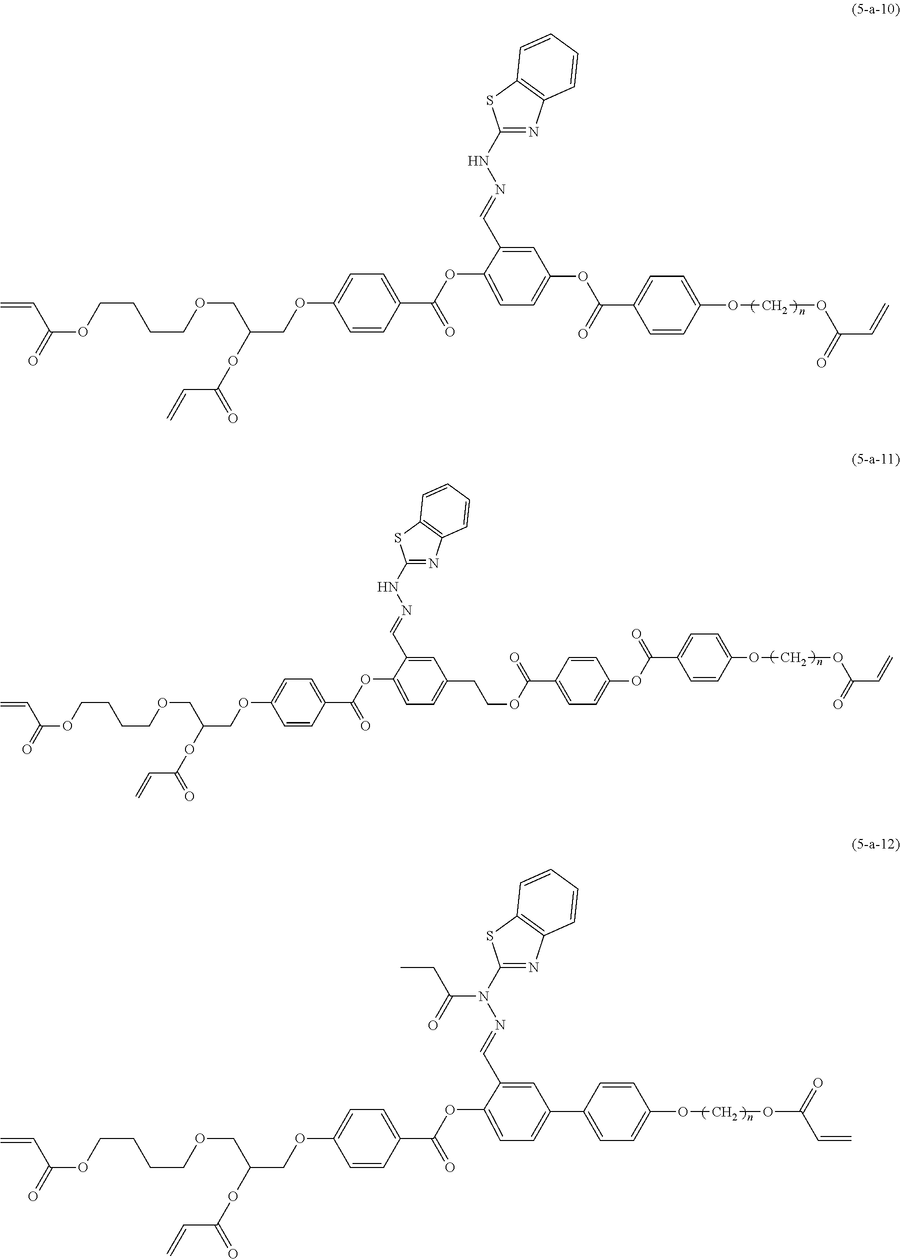

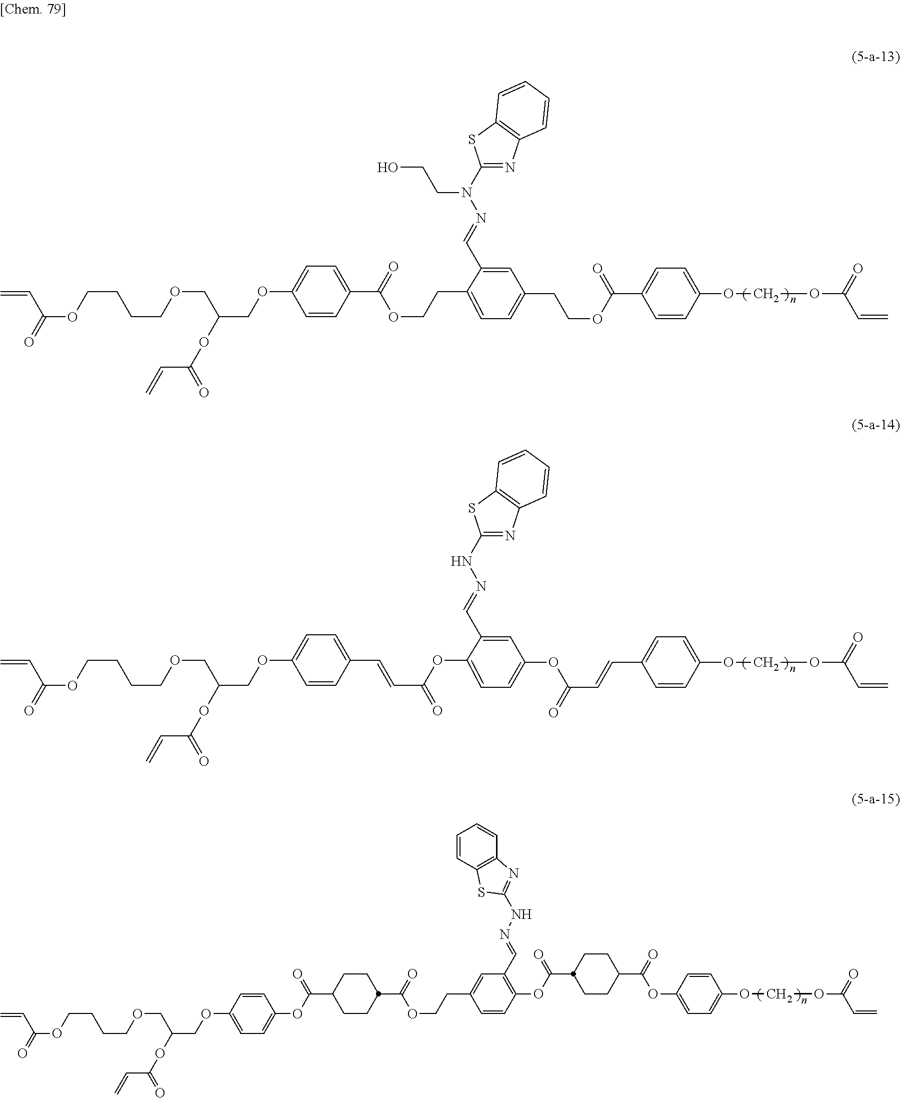

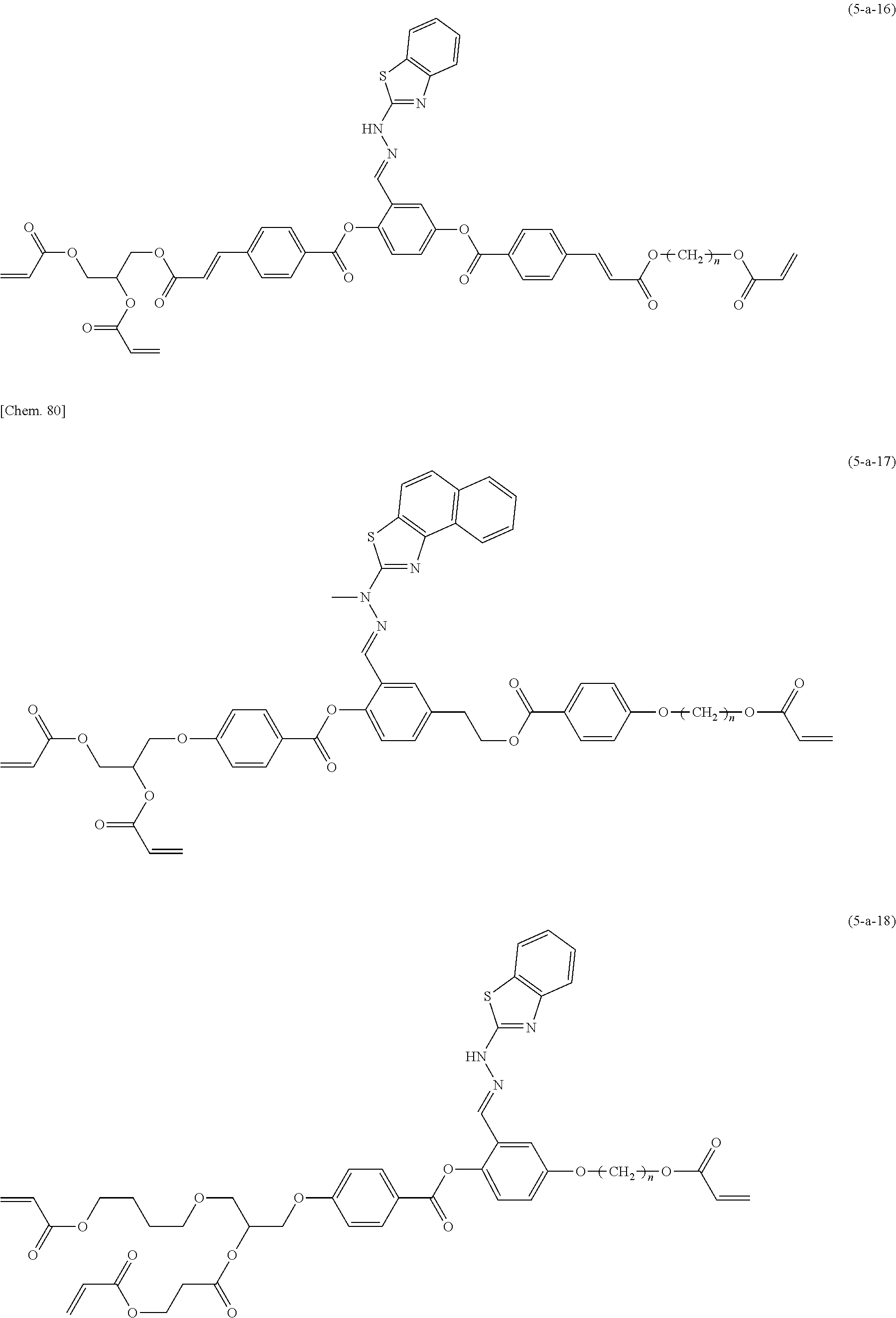

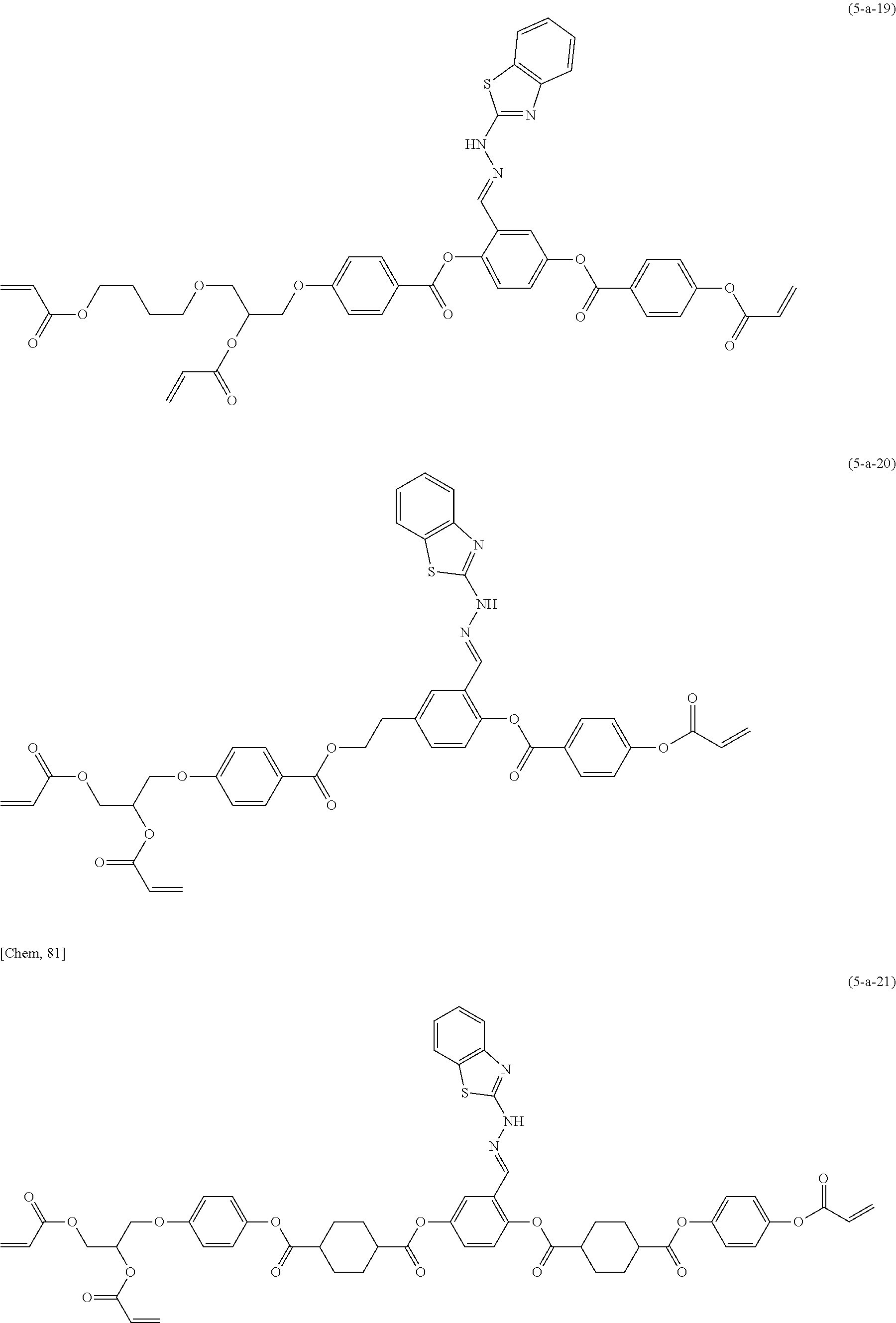

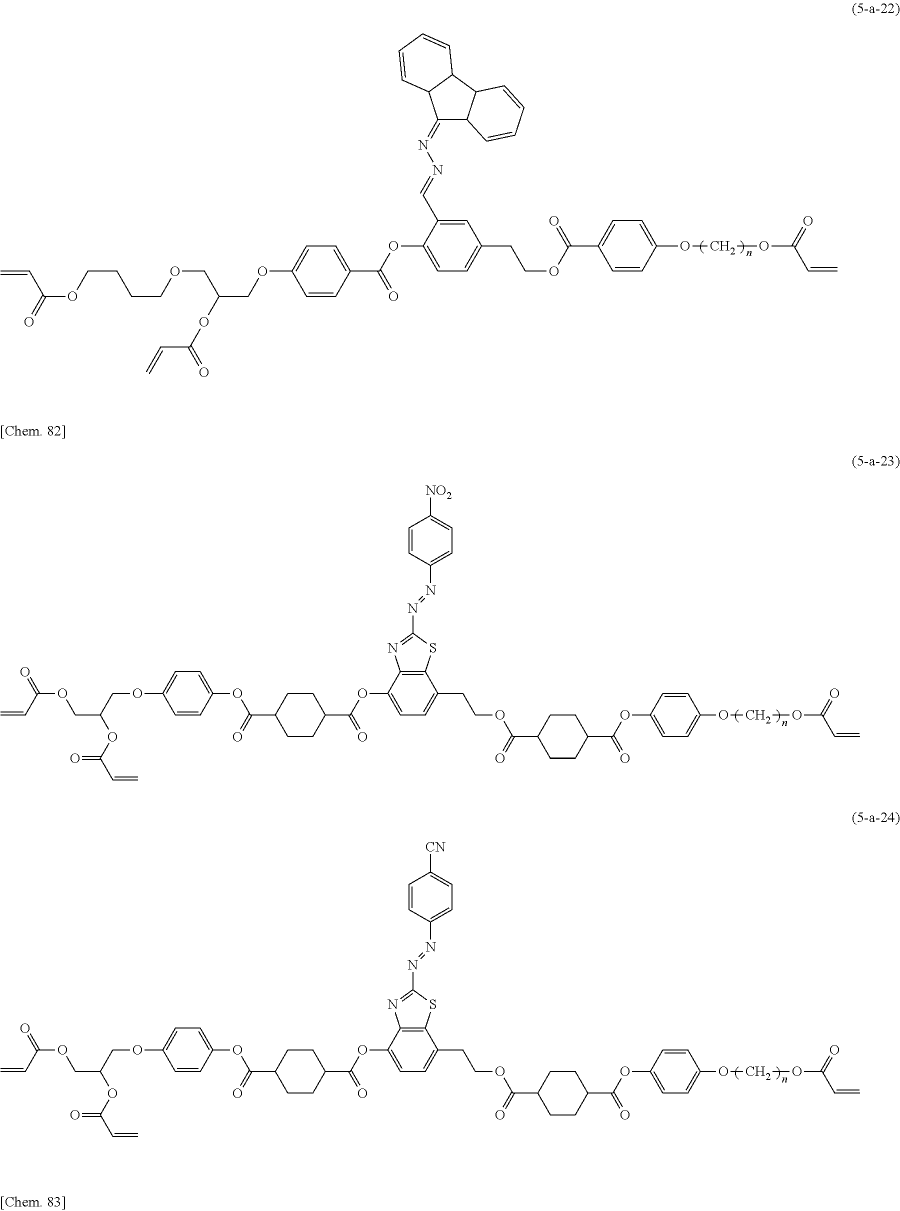

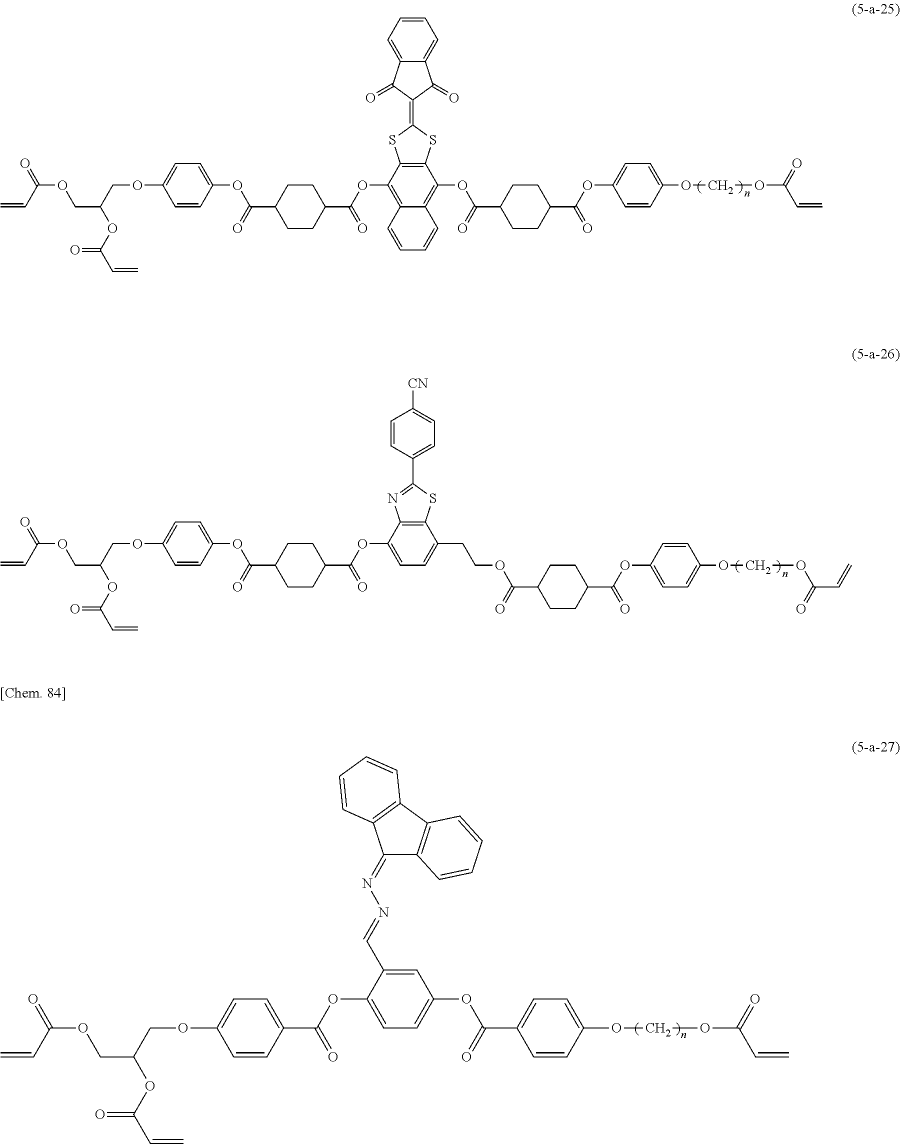

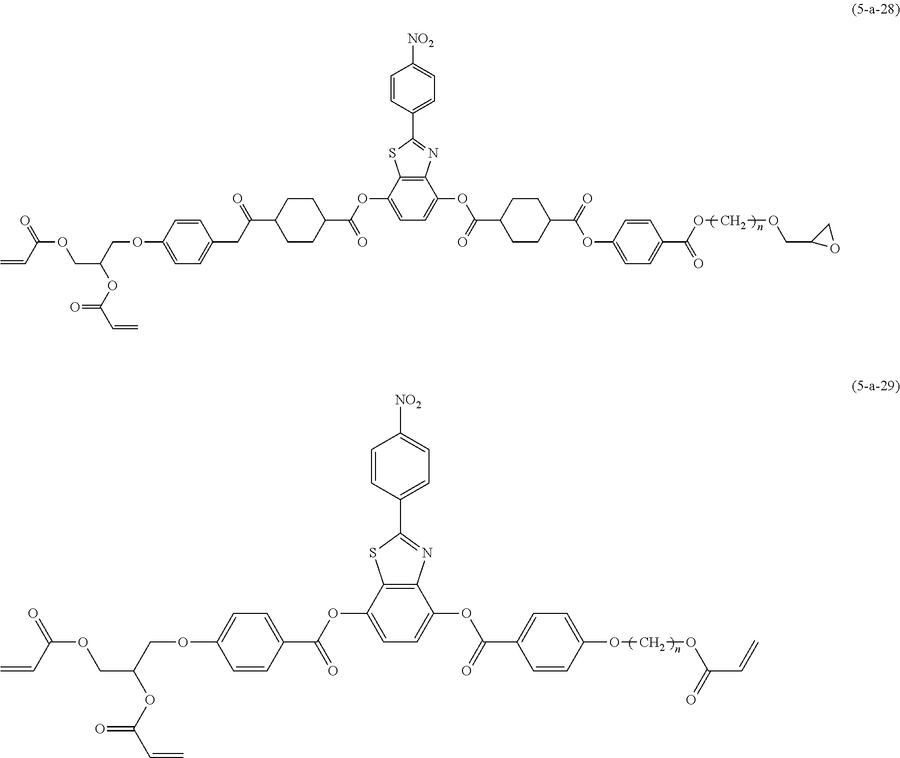

(where n represents the number of carbon atoms that is 1 to 10). These liquid-crystal compounds may be used alone or in combination of two or more thereof.

Specific preferred examples of the compound represented by General formula (6) include compounds represented by the following Formula (6-a-1) to Formula (6-a-25).

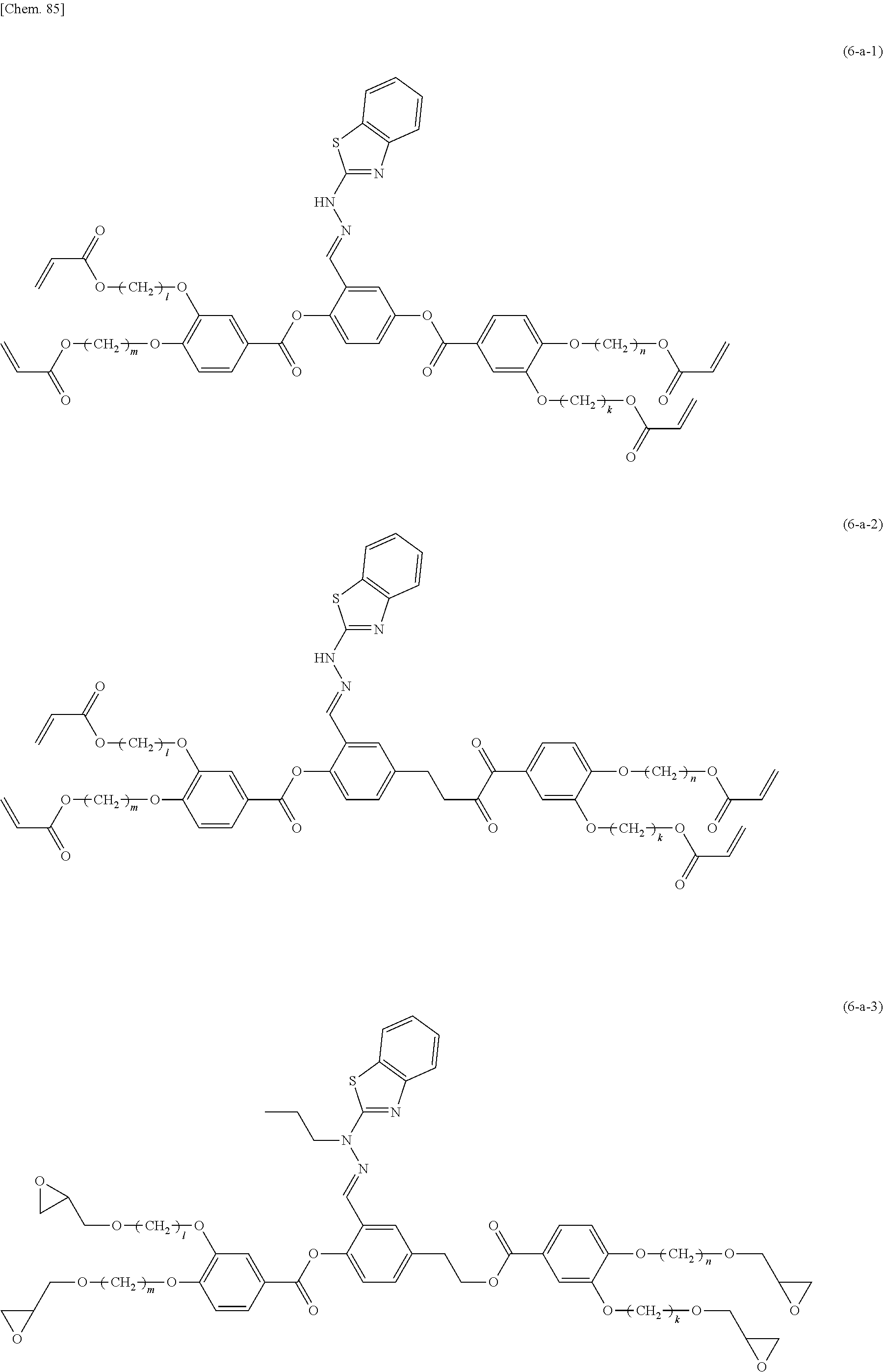

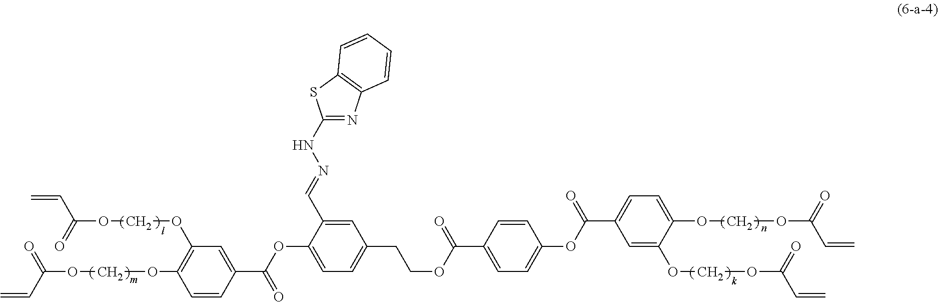

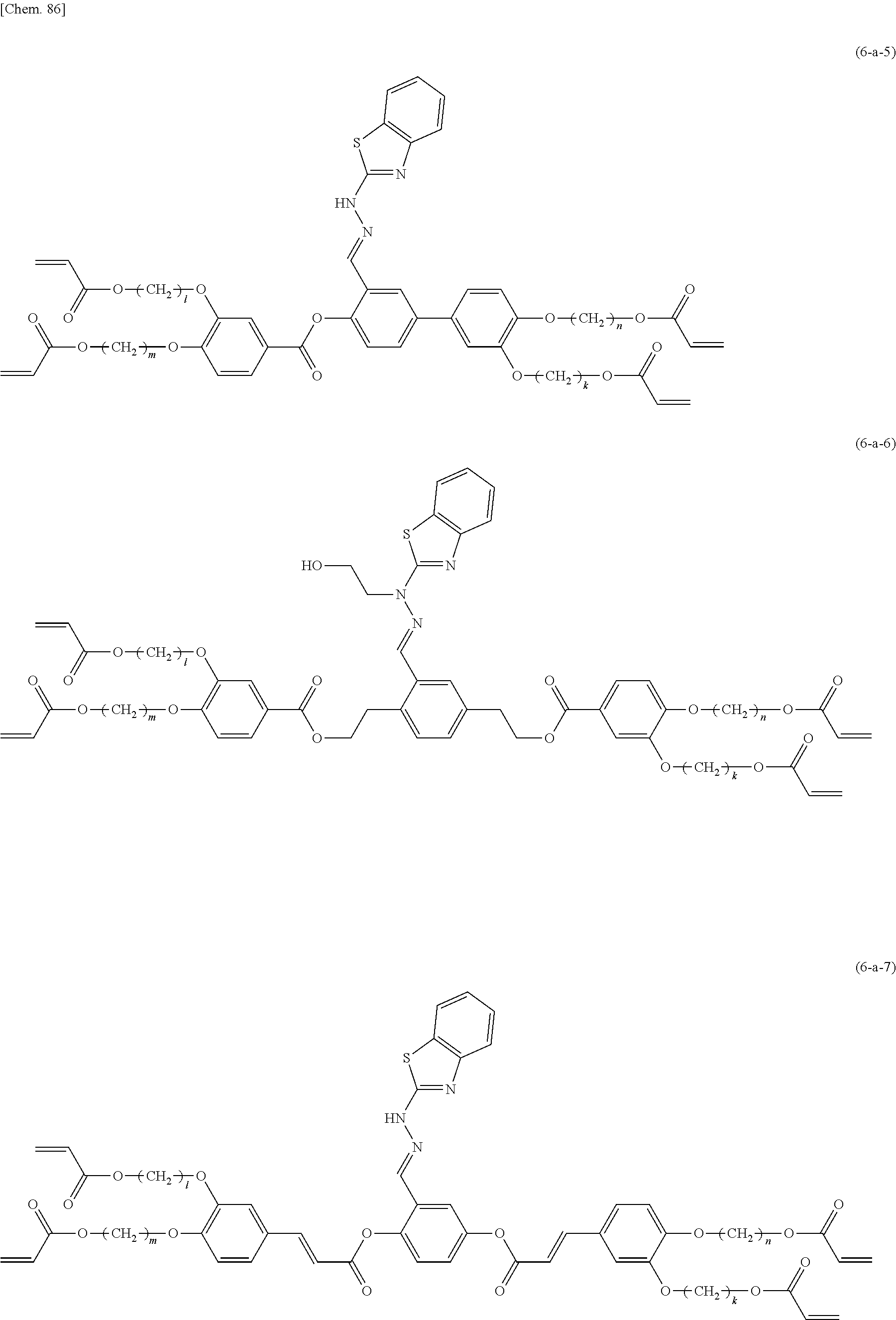

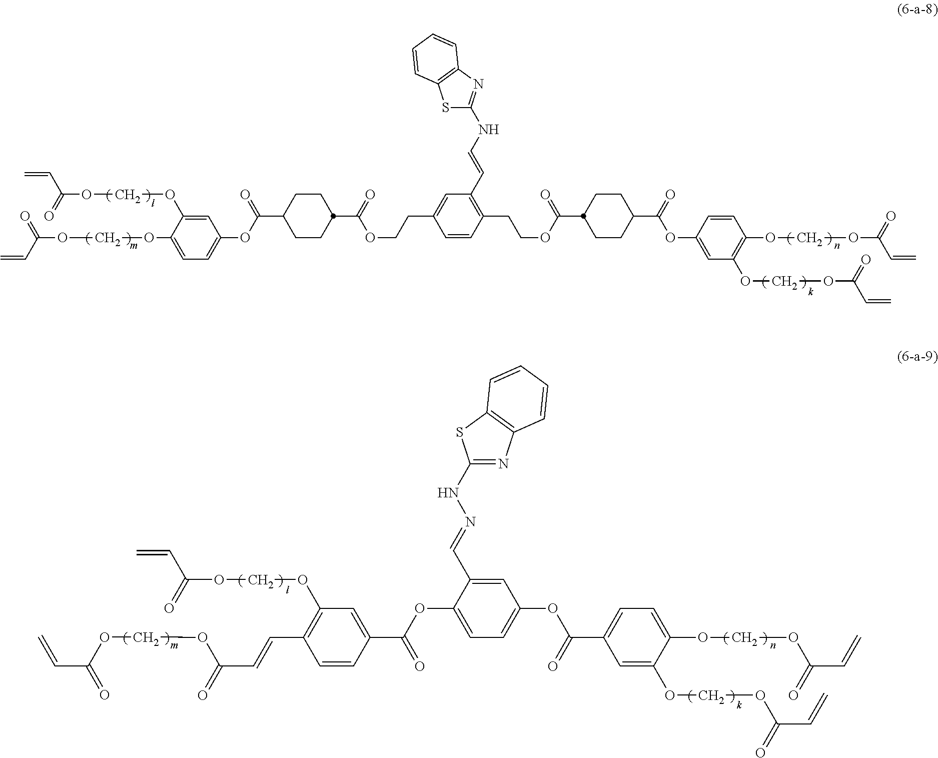

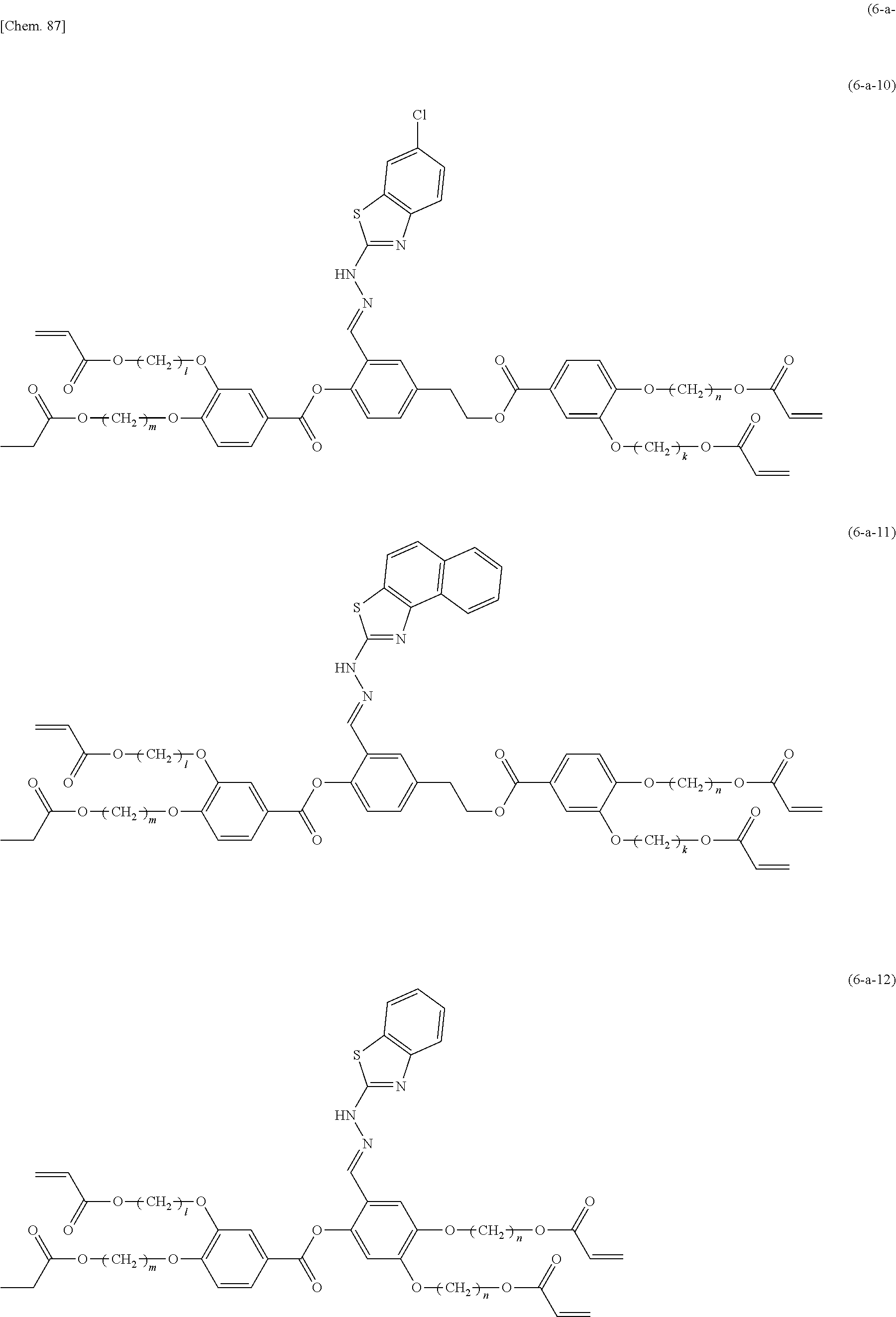

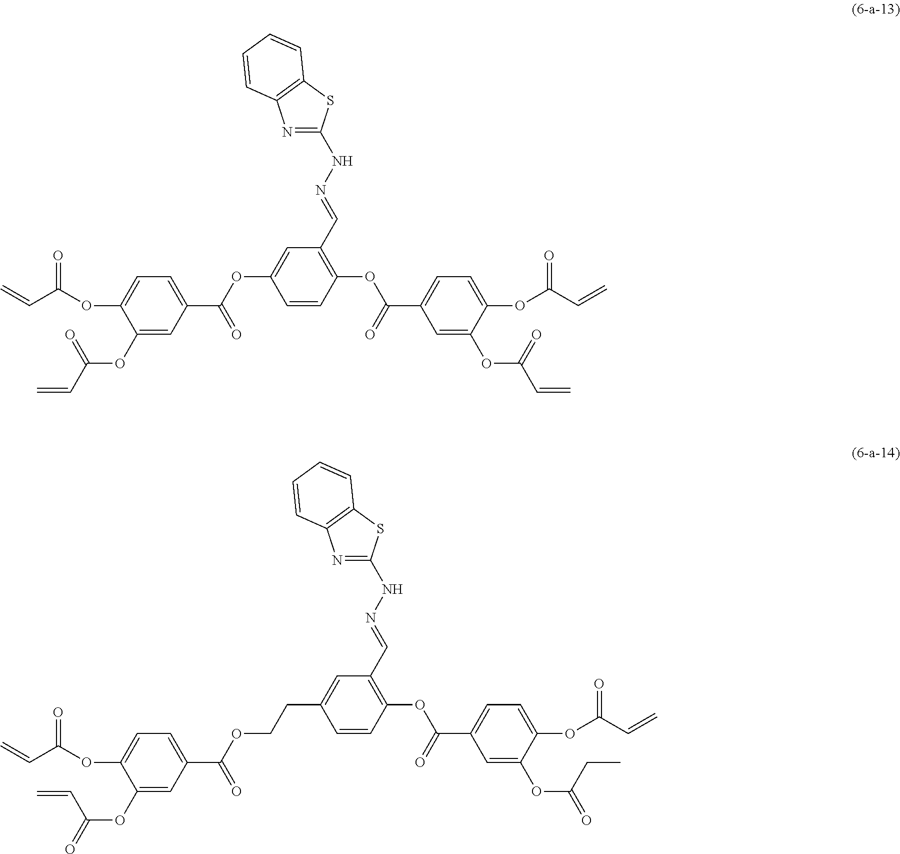

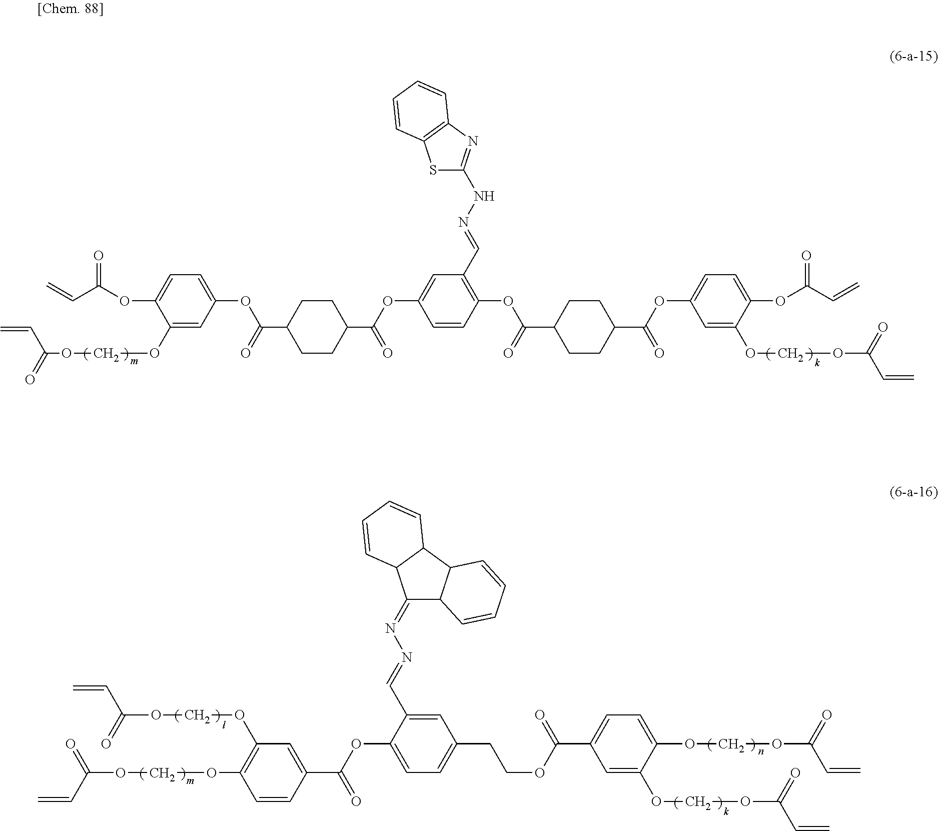

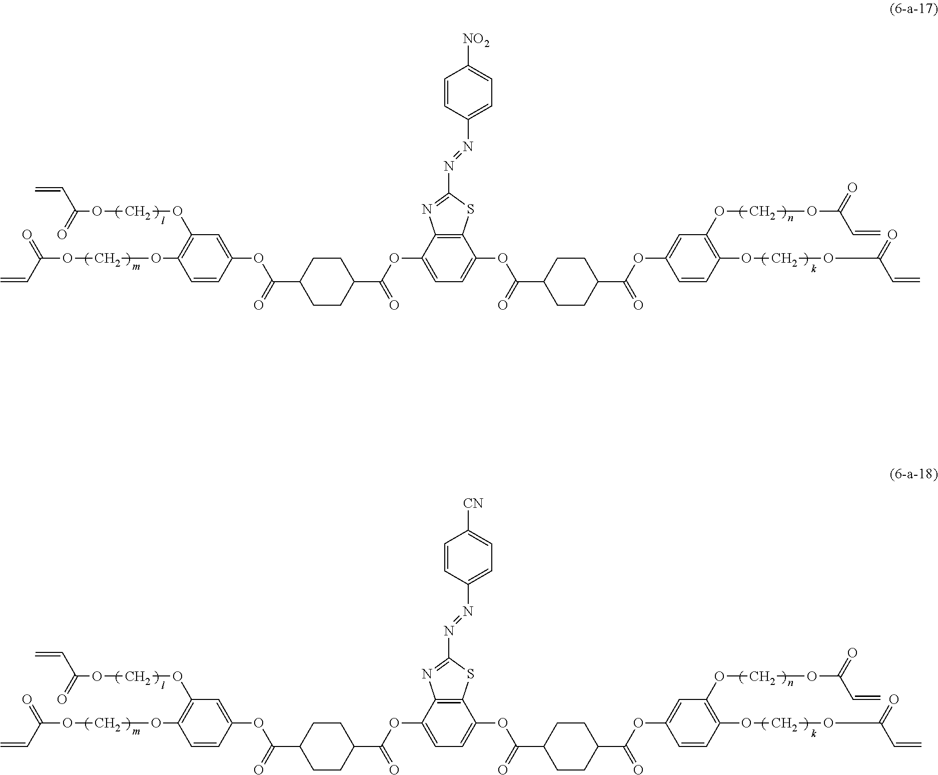

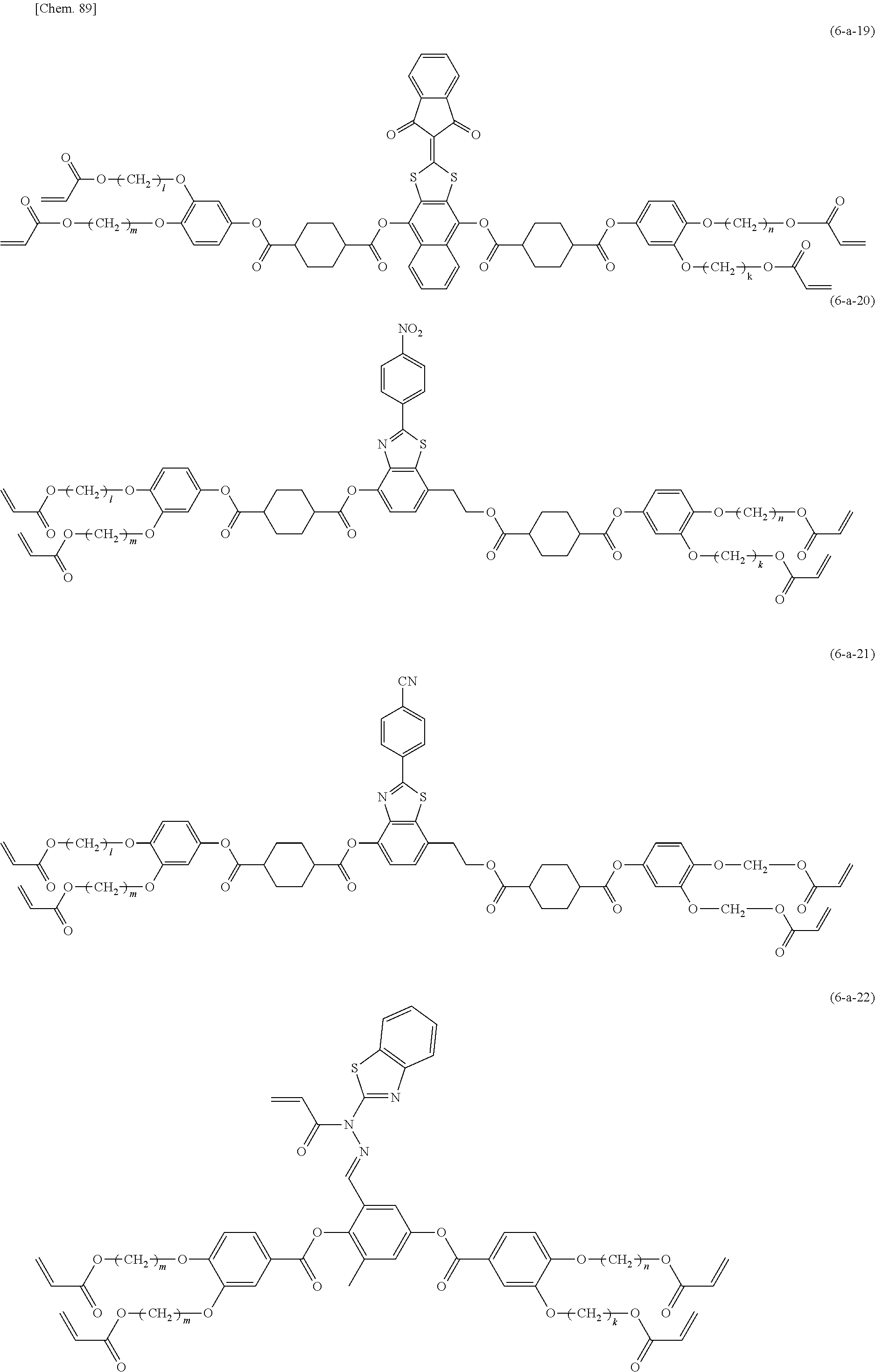

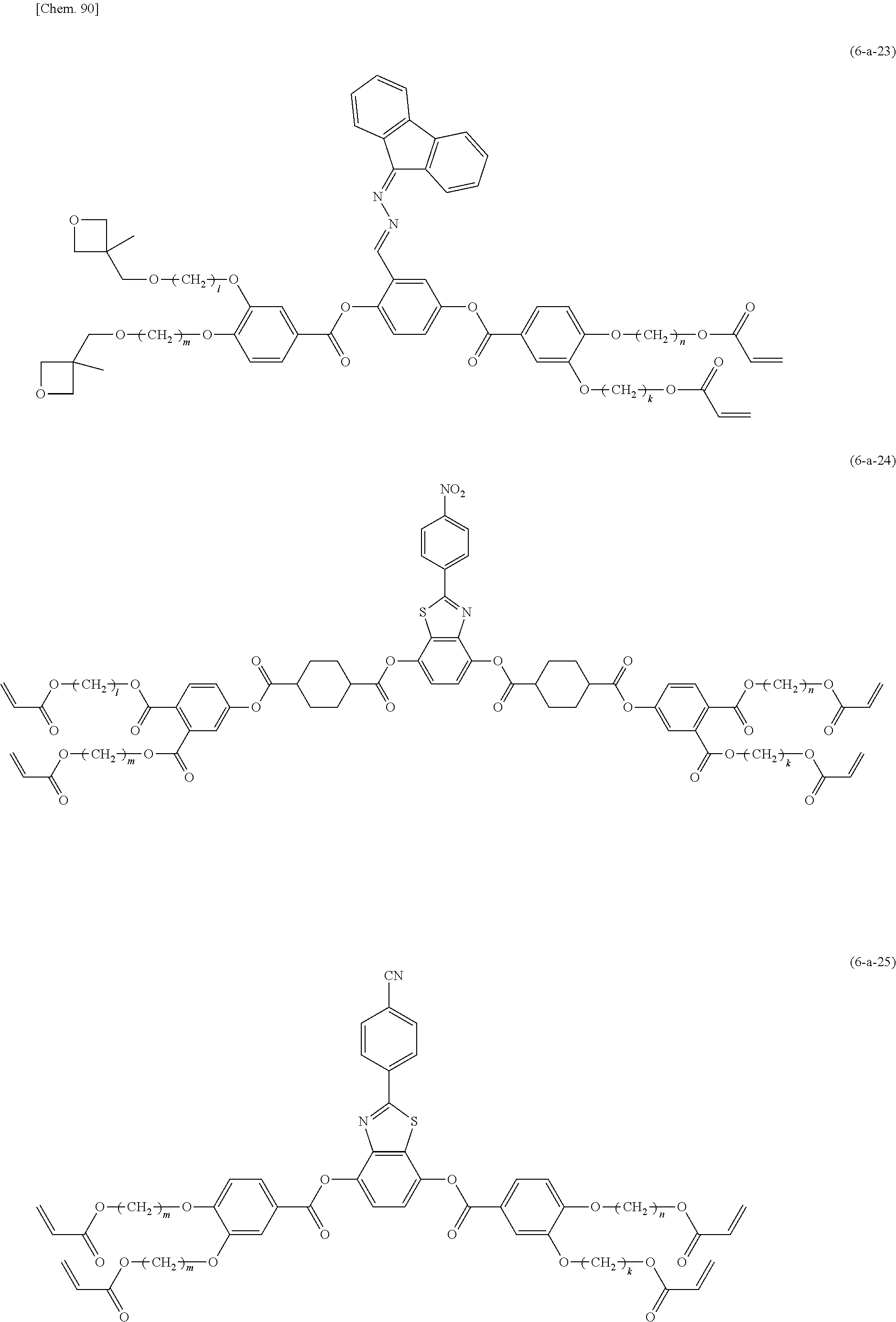

(where k, l, m, and n each independently represent the number of carbon atoms that is 1 to 10).

These liquid-crystal compounds may be used alone or in combination of two or more thereof.

Specific preferred examples of the compound represented by General formula (7) include compounds represented by the following Formula (7-a-1) to Formula (7-a-26).

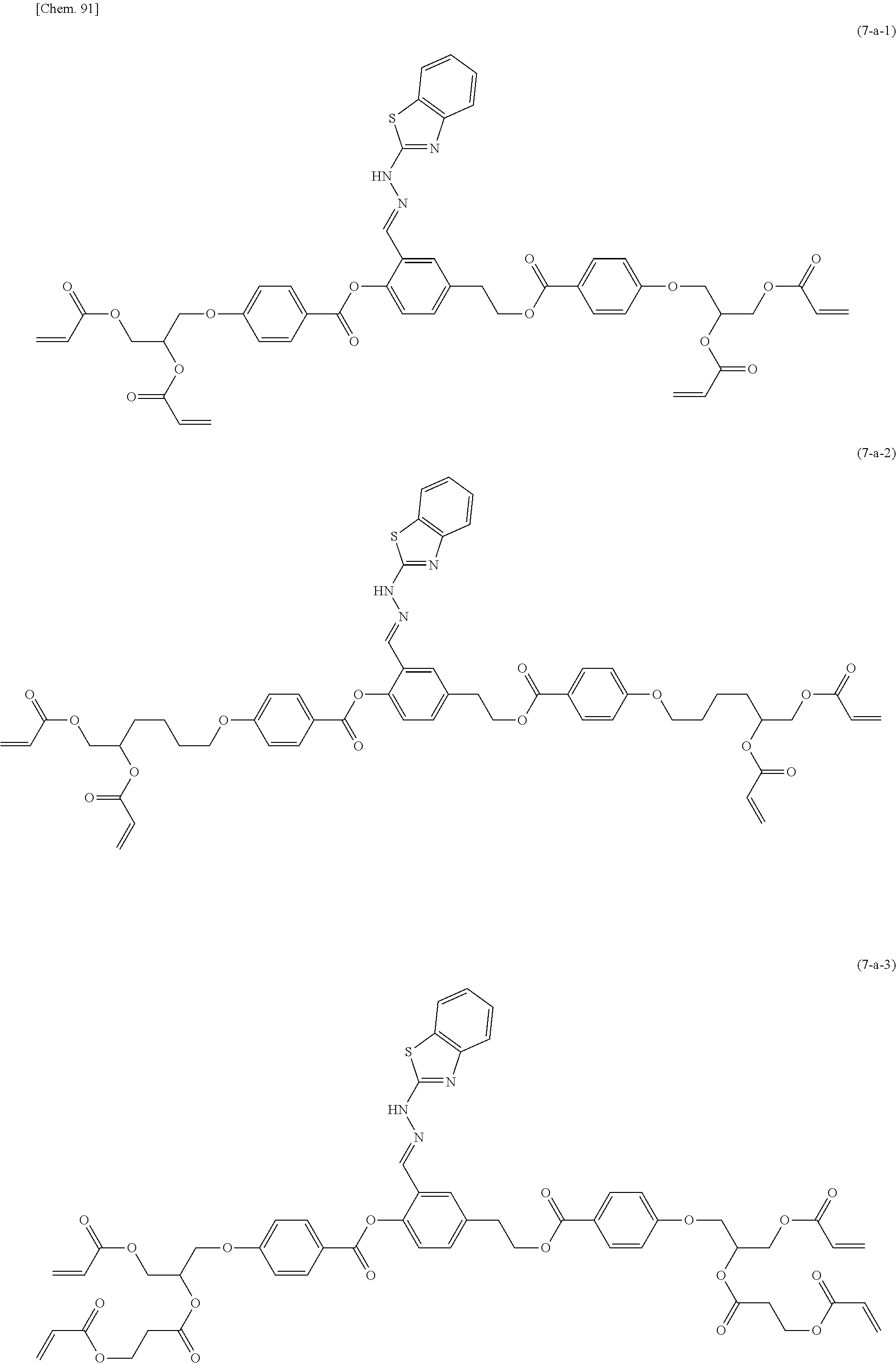

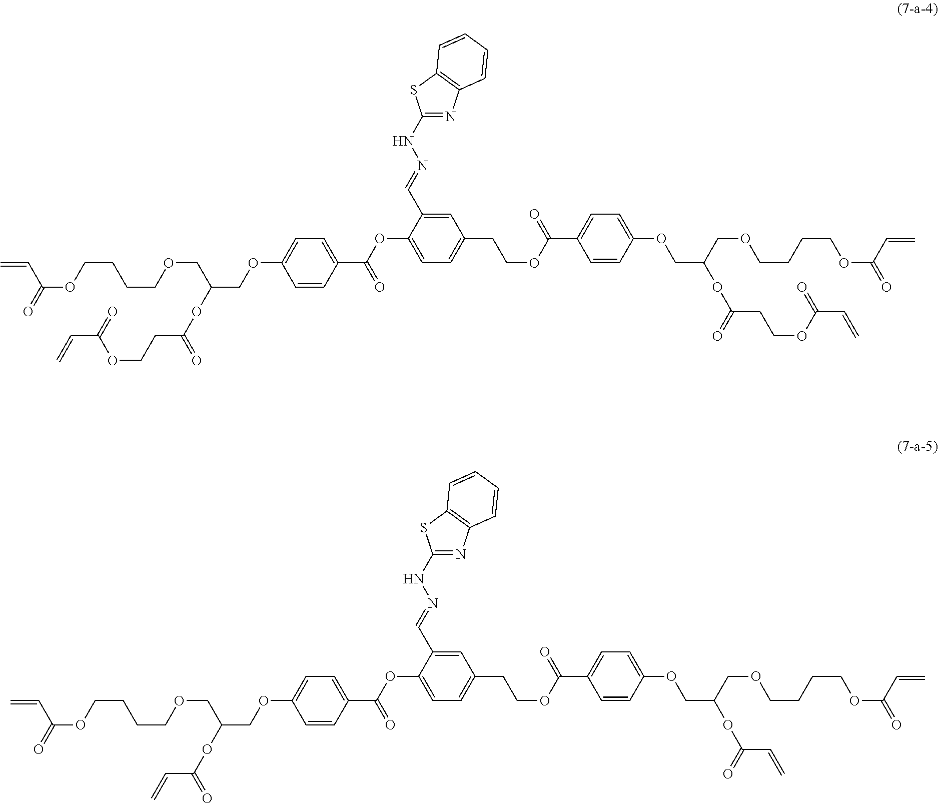

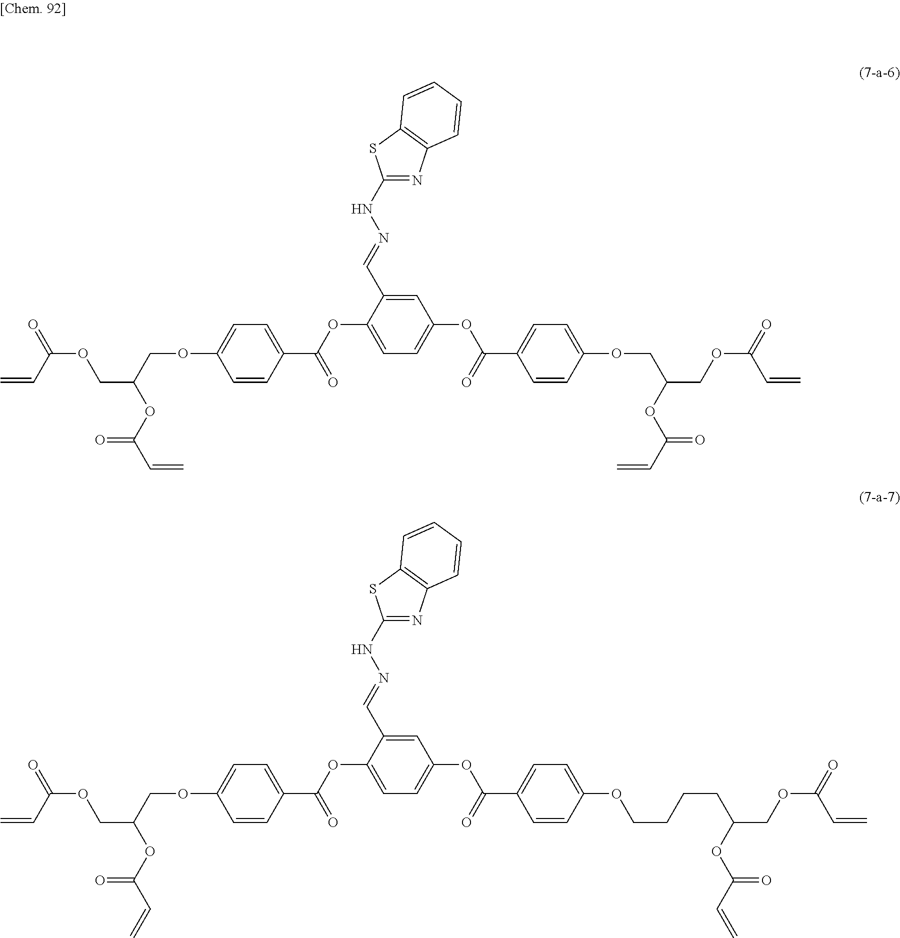

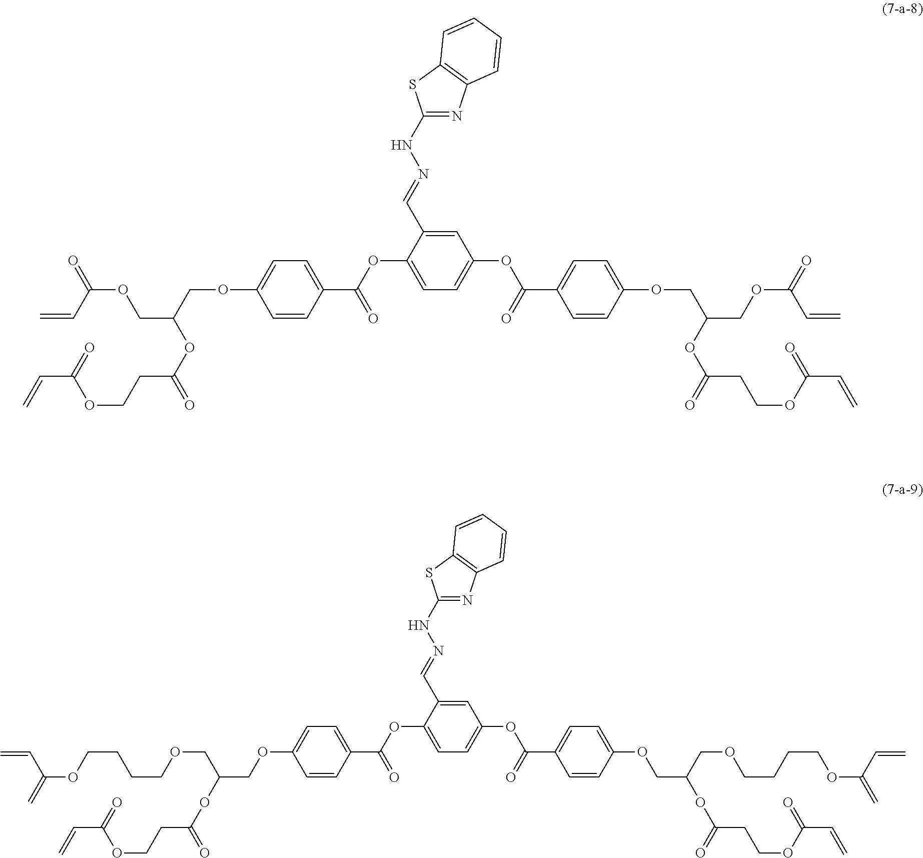

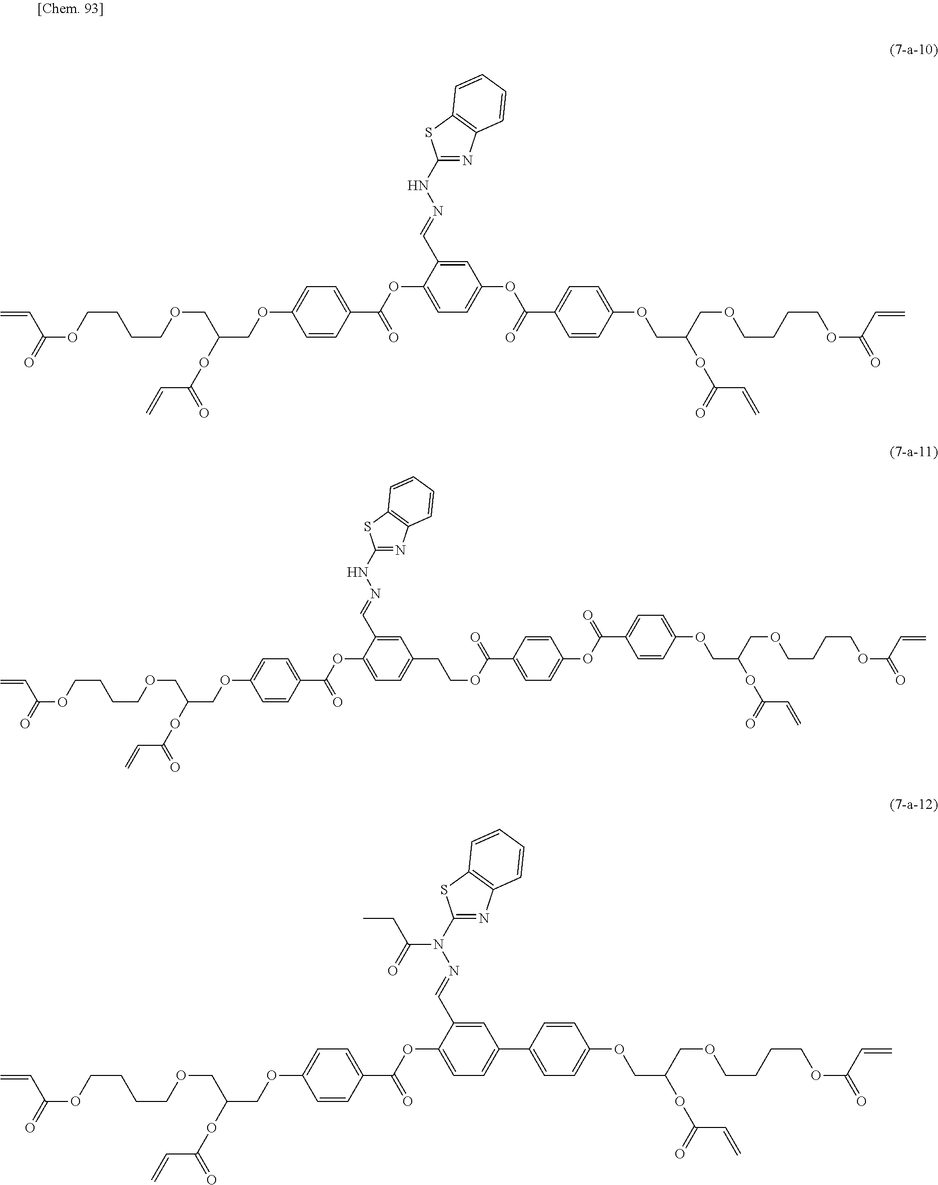

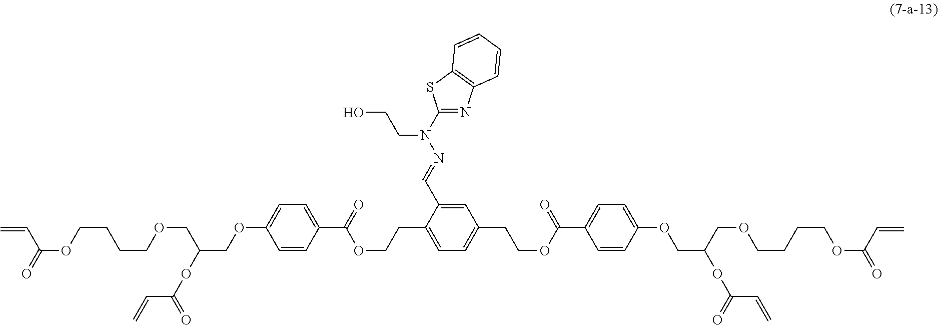

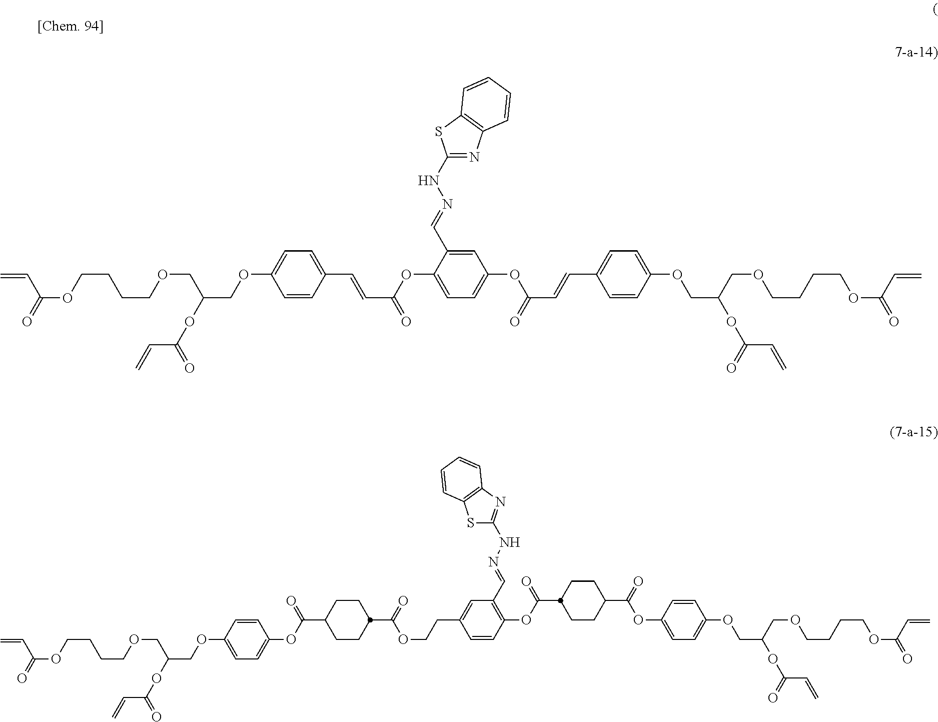

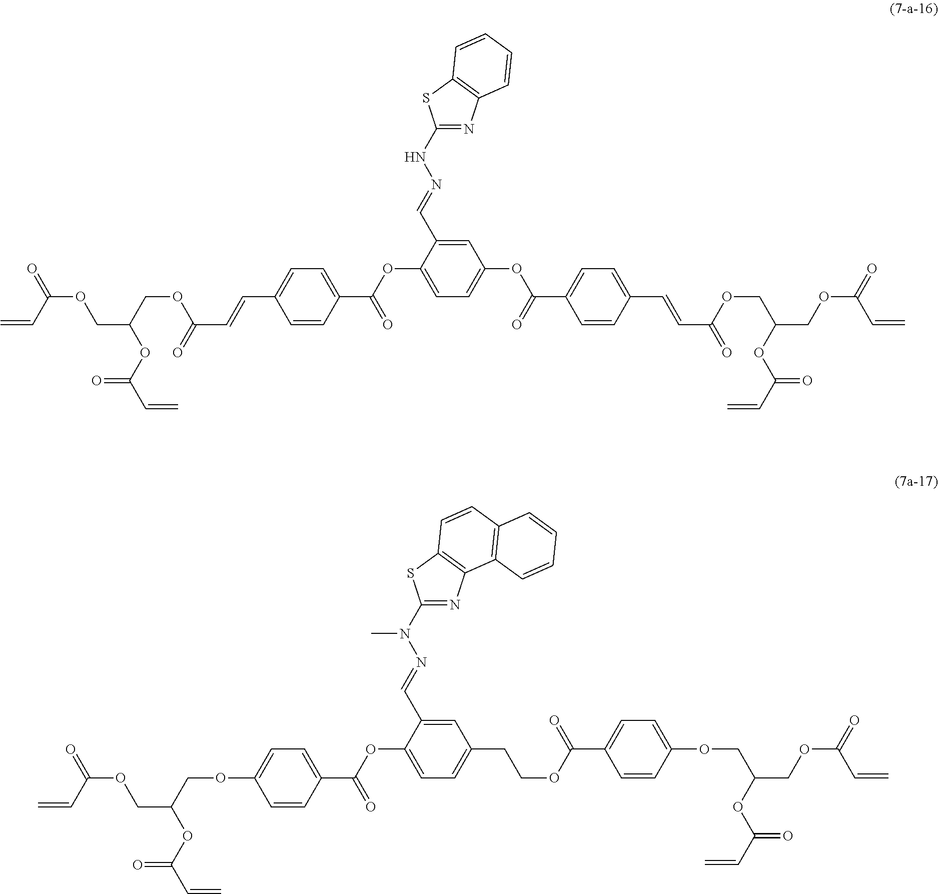

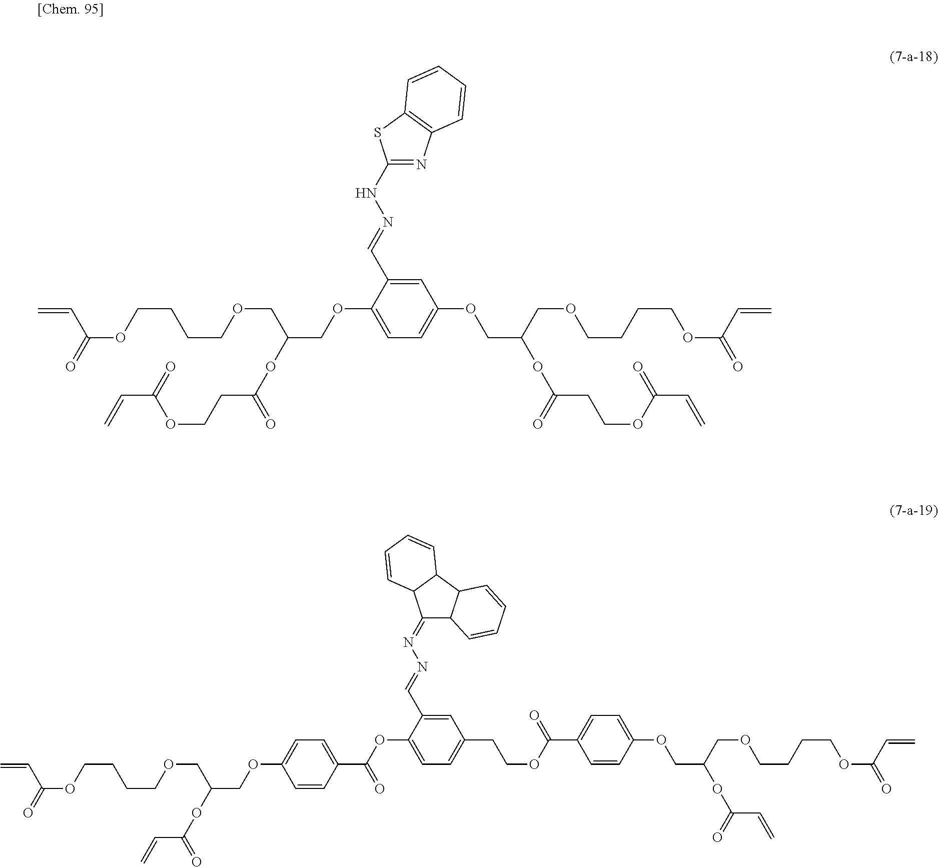

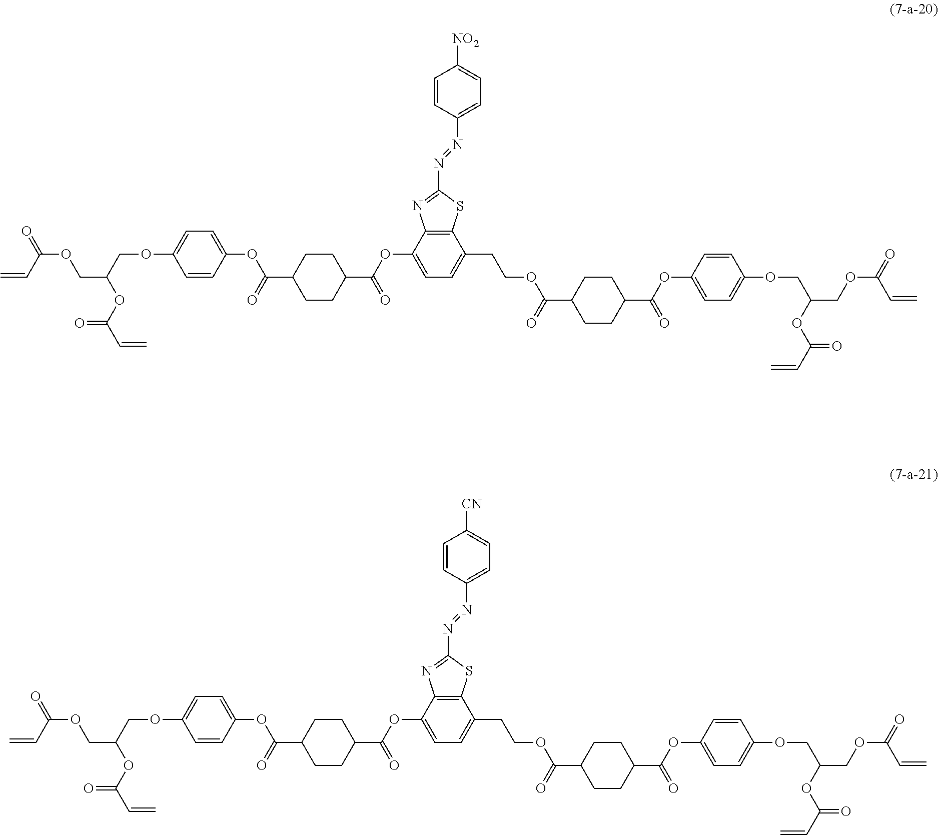

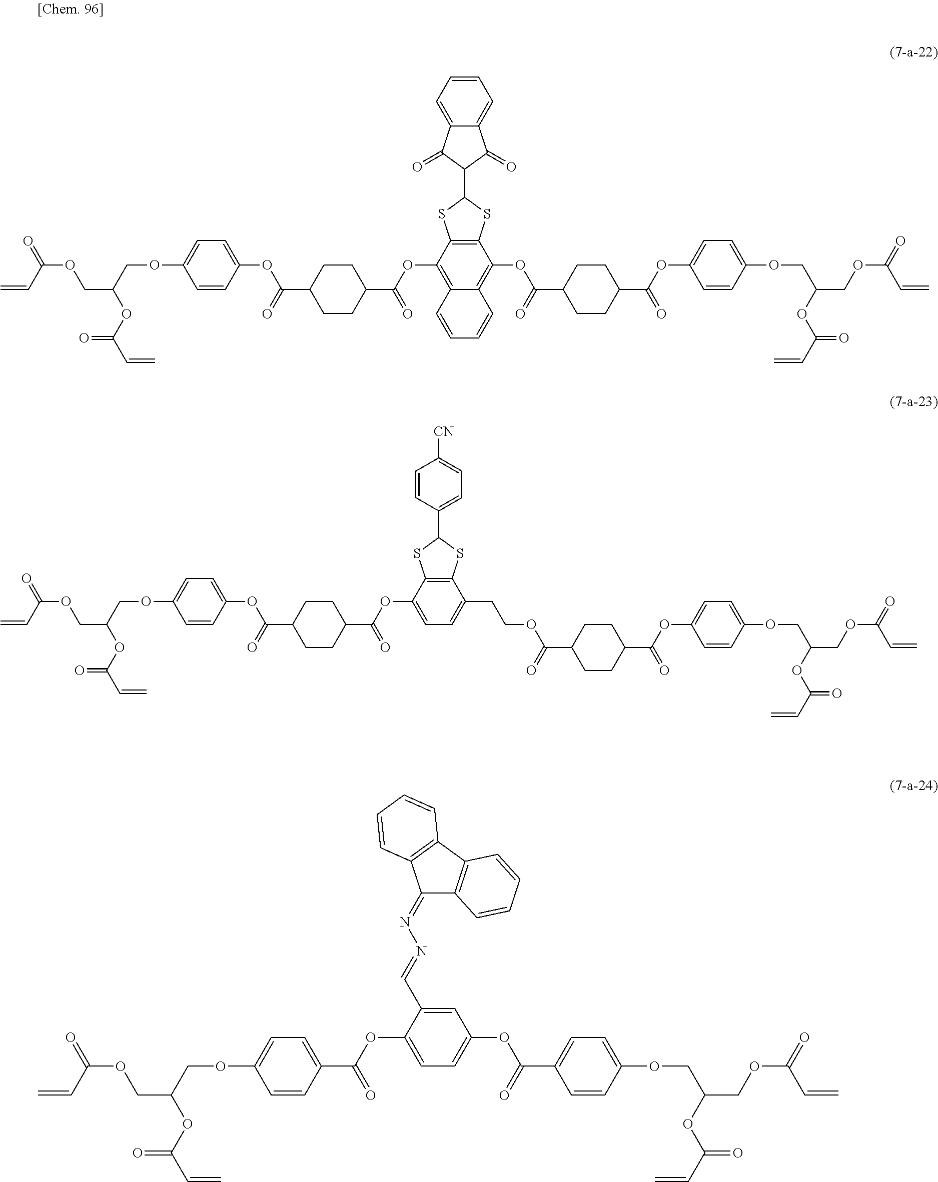

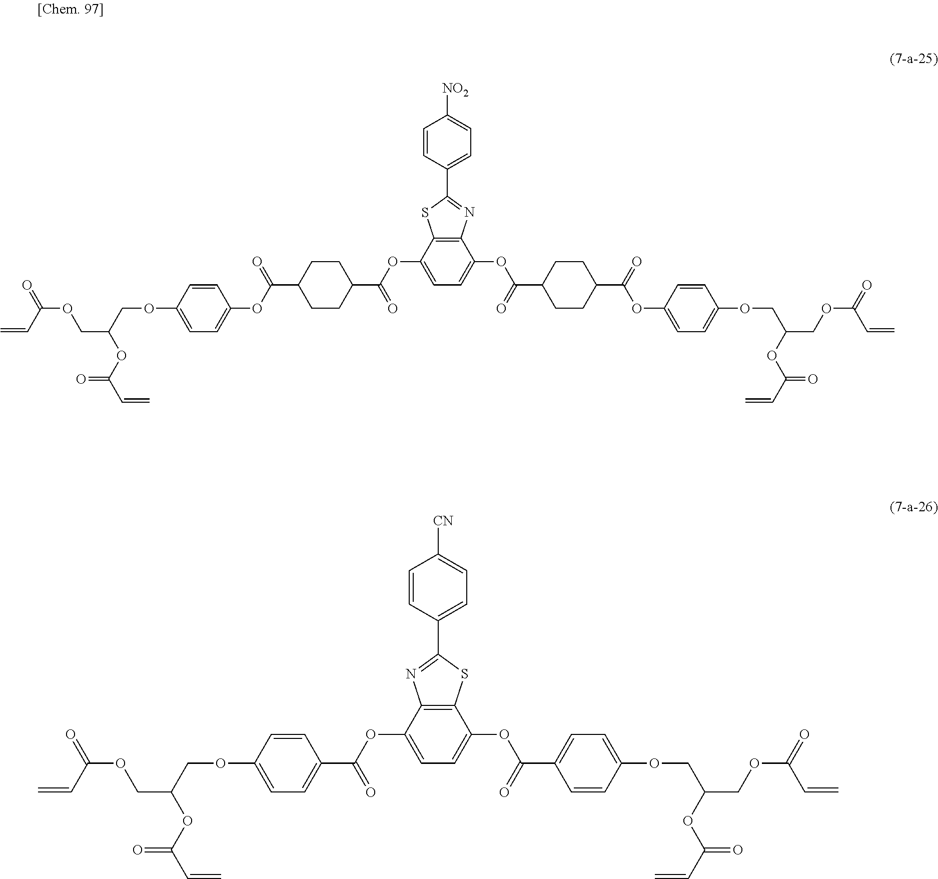

These liquid-crystal compounds may be used alone or in combination of two or more thereof.

The total content of the liquid-crystal compound including at least one polymerizable group relative to the total amount of liquid-crystal compound in the polymerizable composition is preferably 60 to 100 mass %, more preferably 65 to 98 mass %, particularly preferably 70 to 95 mass %.

The compounds represented by General formulas (1) to (7) and having reverse wavelength dispersion characteristics have a “T-shape” structure. Other examples of the compounds having reverse wavelength dispersion characteristics include compounds having a “cross-shape” structure or an “H-shape” structure. The compounds having an “H-shape” structure inherently have lower heat resistance. The compounds having a “cross-shape” structure and having two polymerizable functional groups unlikely provide polymers having high cross-linking densities because of steric hindrance of the compound structure, and the polymers have lower heat resistance.

From the viewpoint of heat resistance, among the compounds represented by General formulas (1) to (7), the composition preferably contains a compound having two or more polymerizable functional groups, more preferably contains a compound having three or more polymerizable functional groups. On the other hand, from the viewpoint of liquid crystallinity, the composition preferably contains the compound represented by General formula (1) or (2).

From the viewpoint of both of heat resistance and liquid crystallinity, more preferred is a compound represented by General formula (2) in which W⁸² is a group represented by P⁸—(S⁸—X⁸)ⱼ— (where P⁸, S⁸, X⁸, and j are defined as with above).

Specifically, preferred are compounds represented by Formulas (2-a-48), (2-a-49), (2-a-52), (2-a-56), (2-a-60), and (2-a-68) above.

### (Other Liquid-Crystal Compounds)

A polymerizable composition used for producing a retardation film according to the present invention may contain, in addition to the liquid-crystal compounds represented by General formula (1) to General formula (7), a liquid-crystal compound having at least one polymerizable group. Examples of such a liquid-crystal compound include liquid-crystal compounds represented by General formula (1-b) to General formula (7-b). However, when the amount of addition is excessively large, the value of (Formula 1-1) exceeds 1. Thus, the amount of addition relative to the total amount of polymerizable compounds used for the polymerizable composition is preferably 30 mass % or less, more preferably 20 mass % or less, particularly preferably 10 mass % or less.

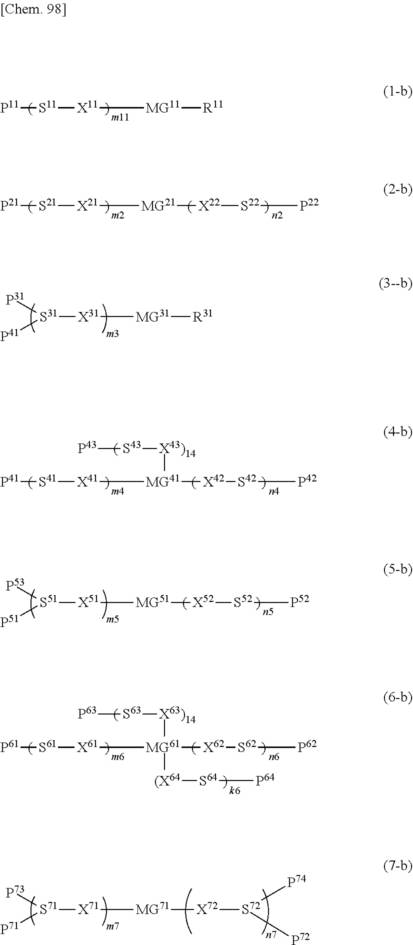

(where P¹¹ to P⁷⁴ represent a polymerizable group; S¹¹ to S⁷² represent a spacer group or a single bond; when a plurality of S¹¹'s to S⁷²'s are present, they may be the same or different; X¹¹ to X⁷² represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C═C—, or a single bond; when a plurality of X¹¹'s to X⁷²'s are present, they may be the same or different (provided that the P—(S—X)— bonds do not include —O—O—); MG¹¹ to MG⁷¹ each independently represent Formula (b),

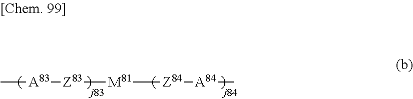

(where A⁸³ and A⁸⁴ each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group; these groups may be unsubstituted or may be substituted by at least one L²; when a plurality of A⁸³'s and/or A⁸⁴'s are present, they may be the same or different, Z⁸³ and Z⁸⁴ each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C═C—, or a single bond; when a plurality of Z⁸³'s and/or Z⁸⁴'s are present, they may be the same or different,

M⁸¹ represents a group selected from a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group-, a 1,2,3,4-tetrahydronaphthalene-2,6-diyl group, a naphthylene-1,4-diyl group, a naphthylene-1,5-diyl group, a naphthylene-1,6-diyl group, a naphthylene-2,6-diyl group, a phenanthrene-2,7-diyl group, a 9,10-dihydrophenanthrene-2,7-diyl group, a 1,2,3,4,4a,9,10a-octahydrophenanthrene-2,7-diyl group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, and a fluorene-2,7-diyl group; these groups may be unsubstituted or may be substituted by at least one L²

L² represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms; the alkyl group may be linear or branched; any hydrogen atom may be substituted by a fluorine atom; in the alkyl group, one —CH₂— or non-adjacent two or more —CH₂— may each be independently substituted by a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, and —C═C—; when a plurality of L²'s are present in the compound, they may be the same or different; m represents an integer of 0 to 8; j83 and j84 each independently represent an integer of 0 to 5 provided that j83+j84 is an integer of 1 to 5); R¹¹ and R³¹ represent a hydrogen atom, a fluorine atom, a chlorine atom, a bromine atom, an iodine atom, a pentafluorosulfuranyl group, a cyano group, a nitro group, an isocyano group, a thioisocyano group, or an alkyl group having 1 to 20 carbon atoms; the alkyl group may be linear or branched; any hydrogen atom in the alkyl group may be substituted by a fluorine atom; in the alkyl group, one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, or —C═C—; m11 represents an integer of 0 to 8; m2 to m7, n2 to n7, l4 to l6, and k6 each independently represent an integer of 0 to 5; provided that General formula (1) to General formula (7) are excluded).

Specific examples of the compound represented by General formula (1-b) include compounds represented by the following Formula (1-b-1) to Formula (1-b-39).

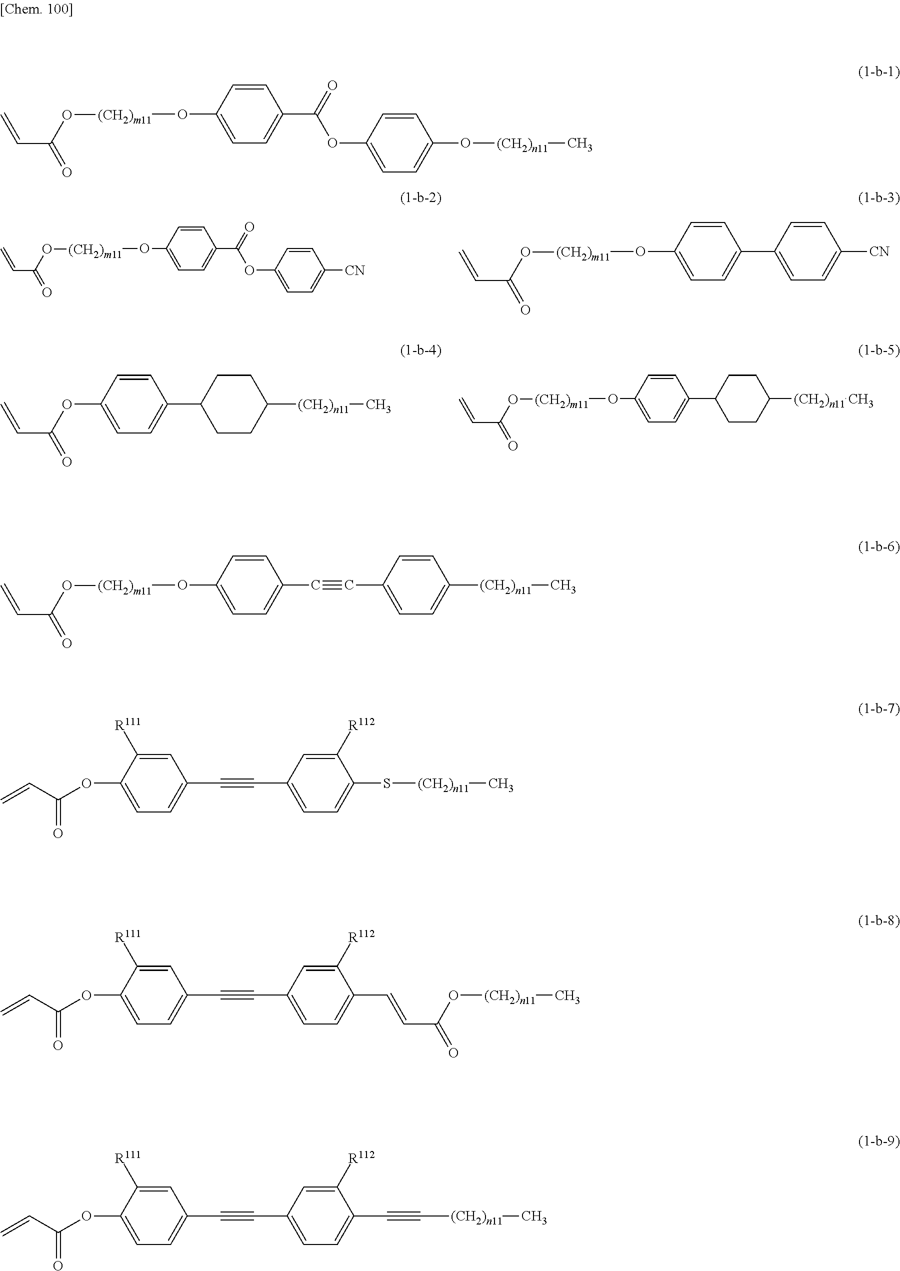

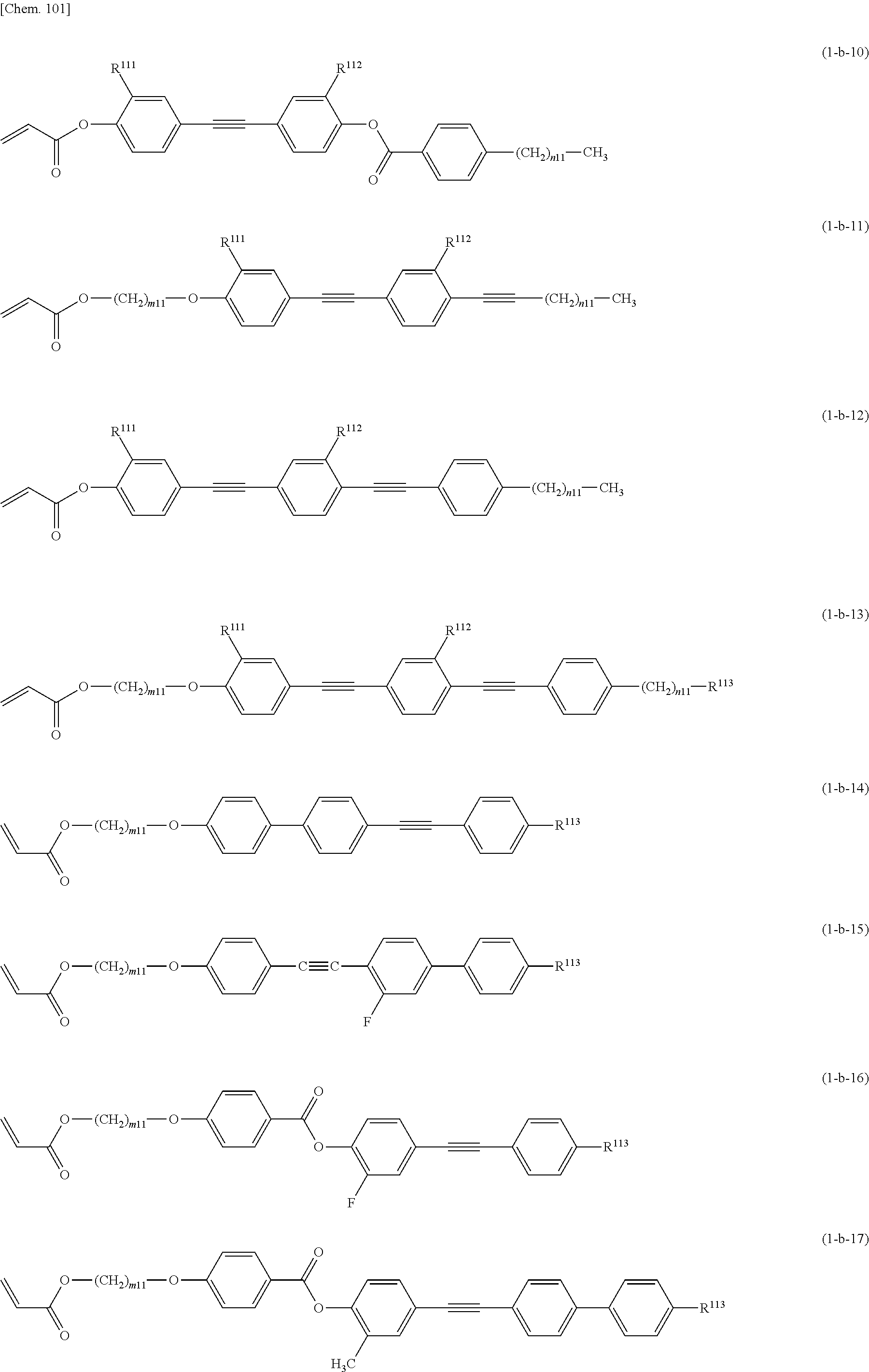

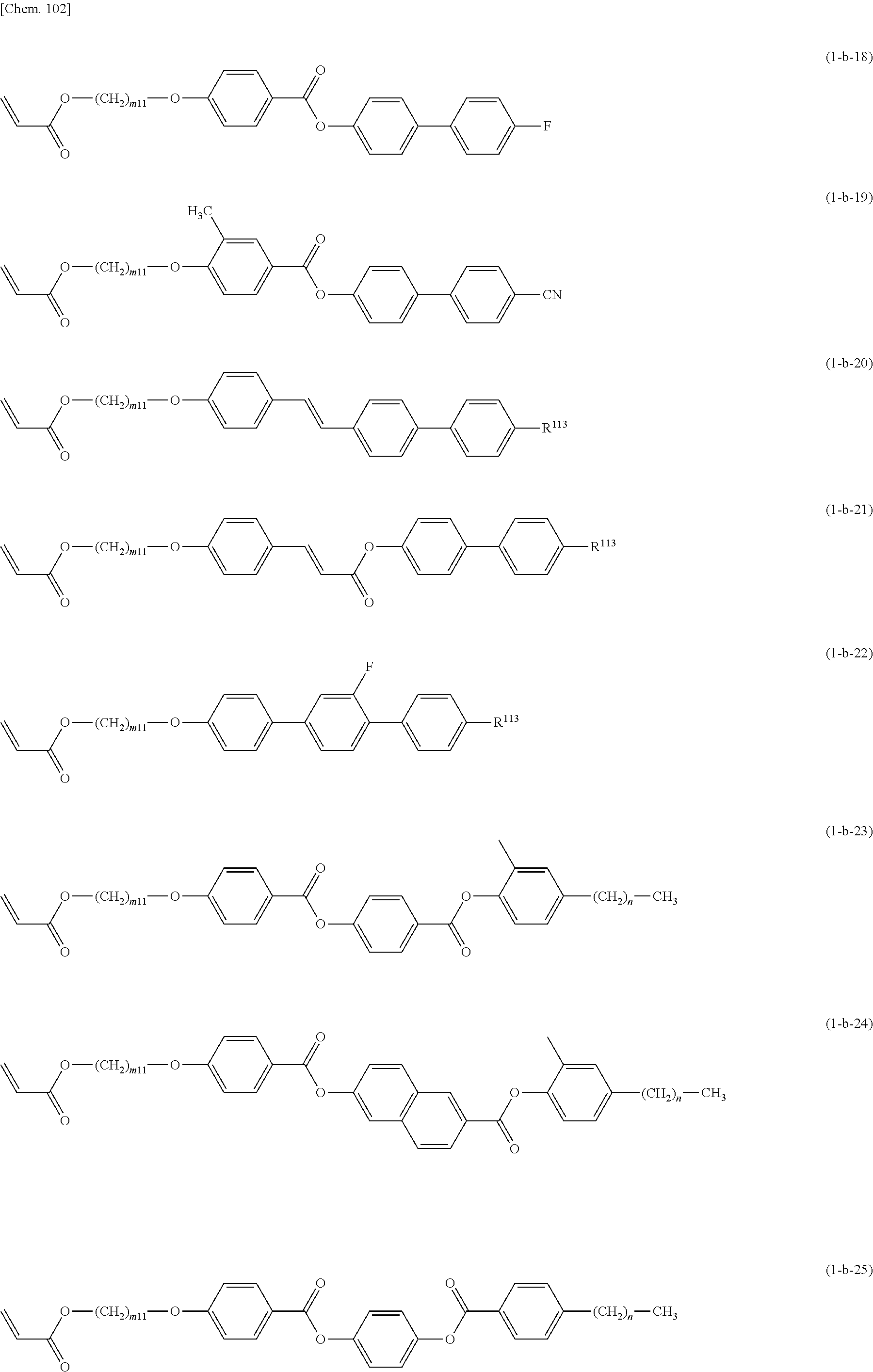

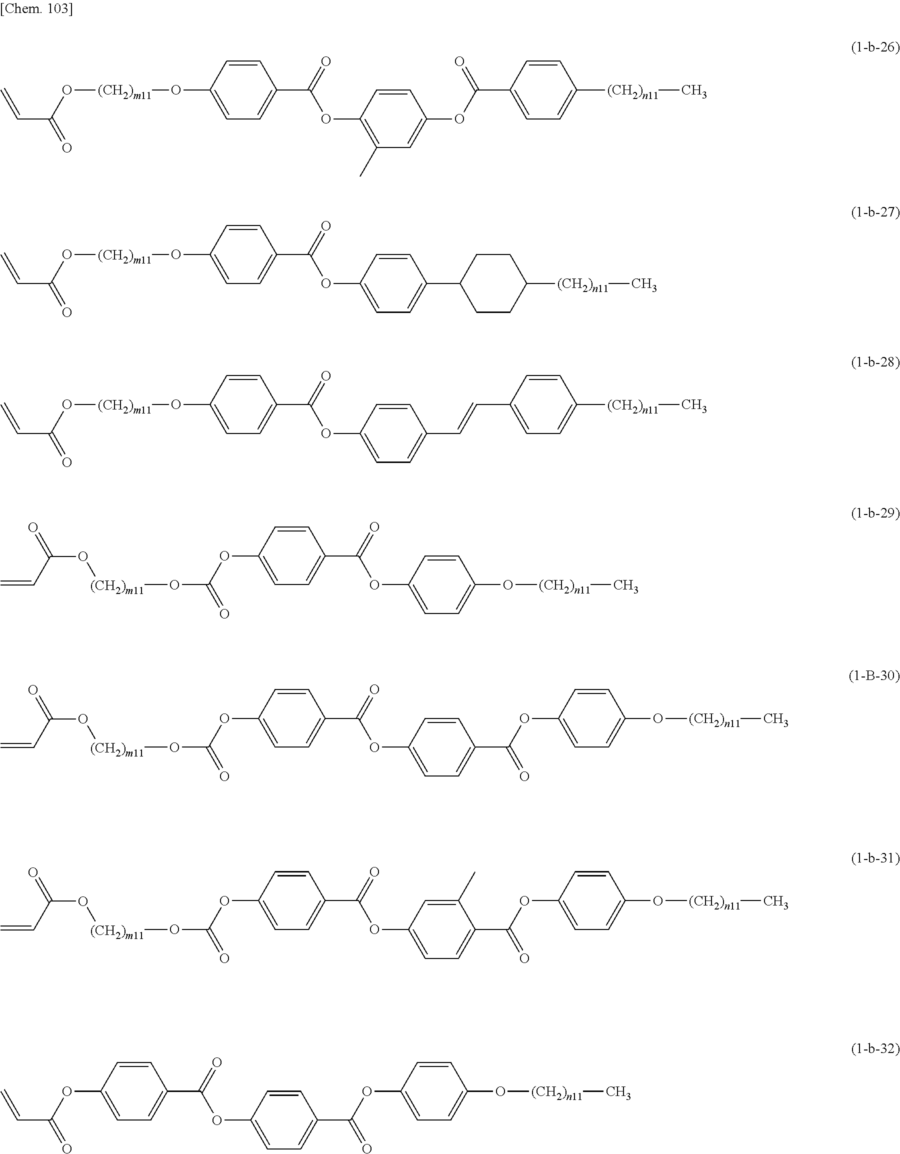

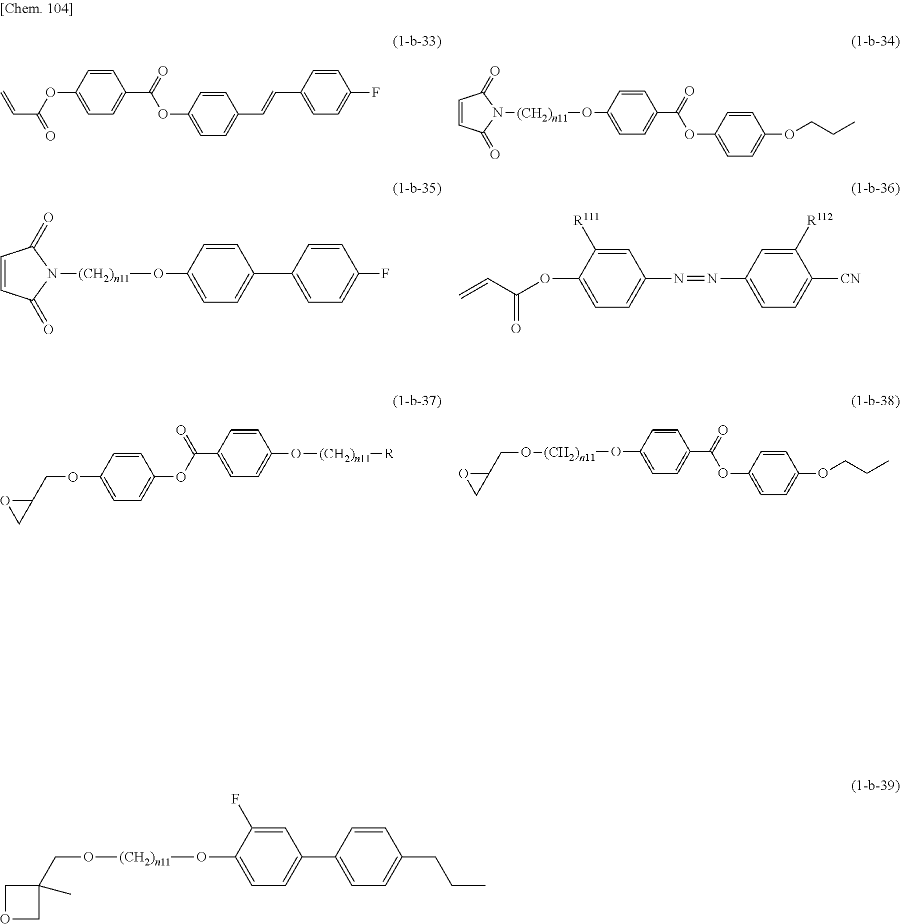

(where m11 and n11 each independently represent an integer of 1 to 10; R¹¹¹ and R¹¹² each independently represent a hydrogen atom, an alkyl group having 1 to 10 carbon atoms, or a fluorine atom; Rm represents a hydrogen atom, a fluorine atom, a chlorine atom, a bromine atom, an iodine atom, a pentafluorosulfuranyl group, a cyano group, a nitro group, an isocyano group, a thioisocyano group, or a linear or branched alkyl group having 1 to 20 carbon atoms in which one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, or —C═C—; in the alkyl group, any hydrogen atom may be substituted by a fluorine atom). These liquid-crystal compounds may be used alone or in combination of two or more thereof.

Specific examples of the compound represented by General formula (2-b) include compounds represented by the following Formula (2-b-1) to Formula (2-b-34).

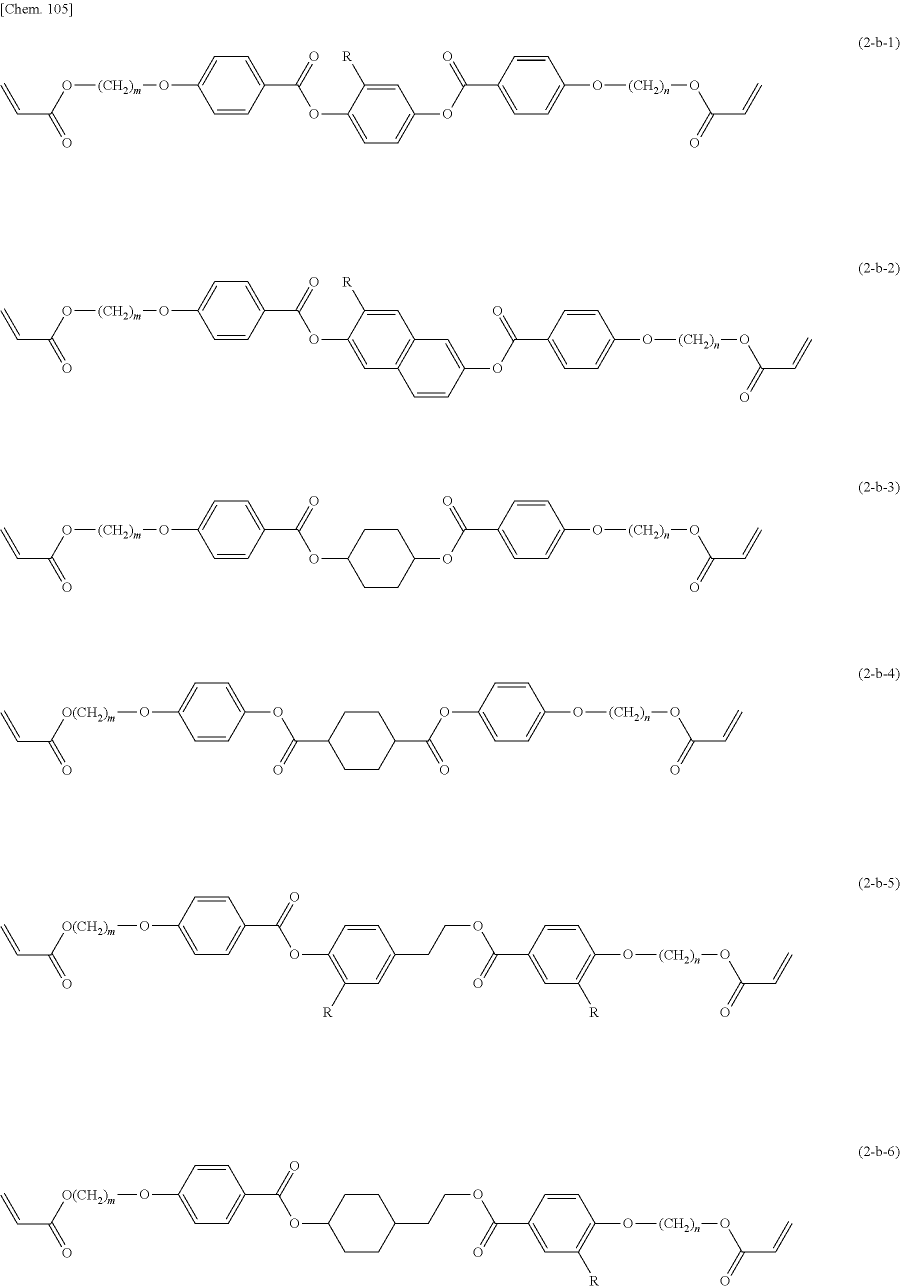

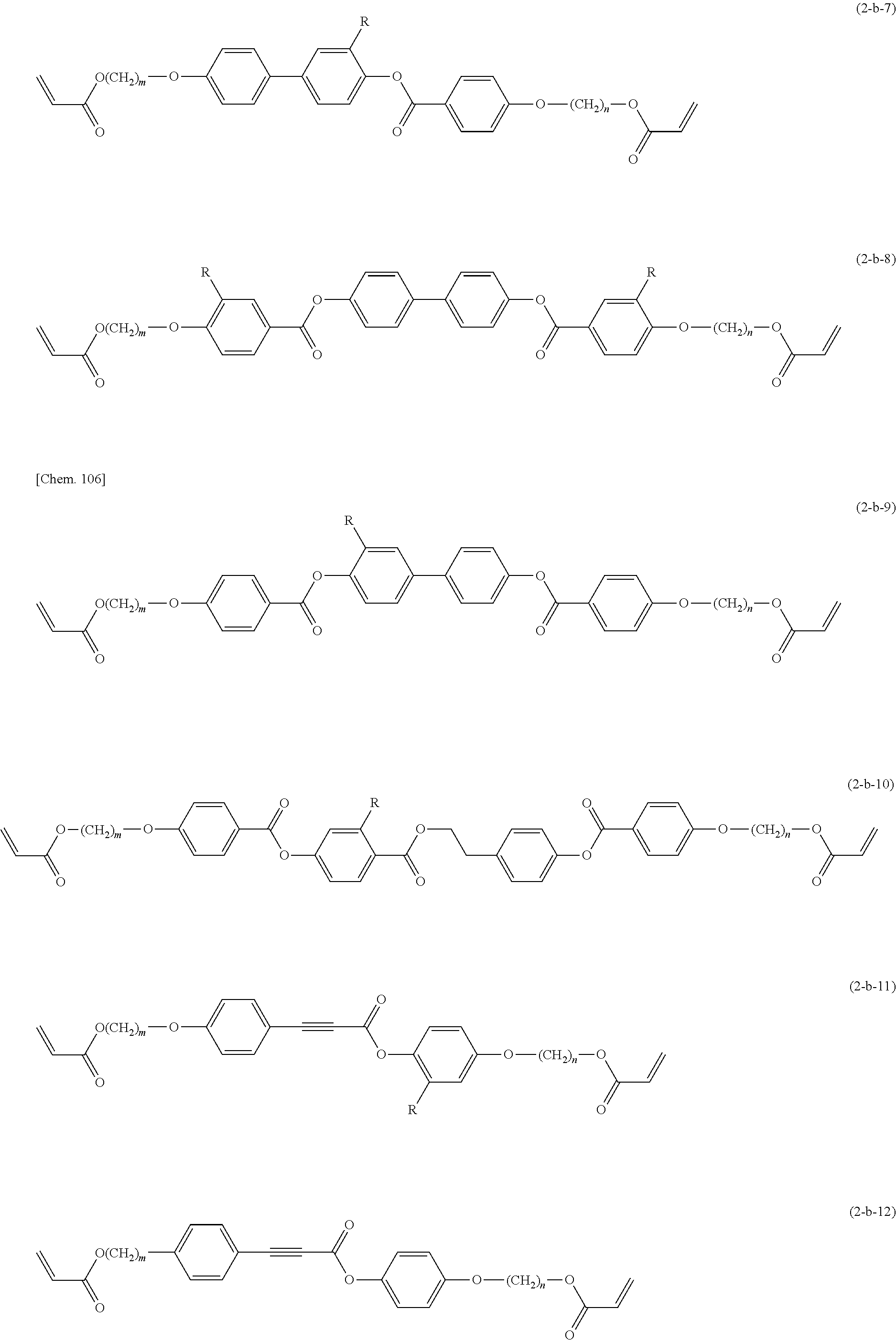

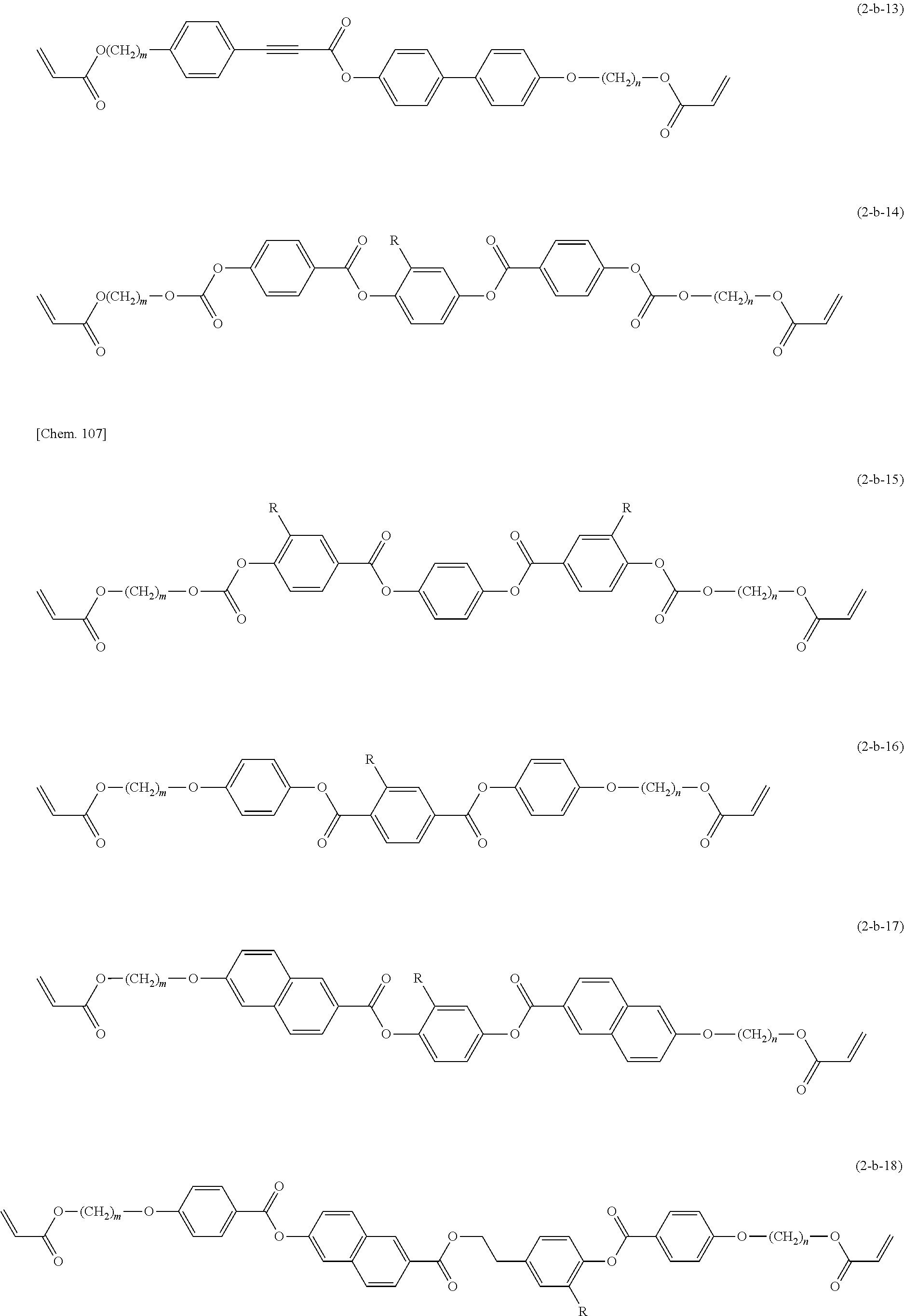

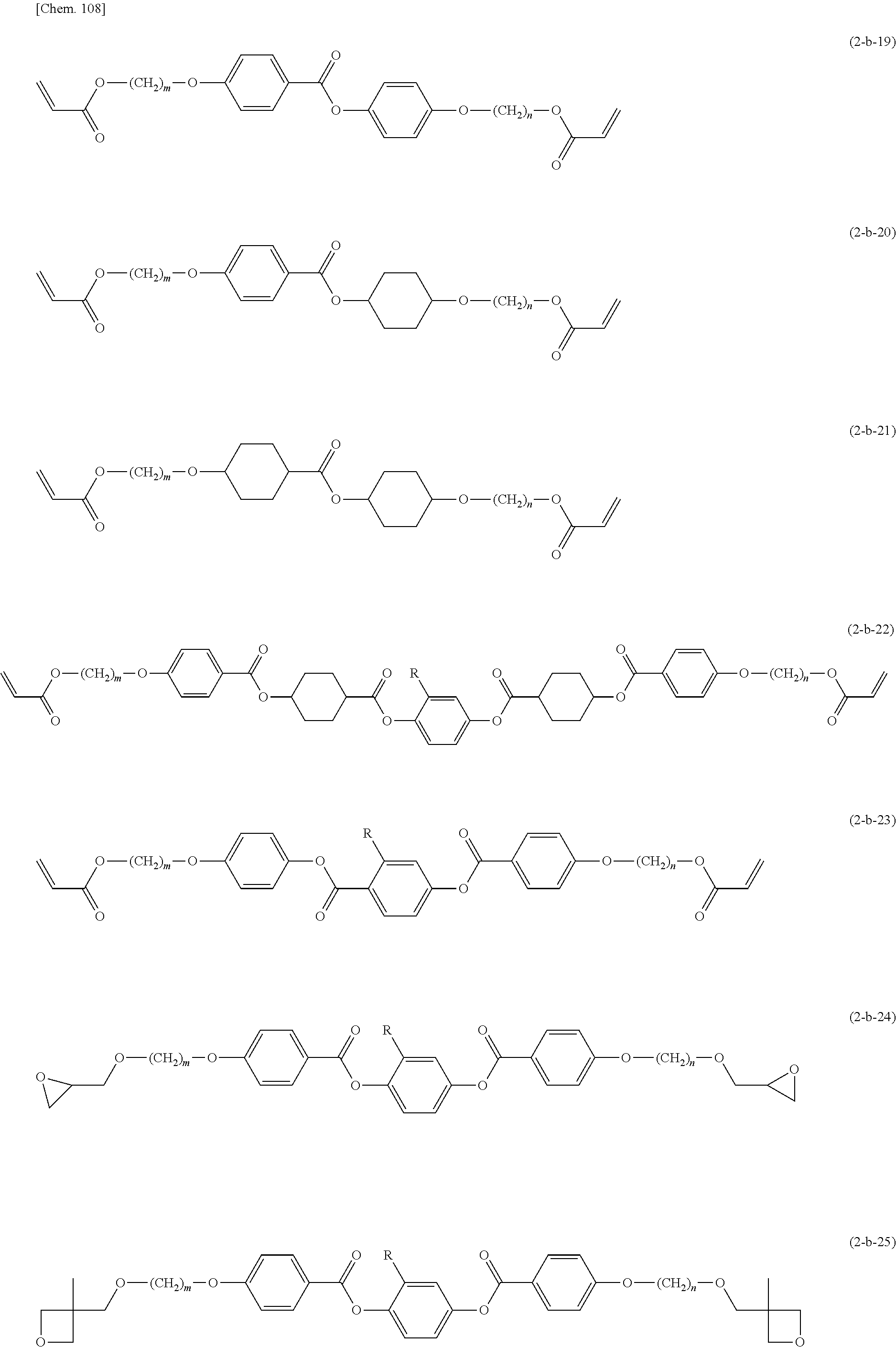

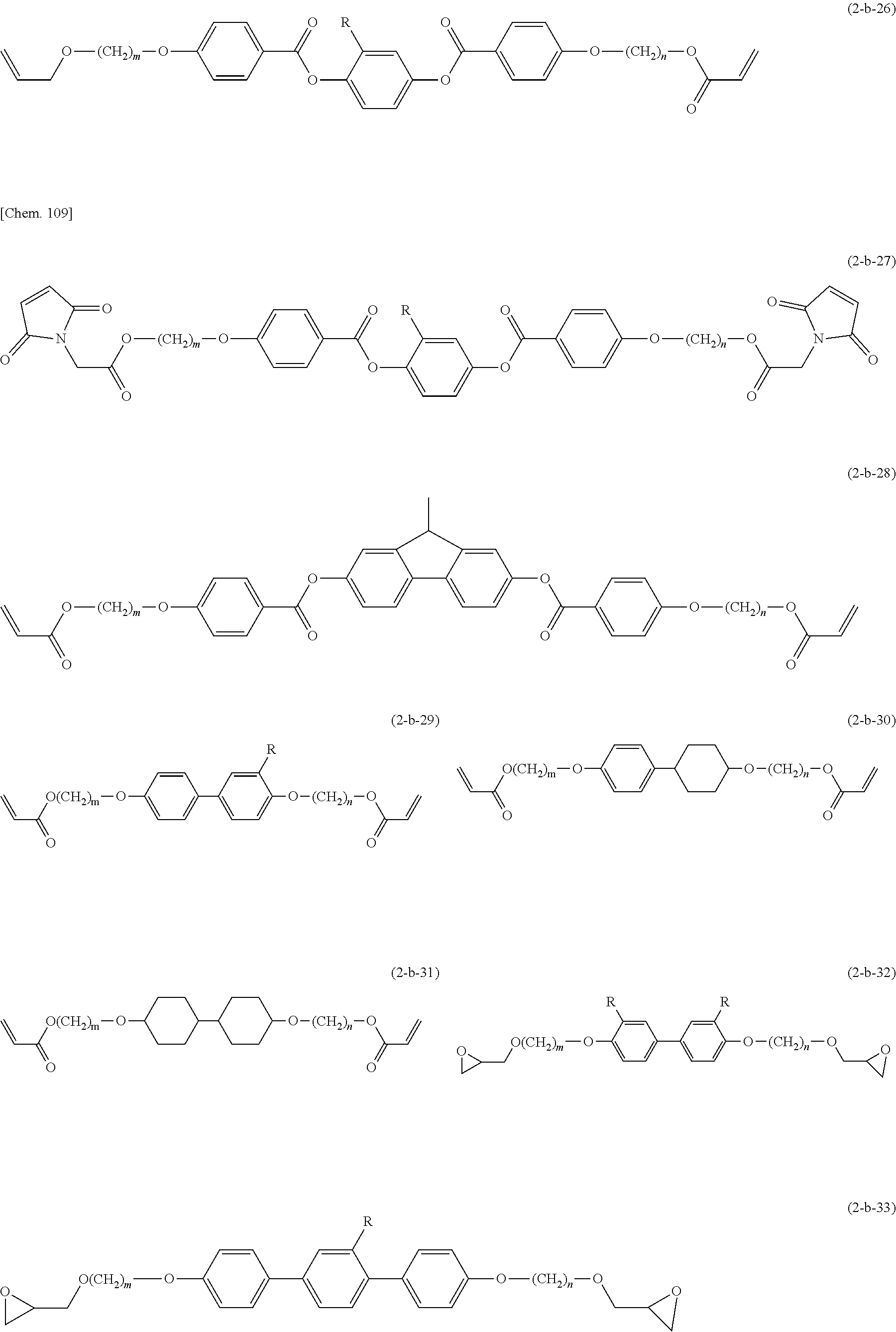

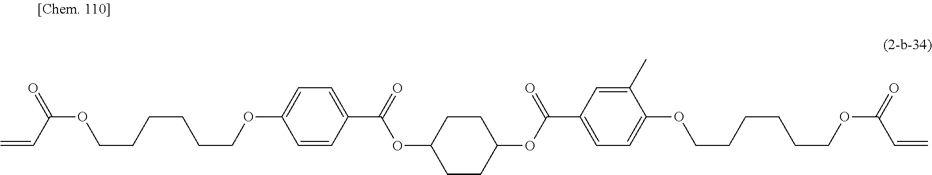

(where m and n each independently represent an integer of 1 to 18; and R represents a hydrogen atom, a halogen atom, an alkyl group having 1 to 6 carbon atoms, an alkoxy group having 1 to 6 carbon atoms, or a cyano group. When such a group is an alkyl group having 1 to 6 carbon atoms or an alkoxy group having 1 to 6 carbon atoms, the group may be wholly unsubstituted or may be substituted by one or two or more halogen atoms.) These liquid-crystal compounds may be used alone or in combination of two or more thereof.

Specific examples of the compound represented by General formula (3-b) include compounds represented by the following Formula (3-b-1) to Formula (3-b-16).

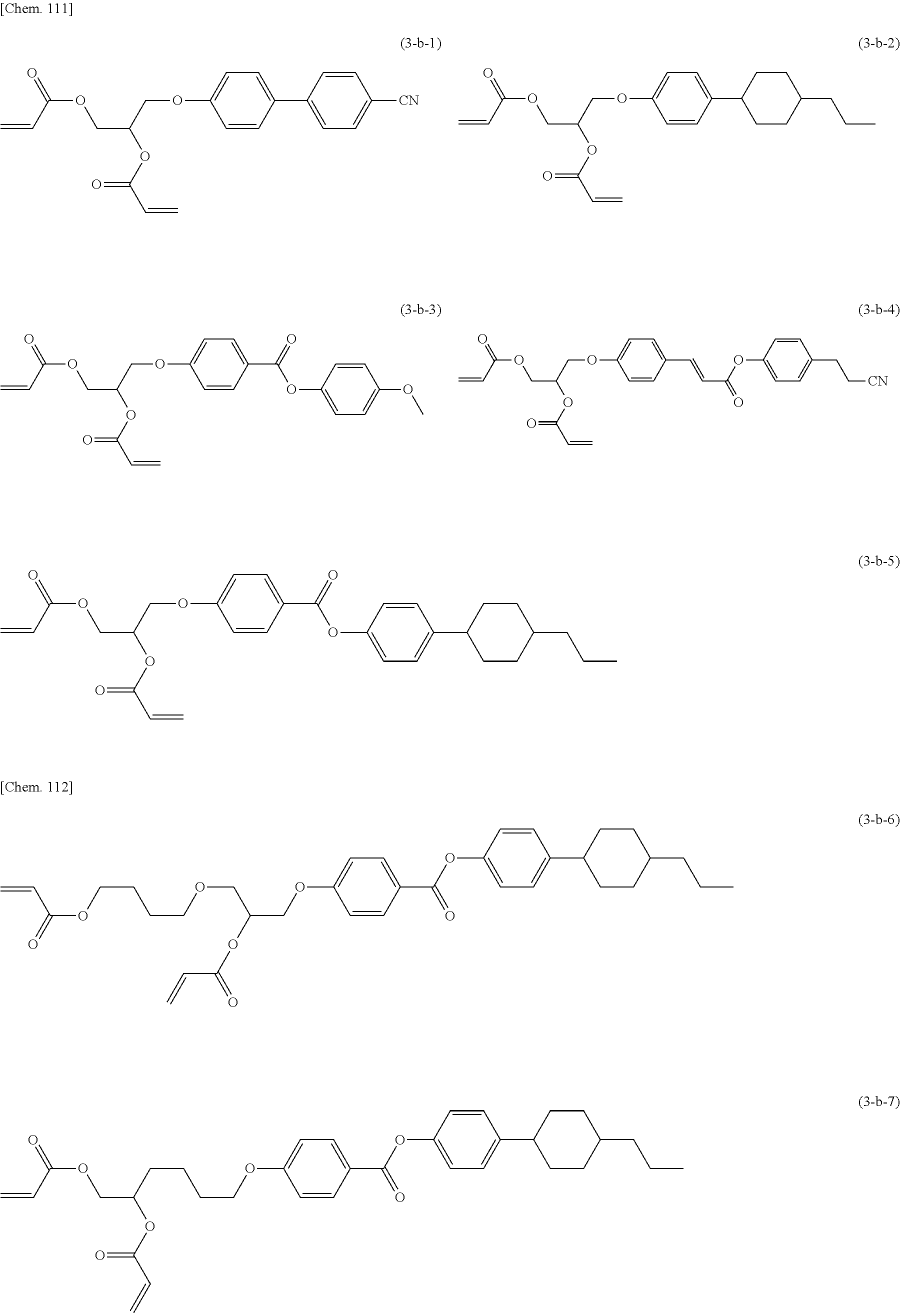

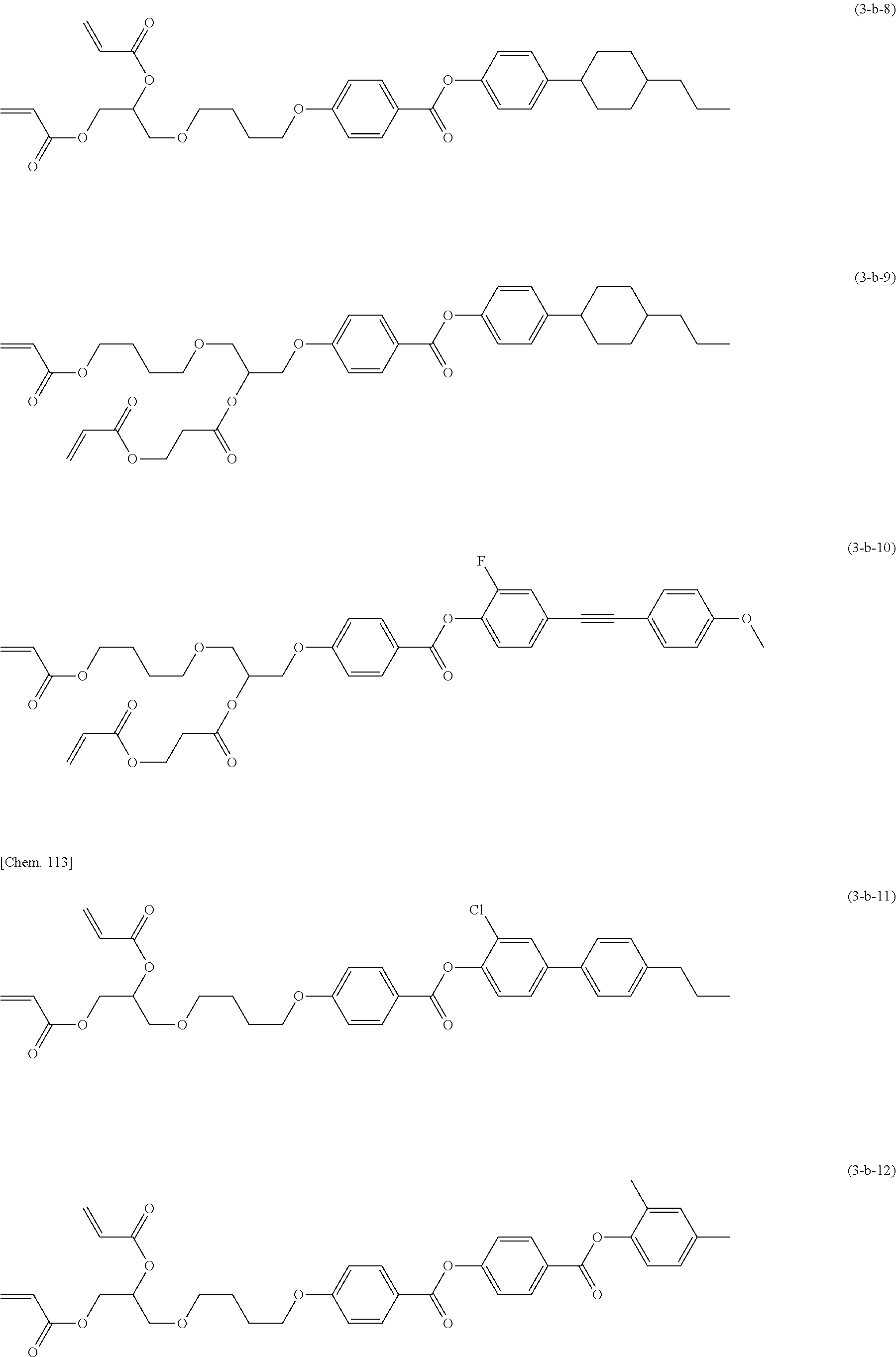

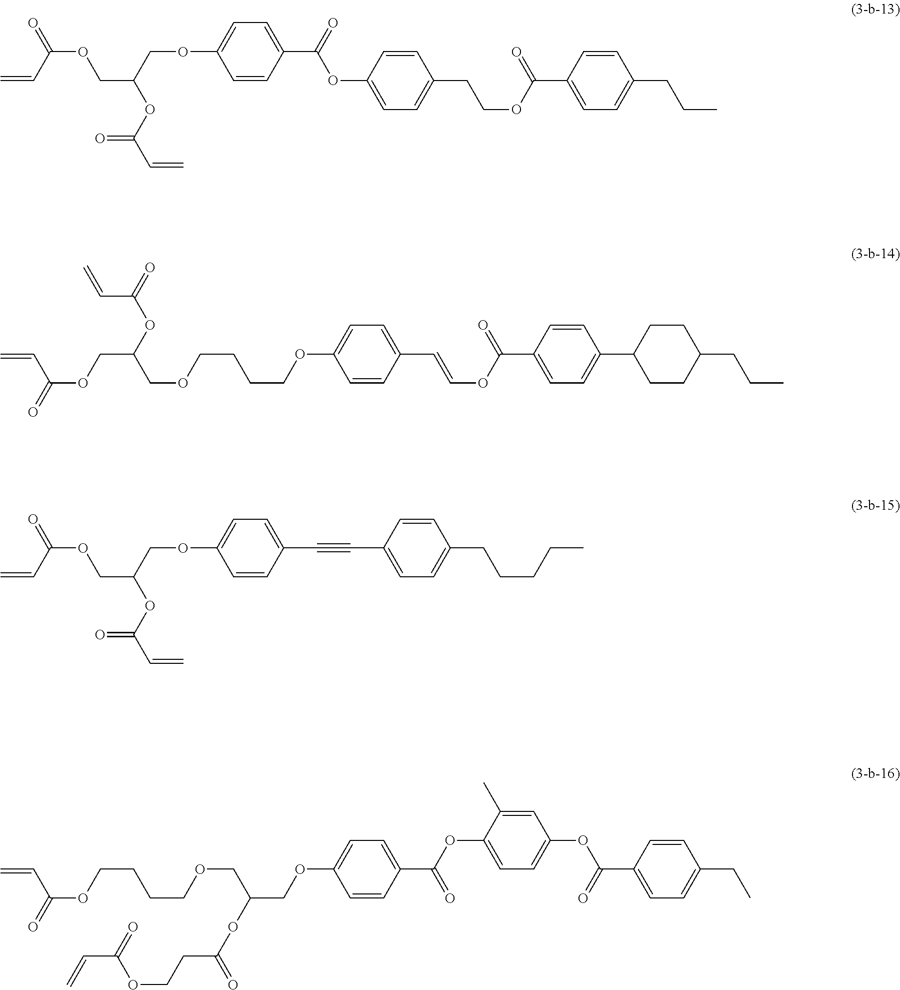

These liquid-crystal compounds may be used alone or in combination of two or more thereof.

Specific examples of the compound represented by General formula (4-b) include compounds represented by the following Formula (4-b-1) to Formula (4-b-29).

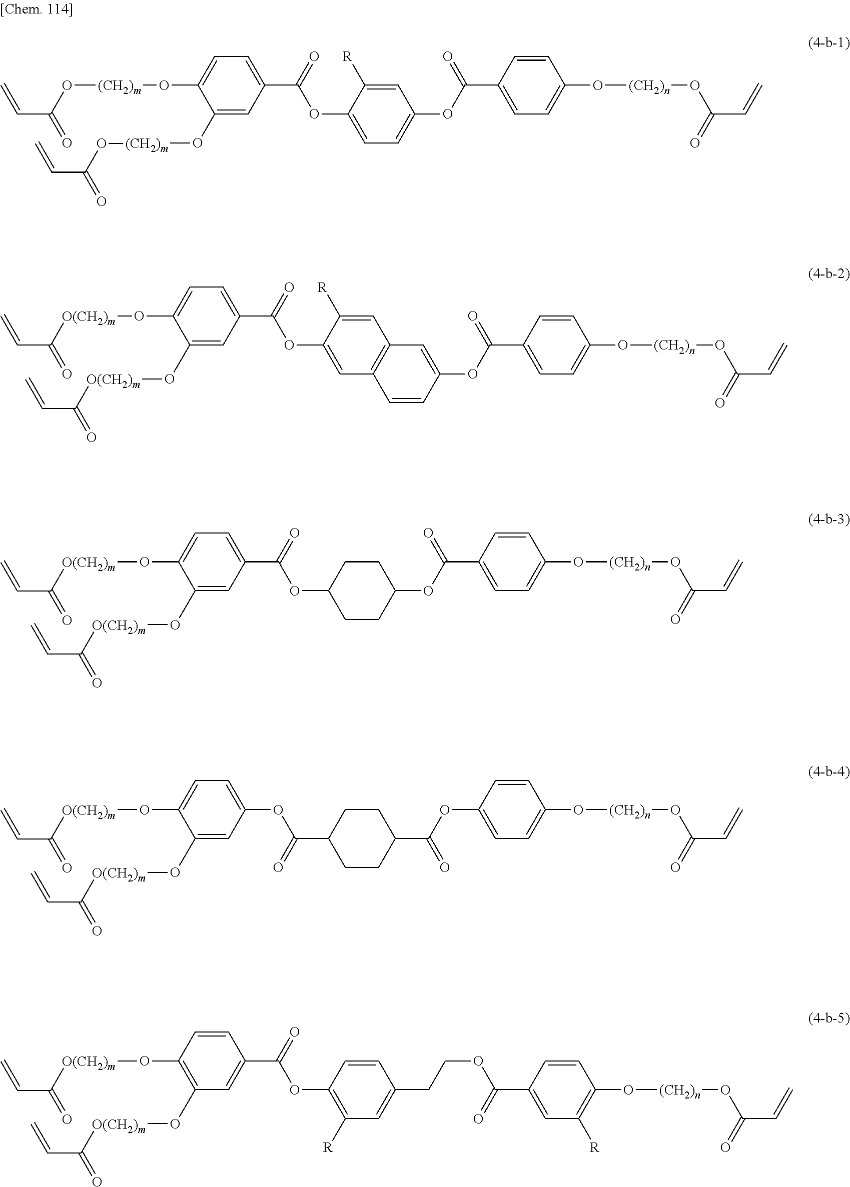

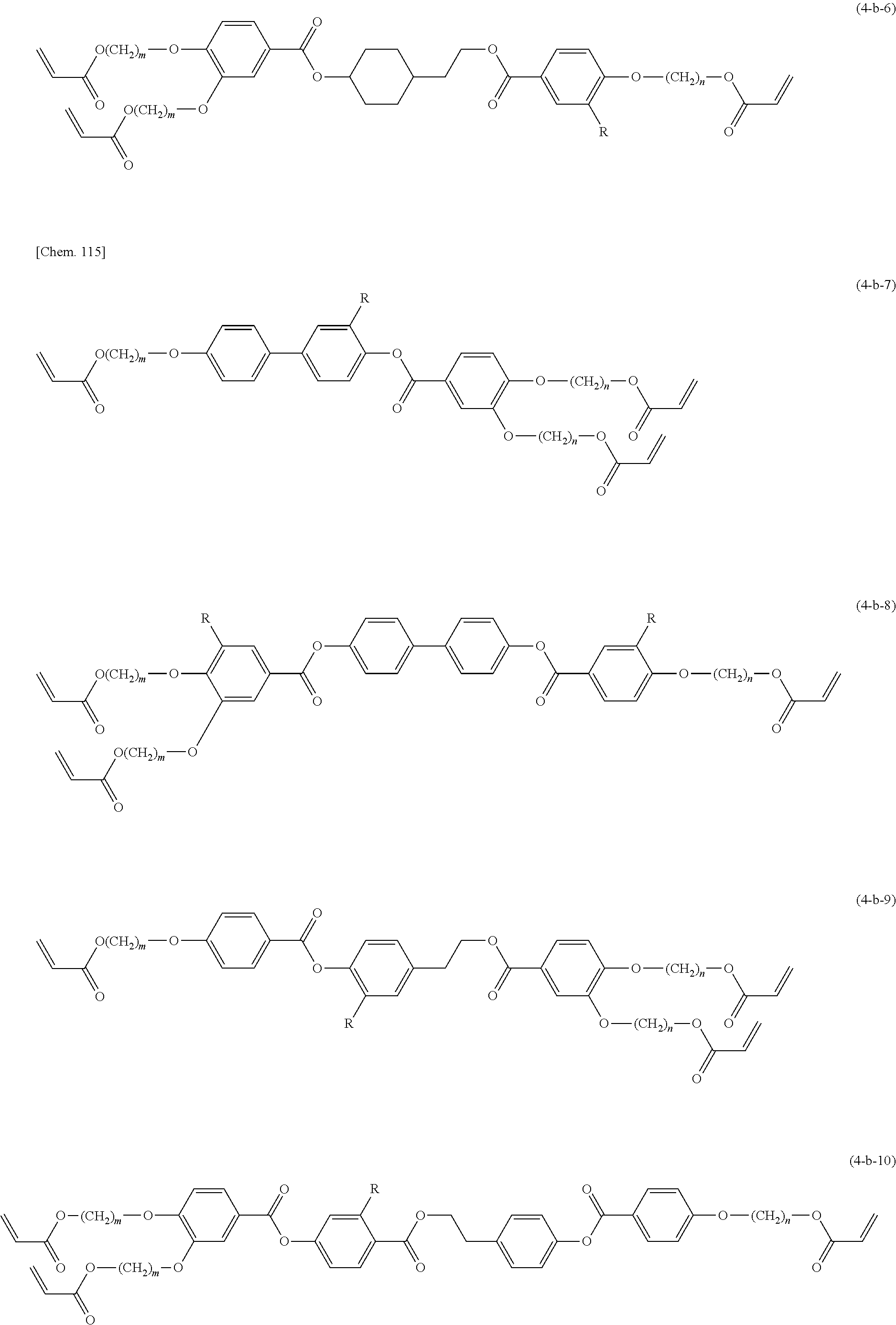

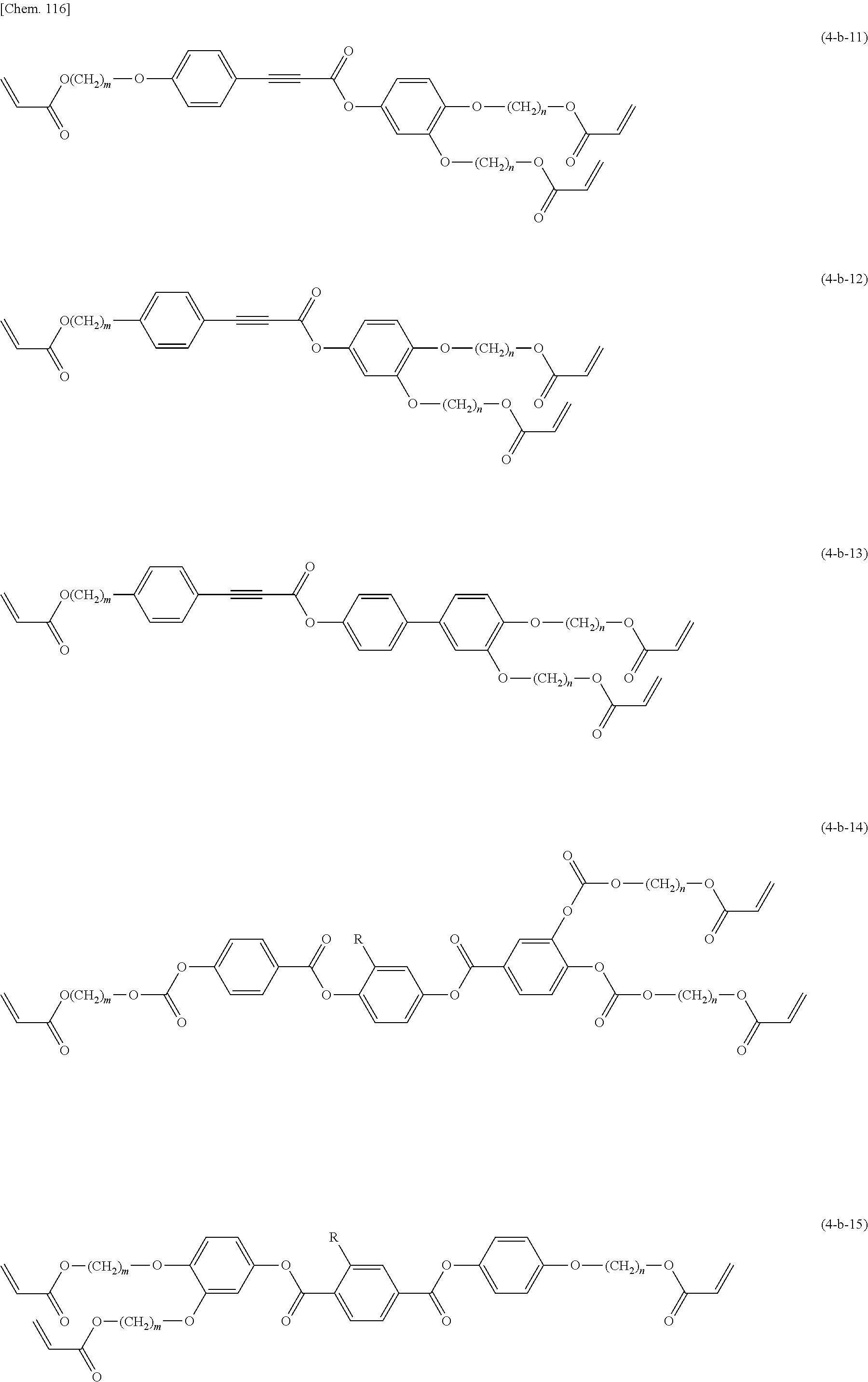

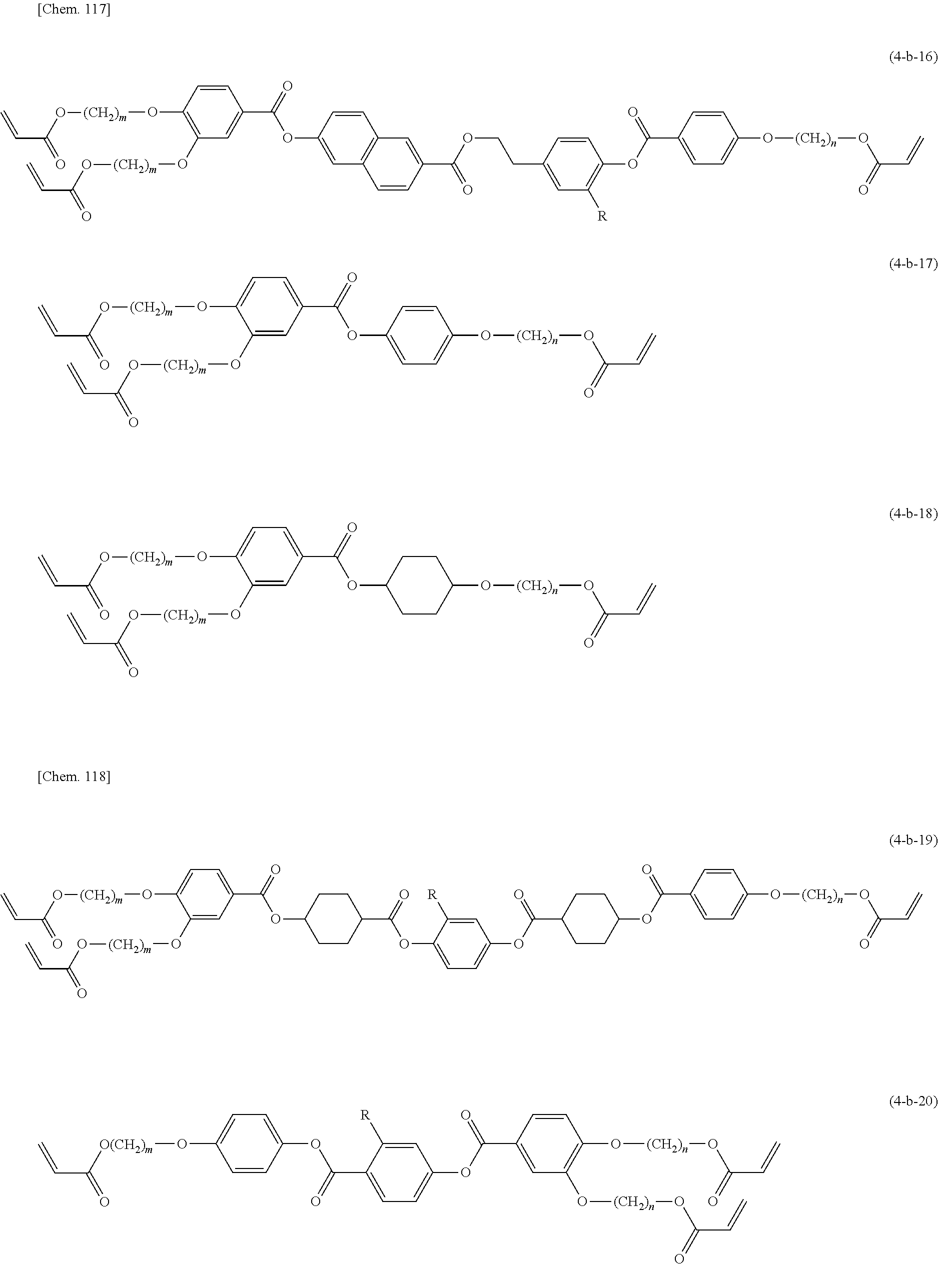

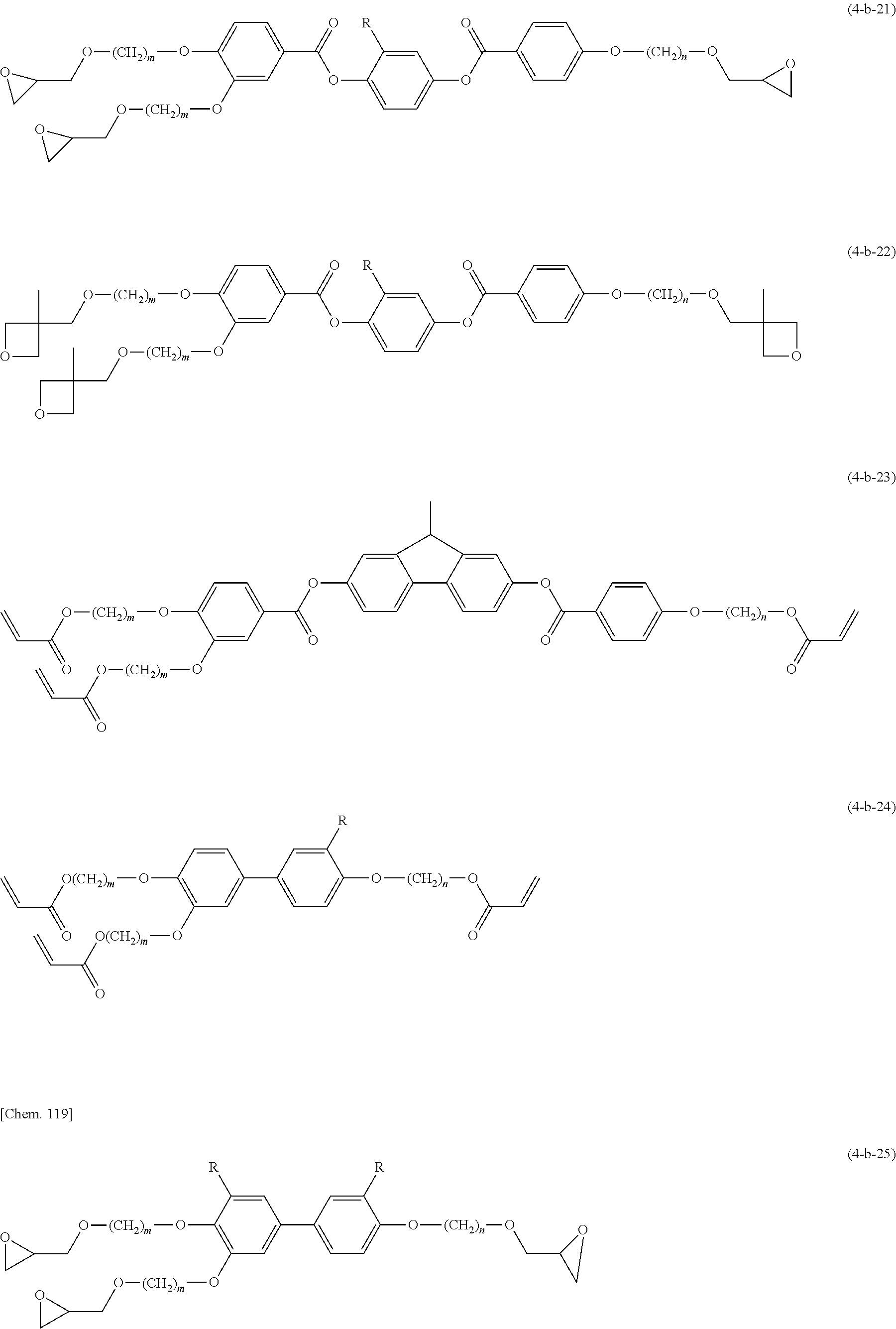

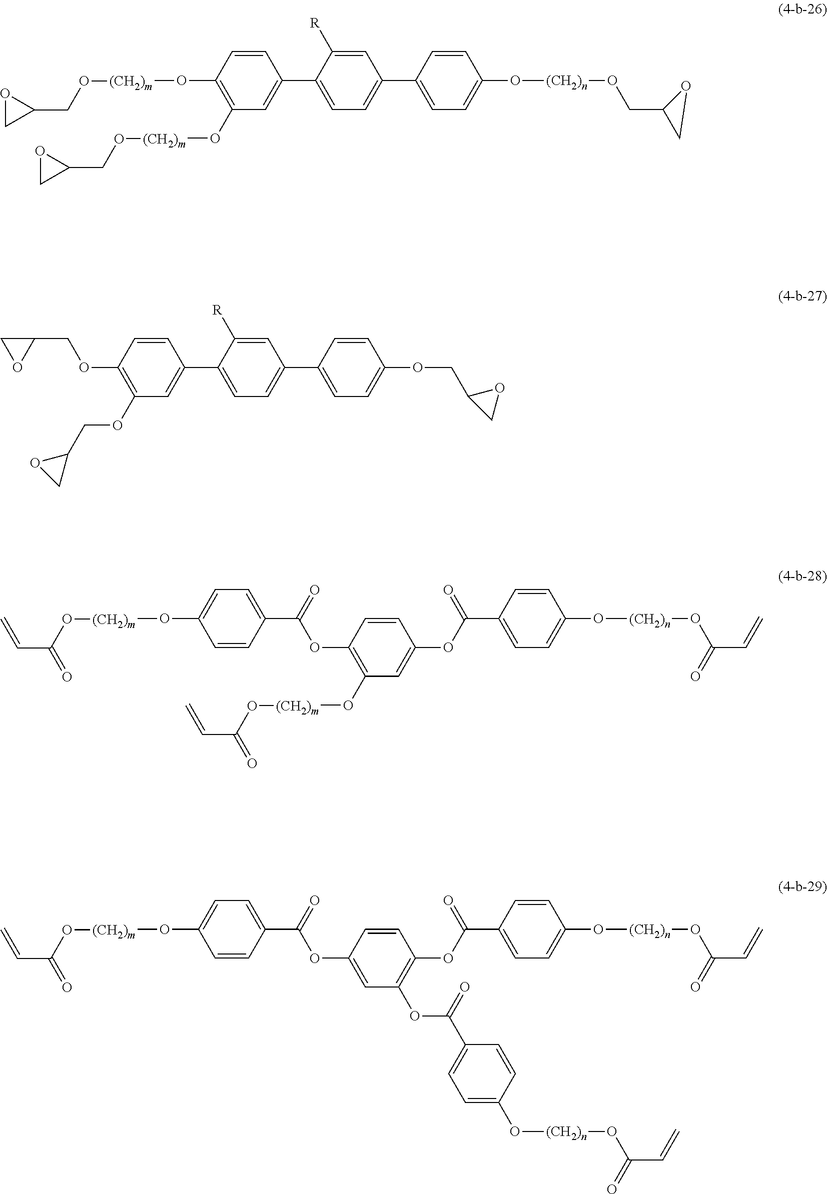

(where m and n each independently represent an integer of 1 to 10. R represents a hydrogen atom, a halogen atom, an alkyl group having 1 to 6 carbon atoms, an alkoxy group having 1 to 6 carbon atoms, or a cyano group. When such a group is an alkyl group having 1 to 6 carbon atoms or an alkoxy group having 1 to 6 carbon atoms, the group may be wholly unsubstituted or may be substituted by one or two or more halogen atoms). These liquid-crystal compounds may be used alone or in combination of two or more thereof.

Specific examples of the compound represented by General formula (5-b) include compounds represented by the following Formula (5-b-1) to Formula (5-b-26).

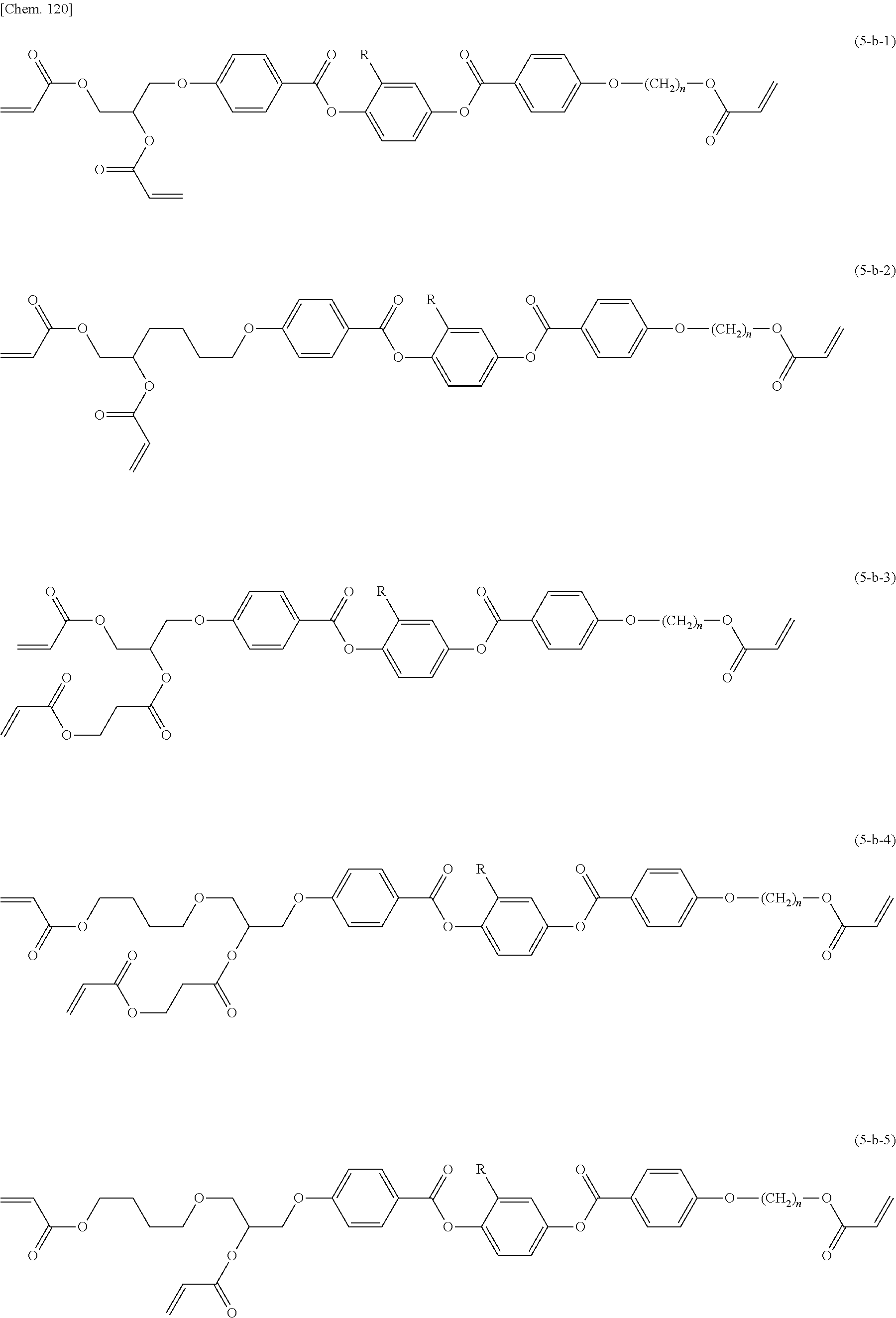

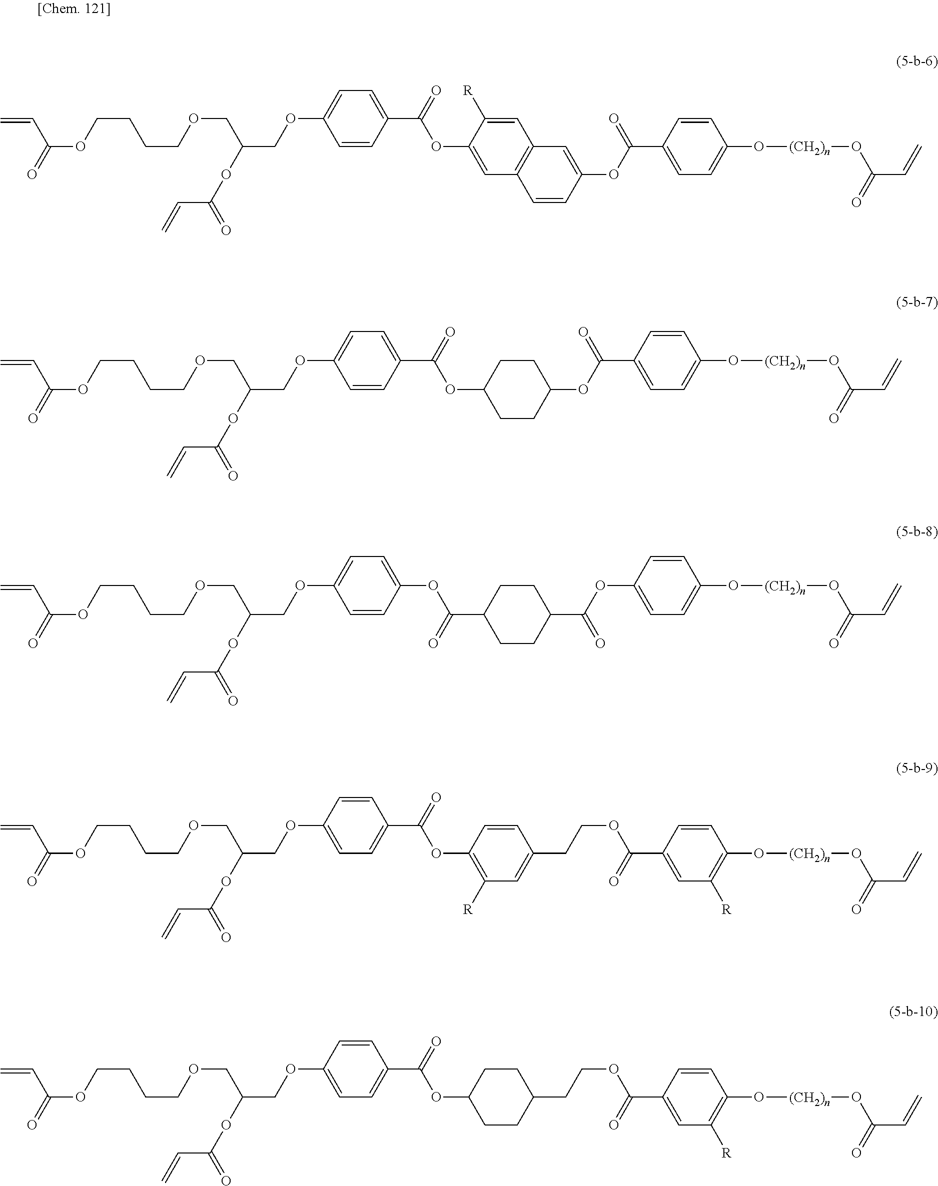

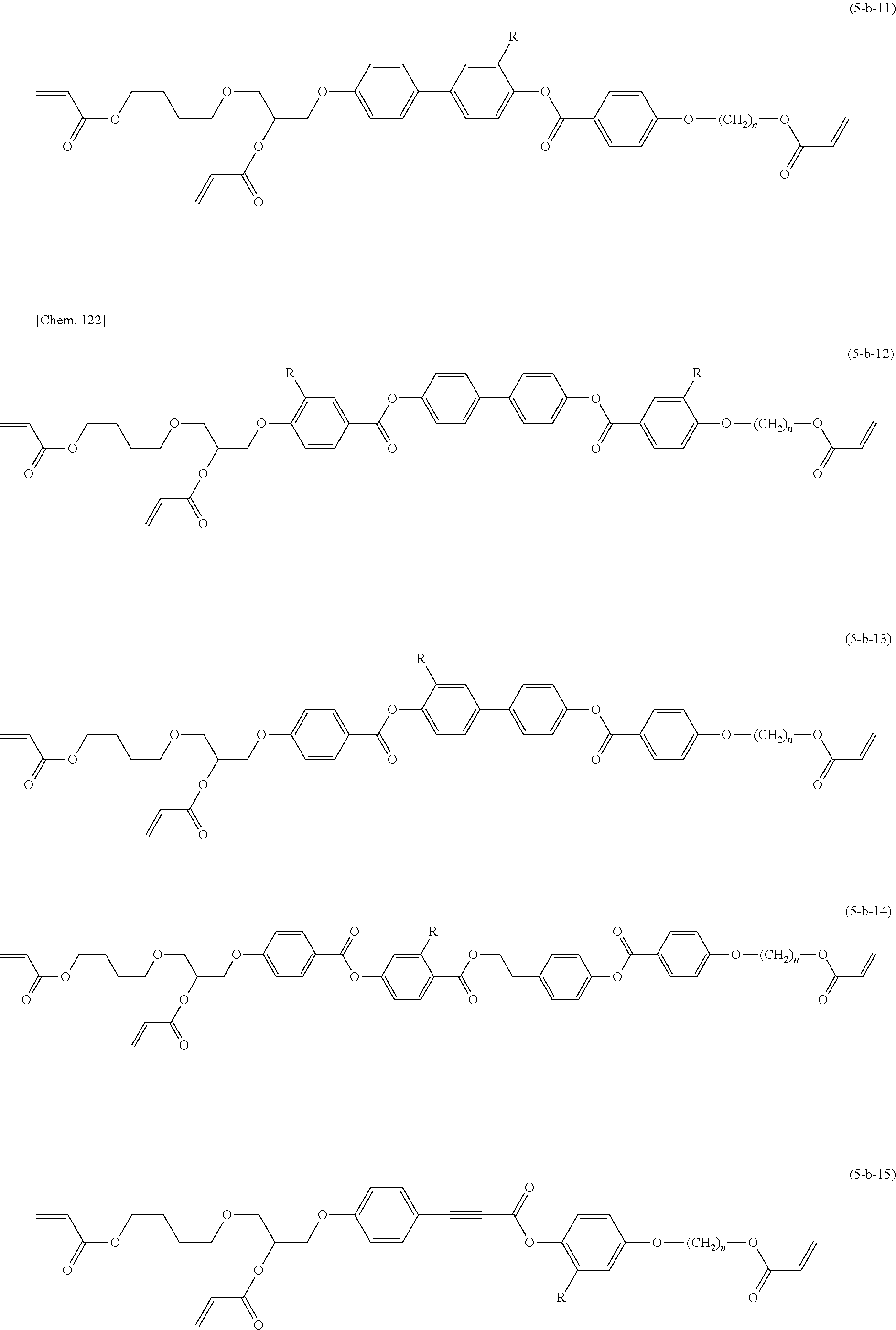

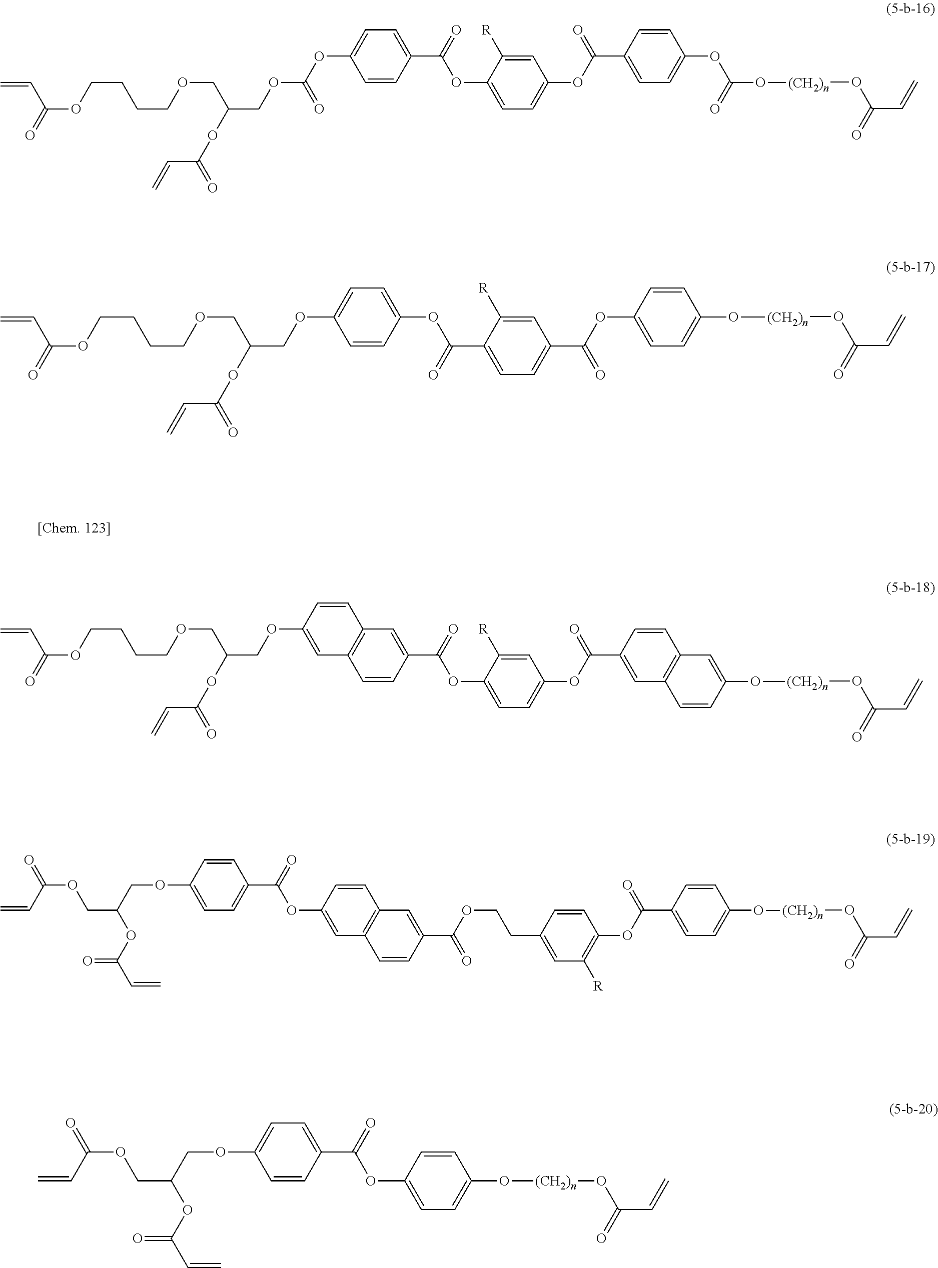

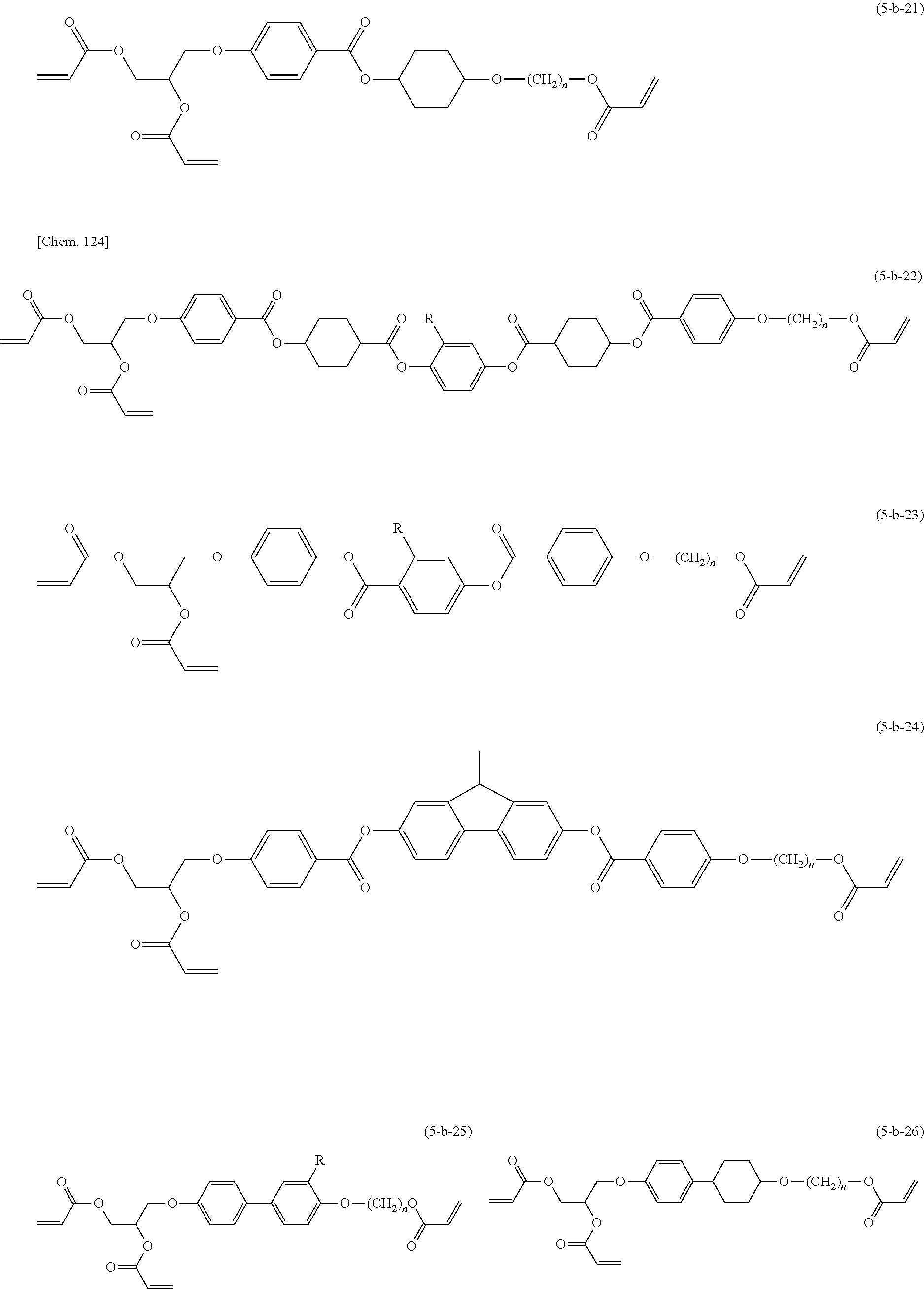

(where n's each independently represent an integer of 1 to 10. R represents a hydrogen atom, a halogen atom, an alkyl group having 1 to 6 carbon atoms, an alkoxy group having 1 to 6 carbon atoms, or a cyano group. When such a group is an alkyl group having 1 to 6 carbon atoms or an alkoxy group having 1 to 6 carbon atoms, the group may be wholly unsubstituted or may be substituted by one or two or more halogen atoms.) These liquid-crystal compounds may be used alone or in combination of two or more thereof.

Specific examples of the compound represented by General formula (6-b) include compounds represented by the following Formula (6-b-1) to Formula (6-b-23).

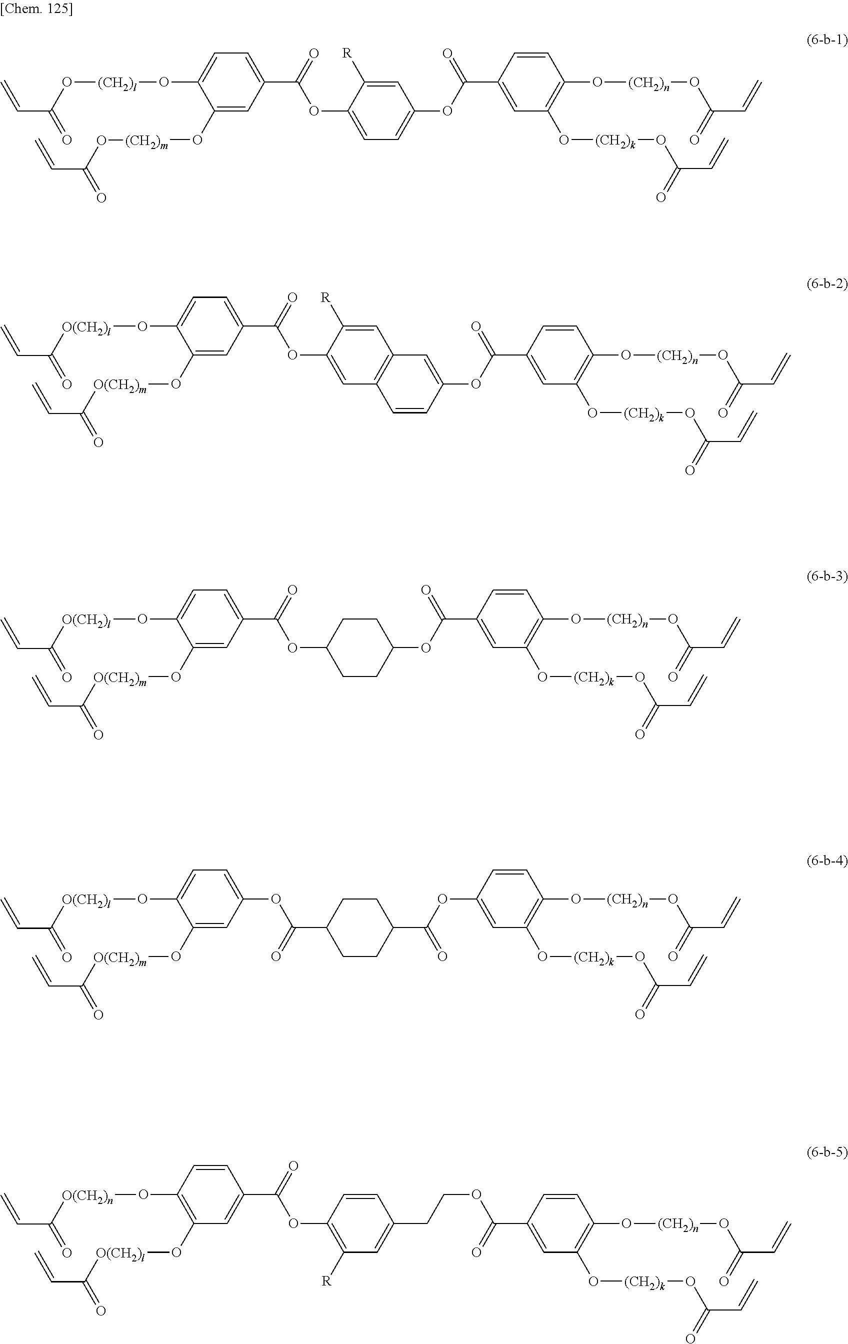

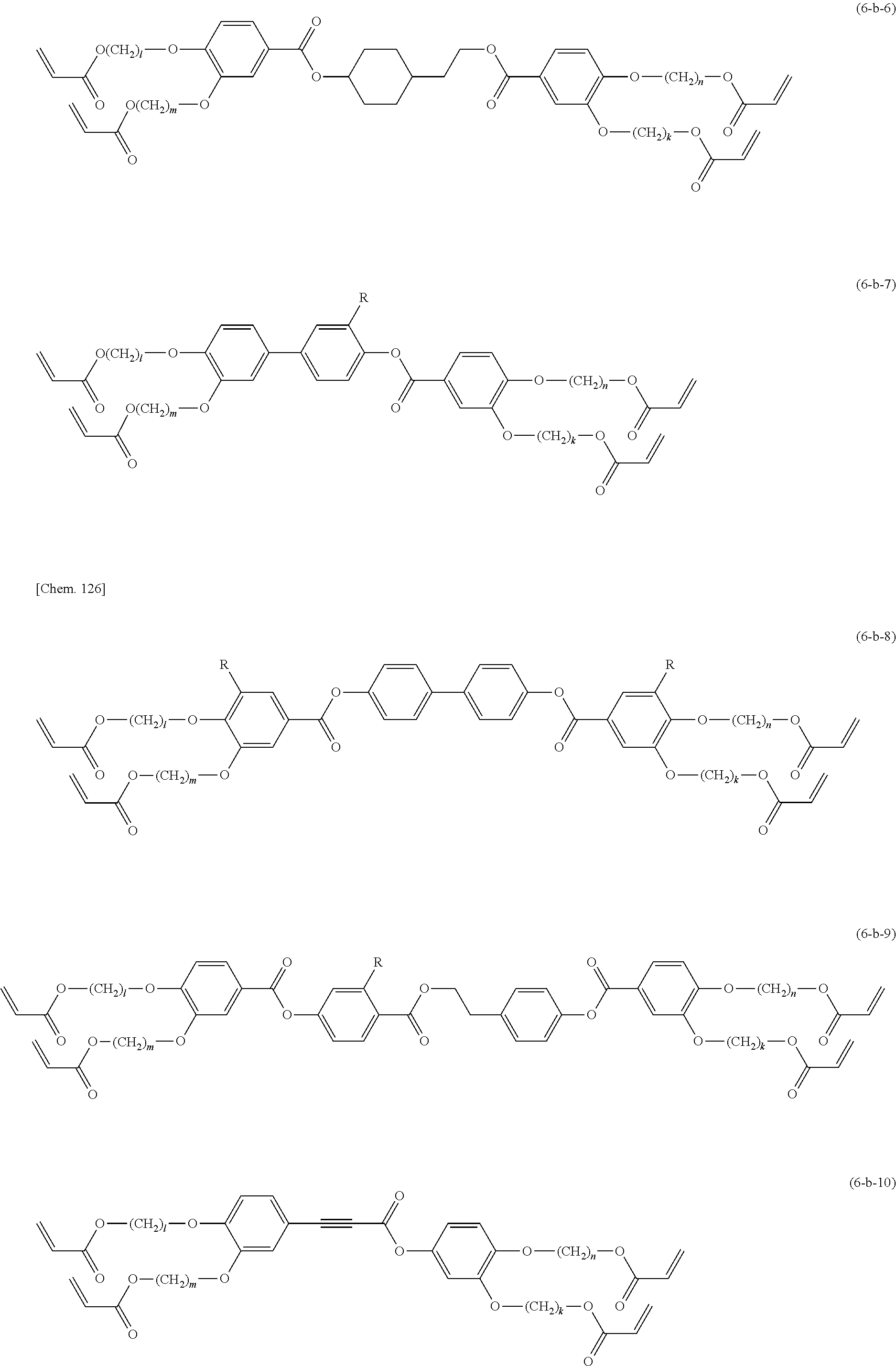

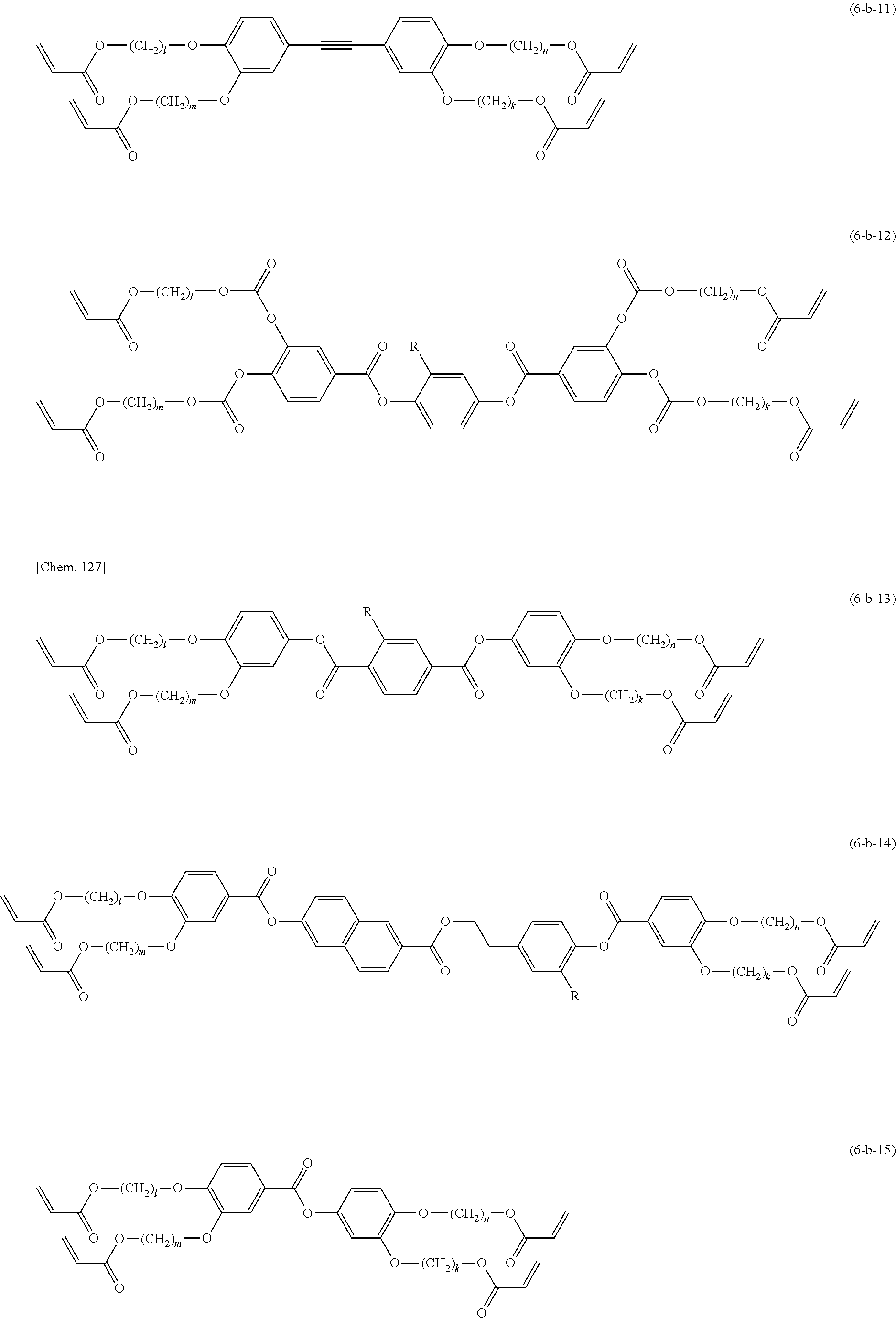

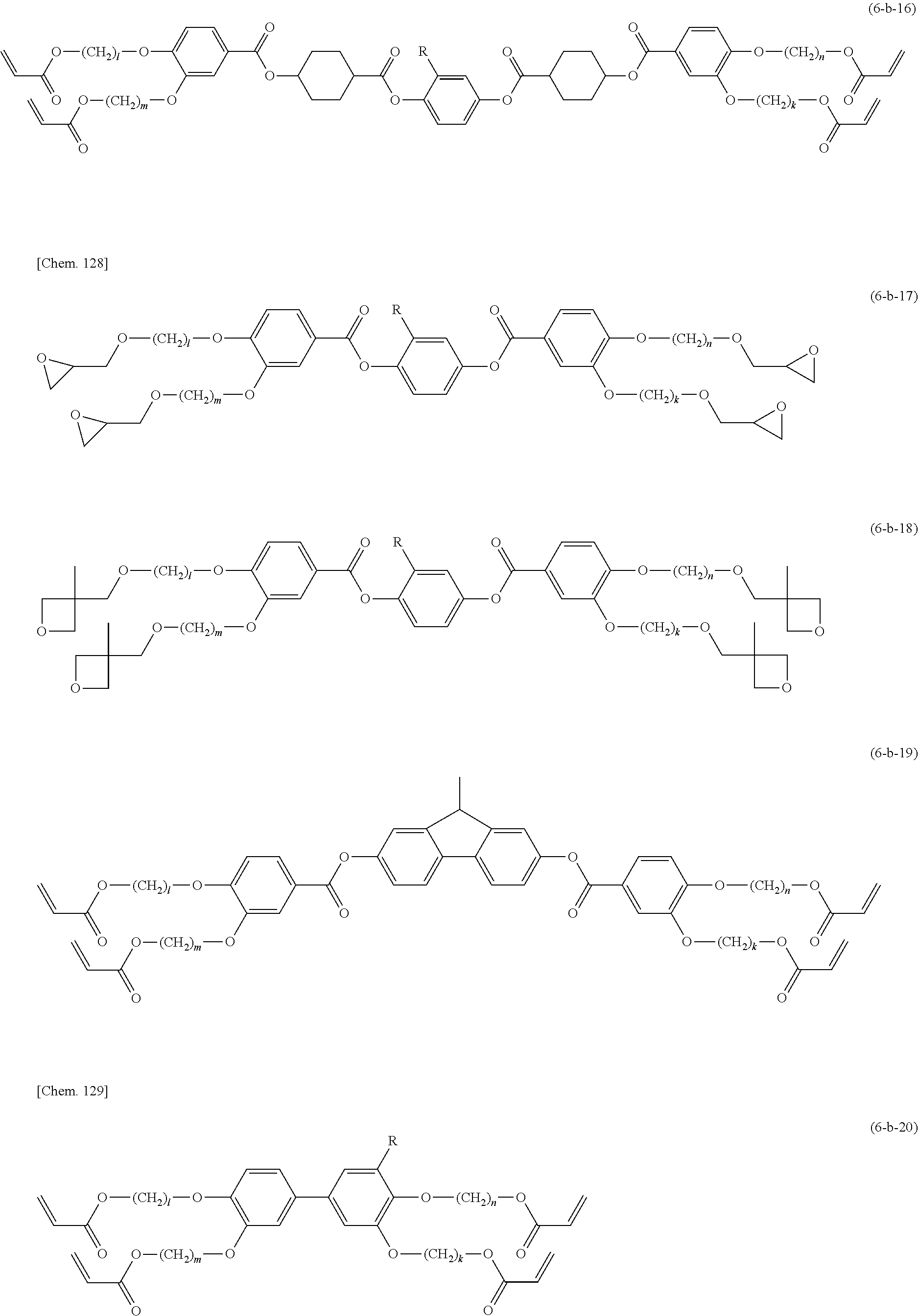

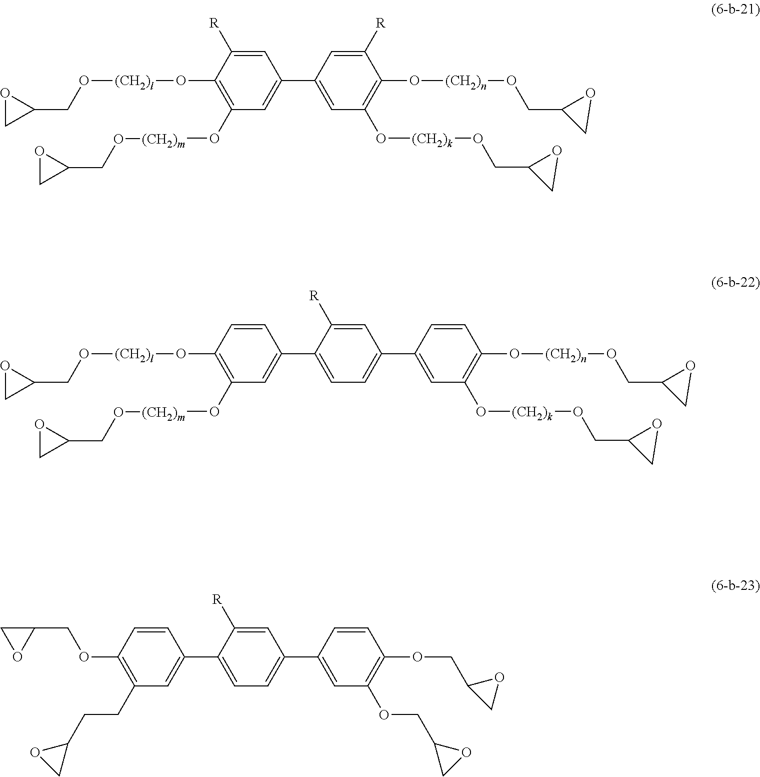

(where k, l, m, and n each independently represent an integer of 1 to 10. R represents a hydrogen atom, a halogen atom, an alkyl group having 1 to 6 carbon atoms, an alkoxy group having 1 to 6 carbon atoms, or a cyano group. When such a group is an alkyl group having 1 to 6 carbon atoms or an alkoxy group having 1 to 6 carbon atoms, the group may be wholly unsubstituted or may be substituted by one or two or more halogen atoms.) These liquid-crystal compounds may be used alone or in combination of two or more thereof.

Specific examples of the compound represented by General formula (7-b) include compounds represented by the following Formula (7-b-1) to Formula (7-b-25).

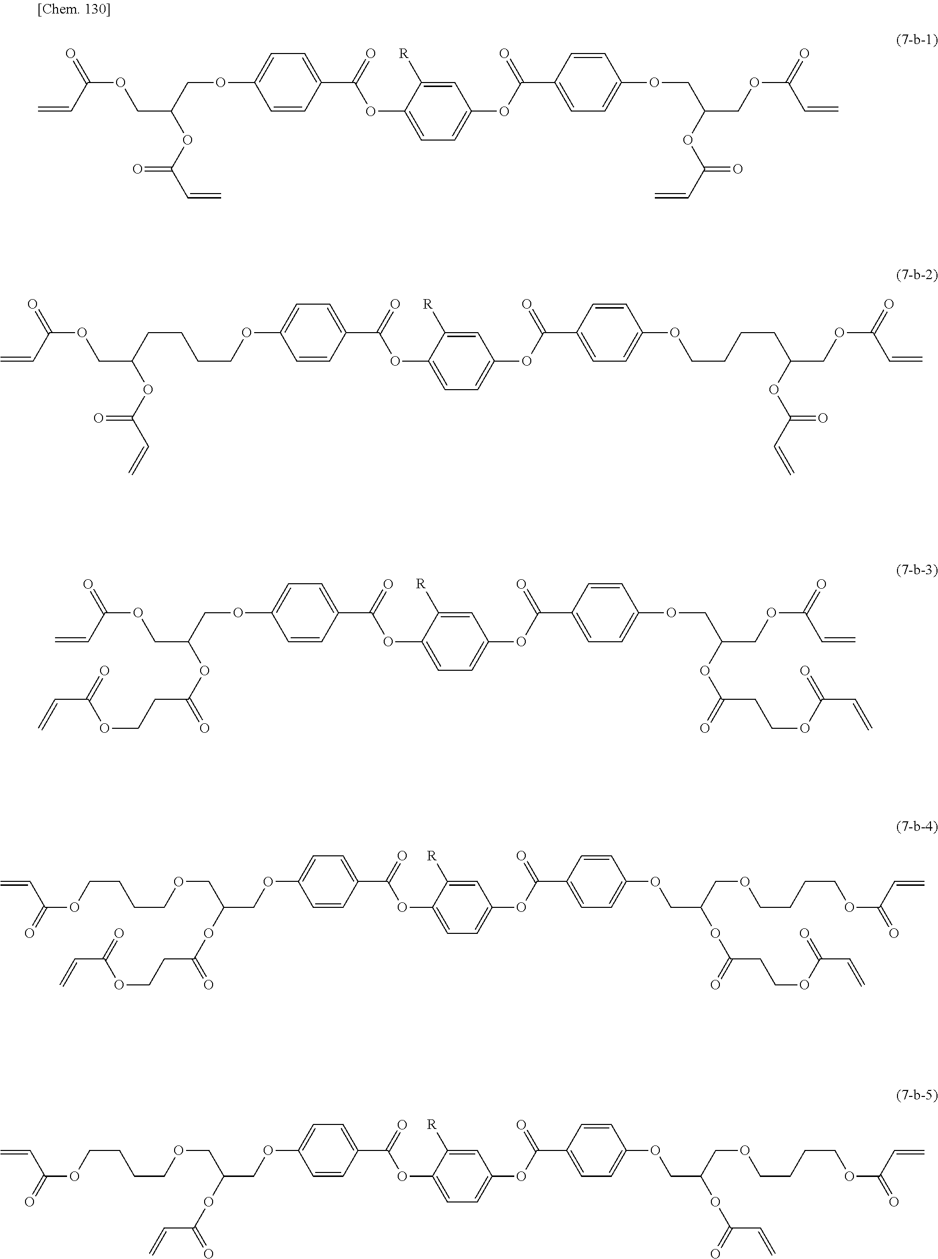

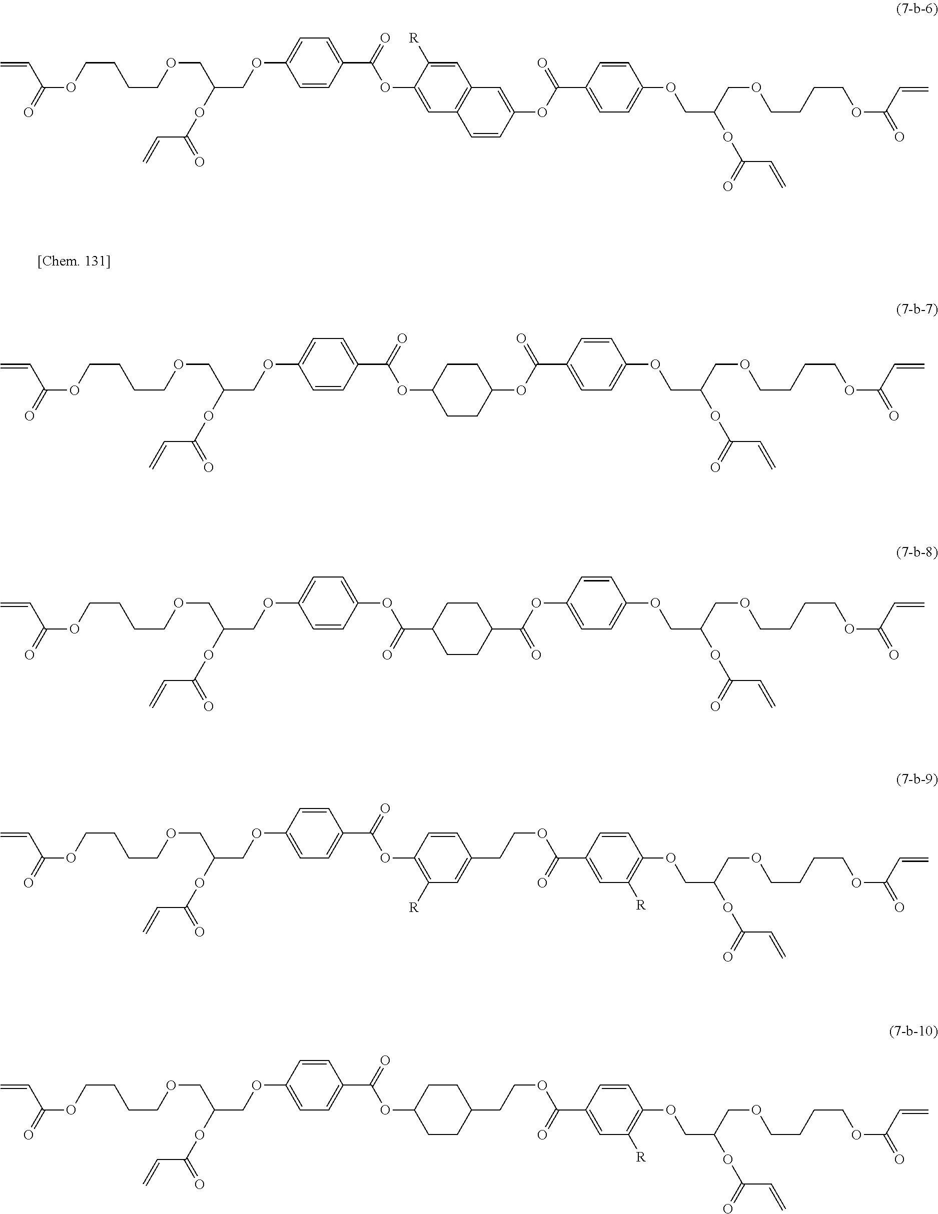

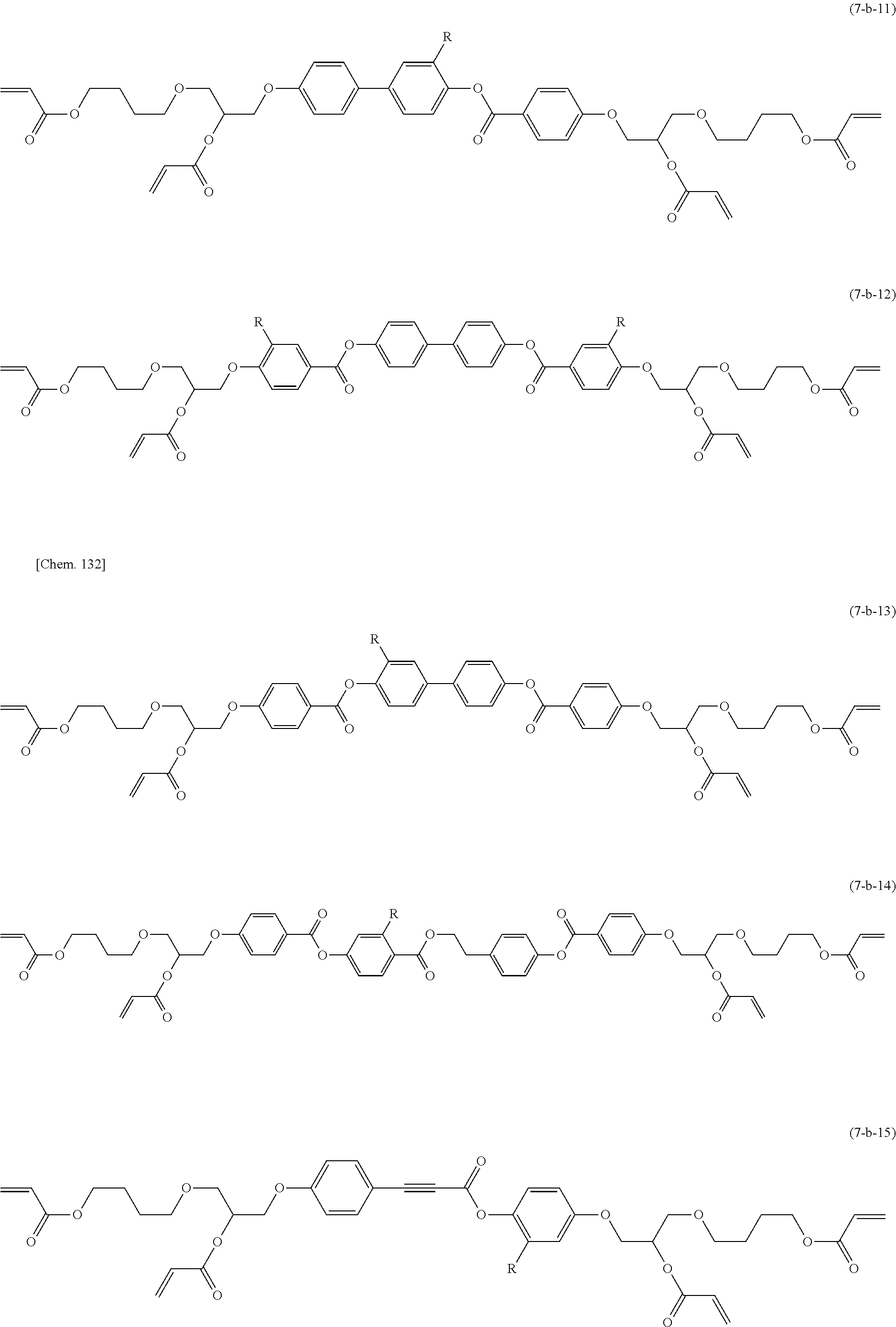

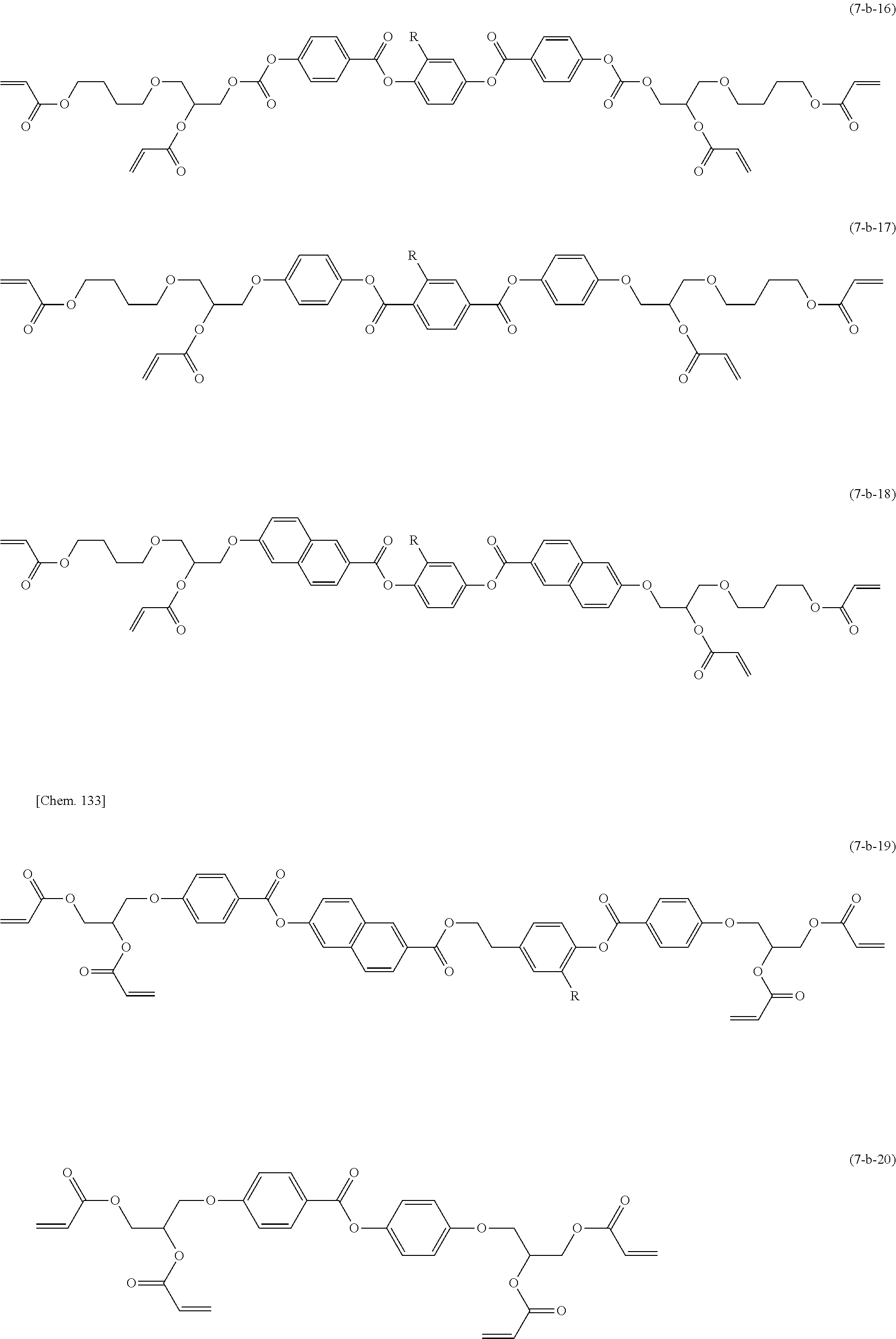

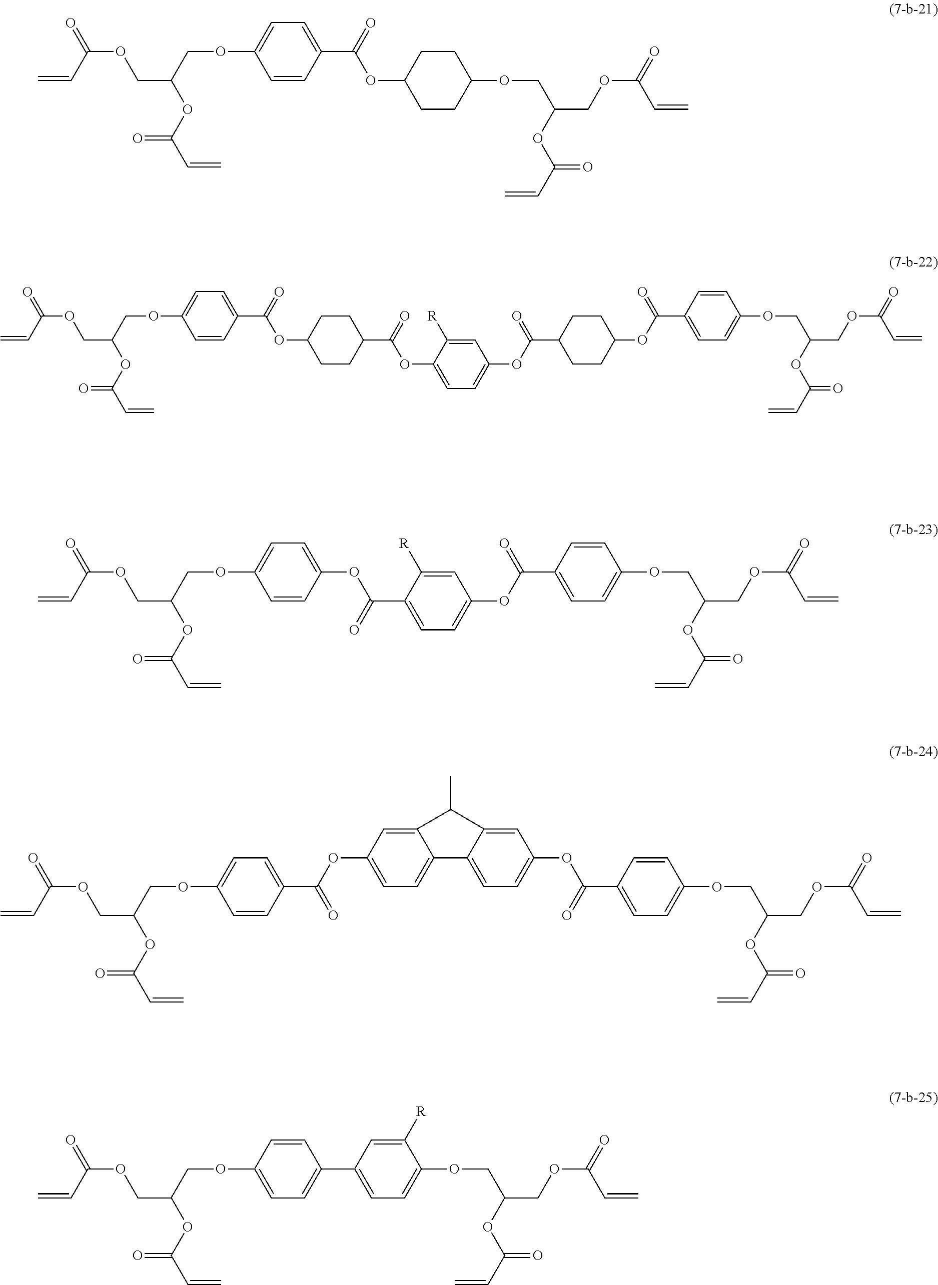

(where R represents a hydrogen atom, a halogen atom, an alkyl group having 1 to 6 carbon atoms, an alkoxy group having 1 to 6 carbon atoms, or a cyano group. When such a group is an alkyl group having 1 to 6 carbon atoms or an alkoxy group having 1 to 6 carbon atoms, the group may be wholly unsubstituted or may be substituted by one or two or more halogen atoms.) These liquid-crystal compounds may be used alone or in combination of two or more thereof.

Among General formulas (1) to (7) and General formulas (1-b) to (7-b) above, containing the compound represented by General formula (1) or General formula (1-b) stabilizes the hybrid structure, which is preferred. These compounds each have ends that have different polarities. When a polymerizable composition used in the present invention is applied to a substrate, hydrophobic groups tend to appear on the air-interface side. Thus, the compound may be added and, the type of and the amount of addition of a leveling agent, an alignment control agent, or the like described later may be appropriately selected, to thereby stabilize the alignment angle of the polymerizable liquid crystal at the air interface.

### (Chiral Compound)

A polymerizable composition used for forming a retardation film according to the present invention may contain a chiral compound in order to obtain a chiral nematic phase. The chiral compound itself may not necessarily exhibit liquid crystallinity, and may or may not have a polymerizable group. The direction of the helix of the chiral compound can be appropriately selected in accordance with the application of the polymer.

The chiral compound having a polymerizable group is not particularly limited and may be selected from publicly known and commonly used compounds; however, preferred are chiral compounds having large helical twisting power (HTP). The polymerizable group is preferably a vinyl group, a vinyloxy group, an allyl group, an allyloxy group, an acryloyloxy group, a methacryloyloxy group, a glycidyl group, or an oxetanyl group; particularly preferably an acryloyloxy group, a glycidyl group, or an oxetanyl group.

The amount of chiral compound added needs to be appropriately adjusted in accordance with the helical twisting power of the compound; the amount of chiral compound added relative to the total amount of the liquid-crystal compound having a polymerizable group and the chiral compound is preferably 0.1 to 5.0 mass %, more preferably 0.2 to 3.0 mass %, particularly preferably 0.5 to 2.0 mass %.

Specific examples of the chiral compound include compounds represented by the following General formula (10-1) to Formula (10-4); however, the compound is not limited to the following General formulas.

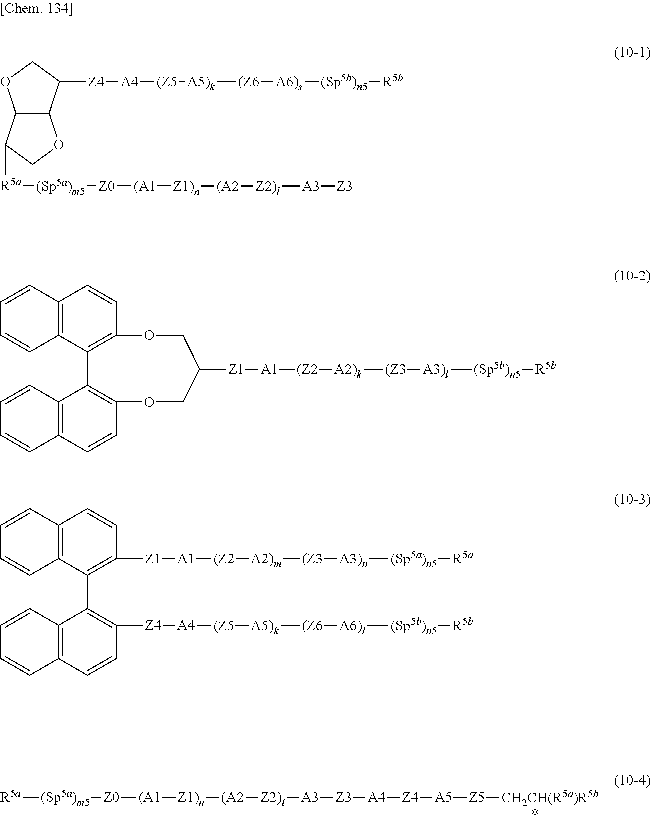

In these formulas, Sp^{5a} and Sp^{5b} each independently represent an alkylene group having 0 to 18 carbon atoms; the alkylene group may be substituted by at least one halogen atom, CN group, or alkyl group having 1 to 8 carbon atoms and a polymerizable functional group; in the group, one CH₂ group or non-adjacent two or more CH₂ groups may each be independently substituted by, so as not to form direct bonds between oxygen atoms, —O—, —S—, —NH—, —N(CH₃)—, —CO—, —COO—, —OCO—, —OCOO—, —SCO—, —COS—, or —C═C—,

A1, A2, A3, A4, A5, and A6 each independently represent a 1,4-phenylene group, a 1,4-cyclohexylene group, a 1,4-cyclohexenyl group, a tetrahydropyran-2,5-diyl group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a thiophene-2,5-diyl group-, a 1,2,3,4-tetrahydronaphthalene-2,6-diyl group, a 2,6-naphthylene group, a phenanthrene-2,7-diyl group, a 9,10-dihydrophenanthrene-2,7-diyl group, a 1,2,3,4,4a,9,10a-octahydrophenanthrene-2,7-diyl group, a 1,4-naphthylene group, a benzo[1,2-b:4,5-b′]dithiophene-2,6-diyl group, a benzo[1,2-b:4,5-b′]diselenophene-2,6-diyl group, a [1]benzothieno[3,2-b]thiophene-2,7-diyl group, a [1]benzoselenopheno[3,2-b]selenophene-2,7-diyl group, or a fluorene-2,7-diyl group; n, 1, and k each independently represent 0 or 1, and satisfy 0≤n+l+k≤3,

m5 represents 0 or 1,

Z0, Z1, Z2, Z3, Z4, Z5, and Z6 each independently represent —COO—, —OCO—, —CH₂CH₂—, —OCH₂—, —CH₂O—, —CH═CH—, —C═C—, —CH═CHCOO—, —OCOCH═CH—, —CH₂CH₂COO—, —CH₂CH₂OCO—, —COOCH₂CH₂—, —OCOCH₂CH₂—, —CONH—, —NHCO—, an alkyl group that has 2 to 10 carbon atoms and that may have a halogen atom, or a single bond,

R^{5a} and R^{5b} represent a hydrogen atom, a halogen atom, a cyano group, or an alkyl group having 1 to 18 carbon atoms; the alkyl group may be substituted by at least one halogen atom or CN; in this group, one CH₂ group or non-adjacent two or more CH₂ groups may each be independently substituted by, so as not to form direct bonds between oxygen atoms, —O—, —S—, —NH—, —N(CH₃)—, —CO—, —COO—, —OCO—, —OCOO—, —SCO—, —COS—, or —C═C—; or R^{5a} and R^{5b} are represented by General formula (10-a),

[Chem. 135]

—P^{5a} (10-a)

(where P^{5a} represents a polymerizable functional group, and Sp^{5a} is defined as with Sp¹).

P^{5a} represents a substituent selected from polymerizable groups represented by the following Formula (P-1) to Formula (P-20).

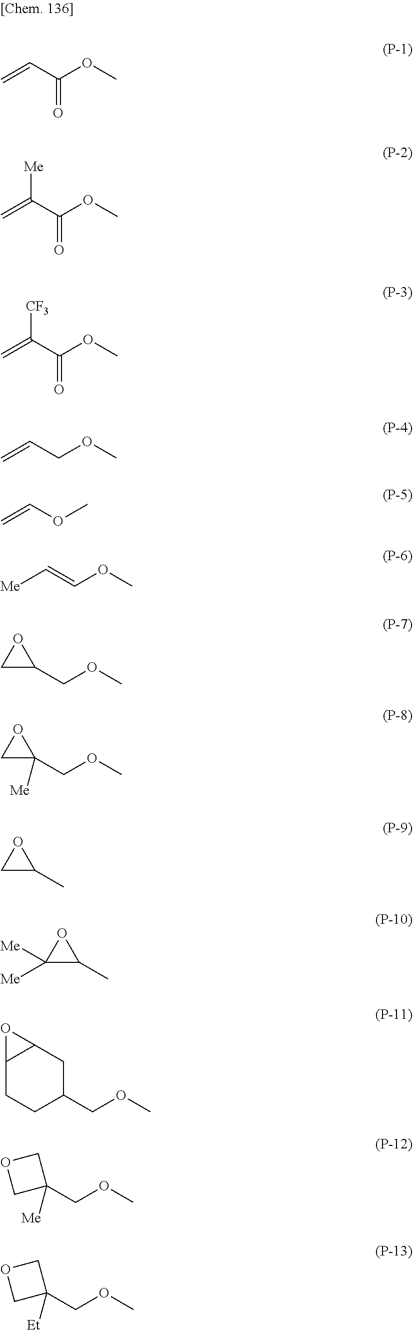

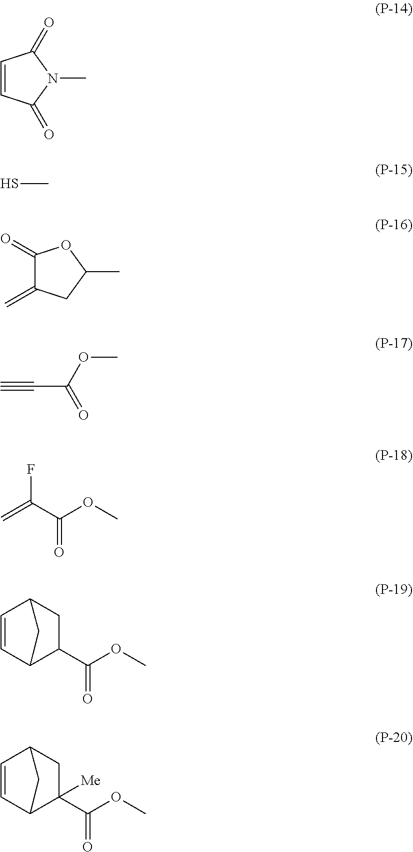

Other specific examples of the chiral compound include compounds represented by the following General formula (10-5) to Formula (10-35).

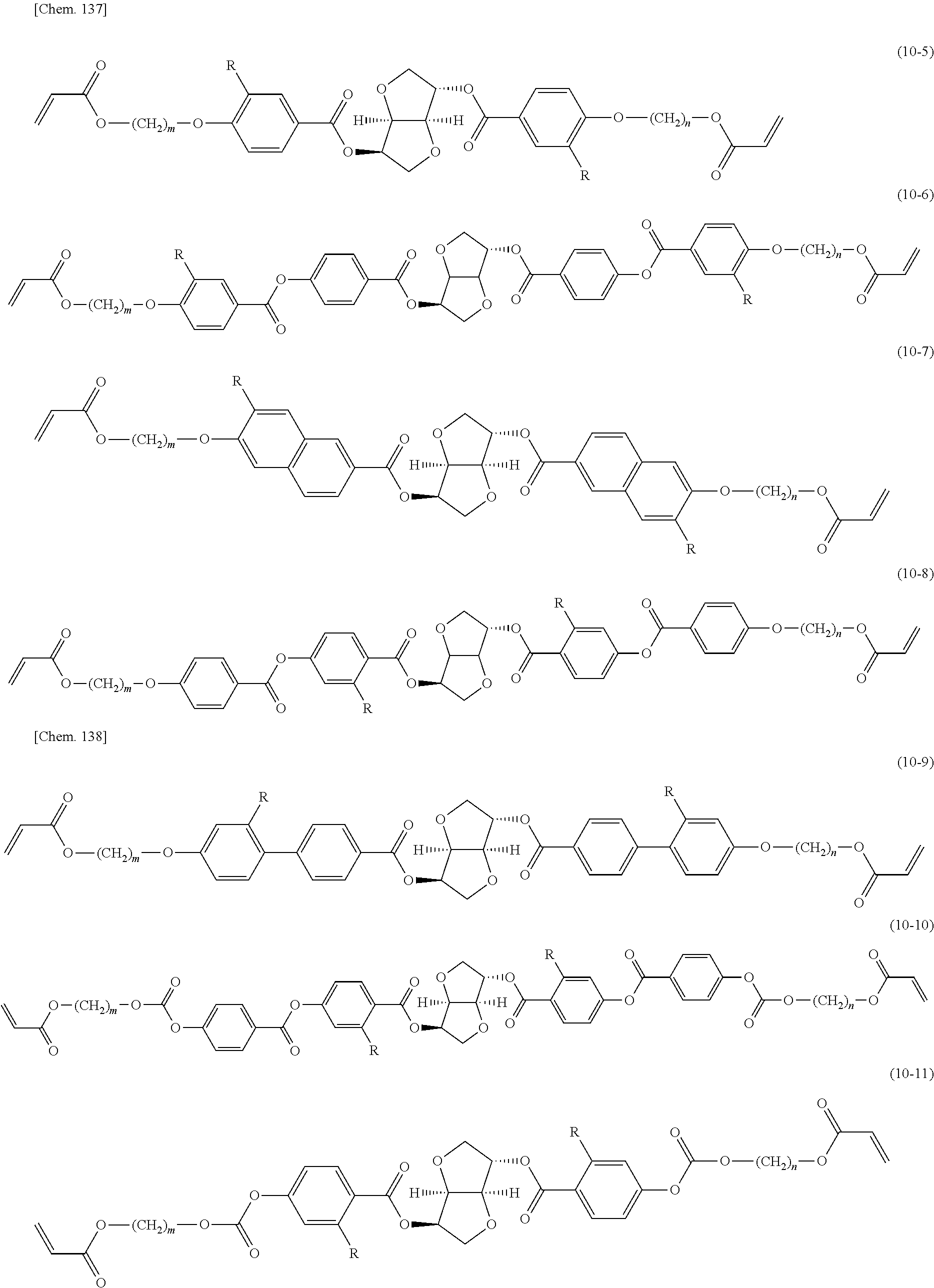

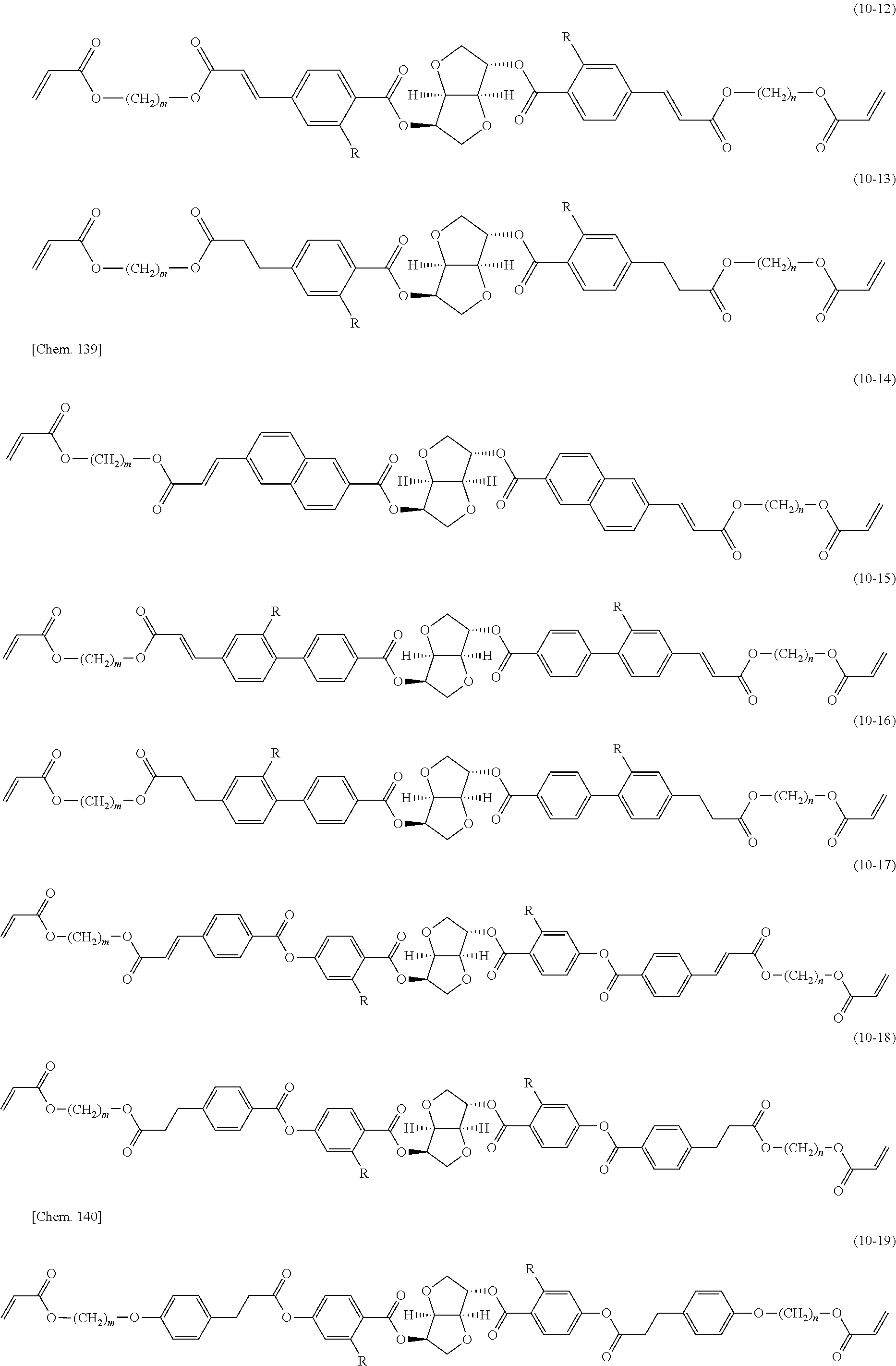

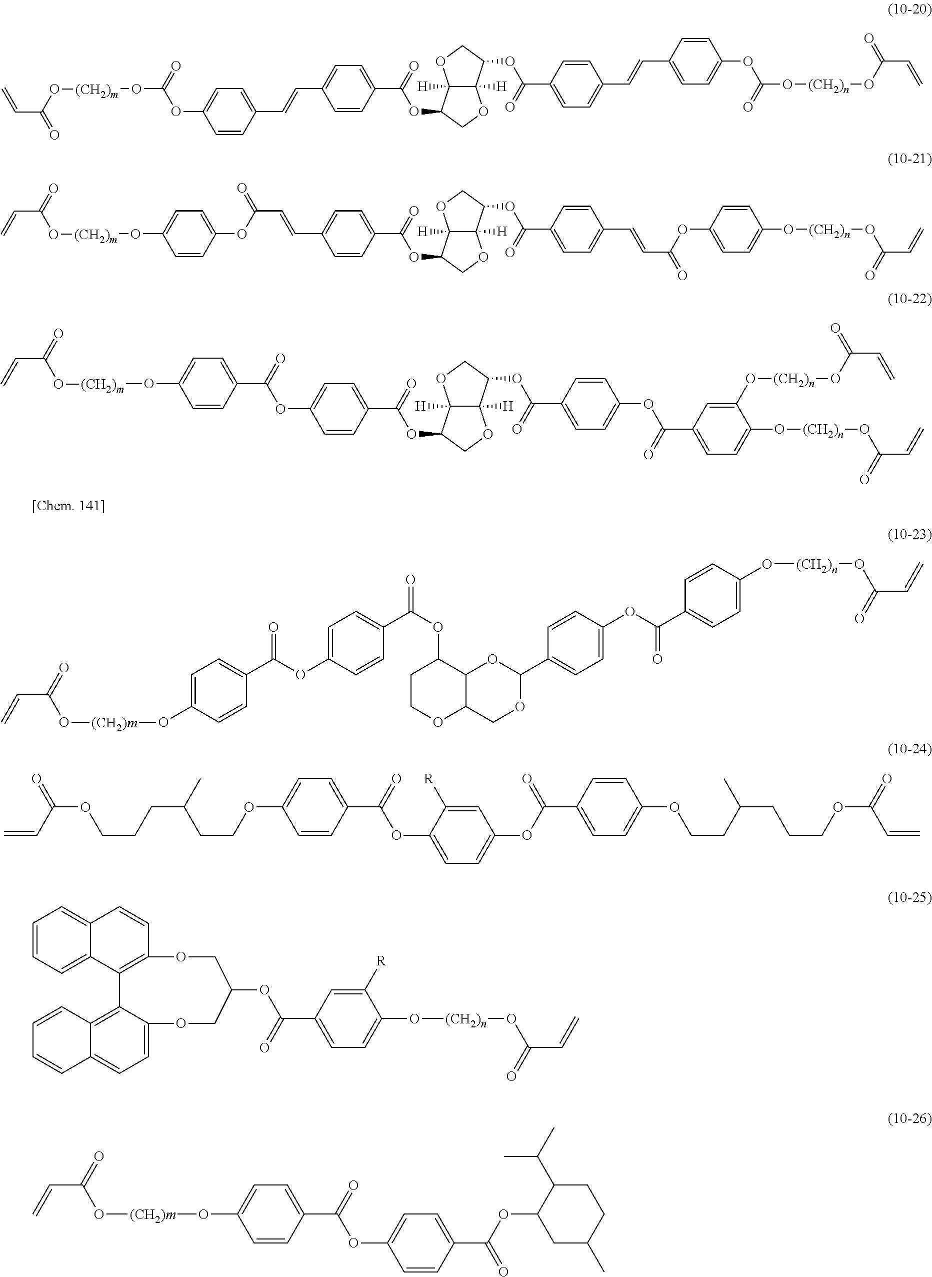

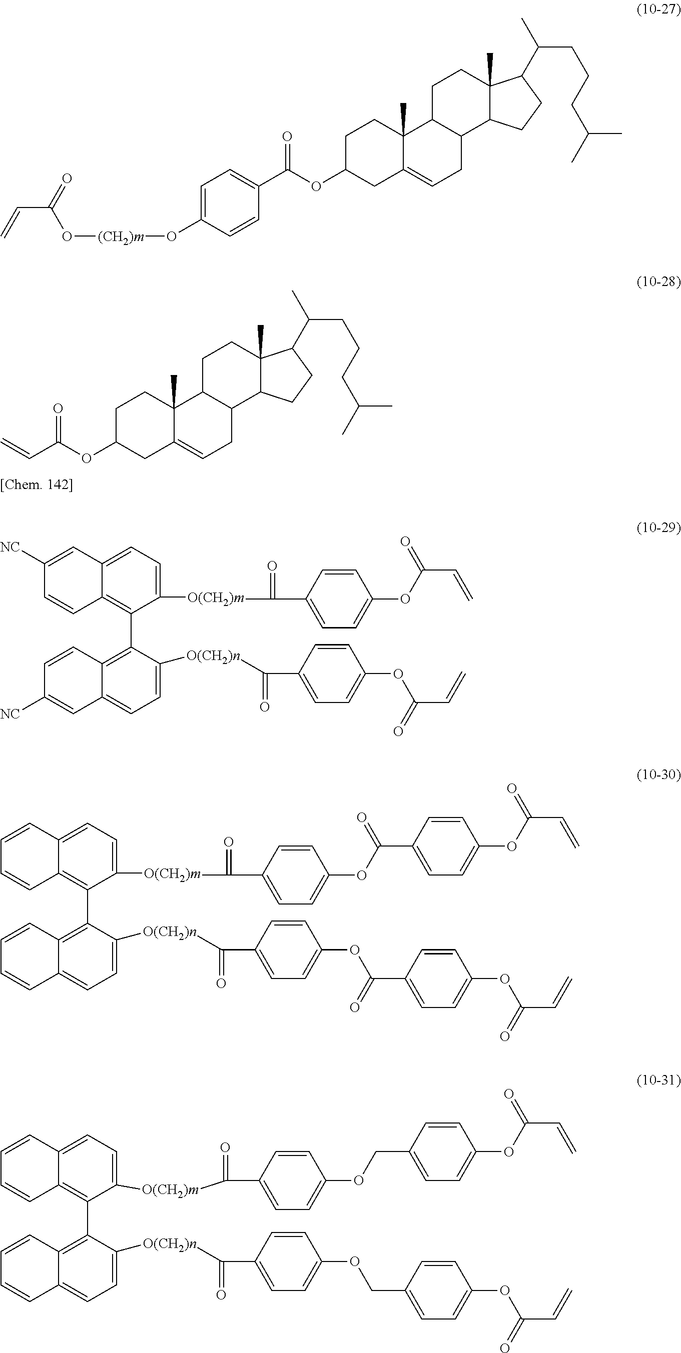

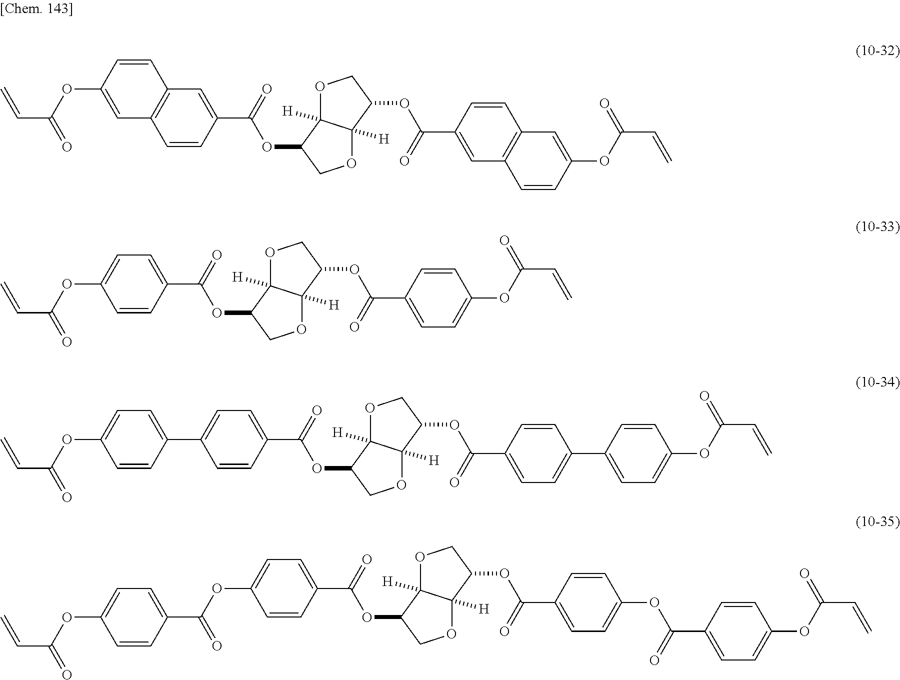

In these formulas, m and n each independently represent an integer of 1 to 10; R represents a hydrogen atom, an alkyl group having 1 to 10 carbon atoms, or a fluorine atom; when a plurality of R's are present, they may be the same or different.

Specific examples of the chiral compound not having any polymerizable group include cholesterol pelargonate having a cholesteryl group as a chiral group, cholesterol stearate, “CB-15” and “C-15” having a 2-methylbutyl group as a chiral group and manufactured by BDH Chemicals Ltd., “S-1011” and “S-1082” manufactured by Merck KGaA, “CM-19”, “CM-20”, and “CM” manufactured by Chisso Corporation, “S-811” having a 1-methylheptyl group as a chiral group and manufactured by Merck KGaA, “CM-21” and “CM-22” manufactured by Chisso Corporation.

In the case of adding such a chiral compound, its amount of addition depends on the application of the polymer of the polymerizable composition. However, the chiral compound is preferably added in an amount such that a value (d/P) calculated by dividing the thickness (d) of the polymer to be obtained by a helical pitch (P) in the polymer is in the range of 0.1 to 100, more preferably in the range of 0.1 to 20.

### (Polymerization Initiator)

A polymerizable composition used for forming a retardation film according to the present invention may optionally contain an initiator. The polymerization initiator used for the polymerizable composition is used to polymerize a polymerizable composition used in the present invention. A photopolymerization initiator used in the case of performing polymerization by photoirradiation is not particularly limited, and may be selected from publicly known and commonly used photopolymerization initiators as long as it does not inhibit the alignment state of the polymerizable compound in the polymerizable composition.

Examples include 1-hydroxycyclohexyl phenyl ketone “IRGACURE 184”, 1-(4-isopropylphenyl)-2-hydroxy-2-methylpropan-1-one “DAROCUR 1116”, 2-methyl-1-[(methylthio)phenyl]-2-morpholinopropane-1 “IRGACURE 907”, 2,2-dimethoxy-1,2-diphenylethan-1-one “IRGACURE 651”, 2-benzyl-2-dimethylamino-1-(4-morpholinophenyl)-butanone “IRGACURE 369”), 2-dimethylamino-2-(4-methylbenzyl)-1-(4-morpholino-phenyl)butan-1-one “IRGACURE 379”, 2,2-dimethoxy-1,2-diphenylethan-1-one, bis(2,4,6-trimethylbenzoyl)-diphenylphosphine oxide “Lucirin TPO”, 2,4,6-trimethylbenzoyl-phenyl-phosphine oxide “IRGACURE 819”, 1,2-octanedione, 1-[4-(phenylthio)-,2-(O-benzoyloxime)], ethanone “IRGACURE OXE01”), 1-[9-ethyl-6-(2-methylbenzoyl)-9H-carbazol-3-yl]-, 1-(O-acetyloxime) “IRGACURE OXE02” (all manufactured by BASF; a mixture of 2,4-diethylthioxanthone (“KAYACURE DETX” manufactured by Nippon Kayaku Co., Ltd.) and ethyl p-dimethylaminobenzoate (“KAYACURE EPA¹¹ manufactured by Nippon Kayaku Co., Ltd.); a mixture of isopropyl thioxanthone (“Quantacure-ITX” manufactured by Ward Blenkinsop & Company Limited) and ethyl p-dimethylaminobenzoate; “ESACURE ONE”, “ESACURE KIP150”, “ESACURE KIP160”, “ESACURE 1001M”, “ESACURE A198”, “ESACURE KIP IT”, “ESACURE KT046”, “ESACURE TZT” (manufactured by Lamberti S.p.A.), “SpeedCure BMS”, “SpeedCure PBZ”, and “benzophenone” manufactured by Lambson Limited. A cationic photoinitiator may be a photoacid generator. Examples of the photoacid generator include diazodisulfonic-based compounds, triphenylsulfonium-based compounds, phenylsulfonic-based compounds, sulfonylpyridine-based compounds, triazine-based compounds, and diphenyliodonium compounds.

The photopolymerization initiator content relative to the total amount of polymerizable compound contained in the polymerizable composition is preferably 0.1 to 10 mass %, particularly preferably 1 to 6 mass %. Such initiators may be used alone or in combination of two or more thereof.

A thermal polymerization initiator used in the case of thermal polymerization may be selected from publicly known and commonly used thermal polymerization initiators. Examples include organic peroxides such as methylacetoacetate peroxide, cumene hydroperoxide, benzoyl peroxide, bis(4-t-butylcyclohexyl)peroxy dicarbonate, t-butylperoxy benzoate, methyl ethyl ketone peroxide, 1,1-bis(t-hexylperoxy)3,3,5-trimethylcyclohexane, p-penta hydroperoxide, t-butyl hydroperoxide, dicumyl peroxide, isobutyl peroxide, di(3-methyl-3-methoxybutyl)peroxy dicarbonate, and 1,1-bis(t-butylperoxy)cyclohexane; azonitrile compounds such as 2,2′-azobisisobutyronitrile and 2,2′-azobis(2,4-dimethylvaleronitrile); azoamidine compounds such as 2,2′-azobis (2-methyl-N-phenylpropione-amidine)dihydrochloride; azoamide compounds such as 2,2′azobis{2-methyl-N-[1,1-bis(hydroxymethyl)-2-hydroxyethyl]propionamide}; and alkylazo compounds such as 2,2′azobis (2,4,4-trimethylpentane). The content of the thermal polymerization initiator is preferably 0.1 to 10 mass %, particularly preferably 1 to 6 mass %. Such initiators may be used alone or in combination of two or more thereof.

### (Polymerization Inhibitor)

A polymerizable composition for forming a retardation film according to the present invention may contain a polymerization inhibitor. When the polymerizable composition contains the polymerization inhibitor, during storage of the polymerizable composition at high temperature, unnecessary polymerization is suppressed and storage stability is ensured. In addition, in a retardation film to be formed, the coating film has heat resistance, which sufficiently ensures durability.

The polymerization inhibitor is preferably a phenolic polymerization inhibitor.

The phenolic polymerization inhibitor is preferably any one of hydroquinone, methoxyphenol, methylhydroquinone, tertiary butylhydroquinone, and tertiary butylcatechol.

The polymerization inhibitor content relative to the total amount of polymerizable compound contained in the polymerizable composition is preferably 0.01 to 1 mass %, particularly preferably 0.01 to 0.5 mass %. Such polymerization inhibitors may be used alone or in combination of two or more thereof.

When the polymerization inhibitor is dissolved in the polymerizable composition, it is preferably dissolved concurrently with dissolution of the polymerizable compound in an organic solvent by heating and stirring. Alternatively, after the polymerizable compound is dissolved in an organic solvent by heating and stirring, the polymerization inhibitor may further be added to the polymerizable composition and dissolved.

### (Additives)

A polymerizable composition used for forming a retardation film according to the present invention may contain general-purpose additives in accordance with various purposes. For example, additives such as an antioxidant, an ultraviolet absorbing agent, a leveling agent, an alignment control agent, a chain transfer agent, an infrared absorbing agent, a thixotropic agent, an antistatic agent, a pigment, a filler, a chiral compound, a non-liquid-crystalline compound having a polymerizable group, another liquid-crystal compound, or an alignment material may be added as long as the addition does not considerably degrade the alignment of liquid crystal.

### (Antioxidant)

A polymerizable composition used for forming a retardation film according to the present invention may optionally contain an antioxidant, for example. Examples of such a compound include hydroquinone derivatives, nitrosamine-based polymerization inhibitors, and hindered-phenol-based antioxidants. More specific examples include tert-butylhydroquinone; “Q-1300” and “Q-1301” from Wako Pure Chemical Industries, Ltd.; pentaerythritoltetrakis[3-(3,5-di-tert-butyl-4-hydroxyphenyl)propionate “IRGANOX 1010”, thiodiethylenebis[3-(3,5-di-tert-butyl-4-hydroxyphenyl)propionate “IRGANOX 1035”, octadecyl-3-(3,5-di-tert-butyl-4-hydroxyphenyl)propionate “IRGANOX 1076”, “IRGANOX 1135”, “IRGANOX 1330”, 4,6-bis (octylthiomethyl)-o-cresol “IRGANOX 1520L”, “IRGANOX 1726”, “IRGANOX 245”, “IRGANOX 259”, “IRGANOX 3114”, “IRGANOX 3790”, “IRGANOX 5057”, “IRGANOX 565” (all manufactured by BASF); ADK STAB AO-20, AO-30, AO-40, AO-50, AO-60, AO-80 manufactured by ADEKA CORPORATION; and SUMILIZER BHT, SUMILIZER BBM-S, and SUMILIZER GA-80 manufactured by Sumitomo Chemical Company, Limited.

The amount of antioxidant added relative to the total amount of polymerizable compound contained in the polymerizable composition is preferably 0.01 to 2.0 mass %, more preferably 0.05 to 1.0 mass %.

### (Ultraviolet Absorbing Agent)

A polymerizable composition used for forming a retardation film according to the present invention may optionally contain an ultraviolet absorbing agent or a light stabilizer. The ultraviolet absorbing agent and light stabilizer for use are not particularly limited, but preferred are those that provide improved light resistance of the retardation film.

Examples of the ultraviolet absorbing agent include 2-(2-hydroxy-5-t-butylphenyl)-2H-benzotriazole “TINUVIN PS”, “TINUVIN 99-2”, “TINUVIN 109”, “TINUVIN 213”, “TINUVIN 234”, “TINUVIN 326”, “TINUVIN 328”, “TINUVIN 329”, “TINUVIN 384-2”, “TINUVIN 571”, 2-(2H-benzotriazol-2-yl)-4,6-bis(1-methyl-1-phenylethyl)phenol “TINUVIN 900”, 2-(2H-benzotriazol-2-yl)-6-(1-methyl-1-phenylethyl)-4-(1,1,3,3-tetramethylbutyl)phenol “TINUVIN 928”, “TINUVIN 1130”, “TINUVIN 400”, “TINUVIN 405”, 2,4-bis[2-hydroxy-4-butoxyphenyl]-6-(2,4-dibutoxyphenyl)-1,3,5-triazine “TINUVIN 460”, “TINUVIN 479”, “TINUVIN 5236” (all manufactured by BASF), “ADK STAB LA-32”, “ADK STAB LA-34”, “ADK STAB LA-36”, “ADK STAB LA-31”, “ADK STAB 1413”, and “ADK STAB LA-51” (all manufactured by ADEKA CORPORATION).

Examples of the light stabilizer include “TINUVIN 111FDL”, “TINUVIN 123”, “TINUVIN 144”, “TINUVIN 152”, “TINUVIN 292”, “TINUVIN 622”, “TINUVIN 770”, “TINUVIN 765”, “TINUVIN 780”, “TINUVIN 905”, “TINUVIN 5100”, “TINUVIN 5050”, “TINUVIN 5060”, “TINUVIN 5151”, “CHIMASSORB 119FL”, “CHIMASSORB 944FL”, “CHIMASSORB 944LD” (all manufactured by BASF); “ADK STAB LA-52”, “ADK STAB LA-57”, “ADK STAB LA-62”, “ADK STAB LA-67”, “ADK STAB LA-63P”, “ADK STAB LA-68LD”, “ADK STAB LA-77”, “ADK STAB LA-82”, and “ADK STAB LA-87” (all manufactured by ADEKA CORPORATION).

### (Leveling Agent)

A polymerizable composition for forming a retardation film according to the present invention may optionally contain a leveling agent. The leveling agent for use is not particularly limited; however, in the case of forming a thin retardation film, the leveling agent preferably enables a reduction in variations in the film thickness. Examples of the leveling agent include alkyl carboxylates, alkyl phosphates, alkyl sulfonates, fluoroalkyl carboxylates, fluoroalkyl phosphates, fluoroalkyl sulfonates, polyoxyethylene derivatives, fluoroalkyl ethylene oxide derivatives, polyethylene glycol derivatives, alkyl ammonium salts, and fluoroalkyl ammonium salts.

Specific examples include “MEGAFACE F-114”, “MEGAFACE F-251”, “MEGAFACE F-281”, “MEGAFACE F-410”, “MEGAFACE F-430”, “MEGAFACE F-444”, “MEGAFACE F-472SF”, “MEGAFACE F-477”, “MEGAFACE F-510”, “MEGAFACE F-511”, “MEGAFACE F-552”, “MEGAFACE F-553”, “MEGAFACE F-554”, “MEGAFACE F-555”, “MEGAFACE F-556”, “MEGAFACE F-557”, “MEGAFACE F-558”, “MEGAFACE F-559”, “MEGAFACE F-560”, “MEGAFACE F-561”, “MEGAFACE F-562”, “MEGAFACE F-563”, “MEGAFACE F-565”, “MEGAFACE F-567”, “MEGAFACE F-568”, “MEGAFACE F-569”, “MEGAFACE F-570”, “MEGAFACE F-571”, “MEGAFACE R-40”, “MEGAFACE R-41”, “MEGAFACE R-43”, “MEGAFACE R-94”, “MEGAFACE RS-72-K”, “MEGAFACE RS-75”, “MEGAFACE RS-76-E”, “MEGAFACE RS-76-NS”, “MEGAFACE RS-90”, “MEGAFACE EXP. TF-1367”, “MEGAFACE EXP. TF1437”, “MEGAFACE EXP. TF1537”, “MEGAFACE EXP. TF-2066” (all manufactured by DIC Corporation),

“FTERGENT 100”, “FTERGENT 100C”, “FTERGENT 110”, “FTERGENT 150”, “FTERGENT 150CH”, “FTERGENT 100A-K”, “FTERGENT 300”, “FTERGENT 310”, “FTERGENT 320”, “FTERGENT 400SW”, “FTERGENT 251”, “FTERGENT 215M”, “FTERGENT 212M”, “FTERGENT 215M”, “FTERGENT 250”, “FTERGENT 222F”, “FTERGENT 212D”, “FTX-218”, “FTERGENT 209F”, “FTERGENT 245F”, “FTERGENT 208G”, “FTERGENT 240G”, “FTERGENT 212P”, “FTERGENT 220P”, “FTERGENT 228P”, “DFX-18”, “FTERGENT 601AD”, “FTERGENT 602A”, “FTERGENT 650A”, “FTERGENT 750FM”, “FTX-730FM”, “FTERGENT 730FL”, “FTERGENT 710FS”, “FTERGENT 710FM”, “FTERGENT 710FL”, “FTERGENT 750LL”, “FTX-730LS”, “FTERGENT 730LM” (all manufactured by NEOS COMPANY LIMITED),

“BYK-3001”, “BYK-3021”, “BYK-3061”, “BYK-307”, “BYK-3101”, “BYK-315”, “BYK-320”, “BYK-322”, “BYK-323”, “BYK-325”, “BYK-330”, “BYK-331”, “BYK-333”, “BYK-337”, “BYK-340”, “BYK-344”, “BYK-370”, “BYK-3751”, “BYK-3771”, “BYK-350”, “BYK-3521”, “BYK-354”, “BYK-355”, “BYK-356”, “BYK-358N”, “BYK-361N”, “BYK-357”, “BYK-390”, “BYK-392”, “BYK-UV3500”, “BYK-UV3510”, “BYK-UV3570”, “BYK-Silclean3700” (all manufactured by BYK-Chemie GmbH),

“TEGO Rad2100”, “TEGO Rad2011”, “TEGO Rad2200N”, “TEGO Rad2250”, “TEGO Rad2300”, “TEGO Rad2500”, “TEGO Rad2600”, “TEGO Rad2650”, “TEGO Rad2700”, “TEGO Flow300”, “TEGO Flow370”, “TEGO Flow425”, “TEGO Flow ATF2”, “TEGO Flow ZFS460”, “TEGO Glide100”, “TEGO Glide110”, “TEGO Glide130”, “TEGO Glide410”, “TEGO Glide411”, “TEGO Glide415”, “TEGO Glide432”, “TEGO Glide440”, “TEGO Glide450”, “TEGO Glide482”, “TEGO Glide A115”, “TEGO Glide B1484”, “TEGO Glide ZG400”, “TEGO Twin4000”, “TEGO Twin4100”, “TEGO Twin4200”, “TEGO Wet240”, “TEGO Wet250”, “TEGO Wet260”, “TEGO Wet265”, “TEGO Wet270”, “TEGO Wet280”, “TEGO Wet500”, “TEGO Wet505”, “TEGO Wet510”, “TEGO Wet520”, “TEGO Wet KL245”, (all manufactured by Evonik Industries), “FC-4430”, “FC-4432” (all manufactured by 3M Japan Limited), “UNIDYNE NS” (manufactured by DAIKIN INDUSTRIES, LTD.), “SURFLON S-241”, “SURFLON 5-242”, “SURFLON 5-243”, “SURFLON 5-420”, “SURFLON 5-611”, “SURFLON 5-651”, “SURFLON 5-386” (all manufactured by AGC SEIMI CHEMICAL CO., LTD.), “DISPARLON OX-880EF”, “DISPARLON OX-881”, “DISPARLON OX-883”, “DISPARLON OX-77EF”, “DISPARLON OX-710”, “DISPARLON 1922”, “DISPARLON 1927”, “DISPARLON1958”, “DISPARLON P-410EF”, “DISPARLON P-420”, “DISPARLON P-425”, “DISPARLON PD-7”, “DISPARLON 1970”, “DISPARLON 230”, “DISPARLON LF-1980”, “DISPARLON LF-1982”, “DISPARLON LF-1983”, “DISPARLON LF-1084”, “DISPARLON LF-1985”, “DISPARLON LHP-90”, “DISPARLON LHP-91”, “DISPARLON LHP-95”, “DISPARLON LHP-96”, “DISPARLON OX-715”, “DISPARLON 1930N”, “DISPARLON 1931”, “DISPARLON 1933”, “DISPARLON 1934”, “DISPARLON 1711EF”, “DISPARLON 1751N”, “DISPARLON 1761”, “DISPARLON LS-009”, “DISPARLON LS-001”, “DISPARLON LS-050” (all manufactured by Kusumoto Chemicals, Ltd.), “PF-151N”, “PF-636”, “PF-6320”, “PF-656”, “PF-6520”, “PF-652-NF”, “PF-3320” (all manufactured by OMNOVA SOLUTIONS Inc.), “POLYFLOW No. 7”, “POLYFLOW No. 50E”, “POLYFLOW No. 50EHF”, “POLYFLOW No. 54N”, “POLYFLOW No. 75”, “POLYFLOW No. 77”, “POLYFLOW No. 85”, “POLYFLOW No. 85HF”, “POLYFLOW No. 90”, “POLYFLOW No. 90D-50”, “POLYFLOW No. 95”, “POLYFLOW No. 99C”, “POLYFLOW KL-400K”, “POLYFLOW KL-400HF”, “POLYFLOW KL-401”, “POLYFLOW KL-402”, “POLYFLOW KL-403”, “POLYFLOW KL-404”, “POLYFLOW KL-100”, “POLYFLOW LE-604”, “POLYFLOW KL-700”, “FlOWLEN AC-300”, “FlOWLEN AC-303”, “FlOWLEN AC-324”, “FlOWLEN AC-326F”, “FlOWLEN AC-530”, “FlOWLEN AC-903”, “FlOWLEN AC-903HF”, “FlOWLEN AC-1160”, “FlOWLEN AC-1190”, “FlOWLEN AC-2000”, “FlOWLEN AC-2300C”, “FlOWLEN AO-82”, “FlOWLEN AO-98”, “FlOWLEN AO-108” (all manufactured by Kyoeisha Chemical Co., Ltd.), “L-7001”, “L-7002”, “8032ADDITIVE”, “57ADDTIVE”, “L-7064”, “FZ-2110”, “FZ-2105”, “67ADDTIVE”, and “8616ADDTIVE” (all manufactured by Dow Corning Toray Silicone Co., Ltd.).

The amount of leveling agent added relative to the total amount of polymerizable compound used for the polymerizable composition is preferably 0.01 to 2 mass %, more preferably 0.05 to 0.5 mass %.

When the type of and the amount of the leveling agent added are appropriately selected and the resultant polymerizable composition is used to form a retardation film, the tilt angle at the air interface can also be controlled.

### (Alignment Control Agent)

A polymerizable composition used for forming a retardation film according to the present invention may contain an alignment control agent in order to control the alignment state of the polymerizable compound. The alignment control agent for use may cause the liquid-crystal compound to be aligned, relative to the substrate, in substantially planar alignment, substantially vertical alignment, or substantially hybrid alignment. When a chiral compound is added, the alignment control agent may provide substantially plane alignment. As described above, some surfactants may induce planar alignment or plane alignment. As long as such alignment states are induced, alignment control agents are not particularly limited, and may be selected from publicly known and commonly used alignment control agents.

An example of such an alignment control agent is a compound that has an effect of effectively decreasing the tilt angle at the air interface in the retardation film to be formed, that has a repeating unit represented by the following General formula (8), and that has a weight-average molecular weight of 100 or more and 1000000 or less.

[Chem. 144]

[symbol]

CR¹¹R¹²—CR¹³R¹⁴ [symbol] (8)

(where R¹¹, R¹², R¹³, and R¹⁴ each independently represent a hydrogen atom, a halogen atom, or a hydrocarbon group having 1 to 20 carbon atoms; in the hydrocarbon group, hydrogen atoms may be substituted by at least one halogen atom.)

Other examples include disc-like liquid-crystal compounds, rod-like liquid-crystal compounds modified with fluoroalkyl groups, and polymerizable compounds including long aliphatic alkyl groups that may have a branched structure.

Examples of an alignment control agent that has an effect of effectively increasing the tilt angle at the air interface of the retardation film to be formed include cellulose nitrate, cellulose acetate, cellulose propionate, cellulose butyrate, rod-like liquid-crystal compounds modified with heteroaromatic ring salts, and rod-like liquid-crystal compounds modified with cyano groups and cyanoalkyl groups.

### (Chain Transfer Agent)

A polymerizable composition used in the present invention may contain a chain transfer agent in order to further improve adhesion between a polymer or a retardation film and a substrate. Examples of the chain transfer agent include aromatic hydrocarbons, chloroform, halogenated hydrocarbons such as carbon tetrachloride, carbon tetrabromide, and bromotrichloromethane, mercaptan compounds such as octyl mercaptan, n-butyl mercaptan, n-pentyl mercaptan, n-hexadecyl mercaptan, n-tetradecyl mercaptans, n-dodecyl mercaptan, t-tetradecyl mercaptan, and t-dodecyl mercaptan; thiol compounds such as hexanedithiol, decanedithiol, 1,4-butanediol bisthiopropionate, 1,4-butanediol bisthioglycolate, ethylene glycol bisthioglycolate, ethylene glycol bisthiopropionate, trimethylolpropane tristhioglycolate, trimethylolpropane tristhiopropionate, trimethylolpropane tris(3-mercaptobutyrate), pentaerythritol tetrakisthioglycolate, pentaerythritol tetrakisthiopropionate, trimercaptopropionic acid tris(2-hydroxyethyl)isocyanurate, 1,4-dimethylmercaptobenzene, 2,4,6-trimercapto-s-triazine, and 2-(N,N-dibutylamino)-4,6-dimercapto-s-triazine; sulfide compounds such as dimethyl xanthogen disulfide, diethyl xanthogen disulfide, diisopropyl xanthogen disulfide, tetramethylthiuram disulfide, tetraethylthiuram disulfide, and tetrabutylthiuram disulfide; N,N-dimethylaniline, N,N-divinylaniline, pentaphenylethane, a-methylstyrene dimer, acrolein, allyl alcohol, terpinolene, a-terpinen, y-terpinen, and dipentene; more preferred are 2,4-diphenyl-4-methyl-1-pentene, and thiol compounds.

Specifically, preferred examples are compounds represented by the following General formulas (9-1) to (9-12).

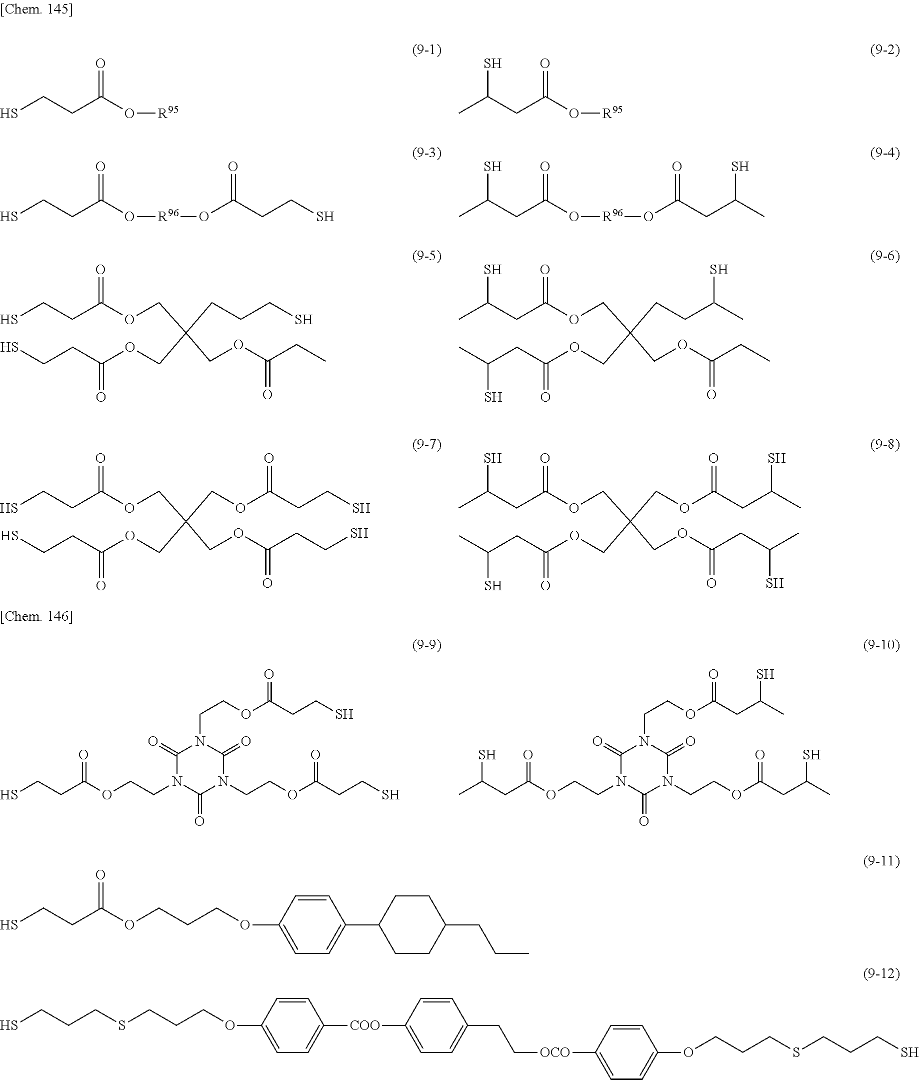

In the formulas, R⁹⁵ represents an alkyl group having 2 to 18 carbon atoms; the alkyl group may have a linear chain or a branched chain; in the alkyl group, at least one methylene group may be substituted by, so as not to form a direct bond between an oxygen atom and a sulfur atom, an oxygen atom, a sulfur atom, —CO—, —OCO—, —COO—, or —CH═CH—. R⁹⁶ represents an alkylene group having 2 to 18 carbon atoms; in the alkylene group, at least one methylene group may be substituted by, so as not to form a direct bond between an oxygen atom and a sulfur atom, an oxygen atom, a sulfur atom, —CO—, —OCO—, —COO—, or —CH═CH—.

The chain transfer agent is preferably added in a step in which the polymerizable compound is mixed with an organic solvent, and heated and stirred to prepare a polymerizable solution; alternatively, the chain transfer agent may be added in a later step in which the polymerizable solution is mixed with a polymerization initiator, or may be added in both of the steps.

The amount of chain transfer agent added relative to the total amount of polymerizable compound contained in the polymerizable composition is preferably 0.5 to 10 mass %, more preferably 1.0 to 5.0 mass %.

In order to adjust properties, a non-polymerizable liquid-crystal compound or the like may be optionally added. A non-liquid-crystalline polymerizable compound is preferably added in the step in which the polymerizable compound is mixed with an organic solvent and heated and stirred to prepare a polymerizable solution; the non-polymerizable liquid-crystal compound or the like may be added in a later step in which the polymerizable solution is mixed with a polymerization initiator, or may be added in both of the steps. The amount of such compounds added relative to the polymerizable composition is preferably 20 mass % or less, more preferably 10 mass % or less, still more preferably 5 mass % or less.

### (Infrared Absorbing Agent)

A polymerizable composition used for forming a retardation film according to the present invention may optionally contain an infrared absorbing agent. The infrared absorbing agent for use is not particularly limited, and may be selected from publicly known and commonly used infrared absorbing agents as long as it does not disturb alignment.

Examples of the infrared absorbing agent include cyanine compounds, phthalocyanine compounds, naphthoquinone compounds, dithiol compounds, diimmonium compounds, azo compounds, and aluminum salts.

Specific examples include diimmonium salt type “NIR-IM1”, aluminum salt type “NIR-AM1” (all manufactured by Nagase ChemteX Corporation), “Karenz IR-T”, “Karenz IR-13F” (all manufactured by SHOWA DENKO K. K.), “YKR-2200”, “YKR-2100” (all manufactured by Yamamoto Chemicals, Inc.), “IRA908”, “IRA931”, “IRA955”, and “IRA1034” (all available from INDECO Inc.).

### (Antistatic Agent)

A polymerizable composition used for forming a retardation film according to the present invention may optionally contain an antistatic agent. The antistatic agent for use is not particularly limited, and may be selected from publicly known and commonly used antistatic agents as long as it does not disturb alignment.

Examples of the antistatic agent include polymers intramolecularly having at least one sulfonate group species or phosphate group species, compounds having a quaternary ammonium salt, and surfactants having a polymerizable group.

In particular, preferred are surfactants having a polymerizable group; examples of anionic surfactants having a polymerizable group include alkyl ether-based surfactants such as “Antox SAD”, “Antox MS-2N” (all manufactured by Nippon Nyukazai Co., Ltd.), “AQUALON KH-05”, “AQUALON KH-10”, “AQUALON KH-20”, “AQUALON KH-0530”, “AQUALON KH-1025” (all manufactured by DAI-ICHI KOGYO SEIYAKU CO., LTD.), “ADEKA REASOAP SR-10N”, “ADEKA REASOAP SR-20N” (all manufactured by ADEKA CORPORATION), and “LATEMUL PD-104” (manufactured by Kao Corporation); sulfosuccinate-based surfactants such as “LATEMUL S-120”, “LATEMUL S-120A”, “LATEMUL S-180P”, “LATEMUL S-180A¹¹ (all manufactured by Kao Corporation), and “ELEMINOL JS-2” (manufactured by Sanyo Chemical Industries, Ltd.); alkylphenyl ether-based or alkylphenyl ester-based surfactants such as “AQUALON H-2855A”, “AQUALON H-3855B”, “AQUALON H-3855C”, “AQUALON H-3856”, “AQUALON HS-05”, “AQUALON HS-10”, “AQUALON HS-20”, “AQUALON HS-30”, “AQUALON HS-1025”, “AQUALON BC-05”, “AQUALON BC-10”, “AQUALON BC-20”, “AQUALON BC-1025”, “AQUALON BC-2020” (all manufactured by DAI-ICHI KOGYO SEIYAKU CO., LTD.), “ADEKA REASOAP SDX-222”, “ADEKA REASOAP SDX-223”, “ADEKA REASOAP SDX-232”, “ADEKA REASOAP SDX-233”, “ADEKA REASOAP SDX-259”, “ADEKA REASOAP SE-10N”, and “ADEKA REASOAP SE-20N” (all manufactured by ADEKA CORPORATION); (meth)acrylate sulfate-based surfactants such as “Antox MS-60”, “Antox MS-2N” (all manufactured by Nippon Nyukazai Co., Ltd.), and “ELEMINOL RS-30” (manufactured by Sanyo Chemical Industries, Ltd.); and phosphate-based surfactants such as “H-3330P” (manufactured by DAI-ICHI KOGYO SEIYAKU CO., LTD.) and “ADEKA REASOAP PP-70” (manufactured by ADEKA CORPORATION).

Examples of nonionic surfactants having a polymerizable group include alkyl ether-based surfactants such as “Antox LMA-20”, “Antox LMA-27”, “Antox EMH-20”, “Antox LMH-20, “Antox SMH-20” (all manufactured by Nippon Nyukazai Co., Ltd.), “ADEKA REASOAP ER-10”, “ADEKA REASOAP ER-20”, “ADEKA REASOAP ER-30”, “ADEKA REASOAP ER-40” (all manufactured by ADEKA CORPORATION), “LATEMUL PD-420”, “LATEMUL PD-430”, and “LATEMUL PD-450” (all manufactured by Kao Corporation); alkylphenyl ether-based or alkylphenyl ester-based surfactants such as “AQUALON RN-10”, “AQUALON RN-20”, “AQUALON RN-30”, “AQUALON RN-50”, “AQUALON RN-2025” (all manufactured by DAI-ICHI KOGYO SEIYAKU CO., LTD.), “ADEKA REASOAP NE-10”, “ADEKA REASOAP NE-20”, “ADEKA REASOAP NE-30”, and “ADEKA REASOAP NE-40” (all manufactured by ADEKA CORPORATION); and (meth)acrylate sulfate-based surfactants such as “RMA-564”, “RMA-568”, and “RMA-1114” (all manufactured by Nippon Nyukazai Co., Ltd.).

Other examples of the antistatic agent include polyethylene glycol (meth)acrylate, methoxypolyethylene glycol (meth)acrylate, ethoxypolyethylene glycol (meth)acrylate, propoxypolyethylene glycol (meth)acrylate, n-butoxypolyethylene glycol (meth)acrylate, n-pentaxypolyethylene glycol (meth)acrylate, phenoxypolyethylene glycol (meth)acrylate, polypropylene glycol (meth)acrylate, methoxypolypropylene glycol (meth)acrylate, ethoxypolypropylene glycol (meth)acrylate, propoxypolypropylene glycol (meth)acrylate, n-butoxypolypropylene glycol (meth)acrylate, n-pentaxypolypropylene glycol (meth)acrylate, phenoxypolypropylene glycol (meth)acrylate, polytetramethylene glycol (meth)acrylate, methoxypolytetramethylene glycol (meth)acrylate, phenoxytetraethylene glycol (meth)acrylate, hexaethylene glycol (meth)acrylate, and methoxyhexaethylene glycol (meth)acrylate.

Such antistatic agents may be used alone or in combination of two or more thereof. The amount of the antistatic agent added relative to the total amount of polymerizable compound contained in the polymerizable composition is preferably 0.001 to 10 weight %, more preferably 0.01 to 5 weight %.

### (Pigment)

A polymerizable composition used for forming a retardation film according to the present invention may optionally contain a pigment. The pigment for use is not particularly limited, and may be selected from publicly known and commonly used pigments as long as it does not disturb alignment.

Examples of the pigment include dichroic pigments and fluorescent pigments. Examples of the pigment include polyazo pigments, anthraquinone pigments, cyanine pigments, phthalocyanine pigments, perylene pigments, perinone pigments, and squarylium pigments. From the viewpoint of addition, the pigment is preferably a pigment that exhibits liquid crystallinity.

Examples of usable pigments include those described in U.S. Pat. No. 2,400,877, Dreyer J. F., Phys. and Colloid Chem., 1948, 52, 808., “The Fixing of Molecular Orientation”, Dreyer J. F., Journal de Physique, 1969, 4, 114., “Light Polarization from Films of Lyotropic Nematic Liquid Crystals”, J. Lydon, “Chromonics” in “Handbook of Liquid Crystals Vol. 2B: Low Molecular Weight Liquid Crystals II”, D. Demus, J. Goodby, G. W. Gray, H. W. Spiessm, V. Vill ed, Willey-VCH, P. 981-1007 (1998), Dichroic Dyes for Liquid Crystal Display A. V. lvashchenko CRC Press, 1994, and “Novel Development of Functional Pigment Market”, Chapter 1, page 1, 1994, published by CMC Publishing Co., Ltd.

Examples of the dichroic pigments include the following Formula (d-1) to Formula (d-8).

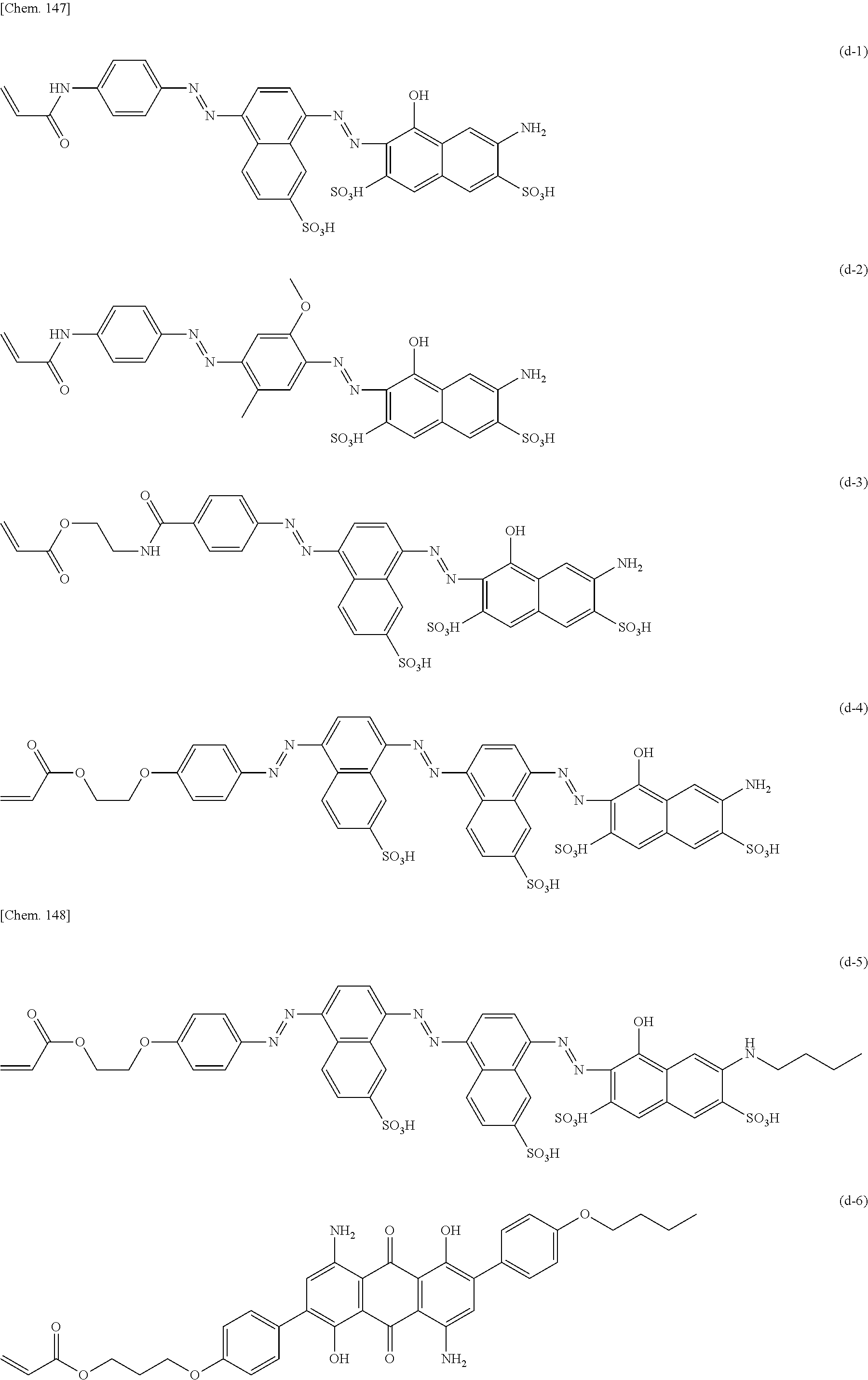

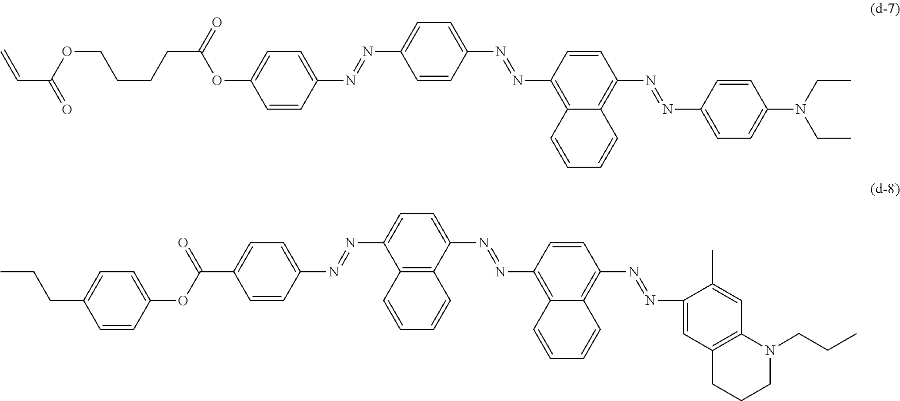

The amount of pigment added, such as the dichroic pigment, relative to the total amount of polymerizable compound contained in the polymerizable composition is preferably 0.001 to 10 weight %, more preferably 0.01 to 5 weight %.

### (Filler)

A polymerizable composition used for forming a retardation film according to the present invention may optionally contain a filler. The filler for use is not particularly limited, and may be selected from publicly known and commonly used fillers as long as it does not decrease the thermal conductivity of the resultant polymerization product.

Examples of the filler include inorganic fillers such as alumina, titanium white, aluminum hydroxide, talc, clay, mica, barium titanate, zinc oxide, and glass fiber; metal powders such as silver powder and copper powder; and thermal conductive fillers such as aluminum nitride, boron nitride, silicon nitride, gallium nitride, silicon carbide, magnesia (aluminum oxide), alumina (aluminum oxide), crystalline silica (silicon oxide), and fused silica (silicon oxide); and silver nanoparticles.

### (Non-Liquid-Crystalline Compound Having Polymerizable Group)

A polymerizable composition used for forming a retardation film according to the present invention may contain a compound that has a polymerizable group but is not a liquid-crystal compound. Such a compound is not particularly limited as long as it is normally recognized as a polymerizable monomer or a polymerizable oligomer in this technical field. When the compound is added, the amount of addition relative to the total amount of polymerizable compound used in the polymerizable composition is preferably 15 mass % or less, more preferably 10 mass % or less.

Specific examples include mono(meth)acrylates such as methyl (meth)acrylate, ethyl (meth)acrylate, 2-hydroxyethyl acrylate, propyl (meth)acrylate, 2-hydroxypropyl (meth)acrylate, butyl (meth)acrylate, isobutyl (meth)acrylate, 4-hydroxybutyl (meth)acrylate, 2-hydroxybutyl (meth)acrylate, octyl (meth)acrylate, 2-ethylhexyl (meth)acrylate, dodecyl (meth)acrylate, stearyl (meth)acrylate, cyclohexyl (meth)acrylate, dicyclopentanyloxyethyl (meth)acrylate, isobornyloxylethyl (meth)acrylate, isobornyl (meth)acrylate, adamantyl (meth)acrylate, dimethyladamantyl (meth)acrylate, dicyclopentanyl (meth)acrylate, dicyclopentenyl (meth)acrylate, methoxyethyl (meth)acrylate, ethylcarbitol (meth)acrylate, tetrahydrofurfuryl (meth)acrylate, benzyl (meth)acrylate, phenoxyethyl (meth)acrylate, 2-phenoxydiethylene glycol (meth)acrylate, 2-hydroxy-3-phenoxyethyl (meth)acrylate, (2-methyl-2-ethyl-1,3-dioxolan-4-yl)methyl (meth)acrylate, (3-ethyloxetan-3-yl)methyl (meth)acrylate, o-phenylphenolethoxy (meth)acrylate, dimethylamino (meth)acrylate, diethylamino (meth)acrylate, 2,2,3,3,3-pentafluoropropyl (meth)acrylate, 2,2,3,4,4,4-hexafluorobutyl (meth)acrylate, 2,2,3,3,4,4,4-heptafluorobutyl (meth)acrylate, 2-(perfluorobutyl)ethyl (meth)acrylate, 2-(perfluorohexyl)ethyl (meth)acrylate, 1H,1H,3H-tetrafluoropropyl (meth)acrylate, 1H,1H,5H-octafluoropentyl (meth)acrylate, 1H,1H,7H-dodecafluoroheptyl (meth)acrylate, 1H-1-(trifluoromethyl)trifluoroethyl (meth)acrylate, 1H,1H,3H-hexafluorobutyl (meth)acrylate, 1,2,2,2-tetrafluoro-1-(trifluoromethyl)ethyl (meth)acrylate, 1H,1H-pentadecafluorooctyl (meth)acrylate, 1H,1H,2H,2H-tridecafluorooctyl (meth)acrylate, 2-(meth)acryloyloxyethylphthalic acid, 2-(meth)acryloyloxyethylhexahydrophthalic acid, glycidyl (meth)acrylate, 2-(meth)acryloyloxyethylphosphoric acid, acryloylmorpholine, dimethylacrylamide, dimethylaminopropylacrylamide, isopropylacrylamide, diethylacrylamide, hydroxyethylacrylamide, and N-acryloyloxyethylhexahydrophthalimide; diacrylates such as 1,4-butanediol di(meth)acrylate, 1,6-hexanediol di(meth)acrylate, 1,9-nonanediol di(meth)acrylate, neopentyl diol di(meth)acrylate, tripropylene glycol di(meth)acrylate, ethylene glycol di(meth)acrylate, diethylene glycol di(meth)acrylate, triethylene glycol di(meth)acrylate, ethylene oxide-modified bisphenol A di(meth)acrylate, tricyclodecane dimethanol di(meth)acrylate, 9,9-bis[4-(2-acryloyloxyethoxy)phenyl]fluorene, glycerol di(meth)acrylate, 2-hydroxy-3-acryloyloxypropyl methacrylate, an acrylic-acid adduct of 1,6-hexanediol diglycidyl ether, and an acrylic-acid adduct of 1,4-butanediol diglycidyl ether; tri(meth)acrylates such as trimethylolpropane tri(meth)acrylate, ethoxylated isocyanurate triacrylate, pentaerythritol tri(meth)acrylate, and 6-caprolactone-modified tris-(2-acryloyloxyethyl)isocyanurate; tetra(meth)acrylates such as pentaerythritol tetra(meth)acrylate, and ditrimethylolpropane tetra(meth)acrylate; dipentaerythritol hexa(meth)acrylate, oligomer (meth)acrylates, various urethane acrylates, various macromonomers, epoxy compounds such as ethylene glycol diglycidyl ether, diethylene glycol diglycidyl ether, propylene glycol diglycidyl ether, neopentyl glycol diglycidyl ether, 1,6-hexanediol diglycidyl ether, glycerol diglycidyl ether, and bisphenol A diglycidyl ether; and maleimide. These may be used alone or in combination of two or more thereof.

### (Alignment Material)

A polymerizable composition used for forming a retardation film according to the present invention may contain an alignment material that improves the alignment, in order to improve the alignment. The alignment material for use may be selected from publicly known and commonly used alignment materials as long as it is soluble in a solvent for dissolving a liquid-crystal compound having a polymerizable group and used in the polymerizable composition; the alignment material is added as long as the addition does not considerably degrade alignment. Specifically, the amount of addition relative to the total amount of polymerizable liquid-crystal compound contained in the polymerizable liquid-crystal composition is preferably 0.05 to 30 weight %, more preferably 0.5 to 15 weight %, particularly preferably 1 to 10 weight %.

Specific examples of the alignment material include photoisomerizable compounds or photodimerizable compounds such as polyimide, polyamide, BCB (benzocyclobutene polymer) polyvinyl alcohol, polycarbonate, polystyrene, polyphenylene ether, polyarylate, polyethyleneterephthalate, polyethersulfone, epoxy resins, epoxy acrylate resins, acrylic resins, coumarin compounds, chalcone compounds, cinnamate compounds, fulgide compounds, anthraquinone compounds, azo compounds, and arylethene compounds; preferred are materials that are aligned by irradiation with ultraviolet light or by irradiation with visible light (photo-alignment materials).

Examples of the photo-alignment materials include polyimide having cycloalkane, wholly aromatic polyarylate, polyvinyl ester of p-methoxycinnamic acid, polyvinyl cinnamate described in Japanese Unexamined Patent Application Publication No. 5-232473, cinnamate derivatives described in Japanese Unexamined Patent Application Publication No. 6-287453 and Japanese Unexamined Patent Application Publication No. 6-289374, and maleimide derivatives described in Japanese Unexamined Patent Application Publication No. 2002-265541. Specifically, preferred are compounds represented by the following Formula (12-1) to Formula (12-7).

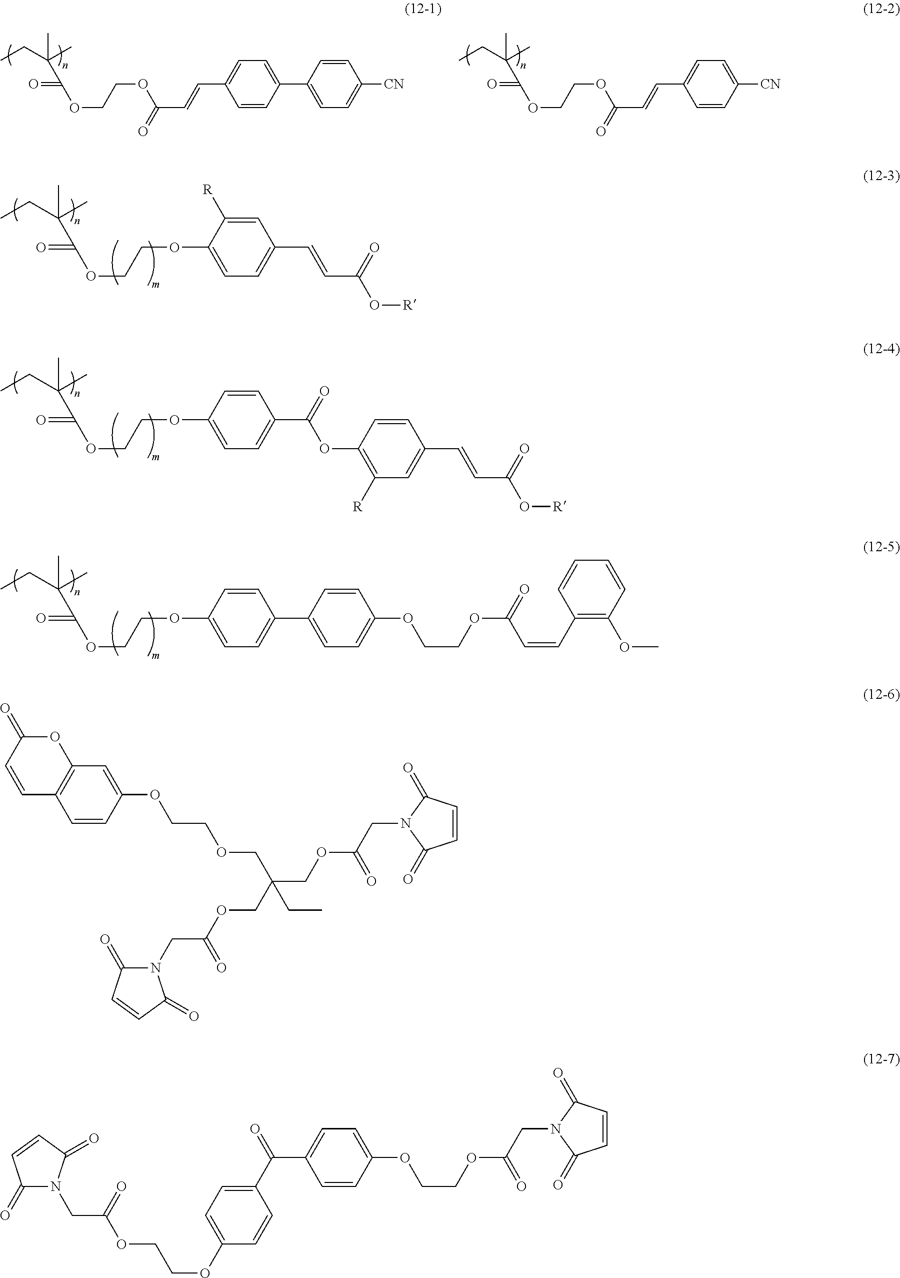

(where R represents a hydrogen atom, a halogen atom, an alkyl group having 1 to 3 carbon atoms, an alkoxy group, or a nitro group. R′ represents a hydrogen atom or an alkyl group having 1 to 10 carbon atoms; the alkyl group may be linear or branched; any hydrogen atom in the alkyl group may be substituted by a fluorine atom; in the alkyl group, one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, or —C═C—; CH₃ at the ends may be substituted by CF₃, CCl₃, a cyano group, a nitro group, an isocyano group, or a thioisocyano group. n represents 4 to 100000. m represents an integer of 1 to 10.)

### (Retardation Film and Method for Producing Retardation Film)

### (Retardation Film)

A polymerizable composition used for forming a retardation film according to the present invention is applied to a substrate or a substrate having an alignment function; liquid-crystal molecules in the polymerizable liquid-crystal composition that are held in a nematic phase or a smectic phase are uniformly aligned and polymerized, to thereby obtain a retardation film according to the present invention.

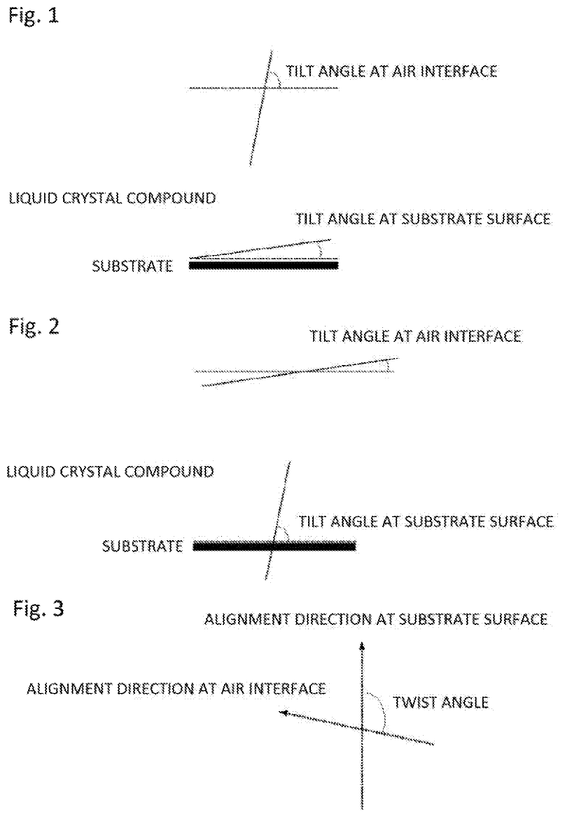

A retardation film according to the present invention has a hybrid alignment. The hybrid alignment means, as illustrated in [FIG. 1] and [FIG. 2], an alignment state in which the tilt angle at the substrate interface is considerably different from the tilt angle at the air interface. The tilt angle at the substrate interface is preferably 0° to 45°, more preferably 0° to 20°, still more preferably 0° to 10°, yet more preferably 0° to 5°, most preferably 0° to 3°. The tilt angle at the air interface is preferably 45° to 90°, more preferably 50° to 80°, still more preferably 55° to 75°. As illustrated in [FIG. 2], these tilt angles may be inverted for the substrate interface and the air interface.

Alternatively, liquid-crystal molecules in the polymerizable liquid-crystal composition are preferably aligned while being held in a twisted structure in the substrate plane. The twisted structure means an alignment state illustrated in [FIG. 3]. The angle formed between the alignment direction at the substrate interface and the alignment direction at the air interface is referred to as a twist angle. The twist angle is preferably 10° to 80°, more preferably 25° to 80°, still more preferably 30° to 70°, most preferably 450 to 65°.

### (Substrate)

A substrate used for a retardation film according to the present invention is not particularly limited as long as it is a substrate that is normally used for liquid-crystal display devices, organic light-emitting display devices, other display devices, optical components, coloring agents, marking, printed matter, or optical films, and that is a material having heat resistance enough to withstand heating during drying after application of the polymerizable composition solution. Examples of the substrate include glass substrates, metal substrates, ceramic substrates, plastic substrates, and organic materials such as paper. In particular, when the substrate is formed of an organic material, examples thereof include cellulose derivatives, polyolefin, polyester, polyolefin, polycarbonate, polyacrylate, polyarylate, polyethersulfone, polyimide, polyphenylene sulfide, polyphenylene ether, nylon, and polystyrene. In particular, preferred are plastic substrates formed of, for example, polyester, polystyrene, polyolefin, a cellulose derivative, polyarylate, or polycarbonate. The substrate may have a shape of a flat plate, alternatively may have a curved surface. Such substrates may optionally have an electrode layer, an antireflection function, or a reflection function.

In order to improve the coatability or adhesion (to a polymer) of a polymerizable composition used for forming a retardation film according to the present invention, such substrates may be subjected to a surface treatment.

Examples of the surface treatment include an ozone treatment, a plasma treatment, a corona treatment, and a silane coupling treatment. Alternatively, in order to adjust transmittance or reflectivity for light, on the surface of the substrate, an organic thin film, an inorganic oxide thin film, a metal thin film, or the like may be formed by a method such as vapor deposition. In order to add an optical value, the substrate may be selected from a pickup lens, a rod lens, an optical disc, a retardation film, a light diffusion film, and a color filter, for example. In particular, because of higher added values, preferred are a pickup lens, a retardation film, a light diffusion film, and a color filter.

(Alignment treatment)

The substrate may be normally subjected to an alignment treatment or may be equipped with an alignment film such that, during application and drying of a polymerizable composition used for forming a retardation film according to the present invention, the polymerizable composition is aligned. Examples of the alignment treatment include a stretching treatment, a rubbing treatment, a polarized ultraviolet-visible irradiation treatment, an ion-beam treatment, and a SiO₂ oblique deposition treatment for a substrate. When an alignment film is used, it is selected from publicly known and commonly used alignment films. Such an alignment film is formed of a compound such as polyimide, polysiloxane, polyamide, polyvinyl alcohol, polycarbonate, polystyrene, polyphenylene ether, polyarylate, polyethyleneterephthalate, polyethersulfone, epoxy resin, epoxy acrylate resin, acrylic resin, an azo compound, a coumarin compound, a chalcone compound, a cinnamate compound, a fulgide compound, an anthraquinone compound, an azo compound, or an arylethene compound, or a polymer or copolymer of such a compound. A compound subjected to an alignment treatment by rubbing is preferably a compound subjected to a heating step during the alignment treatment or after the alignment treatment to thereby promote crystallization of the material. Of compounds subjected to alignment treatments other than rubbing, preferred are photo-alignment materials.

In general, when a liquid-crystal composition is brought into contact with a substrate having an alignment function, liquid-crystal molecules are aligned, near the substrate, in the direction of the alignment treatment performed on the substrate. Whether liquid-crystal molecules are aligned in planar alignment relative to the substrate, or aligned in oblique or vertical alignment relative to the substrate can be controlled by the method of the alignment treatment performed on the substrate. For example, when polyimide is subjected to a rubbing treatment, the substrate interface side of the resultant alignment state has alignment slightly tilted in the rubbing direction.

Some photo-alignment films are obliquely irradiated with polarized ultraviolet light to provide a tilt angle on the substrate-interface side. In general, a photo-alignment film that is perpendicularly exposed to polarized ultraviolet light often provides a substrate-interface-side tilt angle of about 0°. Alternatively, a method of performing oblique vapor deposition of SiO₂ may be employed to provide a tilt angle on the substrate interface side. On the other hand, the air-interface-side tilt angle may be adjusted by changing the type of or amount of addition of the above-described surfactant or alignment control agent.

On the other hand, in order to provide the twist angle, in general, the above-described chiral compound is added to the polymerizable composition. The twist angle can be adjusted by changing the amount of chiral compound added.

### (Coating)

The coating method for obtaining a retardation film according to the present invention may be selected from publicly known and commonly used methods such as the applicator method, the bar coating method, the spin coating method, the roll coating method, the direct gravure coating method, the reverse gravure coating method, the flexographic coating method, the ink jet method, the die coating method, the cap coating method, the dip coating method, the slit coating method, and the spray coating method. The polymerizable composition is applied and then dried.

After the polymerizable composition is applied, liquid-crystal molecules therein are preferably uniformly aligned while being held in a smectic phase or a nematic phase. This can be achieved by methods such as a heat treatment method. Specifically, after the polymerizable composition is applied to a substrate, the liquid-crystal composition is heated at a temperature equal to or higher than the N (nematic phase)-I (isotropic liquid phase) transition temperature (hereafter, abbreviated as the N-I transition temperature), so that the liquid-crystal composition is turned into an isotropic-phase liquid state. This isotropic-phase liquid is optionally subjected to slow cooling to provide a nematic phase. At this time, the isotropic-phase liquid is desirably temporarily held at a temperature for providing a liquid crystal phase, so that liquid-crystal-phase domains are sufficiently grown to provide a mono-domain structure. Alternatively, after the polymerizable composition is applied onto a substrate, a heat treatment may be performed such that the polymerizable composition is held for a period in a temperature range in which a nematic phase appears.

When the heating temperature is excessively high, the polymerizable liquid-crystal compound may unfavorably undergo a polymerization reaction and become degraded. When the polymerizable composition is excessively cooled, it may undergo phase separation, to undergo precipitation of crystals or generation of a high-order liquid-crystal phase such as a smectic phase; as a result, it may become impossible to perform the alignment treatment.

Such a heat treatment enables formation of a retardation film that has less alignment defects and is uniform, compared with a coating method of performing coating alone.

When such a uniform alignment treatment is performed, subsequently the liquid-crystal phase is cooled to a minimum temperature of not undergoing phase separation, namely to a supercooling state, and, at this temperature, the liquid-crystal phase being in an alignment state is polymerized, a retardation film having a higher degree of alignment and high transparency can be obtained.

### (Polymerization Step)

The polymerization treatment for the dried polymerizable composition is performed by, in general, in a uniformly aligned state, irradiation with light such as visible-ultraviolet light or by heating. When the polymerization is performed by irradiation with light, specifically, the irradiation is preferably performed with visible-ultraviolet light at 420 nm or less, most preferably with ultraviolet light at wavelengths of 250 to 370 nm. However, when visible-ultraviolet light at 420 nm or less causes, for example, decomposition of the polymerizable composition, the polymerization treatment is preferably performed with visible-ultraviolet light at 420 nm or more in some cases.

### (Polymerization Method)

Examples of the method of polymerizing a polymerizable composition used for forming a retardation film according to the present invention include a method of irradiation with active energy rays or a thermal polymerization method. The method of irradiation with active energy rays is preferred because heating is not required and the reaction proceeds at room temperature. In particular, preferred is a method of irradiation with light such as ultraviolet light because of the simple procedure. The temperature during irradiation is set such that the polymerizable composition maintains a liquid-crystal phase; in order to avoid induction of thermal polymerization of the polymerizable composition, the temperature is preferably set at 30° C. or less as much as possible. Incidentally, normally, in the process of temperature increase, the polymerizable liquid-crystal composition has a liquid-crystal phase within the range of from the C (solid phase)-N(nematic) transition temperature (hereafter, abbreviated as the C-N transition temperature) to the N-I transition temperature. On the other hand, in the process of temperature decrease, the polymerizable liquid-crystal composition is in a thermodynamically non-equilibrium state, and hence it may remain in the liquid-crystal state without solidifying even below the C-N transition temperature. This state is referred to as a supercooling state. In the present invention, the liquid-crystal composition in a supercooling state is also considered as maintaining a liquid-crystal phase. Specifically, preferred is irradiation with ultraviolet light at 390 nm or less, most preferred is irradiation with light at wavelengths of 250 to 370 nm. However, when ultraviolet light at 390 nm or less causes, for example, decomposition of the polymerizable composition, the polymerization treatment is preferably performed with ultraviolet light at 390 nm or more in some cases. This light is preferably diffused light and is unpolarized light. The intensity of ultraviolet light for irradiation is preferably 0.05 kW/m² to 10 kW/m², particularly preferably 0.2 kW/m² to 2 kW/m². When the intensity of ultraviolet light is less than 0.05 kW/m2, the polymerization takes a very long time to the completion. On the other hand, when the intensity is more than 2 kW/m², liquid-crystal molecules in the polymerizable composition tend to be decomposed by light; or a large amount of polymerization heat may be generated to cause an increase in the temperature during polymerization, which alters the order parameter of the polymerizable liquid crystal to cause deviation in the retardation of the polymerized film.

A retardation film having a plurality of regions having different alignment directions may also be obtained by polymerizing a specific region alone by irradiation with ultraviolet light through a mask; subsequently, changing the alignment state of the unpolymerized region by application of, for example, an electric field, a magnetic field, or a change in the temperature; subsequently polymerizing the unpolymerized region.

A retardation film having a plurality of regions having different alignment directions may also be obtained by, during polymerization of a specific region alone by irradiation with ultraviolet light through a mask, controlling, beforehand, the alignment of the unpolymerized polymerizable liquid-crystal composition by application of, for example, an electric field, a magnetic field, or a change in the temperature; in this state being maintained, polymerizing the unpolymerized polymerizable liquid-crystal composition by irradiation with light from above the mask.

A retardation film obtained by polymerizing a polymerizable liquid-crystal composition used in the present invention may be separated from the substrate and used alone as a retardation film, or may be used as a retardation film without being separated from the substrate. In particular, the retardation film is less likely to contaminate other members, and hence is useful when it is used as a substrate on which a layer is disposed, or used by being bonded to another substrate.

### (Elliptically Polarizing Plate)

A retardation film according to the present invention may be bonded to a linearly polarizing plate, to thereby produce an elliptically polarizing plate according to the present invention. The linearly polarizing plate is normally a polarizer having a protective film on one or both sides of the polarizer. The polarizer is not particularly limited, and may be selected from various polarizers; examples include films that are provided by causing a dichroic material such as iodine or dichroic dye to adsorb on a hydrophilic polymer film such as a polyvinyl alcohol-based film, a partially formalized polyvinyl alcohol-based film, or an ethylene-vinyl acetate copolymer-based partially saponified film, and by uniaxially drawing the hydrophilic polymer film; and polyene-based alignment films such as films obtained by dehydrating polyvinyl alcohol, or by dehydrochlorinating polyvinyl chloride. Of these, preferred are films obtained by drawing a polyvinyl alcohol-based film and causing a dichroic material (iodine, dye) to adsorb and align on the film. Other examples include wire-grid polarizing plates.

When a retardation film according to the present invention and a polarizing plate are bonded together, and the twist angle is about 0°, the angle between the absorption axis of the polarizing plate and the slow axis of the retardation plate is preferably 40° to 50°, more preferably 43° to 47°, most preferably 45°. When the twist angle is formed, the angle between the absorption axis of the polarizing plate and the slow axis of a surface closer to the polarizing plate is preferably 60° to 100°, more preferably 70° to 90°, still more preferably 80° to 90°. The angle between the absorption axis of the polarizing plate and the slow axis of a surface farther from the polarizing plate is preferably 0° to 60°, more preferably 10° to 50°, still more preferably 200 to 40°.

The elliptically polarizing plate may be provided by, as described above, bonding a retardation film according to the present invention to a linearly polarizing plate, alternatively, by directly coating a polarizing plate with a polymerizable composition according to the present invention to form a retardation film layer directly on the polarizing plate.

### (Liquid-Crystal Display Device)

A retardation film according to the present invention may also be used for a liquid-crystal display device. Such a liquid-crystal display device includes at least two substrates, and these substrates at least sandwich a liquid-crystal medium layer, a TFT driving circuit, a black matrix layer, a color filter layer, a spacer, and an appropriate electrode circuit in the liquid-crystal medium layer. Normally, an optical compensation layer, a polarizing plate layer, and a touch panel layer are disposed outside of the two substrates; however, in some cases, an optical compensation layer, an overcoating layer, a polarizing plate layer, and an electrode layer for a touch panel may be sandwiched between the two substrates.

Examples of the alignment mode of the liquid-crystal display device include a TN mode, a VA mode, an IPS mode, an FFS mode, and an OCB mode. When the film is used as an optical compensation film or an optical compensation layer, the film may be formed so as to provide retardation corresponding to the alignment mode. Alternatively, the film may be used as a patterned retardation film.

### (Organic Light-Emitting Display Device)

A retardation film and an elliptically polarizing plate according to the present invention can be used for an organic light-emitting display device according to the present invention. The form of the use may be an antireflective film of the organic light-emitting display device.

### EXAMPLES

Hereinafter, the present invention will be described with reference to Examples and Comparative Examples. However, the present invention is obviously not limited to these Examples. Incidentally, “parts” and “%” are based on mass unless otherwise specified.

### (Polymerizable Composition (1))

The compound represented by Formula (2-a-40) (100 parts) was added to 250 parts of cyclopentanone (CPN), subsequently heated at 60° C., and stirred to be dissolved. After completion of the dissolution was observed, the solution was brought back to room temperature, mixed with 5 parts of IRGACURE OXE01 (OXE01, manufactured by BASF), 0.1 parts of p-methoxyphenol (MEHQ), and 0.2 parts of MEGAFACE F-556 (F-556, manufactured by DIC Corporation), and further stirred to obtain a solution. This solution was transparent and uniform. The obtained solution was filtered through a 0.20 μm membrane filter, to obtain Polymerizable composition (1) for an Example.

### (Polymerizable Compositions (2) to (36))

Polymerizable compositions (2) to (34) for Examples and Polymerizable compositions (35) and (36) for Comparative Examples were obtained under the same conditions as in the preparation of Polymerizable composition (1) except that the ratios of compounds were changed as described in Tables below.

The following Tables 1 to 5 describe the specific formulations of Polymerizable compositions (1) to (34) for the present invention and Polymerizable compositions (35) and (36) for Comparative Examples.

TABLE 1

| Polymerizable | | | | | | | | |
|---|---|---|---|---|---|---|---|---|
| composition | (1) | (2) | (3) | (4) | (5) | (6) | (7) | (8) |
| 1-a-90 | | | | | | | | |
| 1-a-92 | | | | | | | | |
| 1-a-93 | | | | | | | | |
| 2-a-40 | 100 | | | | | | | |
| 2-a-42 | | | | | | | | 100 |
| 2-a-46 | | | | | | | | |
| 2-a-47 | | | | | | | | |
| 2-a-48 | | | | | | | | |
| 2-a-49 | | | | | | | | |
| 2-a-50 | | | | | | | | |
| 2-a-51 | | | | | | | | |
| 2-a-52 | | | | | | | | |
| 2-a-53 | | | | | | | | |
| 2-a-54 | | | | | | | | |
| 2-a-55 | | | | | | | | |
| 2-a-56 | | | | | | | | |
| 2-a-57 | | | | | | | | |
| 2-a-59 | | | | | | | | |
| 2-a-60 | | | | | | | | |
| 2-a-62 | | | | | 100 | 95 | | |
| 2-a-63 | | | | | | | 95 | |
| 2-a-66 | | 80 | | | | | | |
| 2-a-68 | | | 100 | 95 | | | | |
| 1-b-1 | | 20 | | | | | | |
| 1-b-2 | | | | | | | | |
| 1-b-3 | | | | | | | | |
| 1-b-5 | | | | 5 | | | 5 | |
| 1-b-27 | | | | | | | | |
| 2-b-1 | | | | | | | | |
| 2-b-19 | | | | | | | | |
| 20-1 | | | | | | | | |
| 2-b-34 | | | | | | | | |
| 10-10 | | | | | | | | |
| 10-32 | | | | | | | | |
| OXE01 | 5 | 5 | 5 | 5 | 5 | 5 | 5 | 5 |
| MEHQ | 0.1 | 0.1 | 0.1 | 0.1 | 0.1 | 0.1 | 0.1 | 0.1 |
| F-556 | 0.2 | 0.2 | 0.2 | 0.2 | 0.2 | 0.2 | 0.2 | 0.2 |
| CPN | 250 | 250 | 250 | 250 | 250 | 250 | 250 | 250 |

TABLE 2

| Polymerizable | | | | | | | | |
|---|---|---|---|---|---|---|---|---|
| composition | (9) | (10) | (11) | (12) | (13) | (14) | (15) | (16) |
| 1-a-90 | | | | | | | | |
| 1-a-92 | | | | | 10 | | | |
| 1-a-93 | | | | | | | | |
| 2-a-40 | | | | | | | | |
| 2-a-42 | | | | | | | | |
| 2-a-46 | 100 | | | | | | | |
| 2-a-47 | | 100 | 95 | | 90 | 45 | 45 | |
| 2-a-48 | | | | 100 | | | | |
| 2-a-49 | | | | | | 45 | 45 | 95 |
| 2-a-50 | | | | | | | | |
| 2-a-51 | | | | | | | | |
| 2-a-52 | | | | | | | | |
| 2-a-53 | | | | | | | | |
| 2-a-54 | | | | | | | | |
| 2-a-55 | | | | | | | | |
| 2-a-56 | | | | | | | | |
| 2-a-57 | | | | | | | | |
| 2-a-59 | | | | | | | | |
| 2-a-60 | | | | | | | | |
| 2-a-62 | | | | | | | | |
| 2-a-63 | | | | | | | | |
| 2-a-66 | | | | | | | | |
| 2-a-68 | | | | | | | | |
| 1-b-1 | | | | | | | | |
| 1-b-2 | | | | | | | | |
| 1-b-3 | | | | | | 10 | 10 | |
| 1-b-5 | | | | | | | | |
| 1-b-27 | | | 5 | | | | | |
| 2-b-1 | | | | | | | | 5 |
| 2-b-19 | | | | | | | | |
| 20-1 | | | | | | | | |
| 2-b-34 | | | | | | | | |
| 10-10 | | | | | | | 0.68 | |
| 10-32 | | | | | | | | |
| OXE01 | 5 | 5 | 5 | 5 | 5 | 5 | 5 | 5 |
| MEHQ | 0.1 | 0.1 | 0 1 | 0.1 | 0.1 | 0.1 | 0.1 | 0.1 |
| F-556 | 0.2 | 0.2 | 0.2 | 0.2 | 0.2 | 0.2 | 0.2 | 0.2 |
| CPN | 250 | 250 | 250 | 250 | 250 | 250 | 250 | 250 |

TABLE 3

| Polymerizable | | | | | | | | |
|---|---|---|---|---|---|---|---|---|
| composition | (17) | (18) | (19) | (20) | (21) | (22) | (23) | (24) |
| 1-a-90 | | | | | | | | |
| 1-a-92 | | | 5 | | | | | |
| 1-a-93 | | | | | | 5 | | |
| 2-a-40 | | | | | | | | |
| 2-a-42 | | | | | | | | |
| 2-a-46 | | | | | | | | |
| 2-a-47 | | | | | | | | |
| 2-a-48 | | | | | | | | |
| 2-a-49 | 95 | 95 | 95 | | | | | |
| 2-a-50 | | | | | | | | |
| 2-a-51 | | | | | | | | |
| 2-a-52 | | | | | | | | |
| 2-a-53 | | | | | | | | |
| 2-a-54 | | | | 85 | | | | |
| 2-a-55 | | | | | 80 | | | |
| 2-a-56 | | | | | | 95 | | |
| 2-a-57 | | | | | | | 85 | |
| 2-a-59 | | | | | | | | 95 |
| 2-a-60 | | | | | | | | |
| 2-a-62 | | | | | | | | |
| 2-a-63 | | | | | | | | |
| 2-a-66 | | | | | | | | |
| 2-a-68 | | | | | | | | |
| 1-b-1 | | | | | | | | |
| 1-b-2 | | | | | 20 | | | |
| 1-b-3 | | | | | | | | |
| 1-b-5 | 5 | 5 | | | | | | |
| 1-b-27 | | | | | | | | |
| 2-b-1 | | | | | | | 15 | |
| 2-b-19 | | | | | | | | 5 |
| 20-1 | | | | | | | | |
| 2-b-34 | | | | | | | | |
| 10-10 | | 0.71 | | | | | | |
| 10-32 | | | | | | | | |
| OXE01 | 5 | 5 | 5 | 5 | 5 | 5 | 5 | 5 |
| MEHQ | 0.1 | 0.1 | 0.1 | 0.1 | 0.1 | 0.1 | 0.1 | 0.1 |
| F-556 | 0.2 | 0.2 | 0.2 | 0.2 | 0.2 | 0.2 | 0.2 | 0.2 |
| CPN | 250 | 250 | 250 | 250 | 250 | 250 | 250 | 250 |

TABLE 4

| Polymerizable | | | | | | | | |
|---|---|---|---|---|---|---|---|---|
| composition | (25) | (26) | (27) | (28) | (29) | (30) | (31) | (32) |
| 1-a-90 | | | | | | | 10 | 10 |
| 1-a-92 | | | | | | | | |
| 1-a-93 | | | | | | | | |
| 2-a-40 | | | | | | | | |
| 2-a-42 | | | | | | | | |
| 2-a-46 | | | | | | | | |
| 2-a-47 | | | | | | | | |
| 2-a-48 | | | | | | | | |
| 2-a-49 | | | | | | | | |
| 2-a-50 | | 90 | | | | | | |
| 2-a-51 | | | 90 | | | | | |
| 2-a-52 | | | | 100 | 50 | 50 | 80 | 80 |
| 2-a-53 | | | | | 45 | 45 | 10 | 10 |
| 2-a-54 | | | | | | | | |
| 2-a-55 | | | | | | | | |
| 2-a-56 | | | | | | | | |
| 2-a-57 | | | | | | | | |
| 2-a-59 | | | | | | | | |
| 2-a-60 | 100 | | | | | | | |
| 2-a-62 | | | | | | | | |
| 2-a-63 | | | | | | | | |
| 2-a-66 | | | | | | | | |
| 2-a-68 | | | | | | | | |
| 1-b-1 | | | | | | | | |
| 1-b-2 | | 10 | | | | | | |
| 1-b-3 | | | 10 | | | | | |
| 1-b-5 | | | | | | | | |
| 1-b-27 | | | | | | | | |
| 2-b-1 | | | | | 5 | 5 | | |
| 2-b-19 | | | | | | | | |
| 20-1 | | | | | | | | |
| 2-b-34 | | | | | | | | |
| 10-10 | | | | | | 0.75 | | |
| 10-32 | | | | | | | | 0.83 |
| OXE01 | 5 | 5 | 5 | 5 | 5 | 5 | 5 | 5 |
| MEHQ | 0.1 | 0.1 | 0.1 | 0.1 | 0.1 | 0.1 | 0.1 | 0.1 |
| F-556 | 0.2 | 0.2 | 0.2 | 0.2 | 0.2 | 0.2 | 0.2 | 0.2 |
| CPN | 250 | 250 | 250 | 250 | 250 | 250 | 250 | 250 |

TABLE 5

| Polymerizable | | | | |
|---|---|---|---|---|
| composition | (33) | (34) | (35) | (36) |
| 1-a-90 | | | | |
| 1-a-92 | | | | |
| 1-a-93 | | | | |
| 2-a-40 | | | | |
| 2-a-42 | | | | |
| 2-a-46 | | | | |
| 2-a-47 | | | | |
| 2-a-48 | | | | |
| 2-a-49 | | | | |
| 2-a-50 | | | | |
| 2-a-51 | | | | |
| 2-a-52 | 60 | 60 | | |
| 2-a-53 | 35 | 35 | | |
| 2-a-54 | | | | |
| 2-a-55 | | | | |
| 2-a-56 | | | | |
| 2-a-57 | | | | |
| 2-a-59 | | | | |
| 2-a-60 | | | | |
| 2-a-62 | | | | |
| 2-a-63 | | | | |
| 2-a-66 | | | | |
| 2-a-68 | | | | |
| 1-b-1 | | | | |
| 1-b-2 | 5 | 5 | | |
| 1-b-3 | | | | |
| 1-b-5 | | | | |
| 1-b-27 | | | | |
| 2-b-1 | | | | |
| 2-b-19 | | | | |
| 20-1 | | | 90 | 90 |
| 2-b-34 | | | 10 | 10 |
| 10-10 | | | | 0.75 |
| 10-32 | | 0.8 | | |
| OXE01 | 5 | 5 | 15 | 5 |
| MEHQ | 0.1 | 0.1 | 0.1 | 0.1 |
| F-556 | 0.2 | 0.2 | | |
| CPN | 250 | 250 | 250 | 250 |

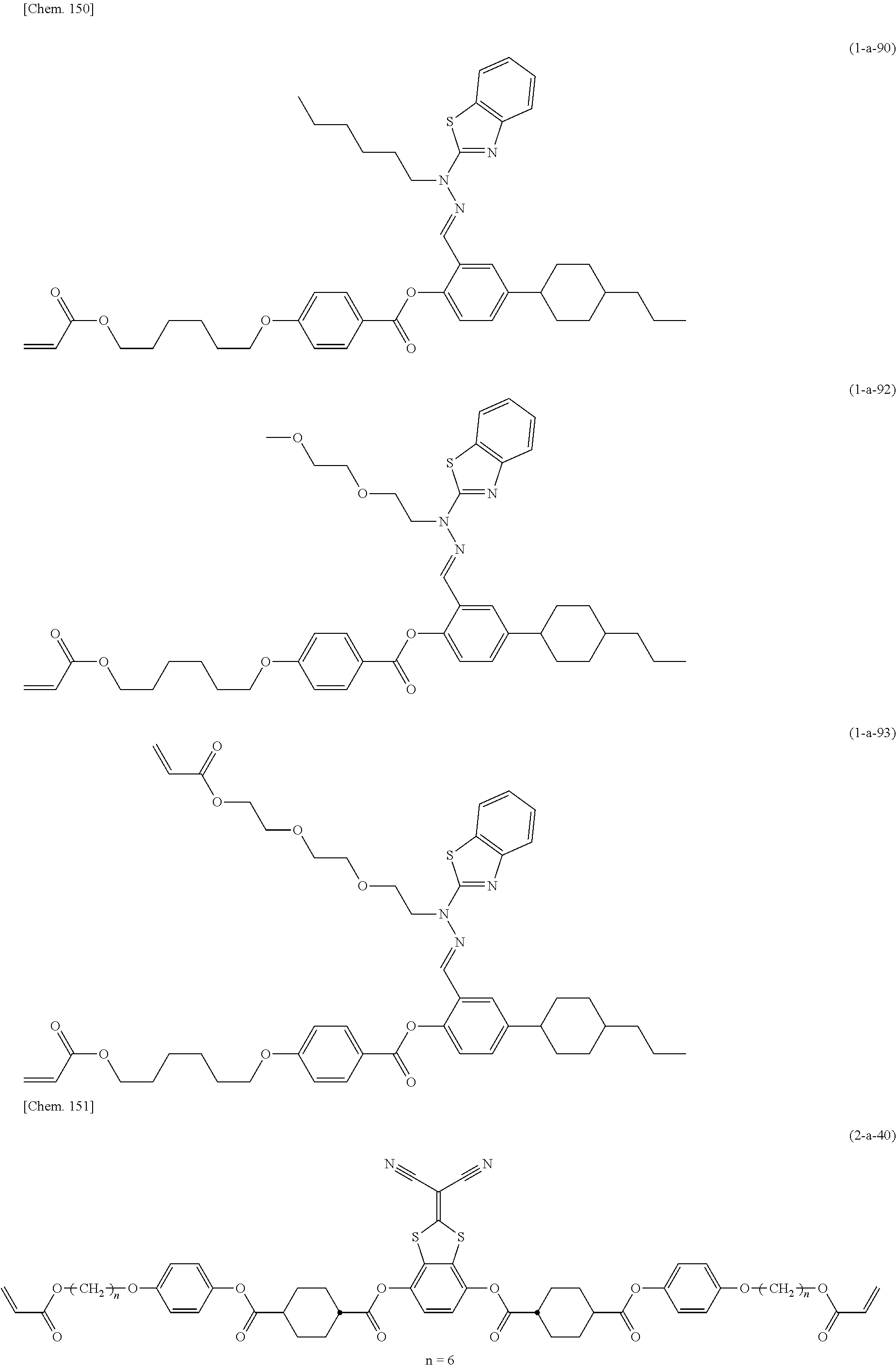

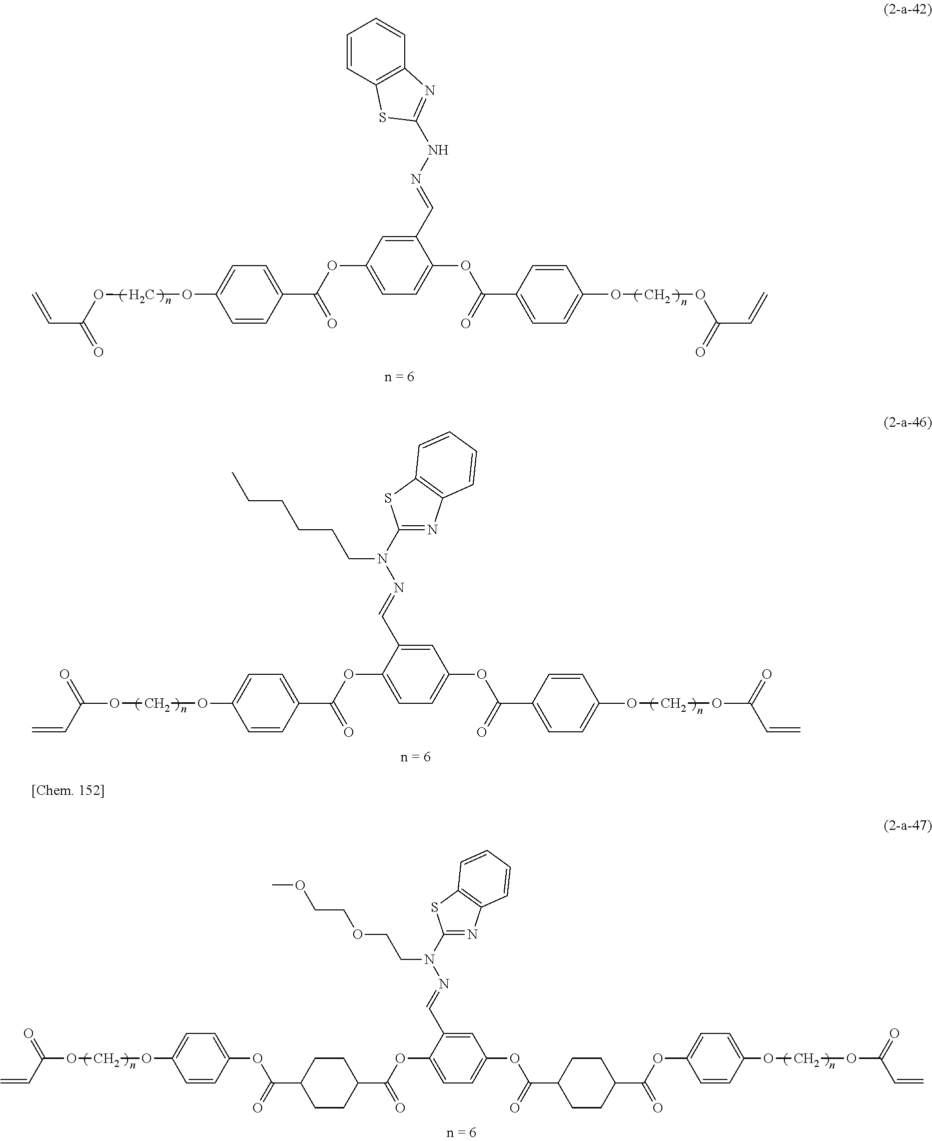

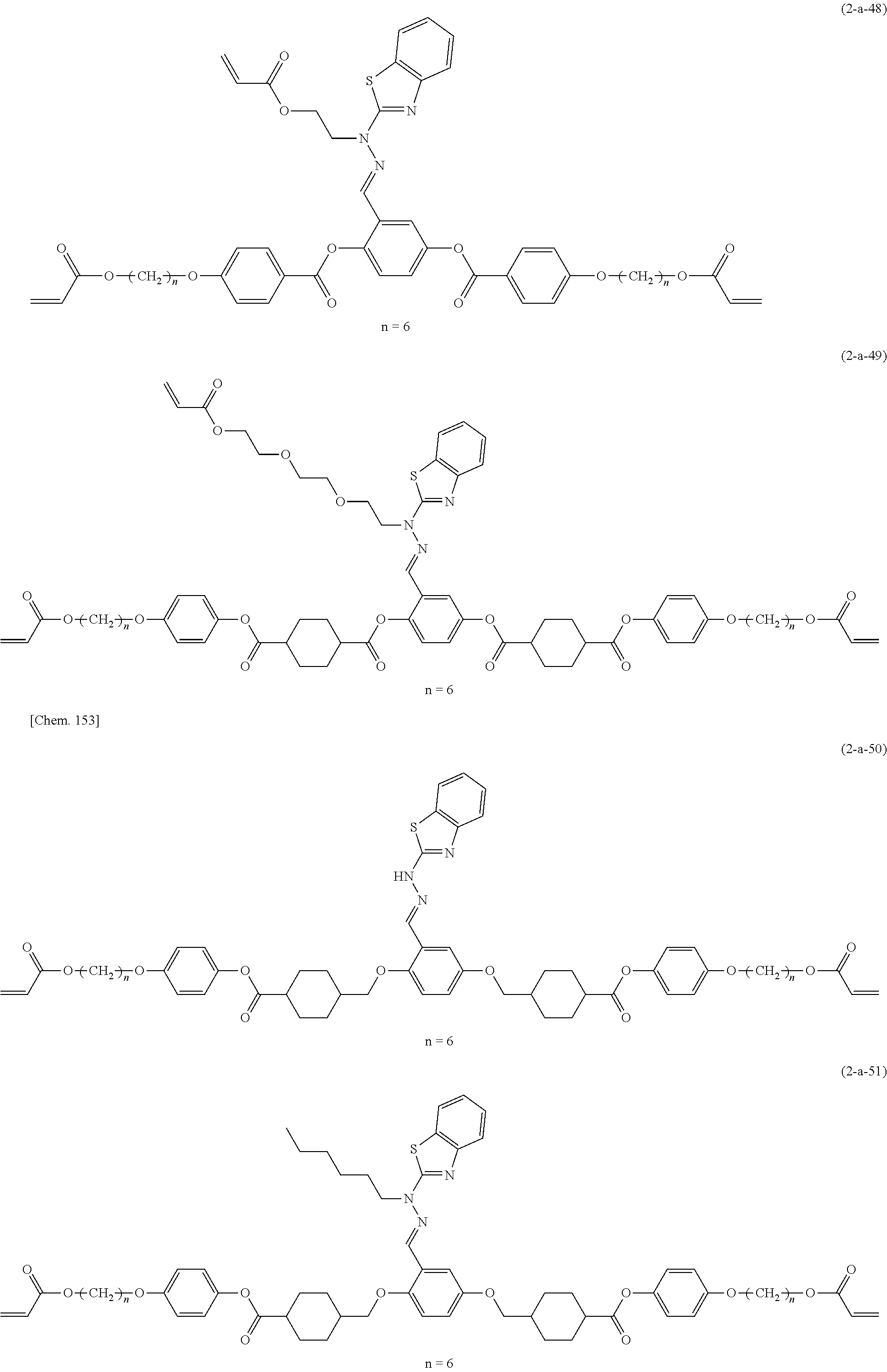

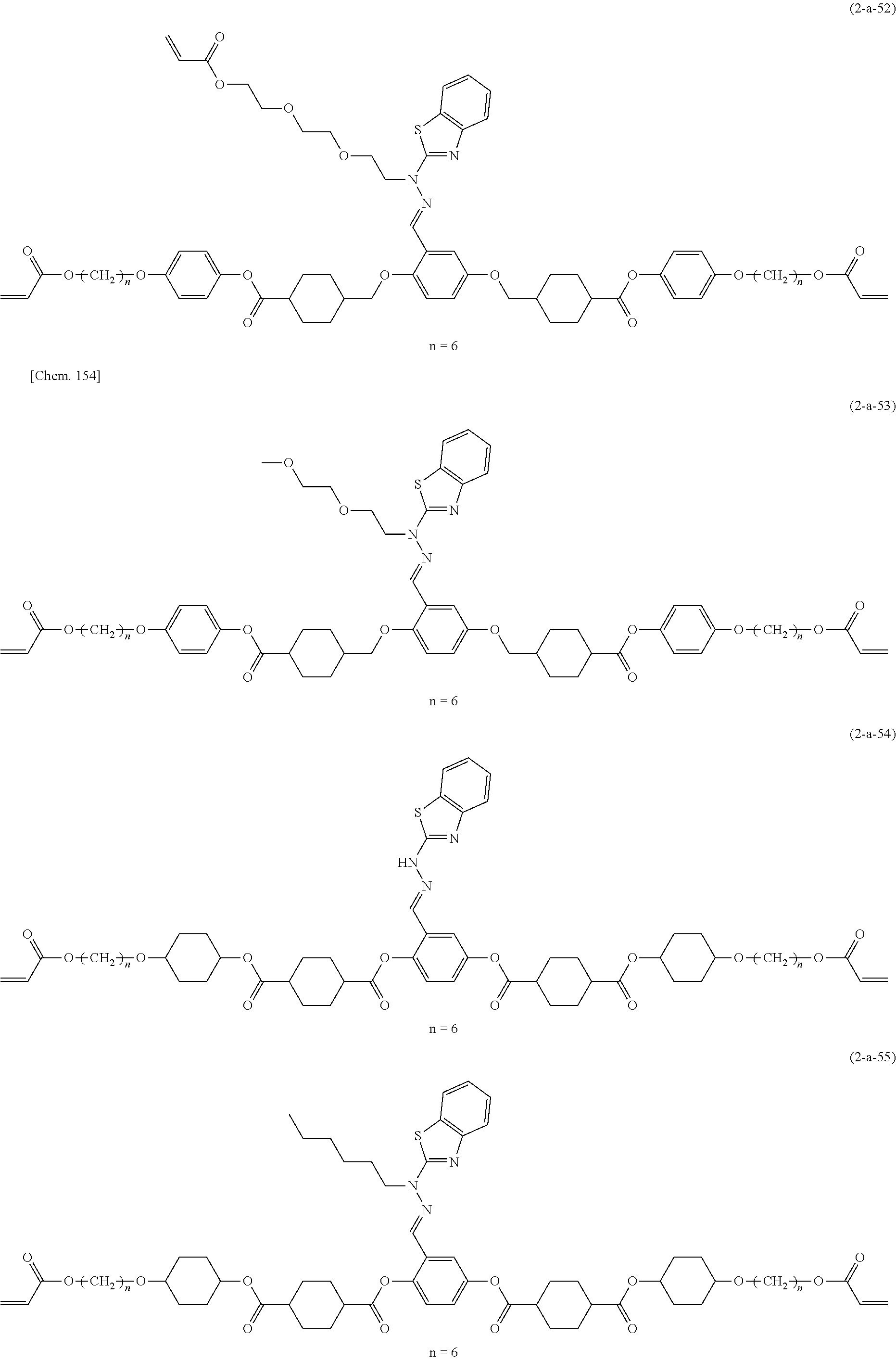

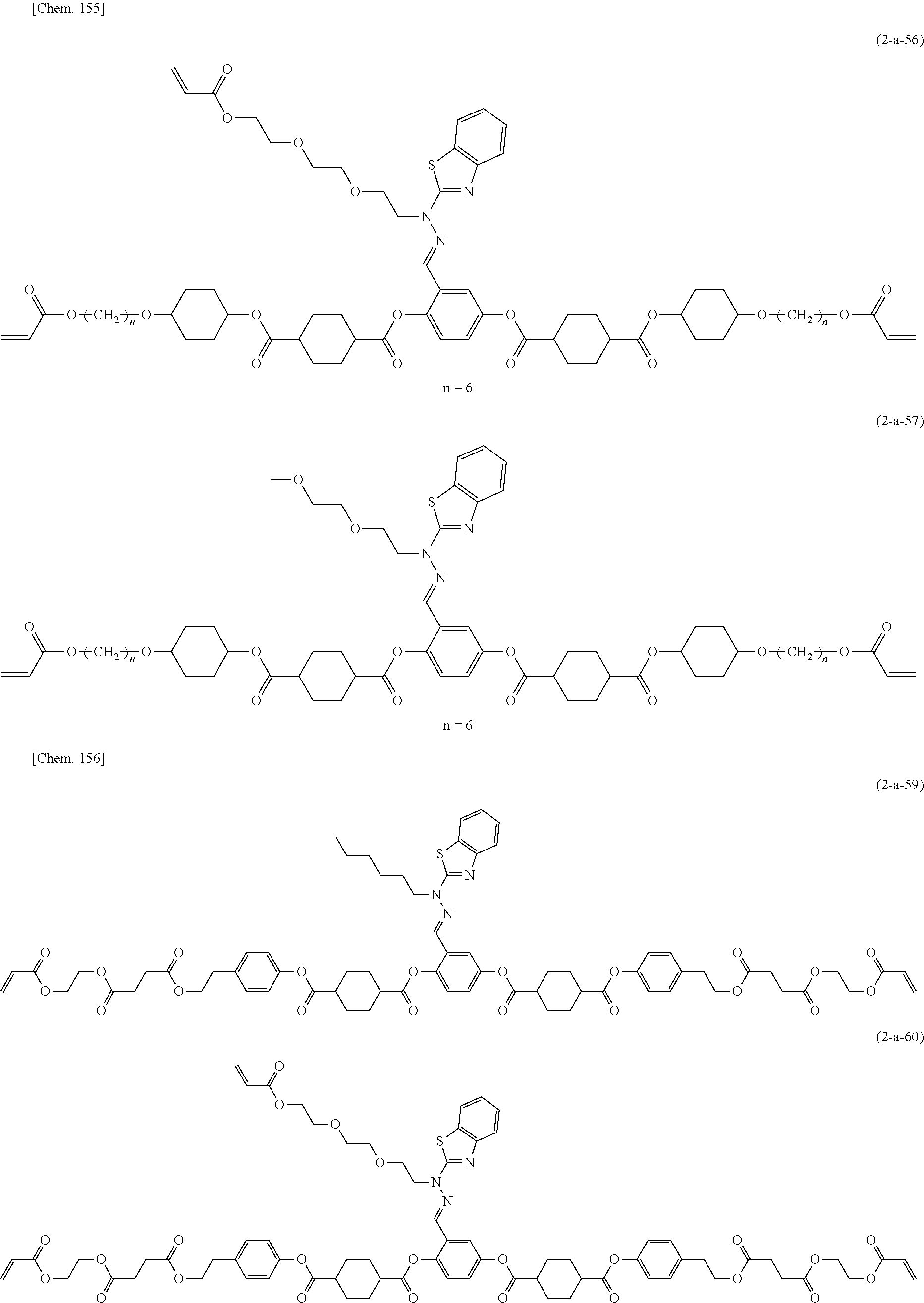

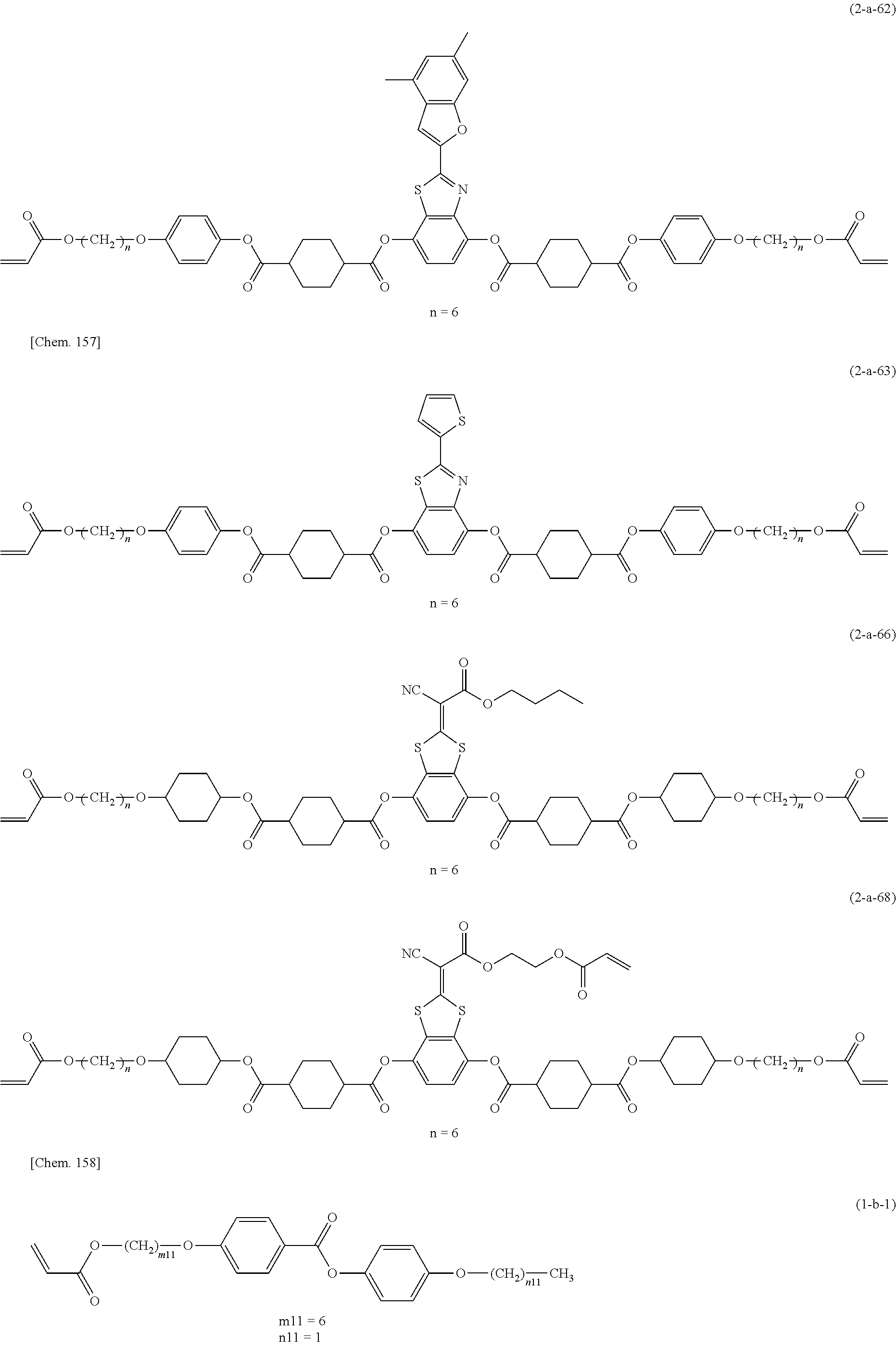

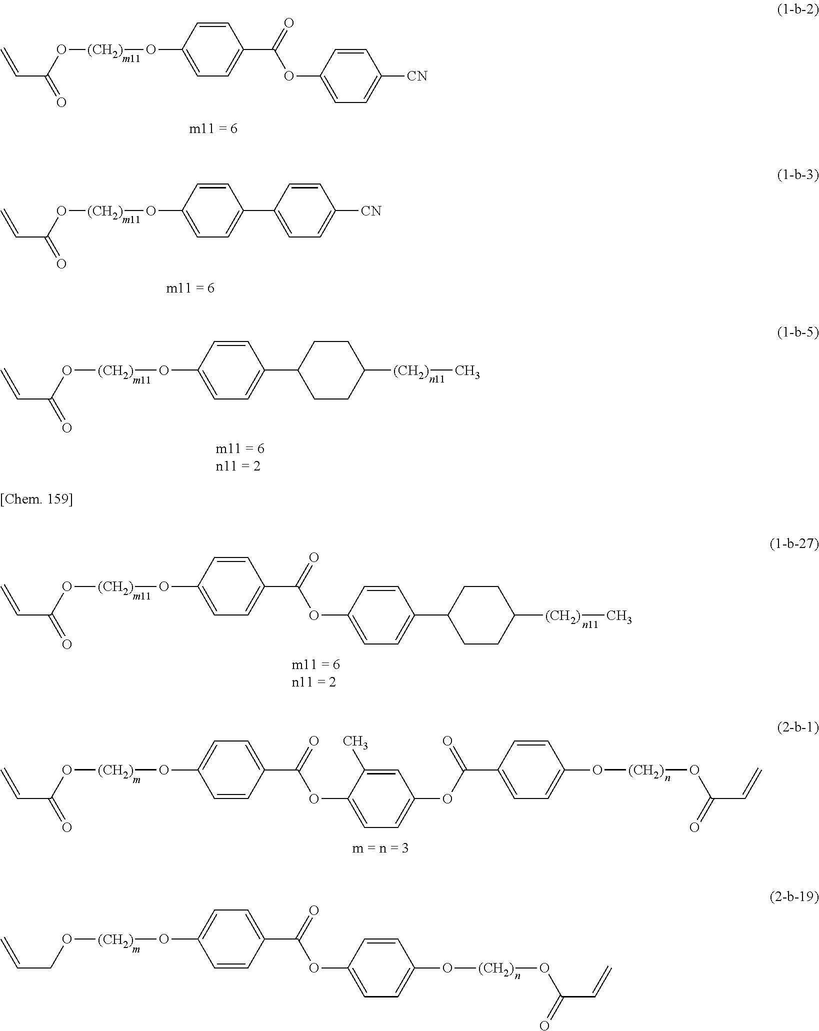

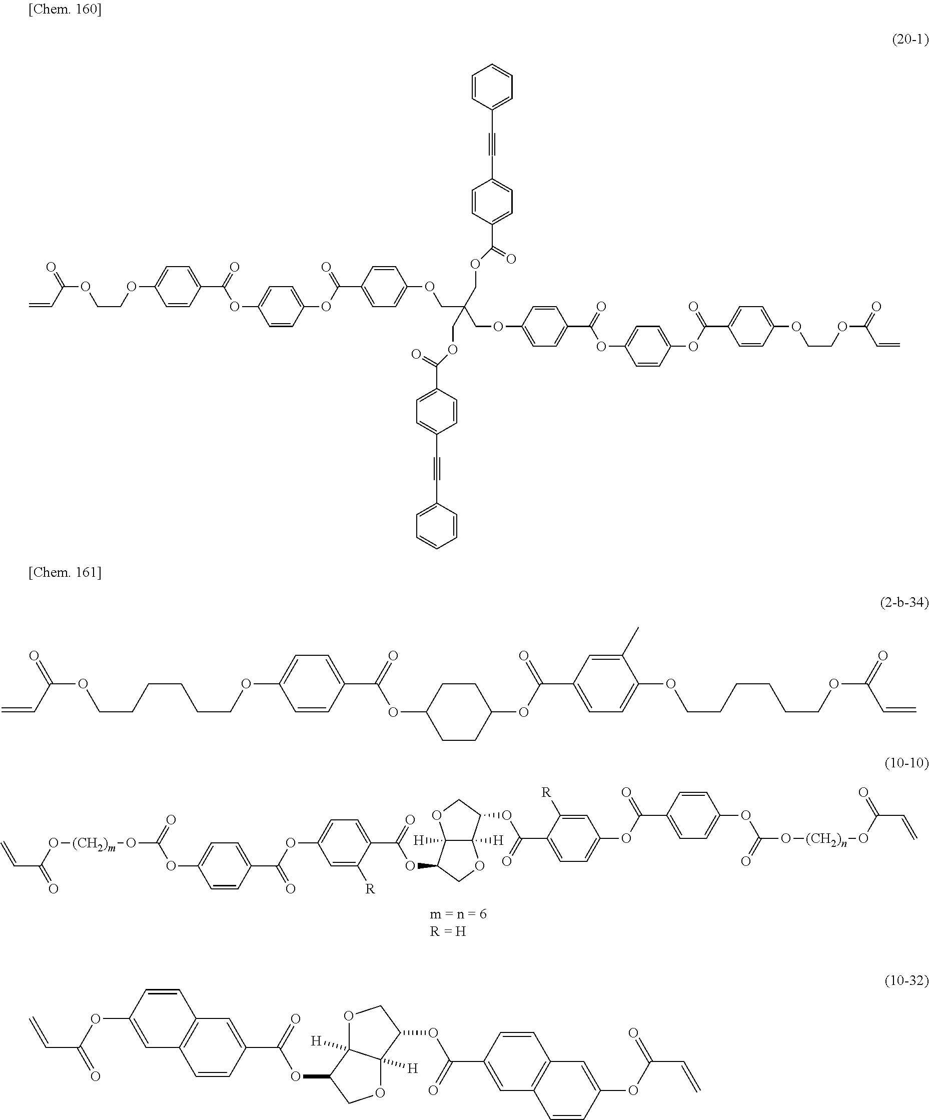

The above-described compounds have the following Re (450 nm)/Re (550 nm). Formula (1-a-90): 0.76, Formula (1-a-92): 0.83, Formula (1-a-93): 0.85, Formula (2-a-40: 0.83, Formula (2-a-42): 0.83, Formula (2-a-46): 0.84, Formula (2-a-47): 0.80, Formula (2-a-48): 0.82, Formula (2-a-49): 0.81, Formula (2-a-50): 0.79, Formula (2-a-51): 0.78, Formula (2-a-52): 0.82, Formula (2-a-53): 0.75, Formula (2-a-54): 0.77, Formula (2-a-55): 0.72, Formula (2-a-56): 0.83, Formula (2-a-57): 0.72, Formula (2-a-59): 0.83, Formula (2-a-60): 0.84, Formula (2-a-62): 0.83, Formula (2-a-63): 0.82, Formula (2-a-66): 0.77, and Formula (2-a-68).

### (Evaluation of Retardation Films Using Polymerizable Compositions (1) to (36))

The compositions of the above-described Polymerizable compositions (1) to (36) were used under the following conditions to form Retardation films (1) to (34) (Examples 1 to 34), Retardation film (35) (Comparative Example 1), and Retardation film (36) (Comparative Example 2).

A polyethylene naphthalate film substrate (PEN manufactured by TEIJIN LIMITED) was spin-coated with a 3% polyvinyl alcohol solution (the solvent was a mixture of pure water and ethanol in a weight ratio of 1:1); the solution was dried at 120° C. for 5 minutes, and then subjected to rubbing treatment using a rayon cloth. The PVA film was coated with each of Polymerizable compositions (1) to (36) with a spin coater such that a retardation at 550 nm was controlled to be 138±5 nm; the composition was then dried at 80° C. for 3 minutes, and left at 60° C. for 5 minutes. The resultant applied polymerizable composition was irradiated with ultraviolet light having a UVB energy of 1 J/cm². The resultant retardation film was separated from the substrate to obtain a retardation thin film.

Table 6 describes, for each of retardation films, the value of Re(450 nm)/Re(550 nm) in (Formula 1-1), the tilt angle of PEN-substrate-side liquid crystal, the tilt angle of air-interface-side liquid crystal, and the twist angle. Incidentally, the value in (Formula 1-1) was measured with a retardation evaluation system RET-100 (manufactured by Otsuka Electronics Co., Ltd.). The tilt angles were obtained by measurements with a tilt-angle measurement system (AxoScan, manufactured by AXOMRETRICS Inc.), and calculation by fitting. For the twist angle, the relation of PC value (P: pitch length, C: addition concentration) between the polymerizable liquid-crystal composition and a chiral agent was determined in advance, and the twist angle was calculated from the amount of chiral compound added.

The retardation thin film and a commercially available polarizing plate were bonded together such that the substrate-side surface of the retardation film was in contact with the polarizing plate, and the angle (bonding angle) between the direction of slow axis of the substrate-side surface and the absorption axis of the polarizing plate was set to a value in Table 6 or 7, to thereby produce an elliptically polarizing plate.

TABLE 6

| | | | | Tilt angle | |
|---|---|---|---|---|---|
| | | | Tilt angle | (air- | |
| | Polymerizable | (Formula | (substrate | interface | Twist |
| | composition | 1-1) | side) | side) | angle |
| Film (1) | (1) | 0.840 | 1° | 50° | 0° |
| Film (2) | (2) | 0.846 | 1° | 55° | 0° |
| Film (3) | (3) | 0.840 | 1° | 50° | 0° |
| Film (4) | (4) | 0.854 | 1° | 50° | 0° |
| Film (5) | (5) | 0.830 | 1° | 55° | 0° |
| Film (6) | (6) | 0.845 | 1° | 45° | 0° |
| Film (7) | (7) | 0.835 | 1° | 50° | 0° |
| Film (8) | (8) | 0.830 | 1° | 45° | 0° |
| Film (9) | (9) | 0.840 | 1° | 45° | 0° |
| Film (10) | (10) | 0.800 | 1° | 45° | 0° |
| Film (11) | (11) | 0.816 | 1° | 50° | 0° |
| Film (12) | (12) | 0.820 | 1° | 50° | 0° |
| Film (13) | (13) | 0.803 | 1° | 55° | 0° |
| Film (14) | (14) | 0.845 | 1° | 50° | 0° |
| Film (15) | (15) | 0.845 | 1° | 50° | 55° |
| Film (16) | (16) | 0.835 | 1° | 50° | 0° |
| Film (17) | (17) | 0.830 | 1° | 50° | 0° |
| Film (18) | (18) | 0.830 | 1° | 55° | 55° |
| Film (19) | (19) | 0.811 | 1° | 50° | 0° |
| Film (20) | (20) | 0.821 | 1° | 45° | 0° |

TABLE 7

| | | | | Tilt angle | |
|---|---|---|---|---|---|
| | | | Tilt angle | (air- | |
| | Polymerizable | (Formula | (substrate | interface | Twist |
| | composition | 1-1) | side) | side) | angle |
| Film (21) | (21) | 0.816 | 1° | 50° | 0° |
| Film (22) | (22) | 0.831 | 1° | 50° | 0° |
| Film (23) | (23) | 0.807 | 1° | 50° | 0° |
| Film (24) | (24) | 0.849 | 1° | 50° | 0° |
| Film (25) | (25) | 0.840 | 1° | 45° | 0° |
| Film (26) | (26) | 0.831 | 1° | 50° | 0° |
| Film (27) | (27) | 0.822 | 1° | 50° | 0° |
| Film (28) | (28) | 0.820 | 1° | 50° | 0° |
| Film (29) | (29) | 0.813 | 1° | 50° | 0° |
| Film (30) | (30) | 0.813 | 1° | 55° | 55° |
| Film (31) | (31) | 0.807 | 1° | 50° | 0° |
| Film (32) | (32) | 0.807 | 1° | 55° | 55° |
| Film (33) | (33) | 0.815 | 1° | 50° | 0° |
| Film (34) | (34) | 0.815 | 1° | 55° | 55° |
| Film (35) | (35) | 0.885 | 1° | 50° | 0° |
| Film (36) | (36) | 0.885 | 1° | 50° | 55° |

The retardation thin film and a commercially available polarizing plate were bonded together such that the angle between the direction of the slow axis of the substrate-side surface and the absorption axis of the polarizing plate, and the angle between the slow axis of the air-interface-side surface and the absorption axis of the polarizing plate were set to values in Table 8 or 9, and the substrate-side surface of the retardation film was bonded to the polarizing plate, to thereby produce an elliptically polarizing plate.

TABLE 8

| | | Angle | Angle |
|---|---|---|---|
| | | between | between |
| | | direction of | slow axis of |
| | | slow axis | air- |
| | | of substrate- | interface-side |
| | | side surface and | surface and |
| | | absorption | absorption |
| | | axis of | axis of |
| | | polarizing | polarizing |
| | Film | plate | plate |
| Elliptically polarizing plate (1) | (1) | 45° | 45° |
| Elliptically polarizing plate (2) | (2) | 45° | 45° |
| Elliptically polarizing plate (3) | (3) | 45° | 45° |
| Elliptically polarizing plate (4) | (4) | 45° | 45° |
| Elliptically polarizing plate (5) | (5) | 45° | 45° |
| Elliptically polarizing plate (6) | (6) | 45° | 45° |
| Elliptically polarizing plate (7) | (7) | 45° | 45° |
| Elliptically polarizing plate (8) | (8) | 45° | 45° |
| Elliptically polarizing plate (9) | (9) | 45° | 45° |
| Elliptically polarizing plate (10) | (10) | 45° | 45° |
| Elliptically polarizing plate (11) | (11) | 45° | 45° |
| Elliptically polarizing plate (12) | (12) | 45° | 45° |
| Elliptically polarizing plate (13) | (13) | 45° | 45° |
| Elliptically polarizing plate (14) | (14) | 45° | 45° |
| Elliptically polarizing plate (15) | (15) | 85° | 30° |
| Elliptically polarizing plate (16) | (16) | 45° | 45° |
| Elliptically polarizing plate (17) | (17) | 45° | 45° |
| Elliptically polarizing plate (18) | (18) | 85° | 30° |
| Elliptically polarizing plate (19) | (19) | 45° | 45° |
| Elliptically polarizing plate (20) | (20) | 45° | 45° |

TABLE 9

| | | Angle | Angle |
|---|---|---|---|
| | | between | between |
| | | direction of | slow axis of |
| | | slow axis | air- |
| | | of substrate- | interface-side |
| | | side surface | surface and |
| | | and absorption | absorption |
| | | axis of | axis of |
| | | polarizing | polarizing |
| | Film | plate | plate |
| Elliptically polarizing plate (21) | (21) | 45° | 45° |
| Elliptically polarizing plate (22) | (22) | 45° | 45° |
| Elliptically polarizing plate (23) | (23) | 45° | 45° |
| Elliptically polarizing plate (24) | (24) | 45° | 45° |
| Elliptically polarizing plate (25) | (25) | 45° | 45° |
| Elliptically polarizing plate (26) | (26) | 45° | 45° |
| Elliptically polarizing plate (27) | (27) | 45° | 45° |
| Elliptically polarizing plate (28) | (28) | 45° | 45° |
| Elliptically polarizing plate (29) | (29) | 45° | 45° |
| Elliptically polarizing plate (30) | (30) | 85° | 30° |
| Elliptically polarizing plate (31) | (31) | 45° | 45° |
| Elliptically polarizing plate (32) | (32) | 85° | 30° |
| Elliptically polarizing plate (33) | (33) | 45° | 45° |
| Elliptically polarizing plate (34) | (34) | 85° | 30° |
| Elliptically polarizing plate (35) | (35) | 45° | 45° |
| Elliptically polarizing plate (36) | (36) | 85° | 30° |

### Examples 1 to 34 and Comparative Examples 1 and 2

The elliptically polarizing plates produced in the above-described manner were evaluated for viewability in accordance with the grading system below.

### (Evaluation of Viewability)

### (Color Cast)

Evaluation of color cast was performed in the following manner. In a GALAXY SII having an organic EL panel and manufactured by SAMSUNG, the originally used circularly polarizing plate was replaced by the above-described elliptically polarizing plate, and the degrees of tinting to the black color when viewed from the front or viewed obliquely at 450 were evaluated in accordance with the following grading system.

A: Substantially no tinting due to reflected light is recognized. (Acceptable)

B: Very slight tinting due to reflected light is recognized, but does not cause any practical problems. (Acceptable)

C: Slight tinting due to reflected light is recognized, but does not cause any practical problems. (Acceptable)

D: Tinting due to reflected light is recognized, but is acceptable in some applications. (Acceptable)

E: Strong tinting due to reflected light is recognized, and is not acceptable.

The elliptically polarizing plate having been used was left in a thermostat at 80° C. for 500 hours, and then evaluated for color cast also in accordance with the above-described grading system.

The results are described in Table 10 and Table 11.

TABLE 10

| | | | | After being | After being |
|---|---|---|---|---|---|
| | Elliptically | | | left at high | left at high |
| | polarizing | Initial | Initial | temperature | temperature |
| | plate | Front | 45° | Front | 45° |
| Example 1 | (1) | A | B | C | D |
| Example 2 | (2) | A | B | B | C |
| Example 3 | (3) | A | B | A | C |
| Example 4 | (4) | A | B | A | B |
| Example 5 | (5) | A | B | C | D |
| Example 6 | (6) | A | B | B | C |
| Example 7 | (7) | A | B | B | C |
| Example 8 | (8) | A | B | C | D |
| Example 9 | (9) | A | B | C | D |
| Example 10 | (10) | A | B | C | D |
| Example 11 | (11) | A | B | B | C |
| Example 12 | (12) | A | B | A | C |
| Example 13 | (13) | A | B | B | C |
| Example 14 | (14) | A | B | A | B |
| Example 15 | (15) | A | A | A | A |
| Example 16 | (16) | A | B | A | C |
| Example 17 | (17) | A | B | A | B |
| Example 18 | (18) | A | A | A | A |
| Example 19 | (19) | A | B | A | B |
| Example 20 | (20) | A | B | B | C |

TABLE 11

| | | | | After being | After being |
|---|---|---|---|---|---|
| | Elliptically | | | left at high | left at high |
| | polarizing | Initial | Initial | temperature | temperature |
| | plate | Front | 45° | Front | 45° |
| Example 21 | (21) | A | B | B | C |
| Example 22 | (22) | A | B | A | B |
| Example 23 | (23) | A | B | B | D |
| Example 24 | (24) | A | B | B | D |
| Example 25 | (25) | A | B | A | C |
| Example 26 | (26) | A | B | B | C |
| Example 27 | (27) | A | B | B | C |
| Example 28 | (28) | A | B | A | C |
| Example 29 | (29) | A | B | A | C |
| Example 30 | (30) | A | A | A | B |
| Example 31 | (31) | A | B | A | B |
| Example 32 | (32) | A | A | A | A |
| Example 33 | (33) | A | B | A | B |
| Example 34 | (34) | A | A | A | A |
| Comparative | (35) | A | B | E | E |
| Example 1 | | | | | |
| Comparative | (36) | A | A | E | E |
| Example 2 | | | | | |

The above-described results have demonstrated that, compared with the configurations of Comparative Examples, the configurations of Examples provide good color cast after being left at the high temperature.

1. A retardation film comprising a retardation layer, wherein the optical film satisfies (Formula 1-1),
Re(450)/Re(550)<1 (Formula 1-1)
(where Re(450) represents an in-plane retardation at a wavelength of 450 nm, and Re(550) represents an in-plane retardation at a wavelength of 550 nm),
the retardation layer is formed of a material that is a polymerizable composition containing at least one polymerizable liquid-crystal compound selected from the group consisting of General formulas (1) to (7) below, and
the retardation layer has a hybrid structure, 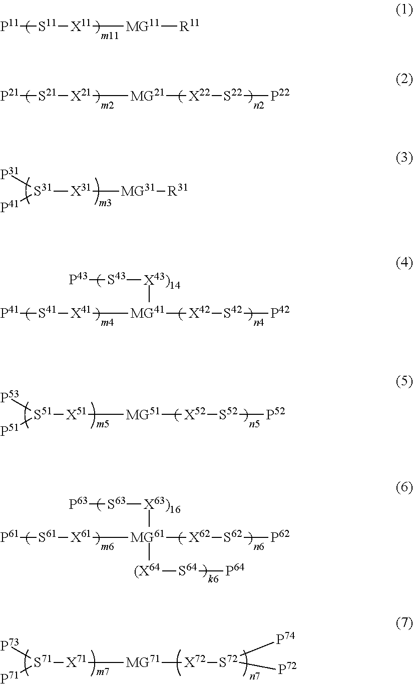
(where P¹¹ to P⁷⁴ represent a polymerizable group,
S¹¹ to S⁷² represent a spacer group or a single bond; when a plurality of S¹¹'s to S⁷²'s are present, they may be the same or different,
X¹ to X⁷² represent —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C≡C—, or a single bond; when a plurality of X¹¹'s to X⁷'s are present, they may be the same or different (provided that each of P—(S—X)— bonds does not include —O—O—),
MG¹¹ to MG⁷¹ each independently represent Formula (a), 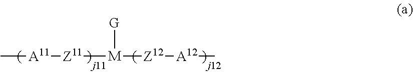
(where
A¹¹ and A¹² each independently represent a 1,4-phenylene group, a 1,4-cyclohexylene group, a pyridine-2,5-diyl group, a pyrimidine-2,5-diyl group, a naphthalene-2,6-diyl group, a naphthalene-1,4-diyl group, a tetrahydronaphthalene-2,6-diyl group, a decahydronaphthalene-2,6-diyl group, or a 1,3-dioxane-2,5-diyl group; these groups may be unsubstituted or may be substituted by at least one L¹; when a plurality of A¹¹'s and/or A¹²'s are present, they may be the same or different,
Z¹¹ and Z¹² each independently represent —O—, —S—, —OCH₂—, —CH₂O—, —CH₂CH₂—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—, —N═CH—, —CH═N—N═CH—, —CF═CF—, —C≡C—, or a single bond; when a plurality of Z¹¹'s and/or Z¹²'s are present, they may be the same or different,
M represents a group selected from Formula (M-1) to Formula (M-11) below, 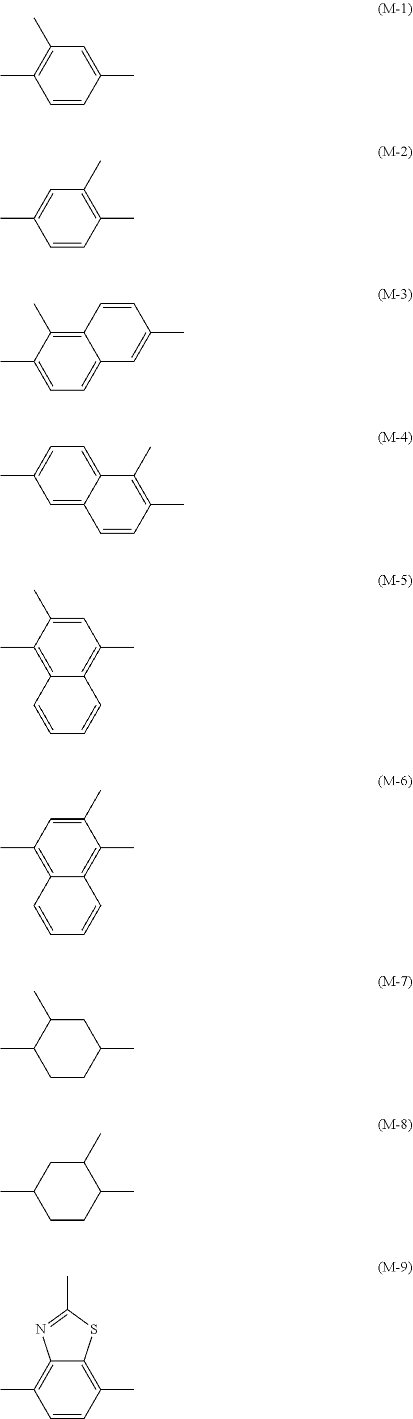 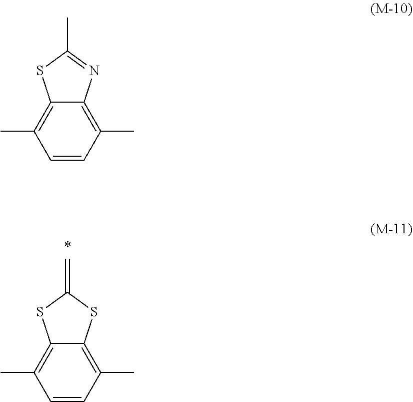
these groups may be unsubstituted or may be substituted by at least one L¹,
G represents Formula (G-1) to Formula (G-6) below, 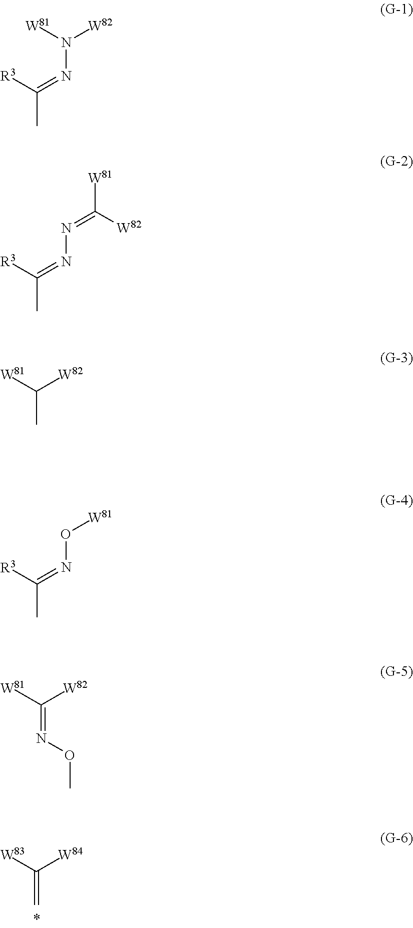
(where R³ represents a hydrogen atom or an alkyl group having 1 to 20 carbon atoms; the alkyl group may be linear or branched; any hydrogen atom in the alkyl group may be substituted by a fluorine atom; one —CH₂— or non-adjacent two or more —CH₂— in the alkyl group may each be independently substituted by —O—, —S—, —CO—, —COO—, —OCO—, —CO—S—, —S—CO—, —O—CO—O—, —CO—NH—, —NH—CO—, or —C═C—,
W⁸¹ represents a group having 5 to 30 carbon atoms and having at least one aromatic group, and may be unsubstituted or may be substituted by at least one L¹,
W⁸² represents a hydrogen atom or an alkyl group having 1 to 20 carbon atoms; the alkyl group may be linear or branched; any hydrogen atom in the alkyl group may be substituted by a fluorine atom and/or —OH; one —CH₂— or non-adjacent two or more —CH₂— in the alkyl group may each be independently substituted by —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, or —C═C—; W⁸² may be defined as with W⁸¹; W⁸¹ and W⁸² may be linked together to form a single ring structure; W⁸² may represent a group represented by P⁸—(S⁸—X⁸)ⱼ— where P⁸ represents a polymerizable group, S⁸ represents a spacer group or a single bond, when a plurality of S⁸'s are present, they may be the same or different, X⁸ represents —O—, —S—, —OCH₂—, —CH₂O—, —CO—, —COO—, —OCO—, —CO—S—, —S—CO—, —O—CO—O—, —CO—NH—, —NH—CO—, —SCH₂—, —CH₂S—, —CF₂O—, —OCF₂—, —CF₂S—, —SCF₂—, —CH═CH—COO—, —CH═CH—OCO—, —COO—CH═CH—, —OCO—CH═CH—, —COO—CH₂CH₂—, —OCO—CH₂CH₂—, —CH₂CH₂—COO—, —CH₂CH₂—OCO—, —COO—CH₂—, —OCO—CH₂—, —CH₂—COO—, —CH₂—OCO—, —CH═CH—, —N═N—, —CH═N—N═CH—, —CF═CF—, —C═C—, or a single bond, when a plurality of X⁸'s are present, they may be the same or different (provided that P⁸—(S⁸—X⁸)ⱼ— does not include any —O—O— bond), j represents an integer of 0 to 10,
W⁸³ and W⁸⁴ each independently represent a halogen atom, a cyano group, a hydroxy group, a nitro group, a carboxyl group, a carbamoyloxy group, an amino group, a sulfamoyl group, a group having 5 to 30 carbon atoms and having at least one aromatic group, an alkyl group having 1 to 20 carbon atoms, a cycloalkyl group having 3 to 20 carbon atoms, an alkenyl group having 2 to 20 carbon atoms, a cycloalkenyl group having 3 to 20 carbon atoms, an alkoxy group having 1 to 20 carbon atoms, an acyloxy group having 2 to 20 carbon atoms, or an alkylcarbonyloxy group having 2 to 20 carbon atoms; in the alkyl group, cycloalkyl group, alkenyl group, cycloalkenyl group, alkoxy group, acyloxy group, and alkylcarbonyloxy group, one —CH₂— or non-adjacent two or more —CH₂— may each be independently substituted by —O—, —S—, —CO—, —COO—, —OCO—, —CO—S—, —S—CO—, —O—CO—O—, —CO—NH—, —NH—CO—, or —C═C—; provided that, when M described above is selected from Formula (M-1) to Formula (M-10) above, G is selected from Formula (G-1) to Formula (G-5); when M is represented by Formula (M-11), G is represented by Formula (G-6),
L¹ represents a fluorine atom, a chlorine atom, a bromine atom, an iodine atom, a pentafluorosulfuranyl group, a nitro group, an isocyano group, an amino group, a hydroxyl group, a mercapto group, a methylamino group, a dimethylamino group, a diethylamino group, a diisopropylamino group, a trimethylsilyl group, a dimethylsilyl group, a thioisocyano group, or an alkyl group having 1 to 20 carbon atoms; the alkyl group may be linear or branched; any hydrogen atom may be substituted by a fluorine atom; one —CH₂— or non-adjacent two or more —CH₂— in the alkyl group may each be independently substituted by a group selected from —O—, —S—, —CO—, —COO—, —OCO—, —CO—S—, —S—CO—, —O—CO—O—, —CO—NH—, —NH—CO—, —CH═CH—COO—, —CH═CH—OCO—, —COO—CH═CH—, —OCO—CH═CH—, —CH═CH—, —CF═CF—, and —C═C—; when a plurality of L¹'s are present in a compound, they may be the same or different,
j11 represents an integer of 1 to 5, j12 represents an integer of 1 to 5, provided that j11+j12 is an integer of 2 to 5), R¹¹ and R³¹ represent a hydrogen atom, a fluorine atom, a chlorine atom, a bromine atom, an iodine atom, a pentafluorosulfuranyl group, a cyano group, a nitro group, an isocyano group, a thioisocyano group, or an alkyl group having 1 to 20 carbon atoms; the alkyl group may be linear or branched; any hydrogen atom in the alkyl group may be substituted by a fluorine atom; one —CH₂— or non-adjacent two or more —CH₂— in the alkyl group may each be independently substituted by —O—, —S—, —CO—, —COO—, —OCO—, —CO—S—, —S—CO—, —O—CO—O—, —CO—NH—, —NH—CO—, or —C≡C—; m11 represents an integer of 0 to 8; and m2 to m7, n2 to n7, l4 to l6, and k6 each independently represent an integer of 0 to 5).

2. The retardation film according to claim 1, wherein the polymerizable groups P¹¹ to P⁷⁴ are each represented by any one of General formulas (P-1) to (P-20).

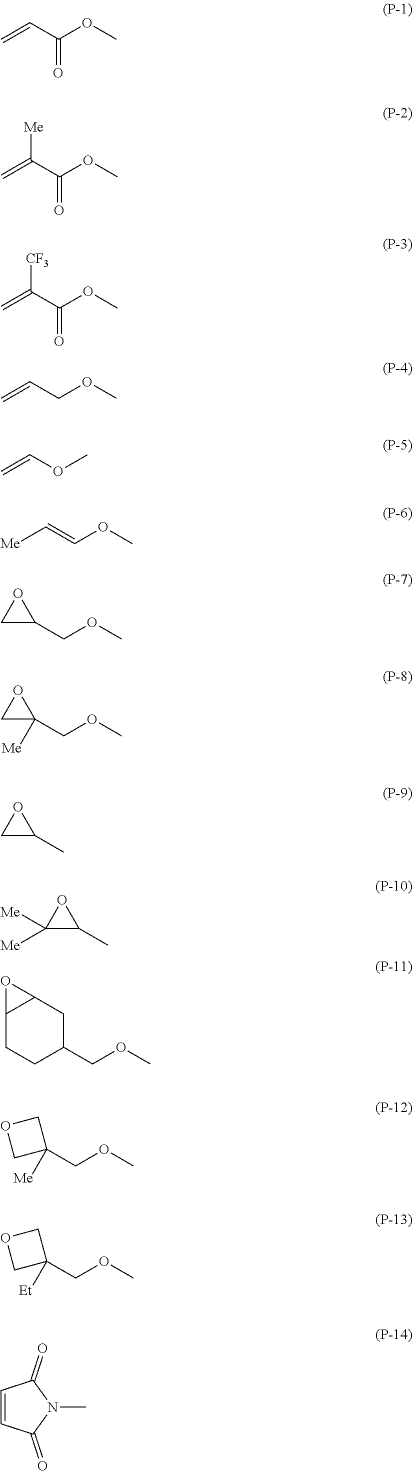

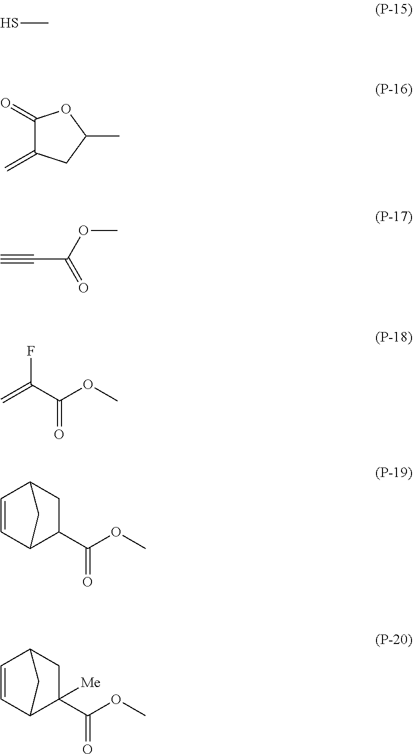

3. The retardation film according to claim 1, wherein the polymerizable composition contains a chiral compound.

4. The retardation film according to claim 3, wherein the chiral compound is a polymerizable chiral compound.

5. The retardation film according to claim 1, wherein a liquid-crystal composition of the retardation film has a tilt angle of 0° to 200 for one of surfaces of the retardation film, and has a tilt angle of 450 to 900 for another one of the surfaces.

6. The retardation film according to claim 1, wherein the retardation film has a twist angle of 250 to 80°.

7. An elliptically polarizing plate comprising the retardation film according to claim 1 and a polarizing plate that are laminated together.

8. A display device comprising the retardation film according to claim 1.

9. A display device comprising the elliptically polarizing plate according to claim 7.

10. An organic light-emitting display device comprising the elliptically polarizing plate according to claim 7.
